(19) United States
(12) Patent Application Publication
(10) Pub. No.: US 2023/0232704 A1
(43) Pub. Date: Jul. 20, 2023

(54) LIGHT EMITTING DEVICE AND ORGANOMETALLIC COMPOUND FOR THE LIGHT EMITTING DEVICE

(71) Applicants: Samsung Display Co., Ltd., Yongin-si (KR); INDUSTRY-ACADEMIC COOPERATION FOUNDATION GYEONGSANG NATIONAL UNIVERSITY, Jinju-si (KR)

(72) Inventors: JUNGHOON HAN, Seoul (KR); Yun-Hi KIM, Jinju-si (KR); Soon-Ki KWON, Jinju-si (KR); SOO-BYUNG KO, Yongin-si (KR); Gyeong Seok LEE, Sacheon-si (KR)

(21) Appl. No.: 17/992,764

(22) Filed: Nov. 22, 2022

(30) Foreign Application Priority Data
Jan. 17, 2022 (KR) 10-2022-0006869

(51) Int. Cl. H01L 51/00; C07F 15/00

(52) U.S. Cl. CPC H01L 51/0087; H01L 51/0094; H01L 51/0072; H01L 51/0073; H01L 51/0067; H01L 51/0074; H01L 51/0064; C07F 15/0086; C07B 2200/05

(57) ABSTRACT

A light emitting device that includes a first electrode, a second electrode oppositely disposed to the first electrode, and an emission layer between the first electrode and the second electrode is provided. The emission layer includes an organometallic compound represented by Formula 1:

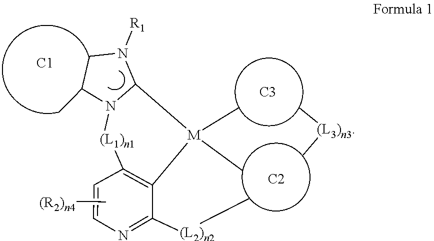

### CROSS-REFERENCE TO RELATED APPLICATION

This application claims priority to and the benefit of Korean Patent Application No. 10-2022-0006869, filed on Jan. 17, 2022, the entire content of which is hereby incorporated by reference.

### BACKGROUND

### 1. Field

Aspects of one or more embodiments of the present disclosure relate to a light emitting device and an organometallic compound utilized in the light emitting device.

### 2. Description of the Related Art

Recently, the development of a luminescence display as an image display is being actively conducted. The luminescence display is different from a liquid crystal display and is a display of a self-luminescent type or kind (e.g., a self-luminescent display) in which holes and electrons injected from a first electrode and a second electrode recombine in an emission layer so that a light emitting material in the emission layer emits light to achieve display (e.g., to display an image).

In the application of a light emitting device to a display, the decrease of a driving voltage and the increase of the emission efficiency and lifetime of the light emitting device are desired (e.g., required), and development on materials for a light emitting device, stably achieving the requirements is being continuously researched (e.g., sought).

### SUMMARY

An aspect of one or more embodiments of the present disclosure is directed toward a light emitting device having an improved emission efficiency and device lifetime.

An aspect of one or more embodiments of the present disclosure is directed toward an organometallic compound which may improve the emission efficiency and device lifetime of a light emitting device.

Additional aspects will be set forth in part in the description which follows and, in part, will be apparent from the description, or may be learned by practice of the presented embodiments of the disclosure.

An embodiment of the present disclosure provides a light emitting device including a first electrode, a second electrode oppositely disposed to the first electrode, and an emission layer between the first electrode and the second electrode, wherein the emission layer includes an organometallic compound represented by Formula 1.

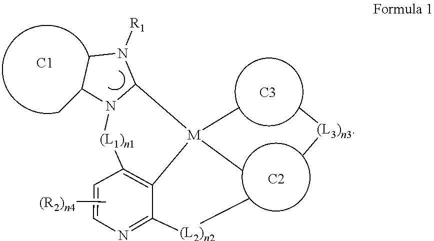

In Formula 1, M may be Pt, Pd, Cu, Ag, Au, Rh, Ir, Ru or Os, rings C1 to C3 may each independently be a substituted or unsubstituted hydrocarbon ring of 5 to 60 ring-forming carbon atoms, or a substituted or unsubstituted heterocycle of 2 to 60 ring-forming carbon atoms, L₁ to L₃ may each independently be a direct linkage, *—O*′, *—S—*′, *—C(R₁₁)(R₁₂)—*′, *—C(R₁₃)═*′, *═C(R₁₄)—*′, *—C(R₁₅)═C(R₁₆)—*′, *—C(═O)—*′, *—C(═S)*′, *—C≡C—*′, *—B(R₁₇)—*′, *—N(R₁₈)—*′, *—P(R₁₉)—*′, *—Si(R₂₀)(R₂₁)*′, *—P(R₂₂)(R₂₃)—*′ or *—Ge(R₂₄)(R₂₅)—*′, R₁ may be a hydrogen atom, a deuterium atom, a halogen atom, a substituted or unsubstituted thio group, a substituted or unsubstituted oxy group, a substituted or unsubstituted boron group, a substituted or unsubstituted amine group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, R₂, and R₁₁ to R₂₅ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, n1 to n3 may each independently be an integer from 1 to 3, and n4 may be an integer from 0 to 2.

In an embodiment, the emission layer may emit phosphorescence.

In an embodiment, the emission layer may include a host and a dopant, and the dopant may include the organometallic compound represented by Formula 1.

In an embodiment, the organometallic compound represented by Formula 1 may be represented by Formula 2.

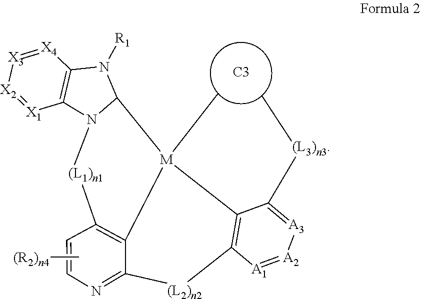

In Formula 2, X₁ to X₄, and A₁ to A₃ may each independently be N, or CR₃, R₃ may be a hydrogen atom, a deuterium atom, a halogen atom, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula 2, the same definitions for M, C3, L₁ to L₃, R₁, R₂, and n1 to n4 defined in Formula 1 may be applied.

In an embodiment, the organometallic compound represented by Formula 2 may be represented by Formula 3.

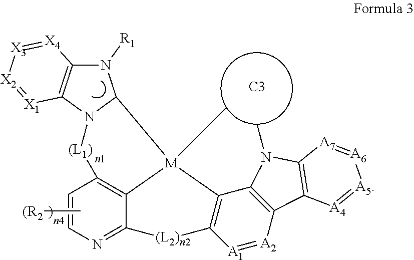

In Formula 3, A₄ to A₇ may each independently be N, or CR₄, R₄ may be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula 3, the same definitions for M, C3, L₁, L₂, X₁ to X₄, R₁, R₂, n1, n2, n4, A₁, and A₂ defined in Formula 1 and Formula 2 may be applied.

In an embodiment, the organometallic compound represented by Formula 2 may be represented by Formula 4.

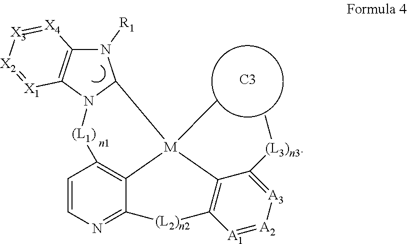

In Formula 4, the same definitions for M, C3, L₁ to L₃, R₁, X₁ to X₄, n1 to n3, and A₁ to A₃ defined in Formula 1 and Formula 2 may be applied.

In an embodiment, the organometallic compound represented by Formula 2 may be represented by any one selected from among Formula 5-1 to Formula 5-3.

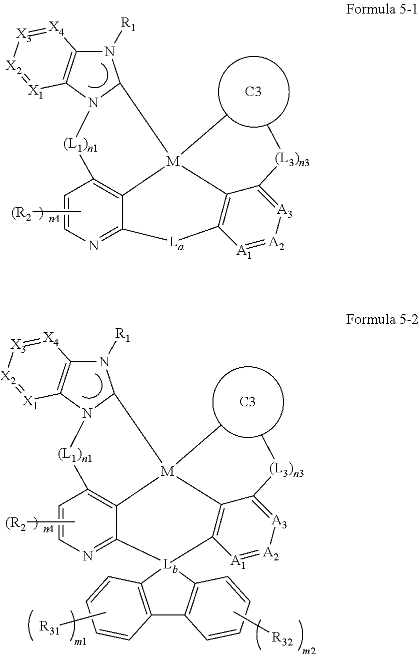

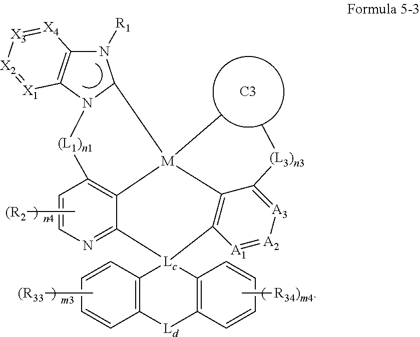

In Formula 5-1 to Formula 5-3, Lₐ may be *—O—*′, *—S—*′, *—C(R₃₅)(R₃₆)—*′, *—N(R₃₇)—*′, or *—Si(R₃₈)(R₃₉)—*′, L_{b}, and L_{c} may each independently be C or Si, L_{d} may be *—O—*′, or *—S—*′, R₃₁ to R₃₉ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and m1 to m4 may each independently be an integer from 0 to 4.

In Formula 5-1 to Formula 5-3, the same definitions for M, C3, L₁, L₃, X₁ to X₄, R₁, R₂, n1, n3, n4, and A₁ to A₃ defined in Formula 1 and Formula 2 may be applied.

In an embodiment, the organometallic compound represented by Formula 2 may be represented by Formula 6-1 or Formula 6-2.

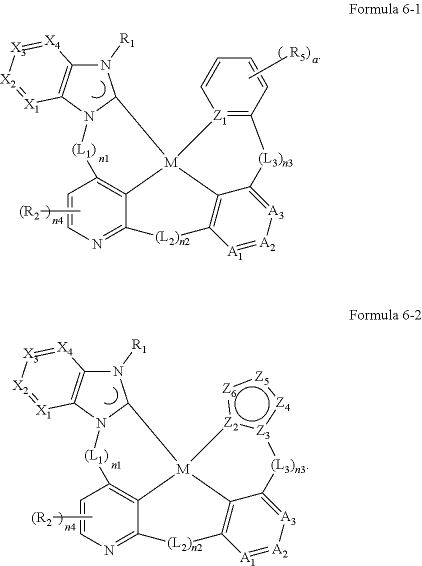

In Formula 6-1 and Formula 6-2, Z₁ to Z₃ may each independently be N or C, Z₄ to Z₆ may each independently be N, NR₆, CR₇, O, or S, R₅ is a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, R₆ and R₇ may each independently be a hydrogen atom, a deuterium atom, a halogen atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and “a” may be an integer from 0 to 4.

In Formula 6-1 and Formula 6-2, the same definitions for M, L₁ to L₃, X₁ to X₄, R₁, R₂, n1 to n4, and A₁ to A₃ defined in Formula 1 and Formula 2 may be applied.

In an embodiment, the organometallic compound represented by Formula 6-1 may be represented by any one selected from among Formula 7-1 to Formula 7-6.

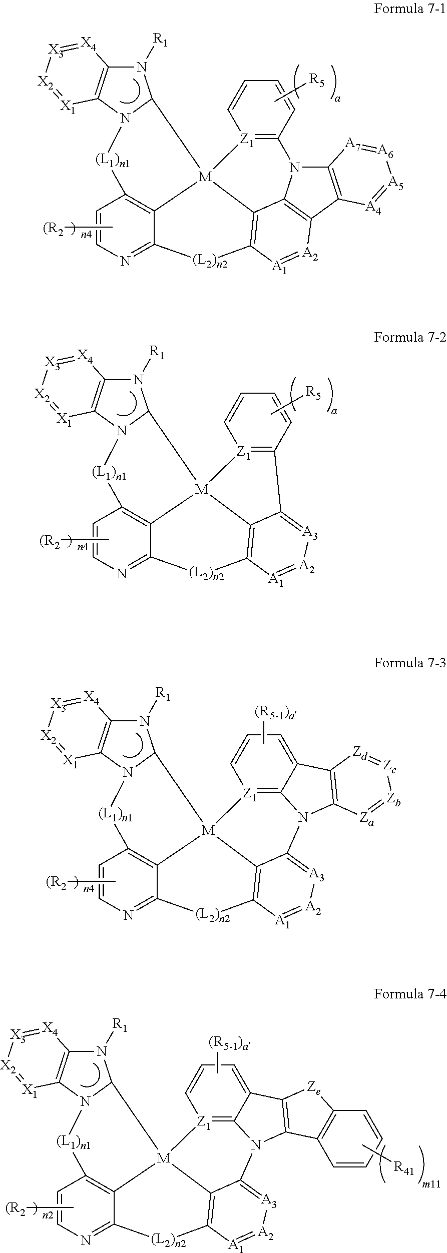

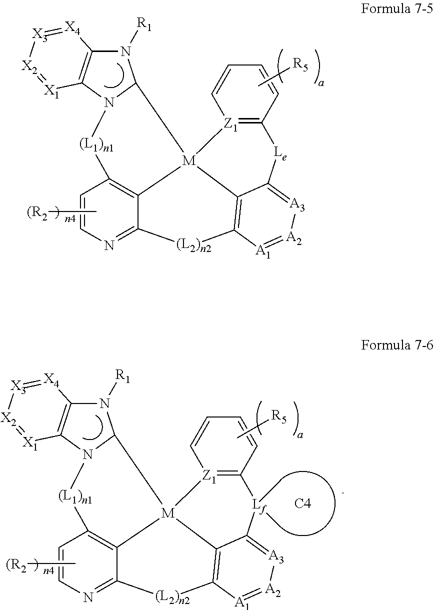

In Formula 7-1 to Formula 7-6, A₄ to A₇, and Zₐ to Z_{d} may each independently be N, or CR₄₂, Zₑ may be NR₄₃, or O, Lₑ may be *—O—*′, *—S—*′ or *—N(R₄₄)—*′, Lf may be C or Si, R₅₋₁, and R₄₁ to R₄₄ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, ring C4 may be a substituted or unsubstituted hydrocarbon ring of 5 to 60 ring-forming carbon atoms, or a substituted or unsubstituted heterocycle of 2 to 60 ring-forming carbon atoms, a′ may be an integer from 0 to 3, and m11 may be an integer from 0 to 4.

In Formula 7-1 to Formula 7-6, the same definitions for M, L₁, L₂, X₁ to X₄, Z₁, R₁, R₂, n1, n2, n4, “a”, R₅, and A₁ to A₃ defined in Formula 1, Formula 2 and Formula 6-1 may be applied.

In an embodiment, the organometallic compound represented by Formula 6-2 may be represented by any one selected from among Formula 8-1 to Formula 8-6.

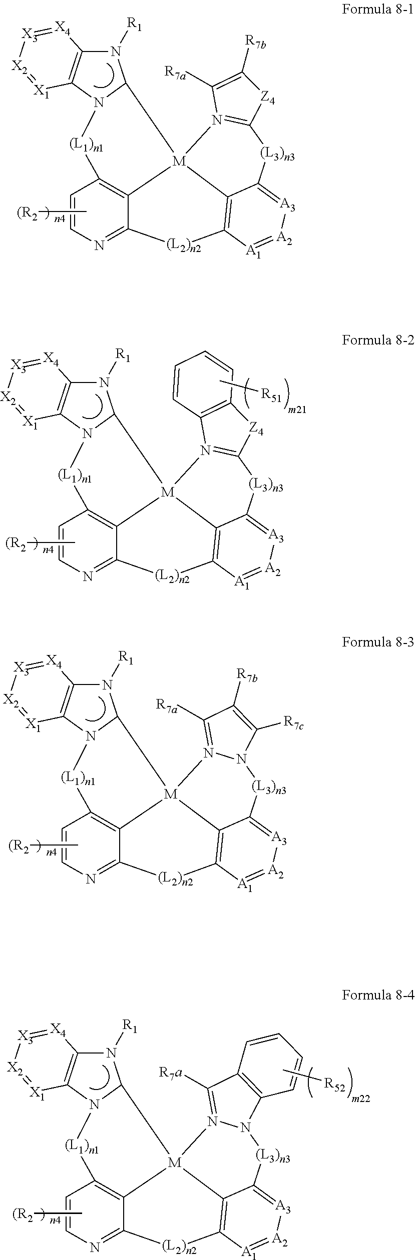

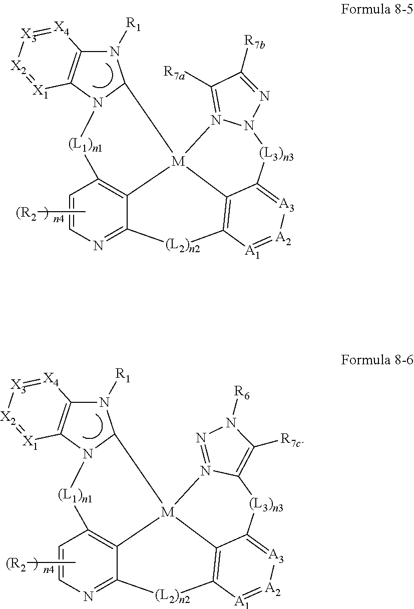

In Formula 8-1 to Formula 8-6, R₇ₐ to R_{7c}, R₅₁, and R₅₂ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and m21 and m22 may each independently be an integer from 0 to 4.

In Formula 8-1 to Formula 8-6, the same definitions for M, L₁ to L₃, X₁ to X₄, R₁, R₂, n1 to n4, Z₄, A₁ to A₃, and R₆ defined in Formula 1, Formula 2 and Formula 6-2 may be applied.

In an embodiment, the host may include a first host and a second host, the first host may be represented by Formula HT-1, and the second host may be represented by Formula ET-1 or Formula ET-2.

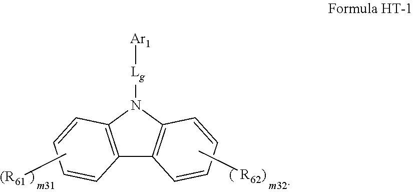

In Formula HT-1, L_{g} may be a direct linkage, a substituted or unsubstituted arylene group of 6 to 30 ring-forming carbon atoms, or a substituted or unsubstituted heteroarylene group of 2 to 30 ring-forming carbon atoms, Ar₁ may be a substituted or unsubstituted aryl group of 6 to 30 ring-forming carbon atoms, or a substituted or unsubstituted heteroaryl group of 2 to 30 ring-forming carbon atoms, R₆₁ and R₆₂ may each independently be a hydrogen atom, a deuterium atom, a halogen atom, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and m31 and m32 may each independently be an integer from 0 to 4.

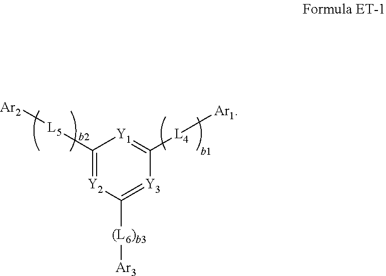

In Formula ET-1, Y₁ to Y₃ may each independently be N, or CRₐ, Rₐ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, b1 to b3 may each independently be an integer from 0 to 10, L₄ to L₆ may each independently be a direct linkage, a substituted or unsubstituted arylene group of 6 to 30 ring-forming carbon atoms, or a substituted or unsubstituted heteroarylene group of 2 to 30 ring-forming carbon atoms, and Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

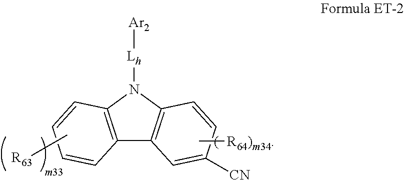

In Formula ET-2, Lₕ may be a direct linkage, a substituted or unsubstituted arylene group of 6 to 30 ring-forming carbon atoms, or a substituted or unsubstituted heteroarylene group of 2 to 30 ring-forming carbon atoms, Ar₂ may be a substituted or unsubstituted aryl group of 6 to 30 ring-forming carbon atoms, or a substituted or unsubstituted heteroaryl group of 2 to 30 ring-forming carbon atoms, R₆₃ and R₆₄ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, m33 may be an integer from 0 to 4, and m34 is an integer from 0 to 3.

An organometallic compound according to an embodiment of the present disclosure is represented by Formula 1.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a plan view showing a display apparatus according to an embodiment;

FIG. 2 is a cross-sectional view of a display apparatus according to an embodiment;

FIG. 3 is a cross-sectional view schematically showing a light emitting device according to an embodiment;

FIG. 4 is a cross-sectional view schematically showing a light emitting device according to an embodiment;

FIG. 5 is a cross-sectional view schematically showing a light emitting device according to an embodiment;

FIG. 6 is a cross-sectional view schematically showing a light emitting device according to an embodiment;

FIG. 7 is a cross-sectional view of a light emitting device according to an embodiment;

FIG. 8 is a cross-sectional view of a light emitting device according to an embodiment;

FIG. 9 is a cross-sectional view of a display apparatus according to an embodiment; and

FIG. 10 is a cross-sectional view of a display apparatus according to an embodiment.

### DETAILED DESCRIPTION

The present disclosure may have one or more suitable modifications and may be embodied in different forms, and example embodiments will be explained in more detail with reference to the accompanying drawings. The present disclosure may, however, be embodied in different forms and should not be construed as limited to the embodiments set forth herein. Rather, all modifications, equivalents, and substituents which are included in the spirit and technical scope of the present disclosure should be included in the present disclosure.

Like reference numerals refer to like elements throughout, and duplicative descriptions thereof may not be provided. In the drawings, the dimensions of structures may be exaggerated for clarity of illustration. It will be understood that, although the terms first, second, etc. may be utilized herein to describe one or more suitable elements, these elements should not be limited by these terms. These terms are only utilized to distinguish one element from another element. Thus, a first element could be termed a second element without departing from the teachings of the present disclosure. Similarly, a second element could be termed a first element. As utilized herein, the singular forms are intended to include the plural forms as well, unless the context clearly indicates otherwise.

In the disclosure, it will be further understood that the terms “comprises”, “includes” and/or “comprising”, “including,” when utilized in this disclosure, specify the presence of stated features, numerals, steps, operations, elements, parts, or the combination thereof, but do not preclude the presence or addition of one or more other features, numerals, steps, operations, elements, parts, or the combination thereof.

In the disclosure, when a layer, a film, a region, a plate, etc. is referred to as being “on” or “above” another part, it can be “directly on” the other part, or intervening layer(s) may also be present. In contrast, when a layer, a film, a region, a plate, etc. is referred to as being “under” or “below” another part, it can be “directly under” the other part, or intervening layers may also be present. Also, when an element is referred to as being disposed “on” another element, it can be disposed under the other element.

In the disclosure, the term “substituted or unsubstituted” corresponds to substituted or unsubstituted with at least one substituent selected from the group including (e.g., consisting of) a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In some embodiments, each of the exemplified substituents may be substituted or unsubstituted. For example, a biphenyl group may be interpreted as an aryl group or a phenyl group substituted with a phenyl group.

In the disclosure, the term “forming a ring via the combination with an adjacent group” may refer to forming a substituted or unsubstituted hydrocarbon ring, or a substituted or unsubstituted heterocycle via the combination with an adjacent group. The hydrocarbon ring includes an aliphatic hydrocarbon ring and/or an aromatic hydrocarbon ring. The heterocycle includes an aliphatic heterocycle and/or an aromatic heterocycle. The hydrocarbon ring and the heterocycle may be monocycles or polycycles. In some embodiments, the ring formed via the combination with an adjacent group may be combined with another ring to form a spiro structure.

In the disclosure, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In some embodiments, in 4,5-dimethylphenanthrene, two methyl groups may be interpreted as “adjacent groups” to each other.

In the disclosure, a halogen atom may be a fluorine atom, a chlorine atom, a bromine atom or an iodine atom.

In the disclosure, an alkyl group may be a linear, branched or cyclic type or kind. The carbon number of the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the disclosure, a hydrocarbon ring group refers to an optional functional group or substituent derived from an aliphatic hydrocarbon ring. The hydrocarbon ring group may be a saturated hydrocarbon ring group of 5 to 20 ring-forming carbon atoms.

In the disclosure, an aryl group refers to an optional functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the disclosure, a fluorenyl group may be substituted, and two substituents may be combined with each other to form a spiro structure. Examples of a substituted fluorenyl group are as follows, but an embodiment of the present disclosure is not limited thereto.

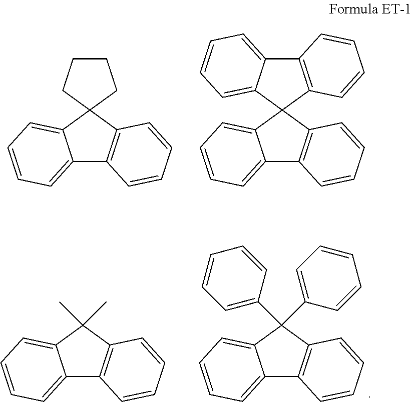

In the disclosure, a heterocyclic group refers to an optional functional group or substituent derived from a ring including one or more selected from among B, O, N, P, Si, and S as heteroatoms. The heterocyclic group includes an aliphatic heterocyclic group and/or an aromatic heterocyclic group. The aromatic heterocyclic group may be a heteroaryl group. The aliphatic heterocyclic group and the aromatic heterocyclic group may be a monocycle or a polycycle.

In the disclosure, a heterocyclic group may include one or more selected from among B, O, N, P, Si and S as heteroatoms. When the heterocyclic group includes two or more heteroatoms, two or more heteroatoms may be the same or different. The heterocyclic group may be a monocyclic heterocyclic group or a polycyclic heterocyclic group, and may include a heteroaryl group. The carbon number for forming rings of the heterocyclic group may be 2 to 30, 2 to 20, or 2 to 10.

In the disclosure, a heteroaryl group may include one or more selected from among B, O, N, P, Si, and S as heteroatoms. When the heteroaryl group includes two or more heteroatoms, two or more heteroatoms may be the same or different. The heteroaryl group may be a monocyclic heterocyclic group or polycyclic heterocyclic group. The carbon number for forming rings of the heteroaryl group may be 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the disclosure, the same definitions for the above-described aryl group may be applied to an arylene group except that the arylene group is a divalent group. The same definitions for the above-described heteroaryl group may be applied to a heteroarylene group except that the heteroarylene group is a divalent group.

In the disclosure, a silyl group includes an alkyl silyl group and/or an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the disclosure, a thio group may include an alkyl thio group and/or an aryl thio group. The thio group may refer to the above-defined alkyl group or aryl group combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the disclosure, an oxy group may refer to the above-defined alkyl group or aryl group which is combined with an oxygen atom. The oxy group may include an alkoxy group and an aryl oxy group. The alkoxy group may be a linear, branched or cyclic chain. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, an embodiment of the present disclosure is not limited thereto.

In the disclosure, a boron group may refer to the above-defined alkyl group or aryl group, combined with a boron atom. The boron group includes an alkyl boron group and/or an aryl boron group. Examples of the boron group include a dimethylboron group, a diethylboron group, a t-butylmethylboron group, a diphenylboron group, a phenylboron group, etc., without limitation.

In the disclosure, the carbon number of an amine group is not specifically limited, but may be 1 to 30. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, a triphenylamine group, etc., without limitation.

In the disclosure, a direct linkage may refer to a single bond.

In some embodiments, in the disclosure, “ [symbol] ” refers to a position to be connected.

Hereinafter, embodiments of the present disclosure will be explained referring to the drawings.

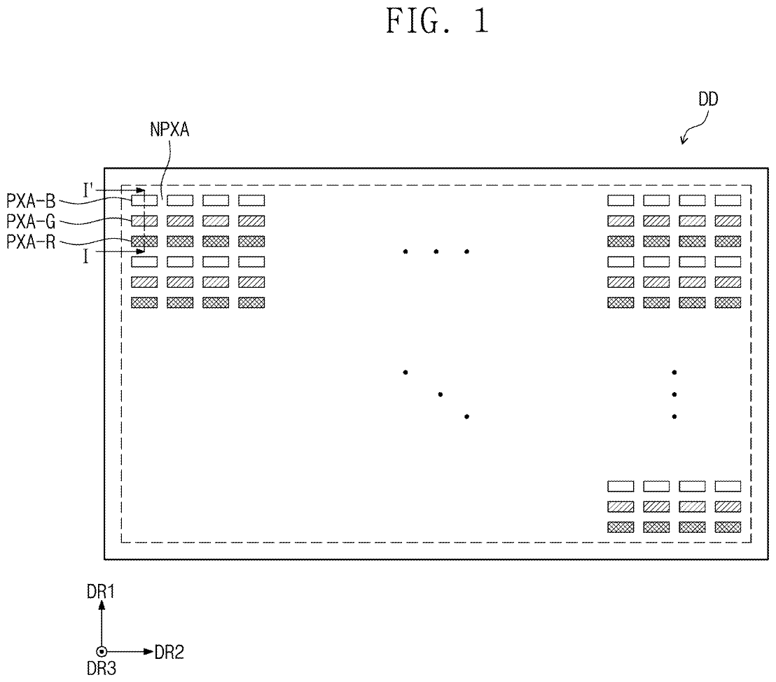

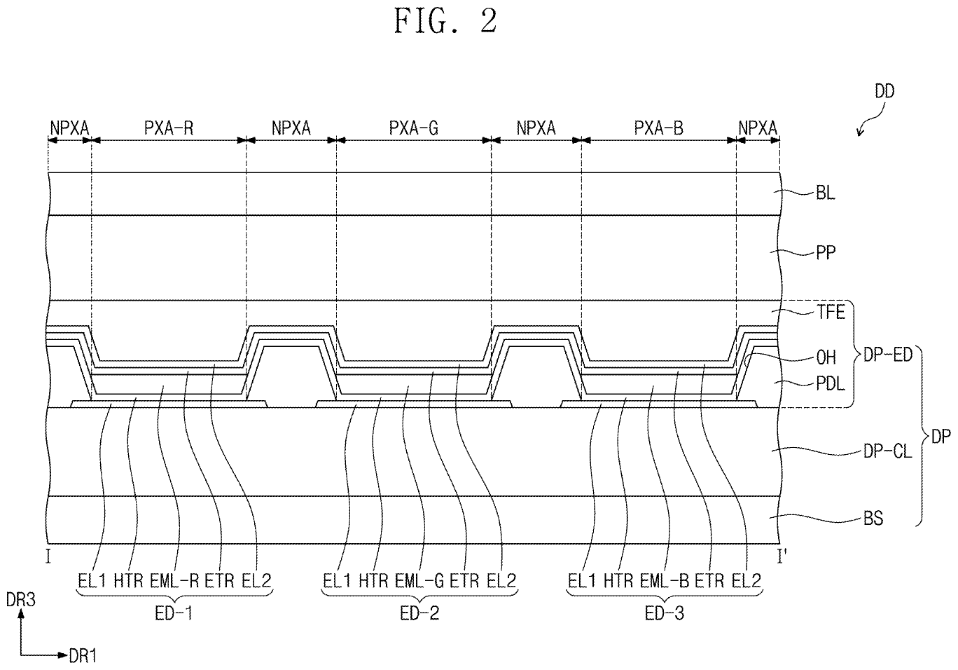

FIG. 1 is a plan view showing an embodiment of a display apparatus DD. FIG. 2 is a cross-sectional view of a display apparatus DD of an embodiment. FIG. 2 is a cross-sectional view showing a part corresponding to line I-I′ of FIG. 1.

The display apparatus DD may include a display panel DP and an optical layer PP on the display panel DP. The display panel DP includes light emitting devices ED-1, ED-2 and ED-3. The display apparatus DD may include multiple light emitting devices ED-1, ED-2 and ED-3. The optical layer PP may be on the display panel DP and control reflected light by external light at the display panel DP. The optical layer PP may include, for example, a polarization layer or a color filter layer. In some embodiments, the optical layer PP may not be provided in the display apparatus DD of an embodiment.

On the optical layer PP, a base substrate BL may be disposed. The base substrate BL may be a member providing a base surface in which the optical layer PP is disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, the base substrate BL may not be provided.

The display apparatus DD according to an embodiment may further include a plugging layer. The plugging layer may be between a display device layer DP-ED and a base substrate BL. The plugging layer may be an organic layer. The plugging layer may include at least one selected from among an acrylic resin, a silicon-based resin and an epoxy-based resin.

The display panel DP may include a base layer BS, a circuit layer DP-CL provided on the base layer BS and a display device layer DP-ED. The display device layer DP-ED may include a pixel definition layer PDL, light emitting devices ED-1, ED-2 and ED-3 disposed in the pixel definition layer PDL, and an encapsulating layer TFE disposed on the light emitting devices ED-1, ED-2 and ED-3.

The base layer BS may be a member providing a base surface in which the display device layer DP-ED is disposed. The base layer BS may be a glass substrate, a metal substrate, a plastic substrate, etc. However, an embodiment of the present disclosure is not limited thereto, and the base layer BS may be an inorganic layer, an organic layer or a composite material layer.

In an embodiment, the circuit layer DP-CL is on the base layer BS, and the circuit layer DP-CL may include multiple transistors. Each of the transistors may include a control electrode, an input electrode, and an output electrode. For example, the circuit layer DP-CL may include switching transistors and driving transistors for driving the light emitting devices ED-1, ED-2 and ED-3 of the display device layer DP-ED.

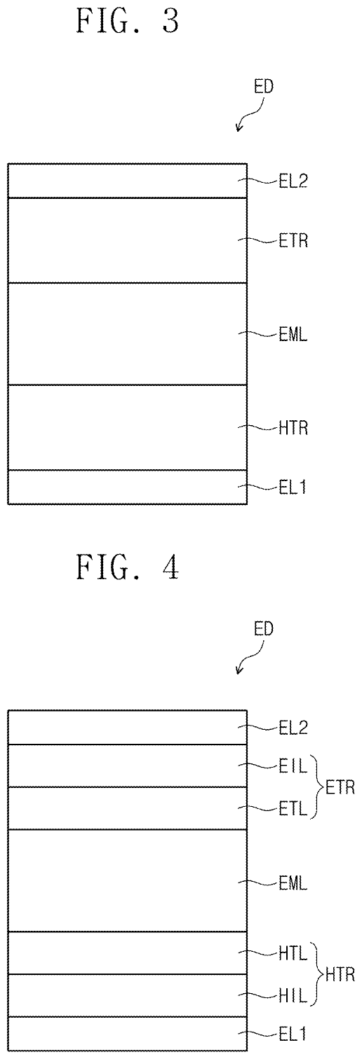

Each of the light emitting devices ED-1, ED-2 and ED-3 may have the structures of light emitting devices ED of embodiments according to FIG. 3 to FIG. 6, which will be explained in more detail. Each of the light emitting devices ED-1, ED-2 and ED-3 may include a first electrode EL1, a hole transport region HTR, emission layers EML-R, EML-G and EML-B, an electron transport region ETR, and a second electrode EL2.

In FIG. 2, shown is an embodiment in which the emission layers EML-R, EML-G and EML-B of light emitting devices ED-1, ED-2 and ED-3 are disposed in opening portions OH defined in a pixel definition layer PDL, and a hole transport region HTR, an electron transport region ETR and a second electrode EL2 are provided as common layers in all light emitting devices ED-1, ED-2 and ED-3. However, an embodiment of the present disclosure is not limited thereto. Different from FIG. 2, in an embodiment, the hole transport region HTR and the electron transport region ETR may be patterned and provided in the opening portions OH defined in the pixel definition layer PDL. For example, in an embodiment, the hole transport region HTR, the emission layers EML-R, EML-G and EML-B, and the electron transport region ETR of the light emitting devices ED-1, ED-2 and ED-3 may be patterned by an inkjet printing method and provided.

An encapsulating layer TFE may cover the light emitting devices ED-1, ED-2 and ED-3. The encapsulating layer TFE may encapsulate the display device layer DP-ED. The encapsulating layer TFE may be a thin film encapsulating layer. The encapsulating layer TFE may be one layer or a stacked layer of multiple layers. The encapsulating layer TFE includes at least one insulating layer. The encapsulating layer TFE according to an embodiment may include at least one inorganic layer (hereinafter, encapsulating inorganic layer). In some embodiments, the encapsulating layer TFE may include at least one organic layer (hereinafter, encapsulating organic layer) and at least one encapsulating inorganic layer.

The encapsulating inorganic layer protects (or reduces the exposure to moisture/oxygen) the display device layer DP-ED from moisture/oxygen, and the encapsulating organic layer protects (or reduces the exposure to foreign particles) the display device layer DP-ED from foreign materials such as dust particles. The encapsulating inorganic layer may include silicon nitride, silicon oxy nitride, silicon oxide, titanium oxide, or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be on the second electrode EL2 and may be disposed while filling the opening portion OH.

Referring to FIG. 1 and FIG. 2, the display apparatus DD may include a non-luminous area NPXA and luminous areas PXA-R, PXA-G and PXA-B. The luminous areas PXA-R, PXA-G and PXA-B may be areas emitting light produced from the light emitting devices ED-1, ED-2 and ED-3, respectively. The luminous areas PXA-R, PXA-G and PXA-B may be separated from each other on a plane (e.g., in a plan view).

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In some embodiments, in the disclosure, each of the luminous areas PXA-R, PXA-G and PXA-B may correspond to each pixel. The pixel definition layer PDL may divide the light emitting devices ED-1, ED-2 and ED-3. The emission layers EML-R, EML-G and EML-B of the light emitting devices ED-1, ED-2 and ED-3 may be disposed and divided in the opening portions OH defined in the pixel definition layer PDL.

The luminous areas PXA-R, PXA-G and PXA-B may be divided into multiple groups according to the color of light produced from the light emitting devices ED-1, ED-2 and ED-3. In the display apparatus DD of an embodiment, shown in FIG. 1 and FIG. 2, three luminous areas PXA-R, PXA-G and PXA-B emitting red light, green light and blue light are illustrated as an embodiment. For example, the display apparatus DD of an embodiment may include a red luminous area PXA-R, a green luminous area PXA-G and a blue luminous area PXA-B, which are separated from each other.

In the display apparatus DD according to an embodiment, multiple light emitting devices ED-1, ED-2 and ED-3 may emit light having different wavelength regions. For example, in an embodiment, the display apparatus DD may include a first light emitting device ED-1 emitting red light, a second light emitting device ED-2 emitting green light, and a third light emitting device ED-3 emitting blue light. For example, each of the red luminous area PXA-R, the green luminous area PXA-G, and the blue luminous area PXA-B of the display apparatus DD may correspond to the first light emitting device ED-1, the second light emitting device ED-2, and the third light emitting device ED-3.

However, an embodiment of the present disclosure is not limited thereto, and the first to third light emitting devices ED-1, ED-2 and ED-3 may emit light in substantially the same wavelength region, or at least one thereof may emit light in a different wavelength region. For example, all the first to third light emitting devices ED-1, ED-2 and ED-3 may emit blue light.

The luminous areas PXA-R, PXA-G and PXA-B in the display apparatus DD according to an embodiment may be arranged in a stripe shape. Referring to FIG. 1, multiple red luminous areas PXA-R may be arranged with each other along a second direction axis DR2, multiple green luminous areas PXA-G may be arranged with each other along the second direction axis DR2, and multiple blue luminous areas PXA-B may be arranged with each other along the second direction axis DR2. In some embodiments, the red luminous area PXA-R, the green luminous area PXA-G and the blue luminous area PXA-B may be arranged by turns along a first direction axis DR1. (DR3 is a third direction which is normal or perpendicular to the plane defined by the first direction DR1 and the second direction DR2).

In FIG. 1 and FIG. 2, the areas of the luminous areas PXA-R, PXA-G and PXA-B are shown to be similar, but an embodiment of the present disclosure is not limited thereto. The areas of the luminous areas PXA-R, PXA-G and PXA-B may be different from each other according to the wavelength region of light emitted. In some embodiments, the areas of the luminous areas PXA-R, PXA-G and PXA-B may refer to areas on a plane defined by the first direction axis DR1 and the second direction axis DR2 (e.g., when viewed in a plan view).

In some embodiments, the arrangement type or kind of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in one or more suitable combinations according to the properties of display quality required for the display apparatus DD. For example, the arrangement type or kind of the luminous areas PXA-R, PXA-G and PXA-B may be a pentile (PENTILE®) arrangement type or kind (for example, an RGBG matrix, an RGBG structure, or RGBG matrix structure), or a Diamond Pixel™ arrangement type or kind (e.g., a display (e.g., an OLED display) containing red, blue, and green (RGB) light emitting regions arranged in the shape of diamonds. PENTILE® is a duly registered trademark of Samsung Display Co., Ltd. Diamond Pixel™ is a trademark of Samsung's displays.

In some embodiments, the areas of the luminous areas PXA-R, PXA-G and PXA-B may be different from each other. For example, in an embodiment, the area of the green luminous area PXA-G may be smaller than the area of the blue luminous area PXA-B, but an embodiment of the present disclosure is not limited thereto.

Hereinafter, FIG. 3 to FIG. 6 are cross-sectional views schematically showing light emitting devices according to embodiments. The light emitting device ED according to an embodiment may include a first electrode EL1, a hole transport region HTR, an emission layer EML, an electron transport region ETR and a second electrode EL2, stacked in order (from the first electrode EL1).

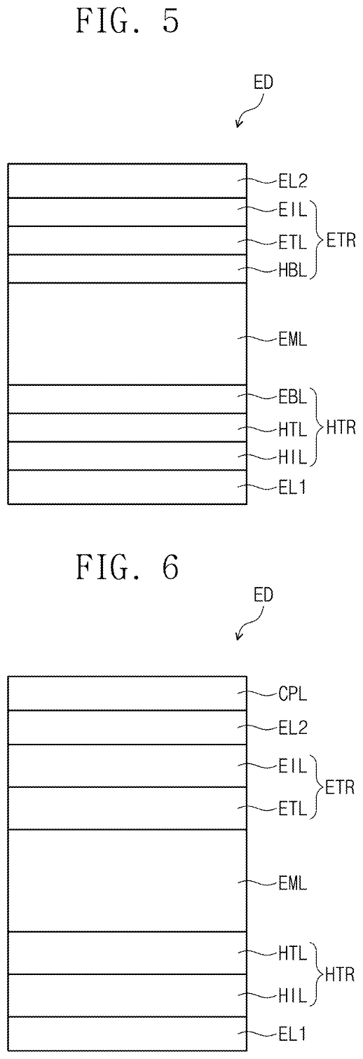

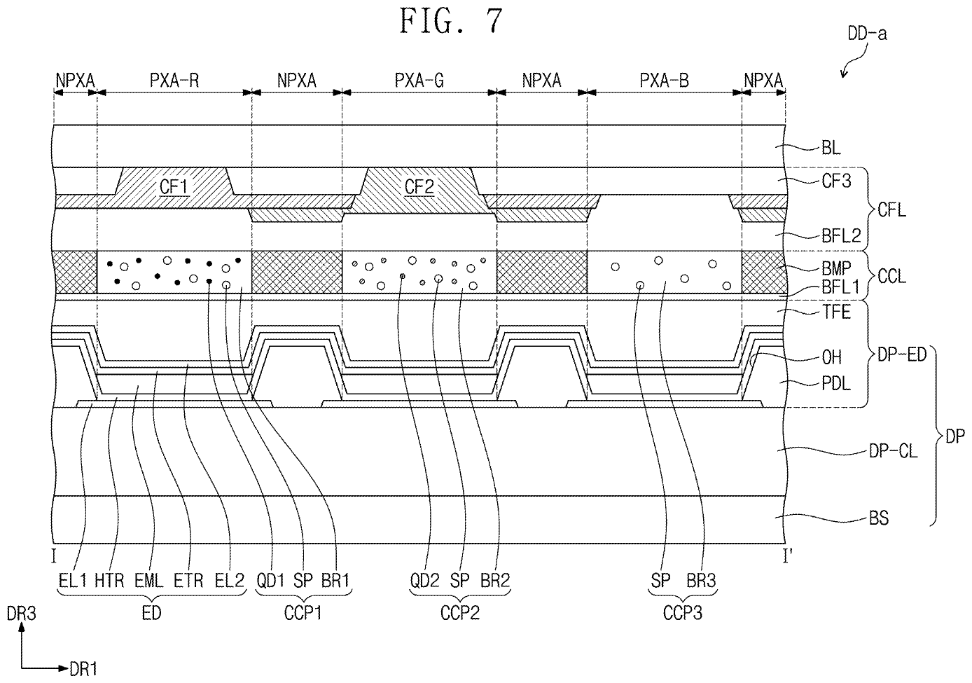

When compared to FIG. 3, FIG. 4 shows the cross-sectional view of a light emitting device ED of an embodiment, wherein a hole transport region HTR includes a hole injection layer HIL and a hole transport layer HTL, and an electron transport region ETR includes an electron injection layer EIL and an electron transport layer ETL. In some embodiments, when compared to FIG. 3, FIG. 5 shows the cross-sectional view of a light emitting device ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared to FIG. 4, FIG. 6 shows the cross-sectional view of a light emitting device ED of an embodiment, including a capping layer CPL on the second electrode EL2.

The first electrode EL1 has conductivity (e.g., is a conductor). The first electrode EL1 may be formed utilizing a metal material, a metal alloy or a conductive compound. The first electrode EL1 may be an anode or a cathode. However, an embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, Zn, compounds comprising one or more of the foregoing elements, combinations of two or more of the foregoing elements or compounds, mixtures of two or more of the foregoing elements or compounds, and/or oxides thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (stacked structure of Li and F), LiF/AI (stacked structure of Li and Al), Mo, Ti, W, compounds thereof, or mixtures thereof (for example, a mixture of Ag and Mg). Also, the first electrode EL1 may have a structure including multiple layers including a reflective layer or a transflective layer formed utilizing the above materials, and a transmissive conductive layer formed utilizing ITO, IZO, ZnO, or ITZO. For example, the first electrode EL1 may have a three-layer structure of ITO/Ag/ITO. However, an embodiment of the present disclosure is not limited thereto. The first electrode EL1 may include the above-described metal materials, combinations of two or more metal materials selected from the above-described metal materials, or oxides of the above-described metal materials. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission auxiliary layer, or an emission blocking layer EBL. The thickness of the hole transport region HTR may be, for example, about 50 Å to about 15,000 Å.

The hole transport region HTR may have a single layer formed utilizing a single material, a single layer formed utilizing multiple different materials, or a multilayer structure including multiple layers formed utilizing multiple different materials.

For example, the hole transport region HTR may have the structure of a single layer of a hole injection layer HIL or a hole transport layer HTL, and may have a structure of a single layer formed utilizing a hole injection material and a hole transport material. In some embodiments, the hole transport region HTR may have a structure of a single layer formed utilizing multiple different materials, or a structure stacked from the first electrode EL1 of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, without limitation.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-2.

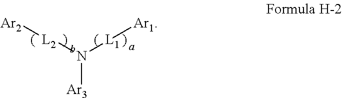

In Formula H-2 above, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. “a” and “b” may each independently be an integer from 0 to 10. In some embodiments, when “a” or “b” is an integer of 2 or more, multiple L₁ and L₂ may each independently be a substituted or unsubstituted arylene group of 6 to 30 ring-forming carbon atoms, or a substituted or unsubstituted heteroarylene group of 2 to 30 ring-forming carbon atoms.

In Formula H-2, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. In some embodiments, in Formula H-2, Ar₃ may be a substituted or unsubstituted aryl group of 6 to 30 ring-forming carbon atoms.

The compound represented by Formula H-2 may be a monoamine compound. In some embodiments, the compound represented by Formula H-2 may be a diamine compound in which at least one selected from among Ar₁ to Ar₃ includes an amine group as a substituent. In some embodiments, the compound represented by Formula H-2 may be a carbazole-based compound in which at least one selected from among Ar₁ and Ar₂ includes a substituted or unsubstituted carbazole group, or a fluorene-based compound in which at least one selected from among Ar₁ and Ar₂ includes a substituted or unsubstituted fluorene group.

The compound represented by Formula H-2 may be represented by any one selected from among the compounds in Compound Group H. However, the compounds shown in Compound Group H are merely examples, and the compound represented by Formula H-2 is not limited to the compounds represented in Compound Group H.

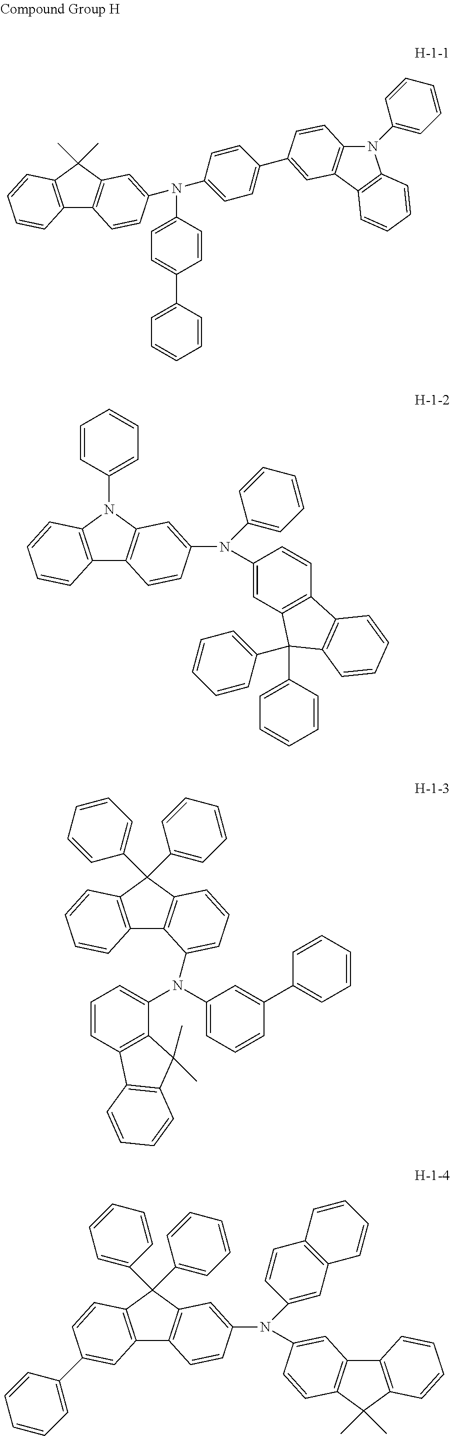 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

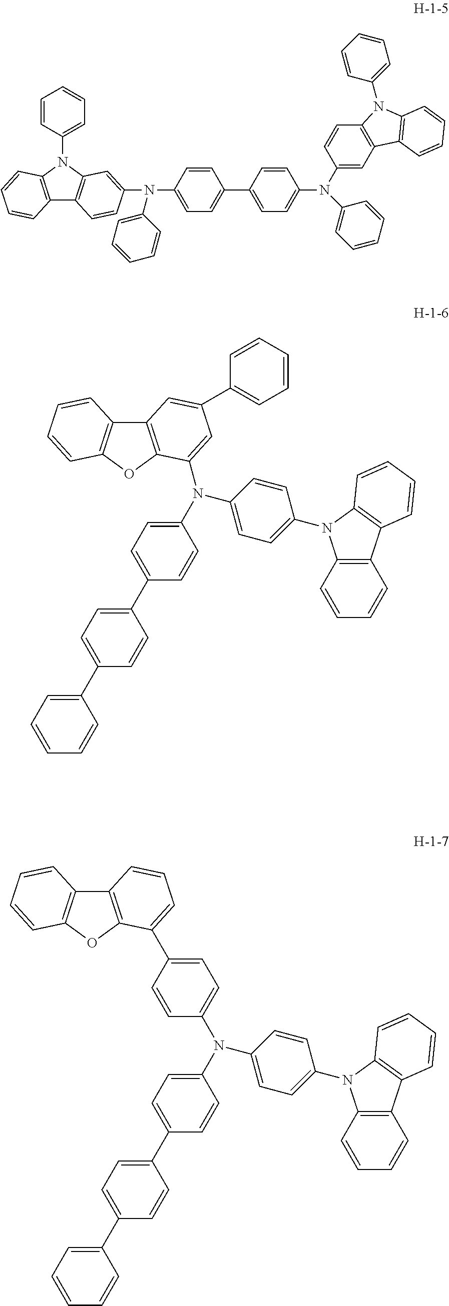 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

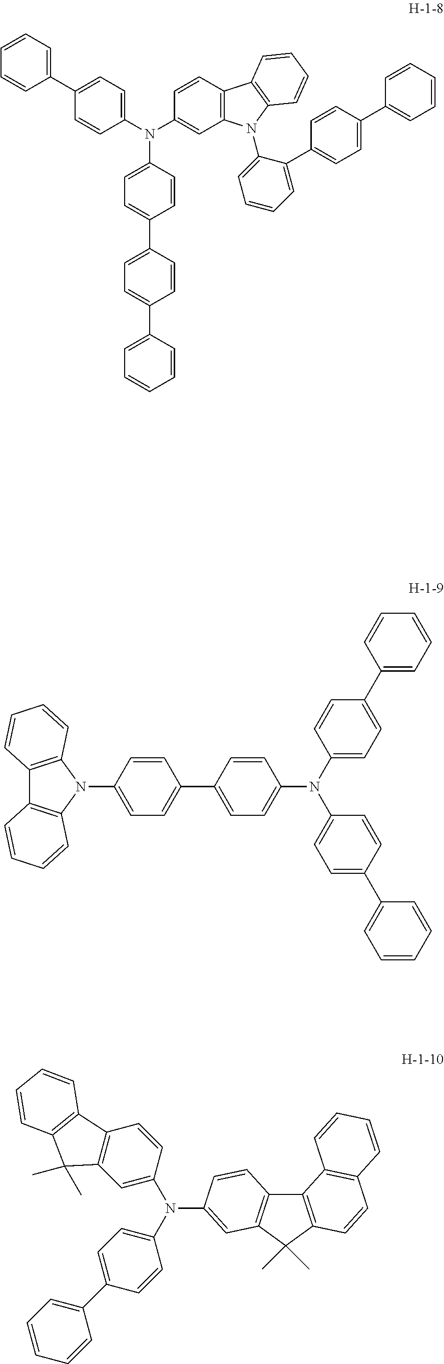 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

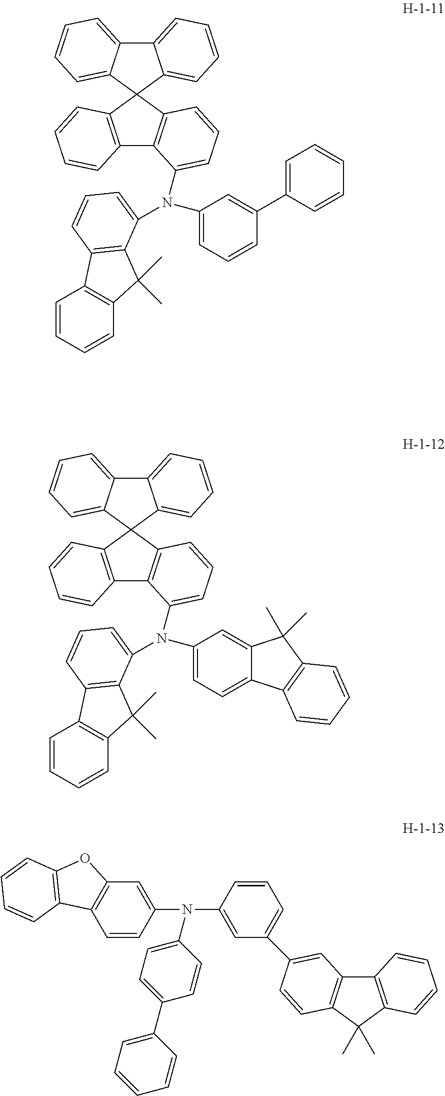 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

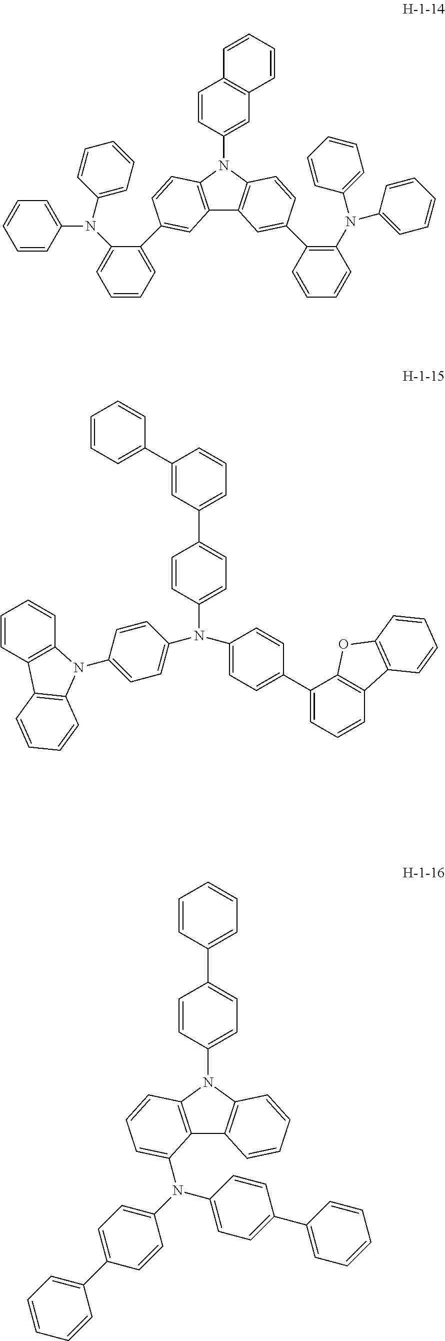 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

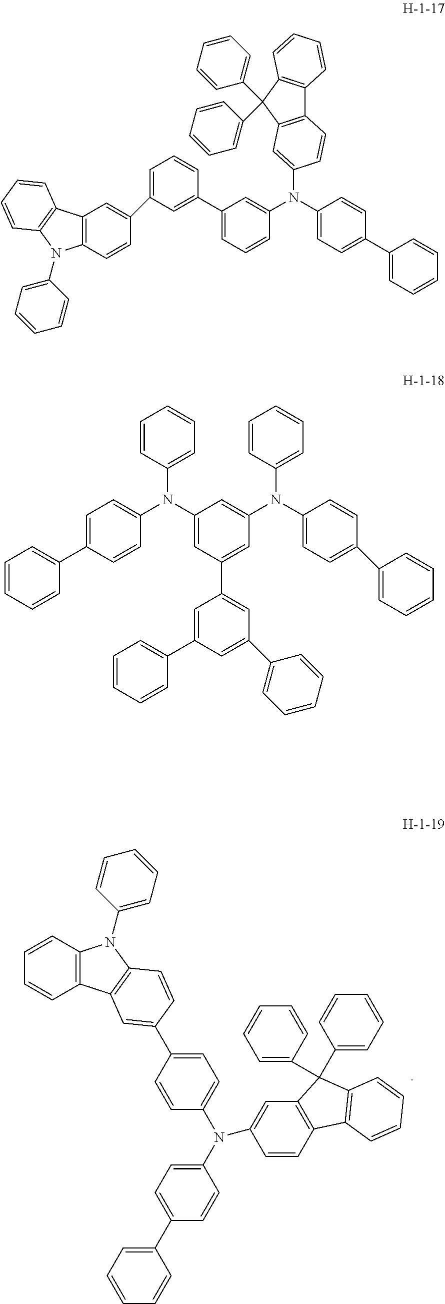 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB or NPD), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h] quinoxaline-2,3,6,7,10,11-hexacarbonitrile (HAT-CN).

The hole transport region HTR may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region HTR in at least one selected from among the hole injection layer HIL, hole transport layer HTL, and electron blocking layer EBL.

The thickness of the hole transport region HTR may be from about 100 Å to about 10,000 Å, for example, from about 100 Å to about 5,000 Å. When the hole transport region HTR includes a hole injection layer HIL, the thickness of the hole injection region HIL may be, for example, from about 30 Å to about 1,000 Å. When the hole transport region HTR includes a hole transport layer HTL, the thickness of the hole transport layer HTL may be from about 30 Å to about 1,000 Å. For example, when the hole transport region HTR includes an electron blocking layer, the thickness of the electron blocking layer EBL may be from about 10 Å to about 1,000 Å. When the thicknesses of the hole transport region HTR, the hole injection layer HIL, the hole transport layer HTL and the electron blocking layer EBL satisfy the above-described ranges, satisfactory (suitable) hole transport properties may be achieved without a substantial increase in a driving voltage.

The hole transport region HTR may further include a charge generating material to increase conductivity in addition to the above-described materials. The charge generating material may be dispersed substantially uniformly or non-uniformly in the hole transport region HTR. The charge generating material may be, for example, a p-dopant. The p-dopant may include at least one of metal halide compounds, quinone derivatives, metal oxides, or cyano group-containing compounds, without limitation. For example, the p-dopant may include metal halide compounds such as CuI and/or RbI, quinone derivatives such as tetracyanoquinodimethane (TCNQ) and 2,3,5,6-tetrafluoro-7,7′,8,8-tetracyanoquinodimethane (F4-TCNQ), metal oxides such as tungsten oxide and/or molybdenum oxide, cyano group-containing compounds such as dipyrazino[2,3-f: 2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one selected from among a buffer layer and an electron blocking layer EBL in addition to the hole injection layer HIL and the hole transport layer HTL. The buffer layer may compensate for resonance distance according to the wavelength of light emitted from an emission layer EML and may increase emission efficiency. Materials which may be included in the hole transport region HTR may also be included in the buffer layer. The electron blocking layer EBL is a layer that may play a role in blocking (or reducing) the injection of electrons from the electron transport region ETR to the hole transport region HTR.

The emission layer EML may be provided on the hole transport region HTR. The emission layer EML may have a thickness of, for example, about 100 Å to about 1,000 Å or about 100 Å to about 300 Å. The emission layer EML may have a single layer formed utilizing a single material, a single layer formed utilizing multiple different materials, or a multilayer structure having multiple layers formed utilizing multiple different materials.

In the light emitting element ED according to an embodiment, the emission layer EML may include the organometallic compound of an embodiment. In an embodiment, the emission layer EML may include the organometallic compound of an embodiment as a dopant. The organometallic compound of an embodiment may be the dopant material of the emission layer EML.

The organometallic compound of an embodiment may include a central metal atom, and a ligand bonded to the central metal atom. For example, the organometallic compound may include a central metal atom, and first to fourth ligands bonded to the central metal atom. The central metal atom and the first to fourth ligands may be bonded through coordination bonds. The first to fourth ligands may be tetradentate ligands in which each of the ligands is connected with at least one adjacent ligand via a connecting group. For example, the first to fourth ligands may be tetradentate ligands selectively connected with each other. For example, the first ligand may be connected with the second ligand through a first connecting group, and with the third ligand through a second connecting group. In some embodiments, the third ligand may be connected with the fourth ligand through a third connecting group. In an embodiment, the first ligand and the fourth ligand may not be connected. In some embodiments, in the present disclosure, the first connecting group may refer to L₁ in Formula 1, which will be explained in more detail, the second connecting group may refer to L₂ in Formula 1, which will be explained in more detail, and the third connecting group may refer to L₃ in Formula 1, which will be explained in more detail.

The metal atom may be platinum (Pt), palladium (Pd), copper (Cu), silver (Ag), gold (Au), rhodium (Rh), iridium (Ir), ruthenium (Ru), or osmium (Os). For example, the metal atom may be a platinum (Pt) atom.

The first ligand may be a six-membered heterocycle including a nitrogen atom as a ring-forming atom. For example, the first ligand may include a pyridine moiety. The first ligand may be bonded to the central metal atom at carbon at a meta position with respect to the nitrogen atom. In some embodiments, the first ligand may be connected with adjacent ligands at carbon at an ortho position and carbon at a para position with respect to the nitrogen atom, respectively. For example, the first ligand may be connected with the second ligand at carbon at a para position with respect to the nitrogen atom, and may be connected with the third ligand at carbon at an ortho position with respect to the nitrogen atom and with respect to the carbon atom connected with the metal atom. For example, in the organometallic compound of an embodiment, the connecting structure of the first ligand is shown in Formula a. The organometallic compound of an embodiment, having such a structure may have a deep energy level of the highest occupied molecular orbital (HOMO). In some embodiments, in the present disclosure, the “shallow” energy level may refer to the absolute value of an energy level that decreases from a vacuum level in the negative direction. In some embodiments, the “deep” energy level may refer to the absolute value of an energy level that increases from a vacuum level in the negative direction.

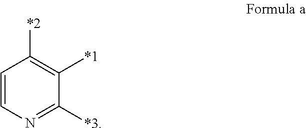

In Formula a, *1 may be a position connected with the central metal atom, *2 may be a position connected with the second ligand, and *3 may be a position connected with the third ligand.

The second ligand may be a substituted or unsubstituted N-heterocyclic carbene group. For example, the second ligand may be a substituted or unsubstituted benzimidazole heterocyclic carbene group. For example, the second ligand may be a substituted or unsubstituted benzimidazol-2-ylidiene group.

The third ligand and the fourth ligand may each independently be a substituted or unsubstituted aryl group, or a substituted or unsubstituted heteroaryl group. For example, the third and fourth ligands may each independently be a substituted or unsubstituted phenyl group, a substituted or unsubstituted pyridine group, a substituted or unsubstituted carbazole group, a substituted or unsubstituted carboline group, a substituted or unsubstituted benzofuroindole group, a substituted or unsubstituted pyrrolo-dipyridine group, a substituted or unsubstituted imidazole group, a substituted or unsubstituted benzimidazole group, a substituted or unsubstituted imidazopyrazine group, a substituted or unsubstituted benzoxazole group, a substituted or unsubstituted benzothiazole group, a substituted or unsubstituted oxazole group, a substituted or unsubstituted thiazole group, a substituted or unsubstituted pyrazole group, a substituted or unsubstituted indazole group, a substituted or unsubstituted pyrazole group, or a substituted or unsubstituted 1,2,3-triazole group. In some embodiments, in the present disclosure, the third ligand may refer to ring C2 in Formula 1, which will be explained in more detail, and the fourth ligand may refer to ring C3 in Formula 2, which will be explained in more detail.

The organometallic compound of an embodiment, represented by Formula 1 may have a deep HOMO energy level, and may have a high triplet energy level. Accordingly, when the organometallic compound of an embodiment, represented by Formula 1 is applied as the dopant material of an emission layer EML, deep blue light having excellent or suitable color purity may be emitted.

In some embodiments, because the organometallic compound of an embodiment has a deep HOMO energy level, a light emitting device ED utilizing the organometallic compound of an embodiment may reduce the difference between the HOMO energy level of a host and the HOMO energy level of the organometallic compound of an embodiment, utilized as the dopant, in an emission layer EML, thereby showing improved device lifetime characteristics.

In the blue phosphorescence emitting device utilizing an N-heterocyclic carbene-based organometallic compound, due to the large HOMO energy level difference between a host and a dopant, a threshold voltage is high, and the generation region of excitons is not in an emission layer but between a hole transport region and an emission layer. Accordingly, there are problems in that the dopant in the emission layer EML acts as a hole trap site, and charge capacity properties are reduced, and device lifetime is reduced. The organometallic compound of an embodiment has a deep HOMO energy level and accordingly, reduces a threshold voltage, suppressing trap phenomenon generated due to the HOMO energy level difference with a host, and may improve emission efficiency and device lifetime characteristics, while shifting an exciton-forming region to the center of the emission layer.

The organometallic compound of an embodiment may be represented by Formula 1.

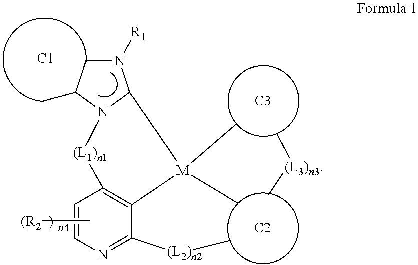

In Formula 1, M may be a metal atom bonded to tetradentate ligands. In an embodiment, M may be Pt, Pd, Cu, Ag, Au, Rh, Ir, Ru or Os. For example, M may be Pt.

In Formula 1, L₁ to L₃ may each independently be a direct linkage, *—O—*′, *—S—*′, *—C(R₁₁)(R₁₂)—*′, *—C(R₁₃)═*′, *═C(R₁₄)—*′, *—C(R₁₅)═C(R₁₆)—*′, *—C(═O)—*′, *—C(═S)—*′, *—C≡C*′, *—B(R₁₇)—*′, *—N(R₁₈)—*′, *—P(R₁₉)—*′, *—Si(R₂₀)(R₂₁)—*′, *—P(R₂₂)(R₂₃)—*′ or *—Ge(R₂₄)(R₂₅)—*′.

In Formula 1, rings C1 to C3 may each independently be a substituted or unsubstituted hydrocarbon ring of 5 to 60 ring-forming carbon atoms, or a substituted or unsubstituted heterocycle of 2 to 60 ring-forming carbon atoms. In an embodiment, rings C1 to C3 may each independently be a substituted or unsubstituted aromatic hydrocarbon ring of 5 to 60 ring-forming carbon atoms, or a substituted or unsubstituted aromatic heterocycle of 2 to 60 ring-forming carbon atoms. Rings C1 to C3 may be combined with adjacent groups to form rings. For example, ring C2 may be combined with adjacent L₃ to form a ring. In an embodiment, n3 may be 1, L₃ may be *—N(R₁₈)*′, and ring C2 may be connected with *—N(R₁₈)—*′. However, an embodiment of the present disclosure is not limited thereto.

In Formula 1, R₁ may be a hydrogen atom, a deuterium atom, a halogen atom, a substituted or unsubstituted thio group, a substituted or unsubstituted oxy group, a substituted or unsubstituted boron group, a substituted or unsubstituted amine group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In an embodiment, R₁ may be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₁ may be a substituted or unsubstituted methyl group, a substituted or unsubstituted isopropyl group, a substituted or unsubstituted t-butyl group, a substituted or unsubstituted 2,2-dimethylbutyl group, a substituted or unsubstituted phenyl group, a substituted or unsubstituted biphenyl group, or a substituted or unsubstituted pyridine group.

In Formula 1, R₂, and R₁₁ to R₂₅ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, R₂, R₃, and R₁₁ to R₂₅ may be combined with adjacent groups to form rings.

In Formula 1, n1 to n3 may each independently be an integer from 1 to 3. In some embodiments, when n1 to n3 are 2 or 3, multiple L₁ to L₃ connecting units are provided, and L₁ to L₃ connecting units connected with each other may represent a connection of adjacent first to fourth ligands from each other. When n1 to n3 are 2 or 3, multiple L₁ to L₃ connecting units may be the same or different from each other.

In Formula 1, n4 is an integer from 0 to 2. In Formula 1, when n4 is 0, the organometallic compound of an embodiment may be unsubstituted with R₂. An embodiment in which n4 is 2, and R₂ are all hydrogen atoms in Formula 1, may be the same as an embodiment in which n4 is 0 in Formula 1. When n4 is 2, multiple R₂ may be all the same, or at least one selected from among the multiple R₂ may be different.

In an embodiment, the organometallic compound represented by Formula 1 may be represented by Formula 2.

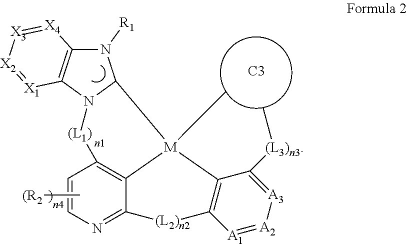

Formula 2 corresponds to Formula 1 in which rings C1 and C2 are embodied.

In Formula 2, X₁ to X₄, and A₁ to A₃ may each independently be N or CR₃.

In Formula 2, R₃ may be a hydrogen atom, a deuterium atom, a halogen atom, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, R₃ may be combined with an adjacent group to form a ring. For example, R₃ may be combined with an adjacent group to form a fused ring. The ring formed by the combination with an adjacent group may be a hydrocarbon ring of 5 to 30 ring-forming carbon atoms, or a heterocycle of 2 to 30 ring-forming carbon atoms.

In Formula 2, the same definitions for M, C3, L₁ to L₃, R₁, R₂, and n1 to n4 referring to Formula 1 may be applied.

In an embodiment, the organometallic compound represented by Formula 2 may be represented by Formula 3.

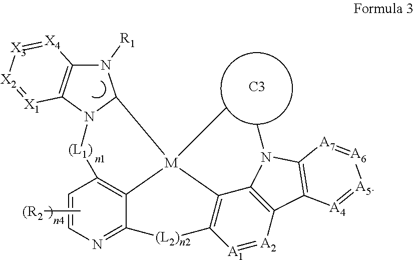

Formula 3 corresponds to Formula 2 in which the type or kind of L₃ is specified. Formula 3 represents Formula 2 in which L₃ is *—N(R₁₈)—*′, and a substituent represented by R₁₈ of *—N(R₁₈)—*′ is connected with A₃ to form a ring.

In Formula 3, A₄ to A₇ may each independently be N or CR₄. In an embodiment, A₄ to A₇ may all be CR₄. In some embodiments, at least one selected from among A₄ to A₇ may be N, and the remainder (i.e., those that are not N) may be CR₄. For example, one or two selected from among A₄ to A₇ may be N, and the remainder may be CR₄. However, an embodiment of the present disclosure is not limited thereto.

In Formula 3, R₄ may be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₄ may be a hydrogen atom, a halogen atom, a substituted or unsubstituted t-butyl group, a substituted or unsubstituted phenyl group, a substituted or unsubstituted pyridine group, a substituted or unsubstituted 1,3,5-triazine group, a substituted or unsubstituted carbazole group, a substituted or unsubstituted dibenzofuran group, or a substituted or unsubstituted dibenzothiophene group.

In Formula 3, the same definitions for M, C3, L₁, L₂, X₁ to X₄, R₁, R₂, n1, n2, n4, A₁, and A₂ referring to Formula 1 and Formula 2 may be applied.

In an embodiment, the organometallic compound represented by Formula 2 may be represented by Formula 4.

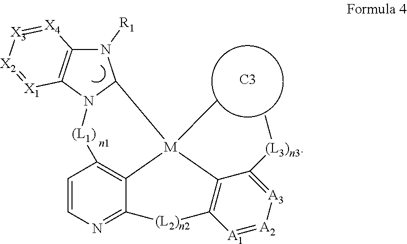

Formula 4 corresponds to Formula 2 in which the type or kind of the R₂ substituent is specified. Formula 4 represents Formula 2 in which the substituent represented by R₂ is specified as a hydrogen atom.

In Formula 4, the same definitions for M, C3, L₁ to L₃, R₁, X₁ to X₄, n1 to n3, and A₁ to A₃ referring to Formula 1 and Formula 2 may be applied.

In an embodiment, the organometallic compound represented by Formula 2 may be represented by any one selected from among Formula 5-1 to Formula 5-3.

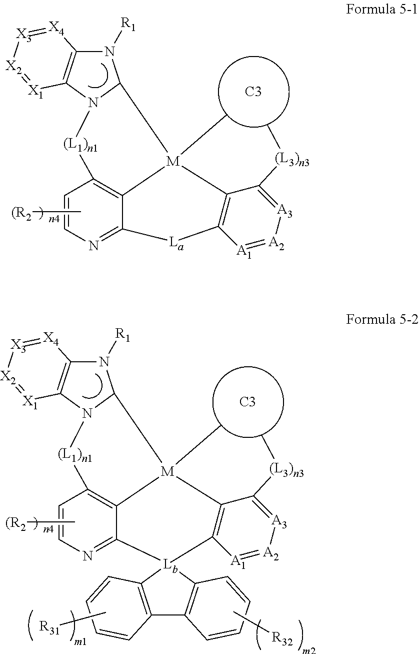

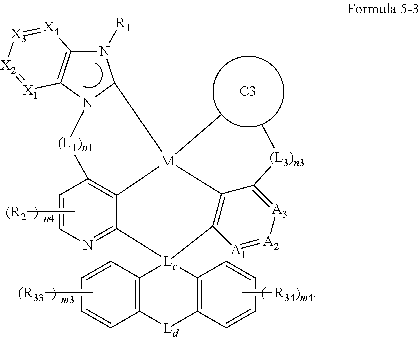

Formula 5-1 to Formula 5-3 correspond to Formula 2 in which the type or kind of L₂ is embodied.

In Formula 5-1, Lₐ may be *—O—*′, *—S—*′, *—C(R₃₅)(R₃₆)—*′, *—N(R₃₇)—*′, or *—Si(R₃₈)(R₃₉)—*′.

In Formula 5-3, L_{b}, and L_{c} may each independently be C or Si.

In Formula 5-3, L_{d} may be *—O—*′, or *—S—*′.

In Formula 5-2 and Formula 5-3, R₃₁ to R₃₉ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₃₁ to R₃₉ may each independently be a hydrogen atom, a substituted or unsubstituted methyl group, or a substituted or unsubstituted phenyl group.

In Formula 5-2 and Formula 5-3, m1 to m4 may each independently be an integer from 0 to 4. When m1 to m4 are 0, the organometallic compound of an embodiment may be unsubstituted with R₃₁ to R₃₄, respectively. Embodiments in which m1 to m4 are 4, and R₃₁ to R₃₄ are hydrogen atoms, may be the same as embodiments in which m1 to m4 are 0, respectively. When m1 to m4 are integers of 2 or more, each of multiple R₃₁ to R₃₄ may be all the same, or at least one selected from among each of multiple R₃₁ to R₃₄ may be different.

In Formula 5-1 to Formula 5-3, the same definitions for M, C3, L₁, L₃, X₁ to X₄, R₁, R₂, n1, n3, n4, and A₁ to A₃ referring to Formula 1 and Formula 2 may be applied.

In an embodiment, the organometallic compound represented by Formula 2 may be represented by Formula 6-1 or Formula 6-2.

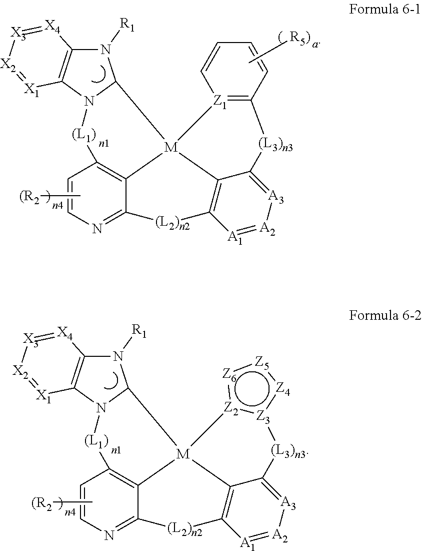

Formula 6-1 and Formula 6-2 correspond to Formula 2 in which ring C3 is embodied.

In Formula 6-1 and Formula 6-2, Z₁ to Z₃ may each independently be N or C.

In Formula 6-1 and Formula 6-2, Z₄ to Z₆ may each independently be N, NR₆, CR₇, O, or S.

In Formula 6-1, R₅ may be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₅ may be a hydrogen atom, a halogen atom, a cyano group, a substituted or unsubstituted methyl group, a substituted or unsubstituted isopropyl group, a substituted or unsubstituted t-butyl group, a substituted or unsubstituted 2,2-dimethylbutyl group, a substituted or unsubstituted N,N-dimethylamine group, a substituted or unsubstituted methoxy group, a substituted or unsubstituted phenyl group, a substituted or unsubstituted pyridine group, a substituted or unsubstituted pyrimidine group, a substituted or unsubstituted 1,3,5-triazine group, or a substituted or unsubstituted carbazole group.

In Formula 6-1 and Formula 6-2, R₆ and R₇ may each independently be a hydrogen atom, a deuterium atom, a halogen atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atom. In some embodiments, R₆ and R₇ may be combined with an adjacent group to form a ring.

In Formula 6-1, “a” is an integer from 0 to 4. In Formula 6-1, when “a” is 0, the organometallic compound of an embodiment may be unsubstituted with R₅. An embodiment in which “a” is 4, and R₅ are all hydrogen atoms in Formula 6-1, may be the same as an embodiment in which “a” is 0 in Formula 6-1. When “a” is an integer of 2 or more, multiple R₅ may be all the same, or at least one selected from among the multiple R₅ may be different.

In Formula 6-1 and Formula 6-2, the same definitions for M, L₁ to L₃, X₁ to X₄, R₁, R₂, n1 to n4, and A₁ to A₃ referring to Formula 1 and Formula 2 may be applied.

In an embodiment, the organometallic compound represented by Formula 6-1 may be represented by any one selected from among Formula 7-1 to Formula 7-6.

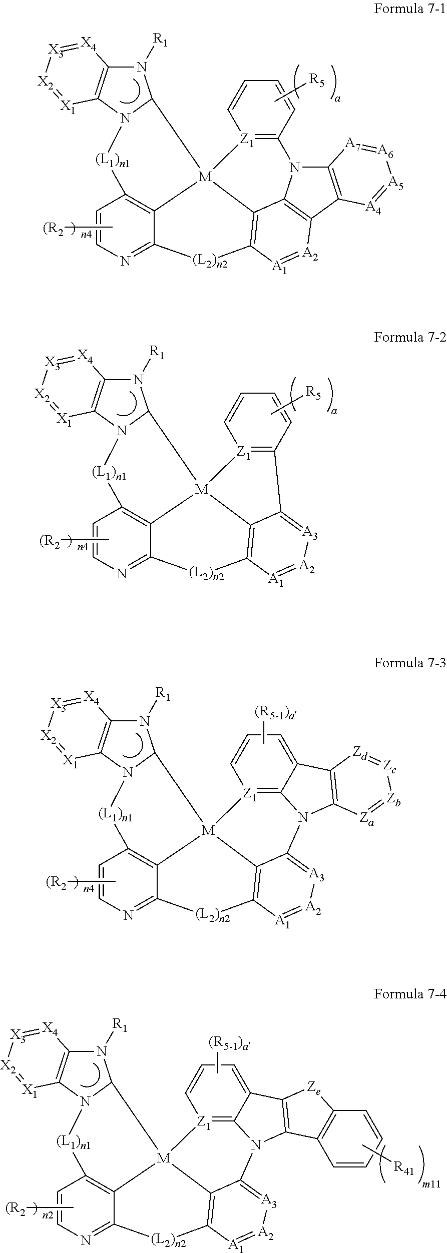

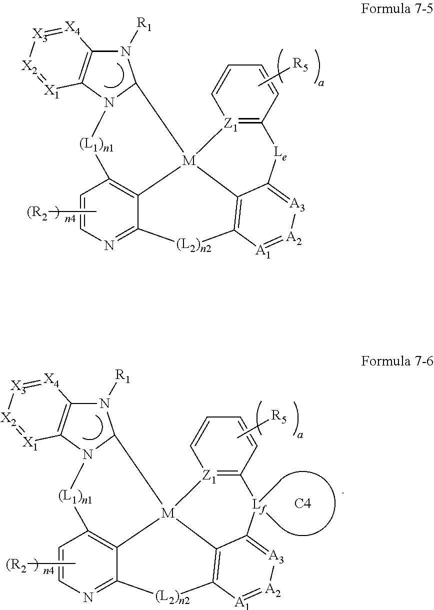

Formula 7-1 to Formula 7-6 represent Formula 6-1 in which the type or kind of L₃ is embodied.

In Formula 7-3, A₄ to A₇, and Zₐ to Z_{d} may each independently be N, or CR₄₂.

In Formula 7-4, Zₑ may be NR₄₃, or O. For example, Zₑ may be O.

In Formula 7-5, Lₑ may be *—O—*′, *—S—*′, or *—N(R₄₄)—*′.

In Formula 7-6, L_{f} may be C or Si.

In Formula 7-3 to Formula 7-6, R₅₋₁, and R₄₁ to R₄₄ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₅₋₁, and R₄₁ to R₄₄ may each independently be a hydrogen atom or a substituted or unsubstituted phenyl group.

In Formula 7-6, ring C4 may be a substituted or unsubstituted hydrocarbon ring of 5 to 60 ring-forming carbon atoms, or a substituted or unsubstituted heterocycle of 2 to 60 ring-forming carbon atoms.

In Formula 7-3 and Formula 7-4, a′ is an integer from 0 to 3. In Formula 7-3 and Formula 7-4, when a′ is 0, the organometallic compound of an embodiment may be unsubstituted with R₅₋₁. Embodiments of Formula 7-3 and Formula 7-4, in which a′ is 3, and R₅₋₁ are all hydrogen atoms, may be the same as embodiments of Formula 7-3 and Formula 7-4, in which a′ is 0. When a′ is an integer of 2 or more, multiple R₅₋₁ may be all the same, or at least one selected from among multiple R₆₋₁ may be different.

In Formula 7-4, m11 is an integer from 0 to 4. In Formula 7-4, when m11 is 0, the organometallic compound of an embodiment may be unsubstituted with R₄₁. An embodiment of Formula 7-4 in which m11 is 4, and R₄₁ are all hydrogen atoms, may be the same as an embodiment of Formula 7-4 in which m11 is 0. When m11 is an integer of 2 or more, multiple R₄₁ may be all the same, or at least one selected from among multiple R₄₁ may be different.

In Formula 7-1 to Formula 7-6, the same definitions for M, L₁, L₂, X₁ to X₄, Z₁, R₁, R₂, n1, n2, n4, “a”, R₅, and A₁ to A₃ referring to in Formula 1, Formula 2 and Formula 6-1 may be applied.

In an embodiment, the organometallic compound represented by Formula 6-2 may be represented by any one selected from among Formula 8-1 to Formula 8-6.

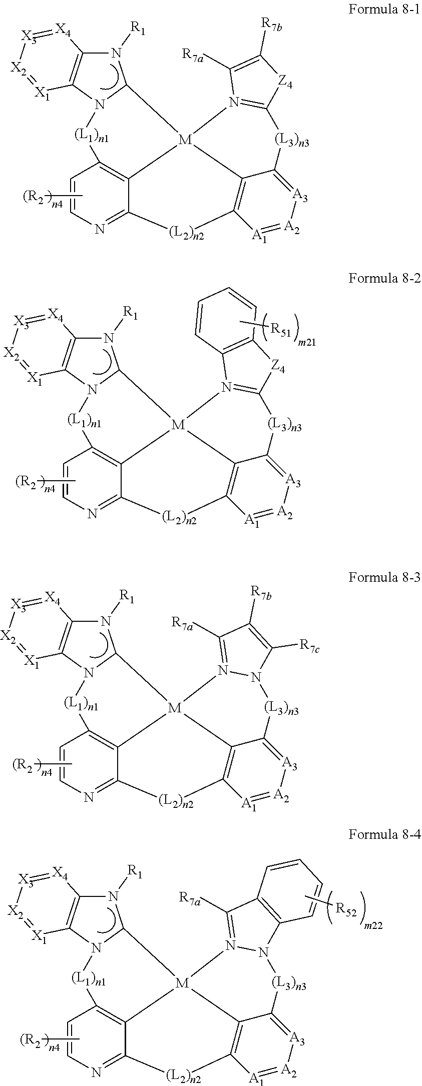

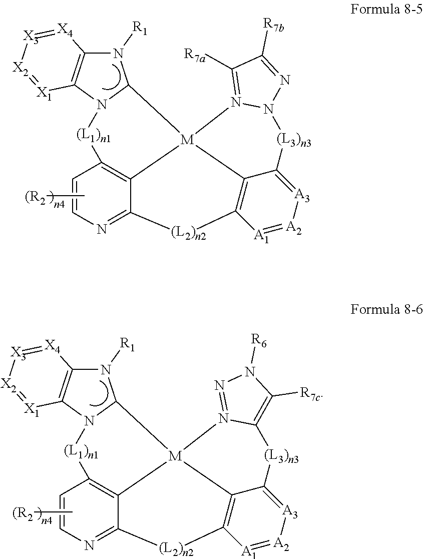

In Formula 8-1 to Formula 8-6, R₇ₐ to R_{7c}, R₅₁, and R₅₂ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₇ₐ to R_{7c}, R₅₁, and R₅₂ may each independently be a hydrogen atom, a substituted or unsubstituted methyl group, or a substituted or unsubstituted phenyl group.

In Formula 8-2 and Formula 8-4, m21 and m22 may each independently be an integer from 0 to 4. When m21 and m22 are 0, the organometallic compound of an embodiment may be unsubstituted with R₅₁ and R₅₂, respectively. Embodiments in which m21 and m22 are 4, and R₅₁ and R₅₂ are hydrogen atoms, may be the same as embodiments in which m21 and m22 are 0, respectively. When m21 and m22 are integers of 2 or more, each of multiple R₅₁ and R₅₂ may be all the same, or at least one selected from among each of multiple R₅₁ and R₅₂ may be different.

In Formula 8-1 and Formula 8-2, the same definitions for M, L₁ to L₃, X₁ to X₄, R₁, R₂, n1 to n4, Z₄, A₁ to A₃, and R₆ referring to Formula 1, Formula 2 and Formula 6-2 may be applied.

The organometallic compound of an embodiment may be any one selected from among the compounds represented in Compound Group 1. The light emitting device ED of an embodiment may include at least one organometallic compound selected from among the compounds represented in Compound Group 1 in an emission layer EML.

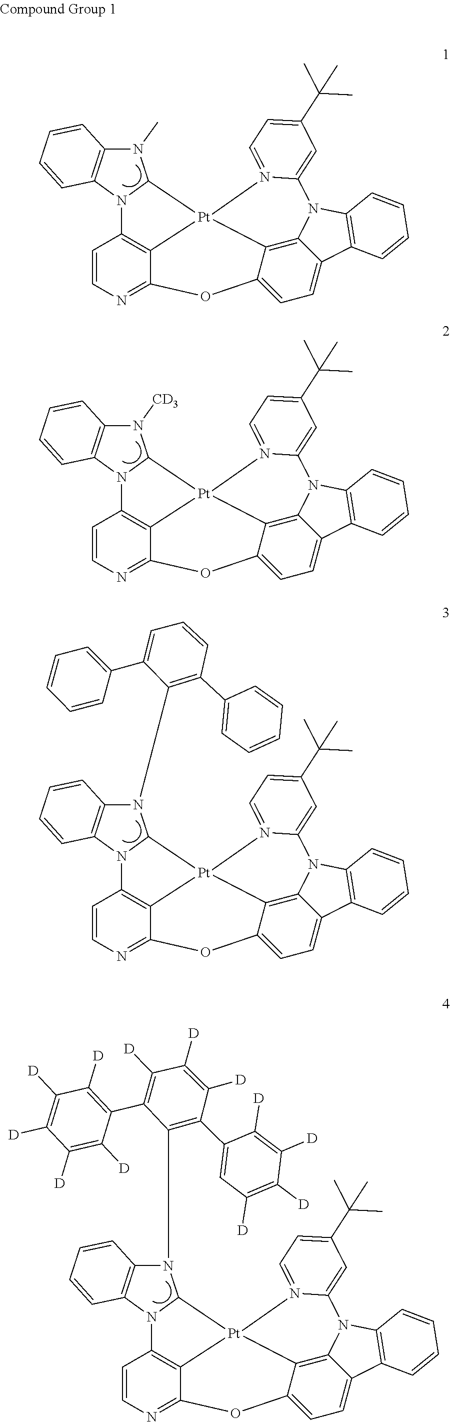

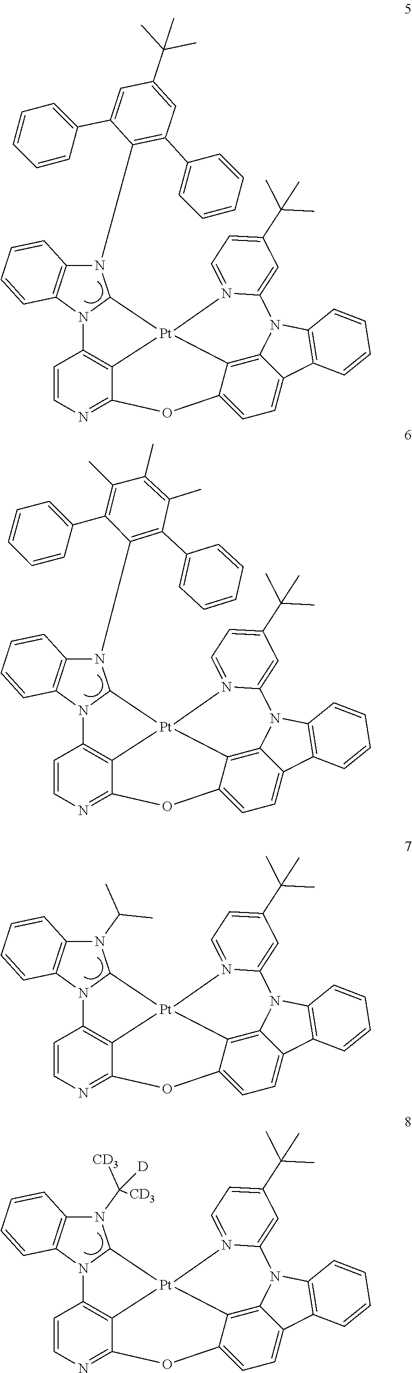

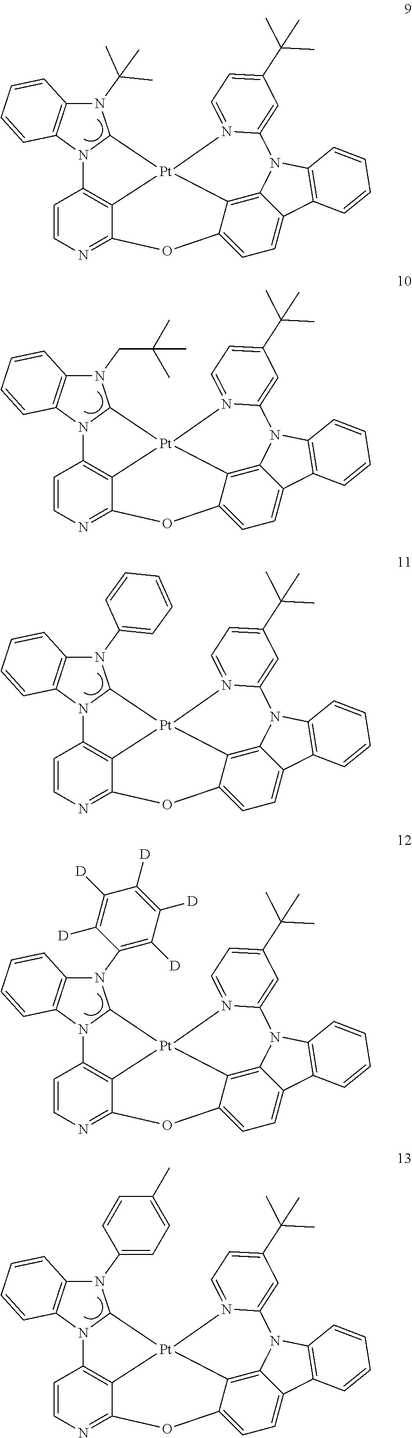

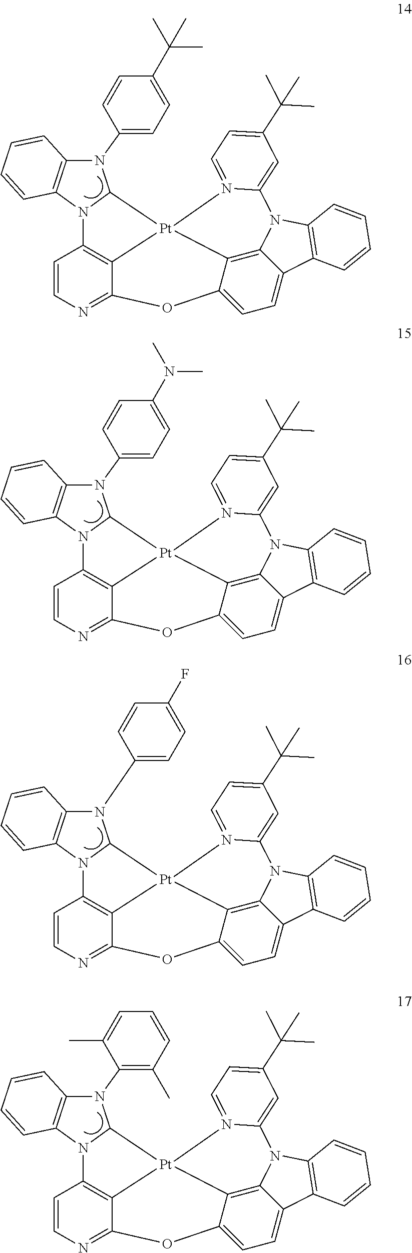

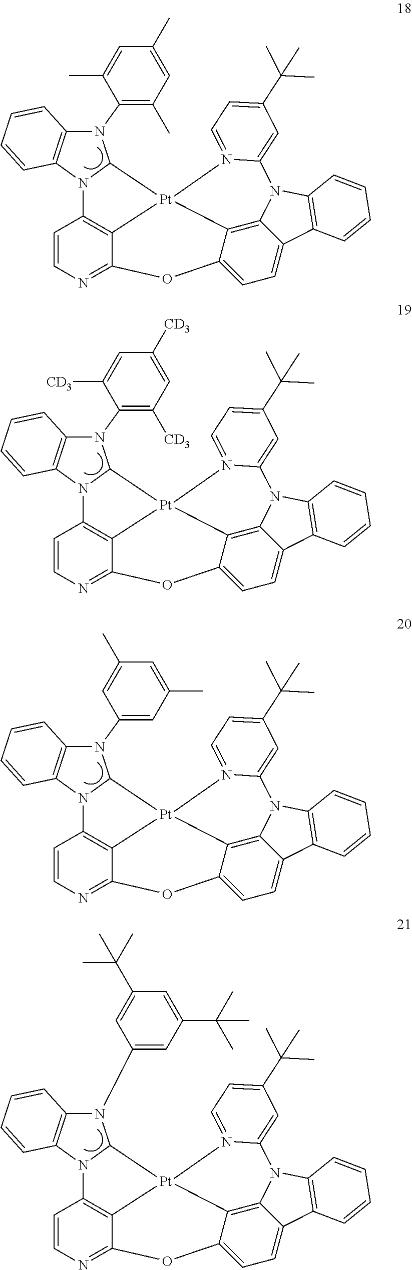

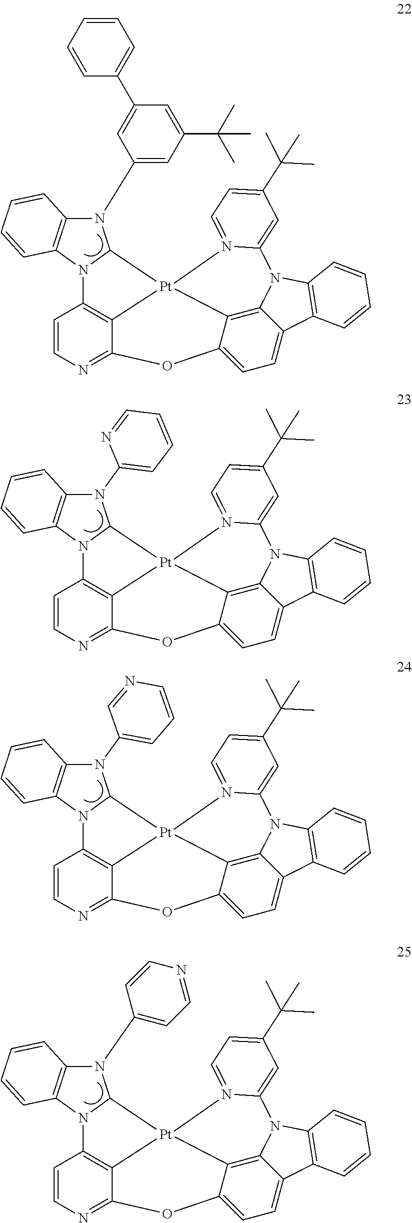

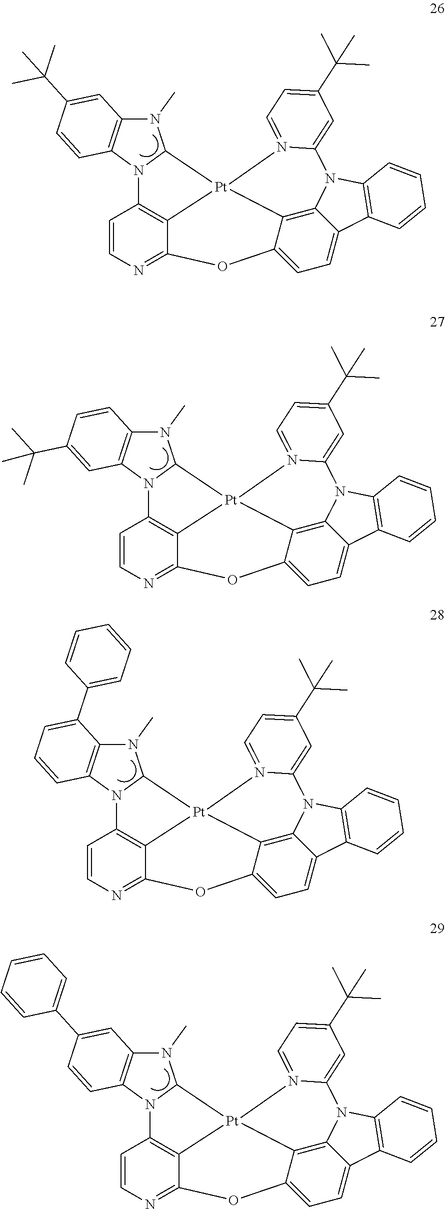

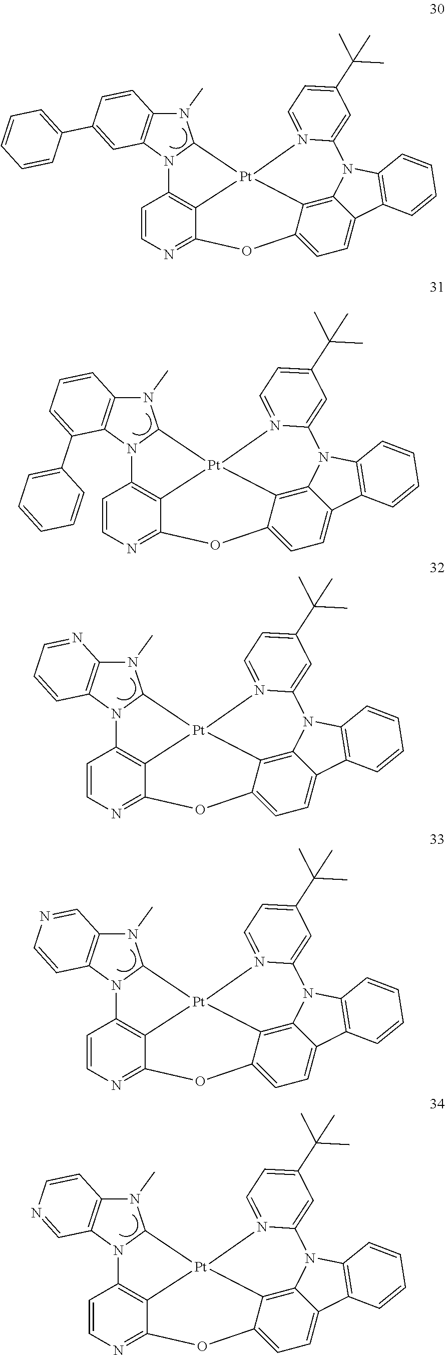

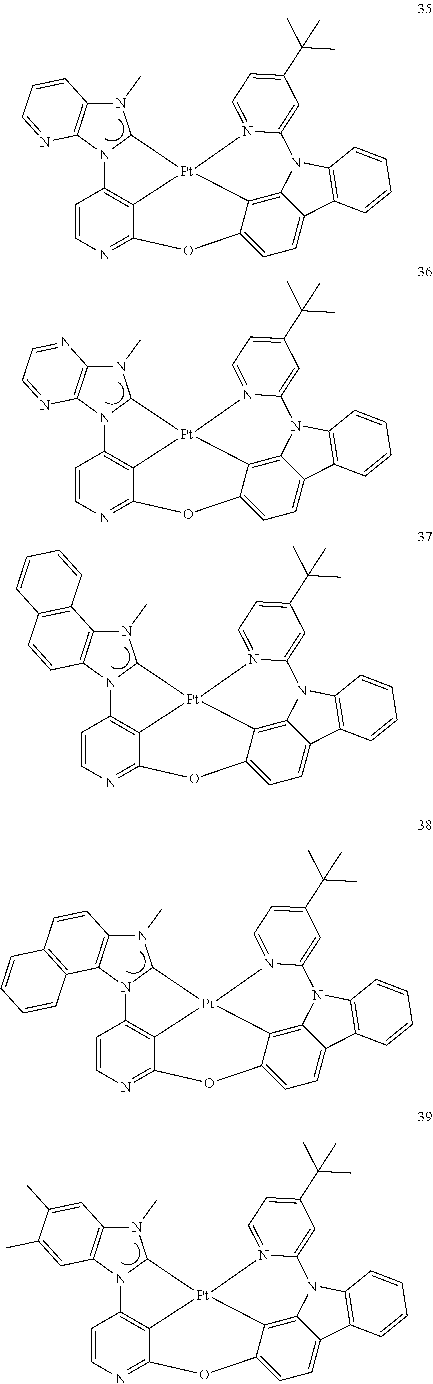

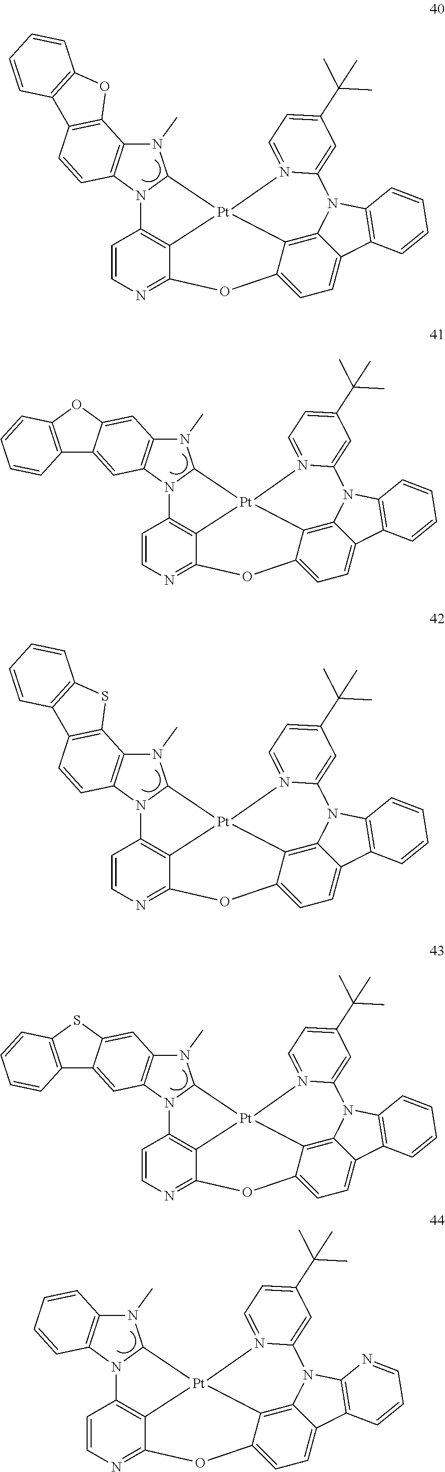

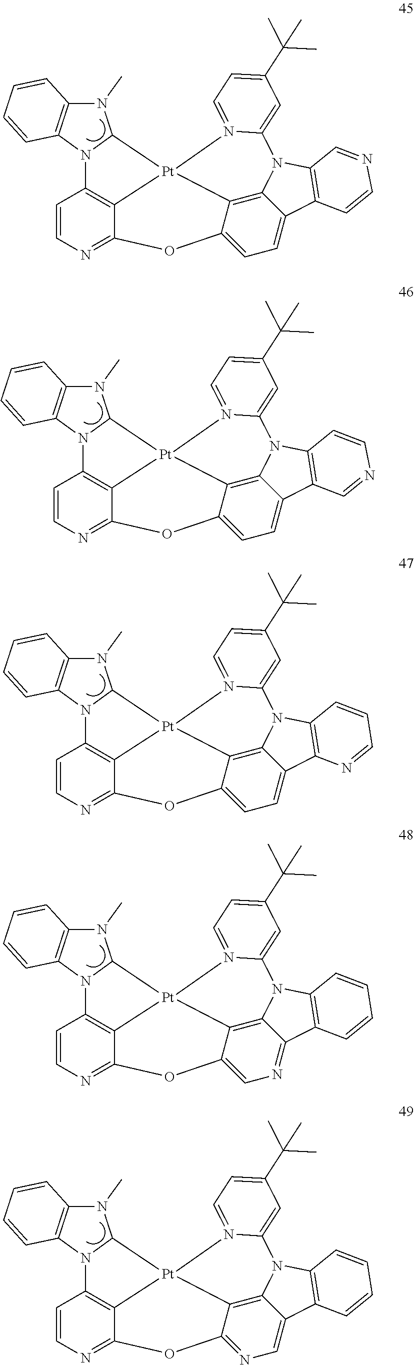

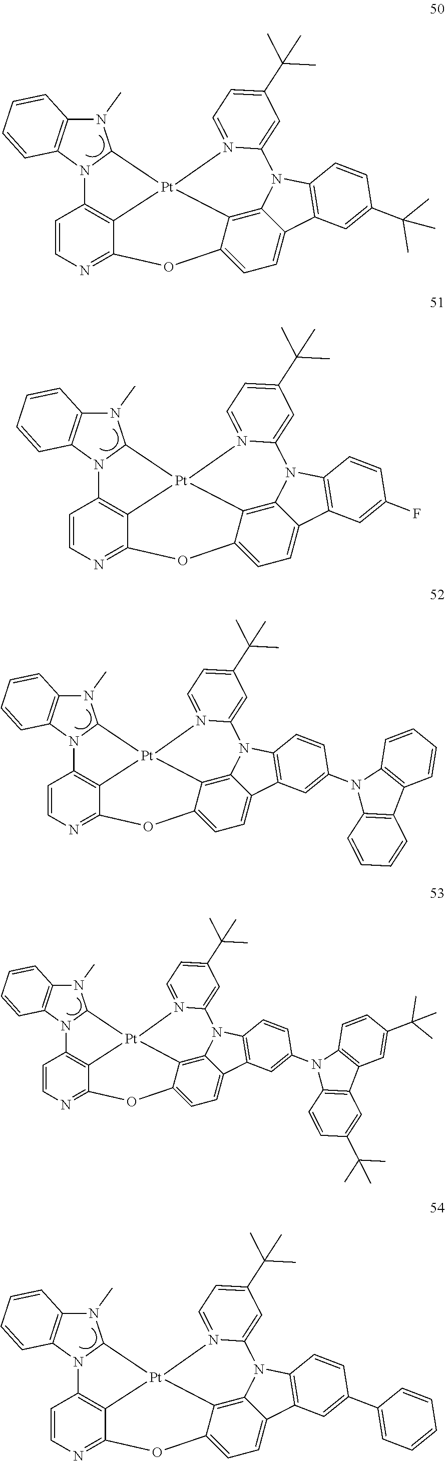

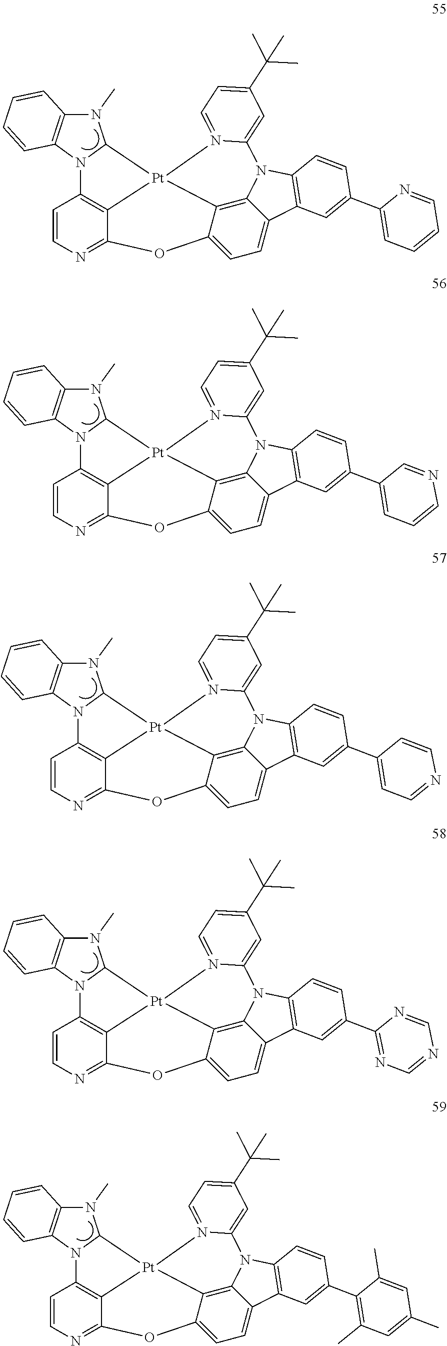

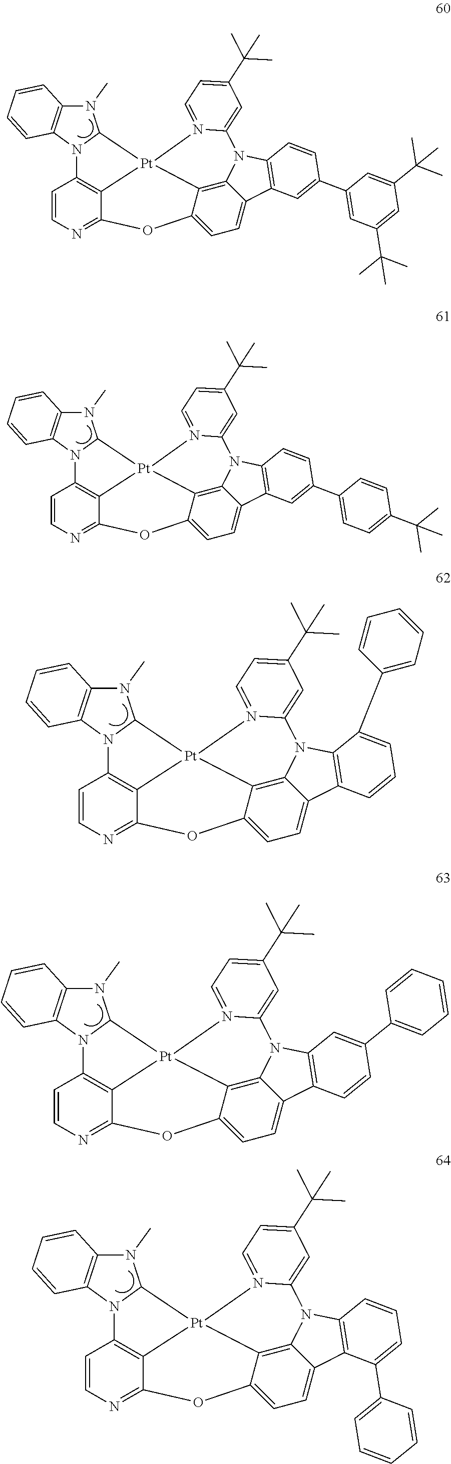

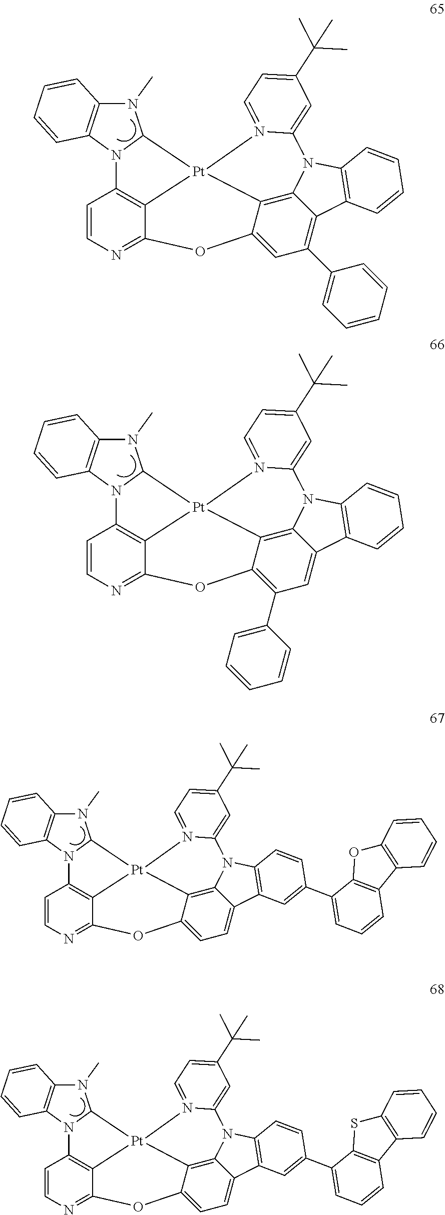

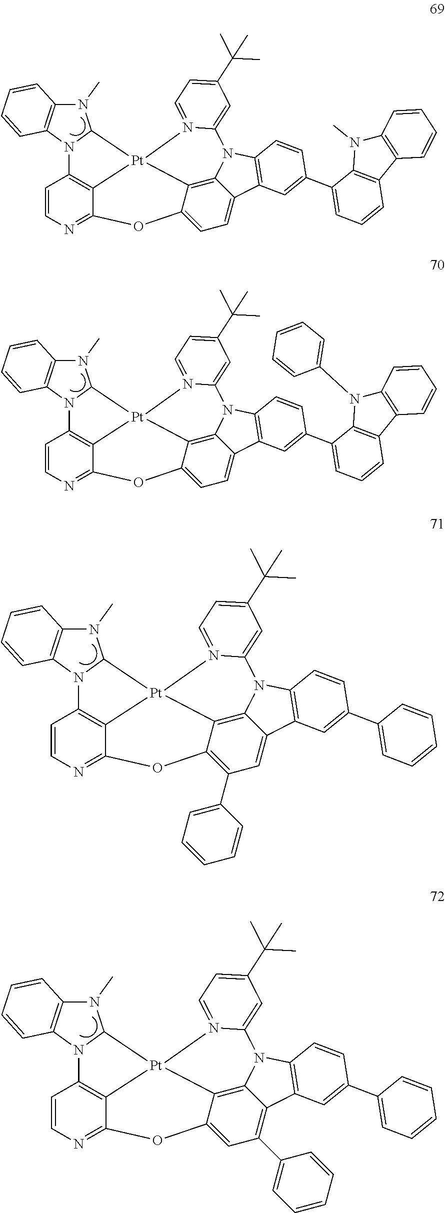

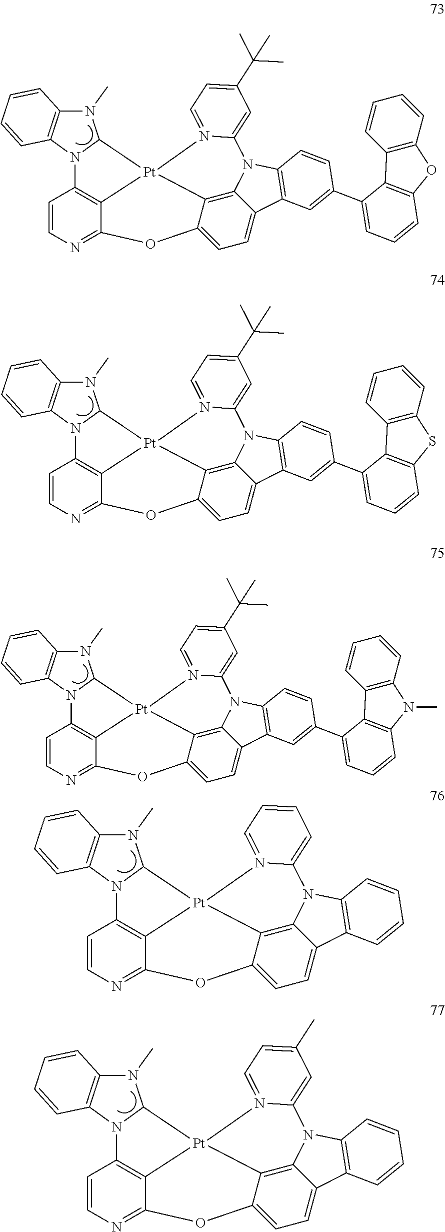

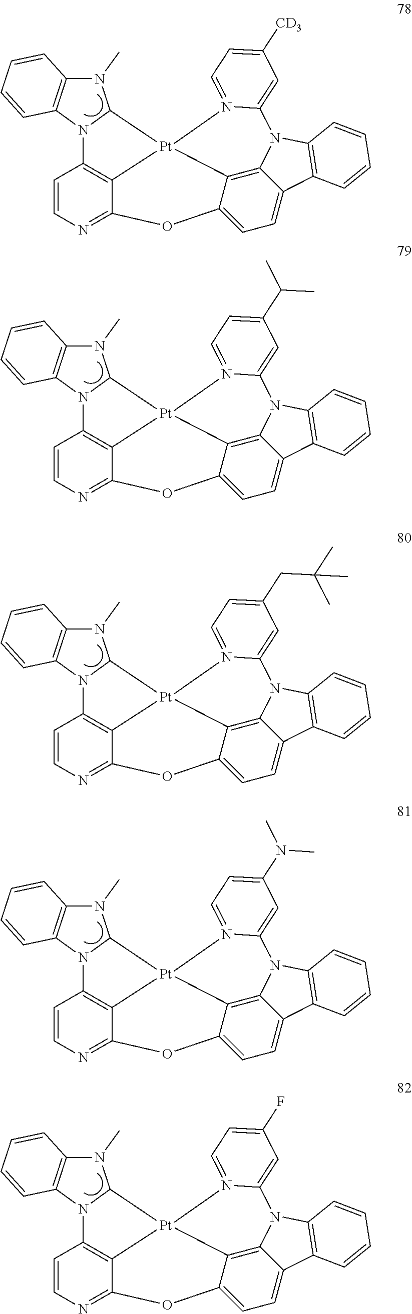

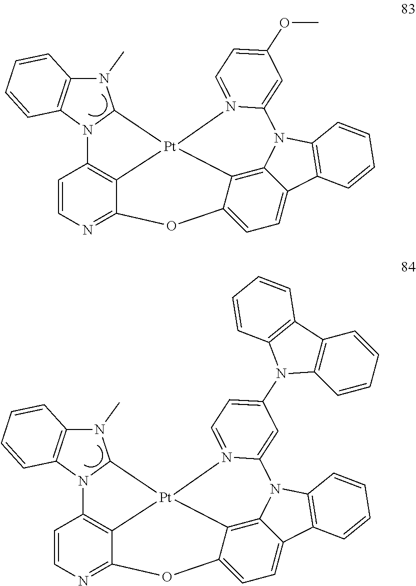

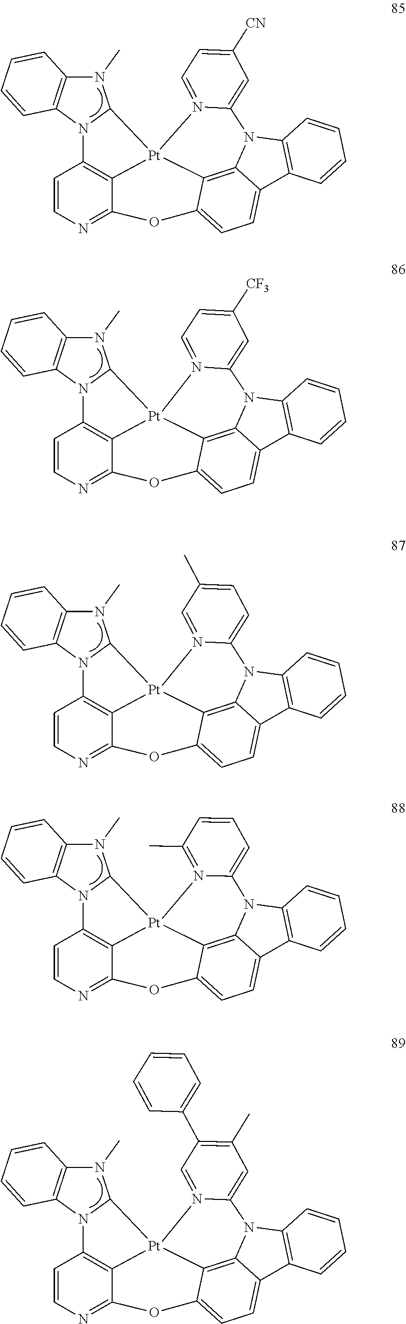

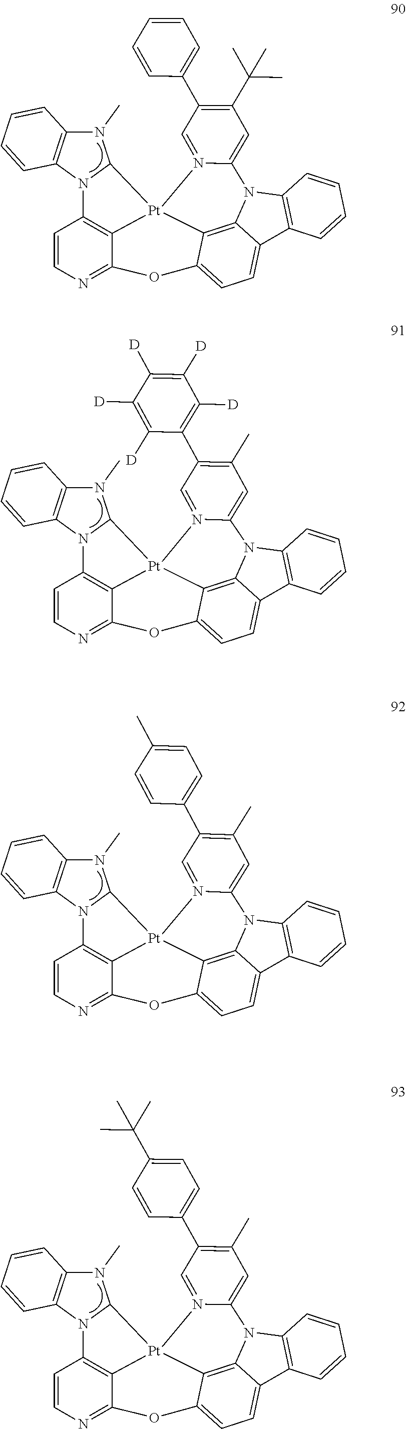

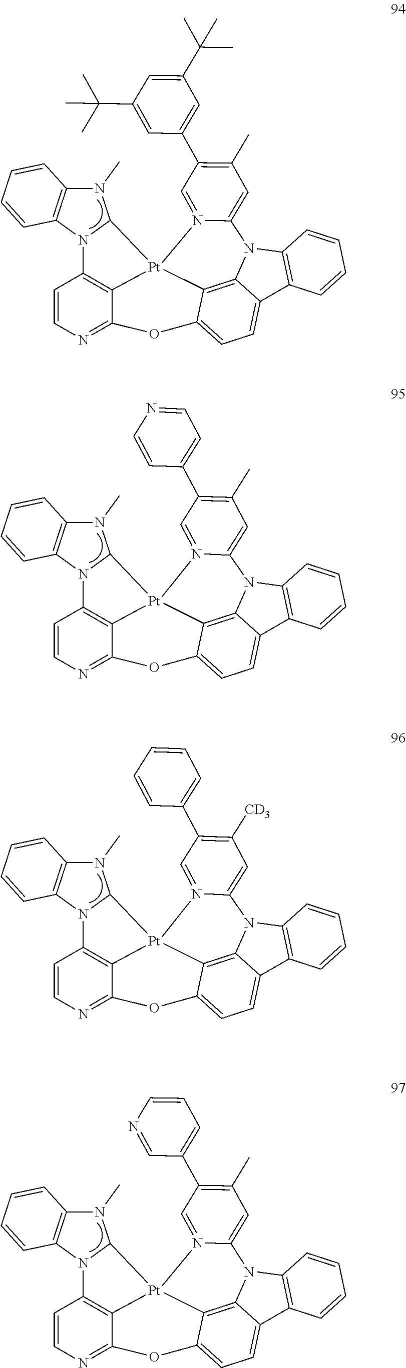

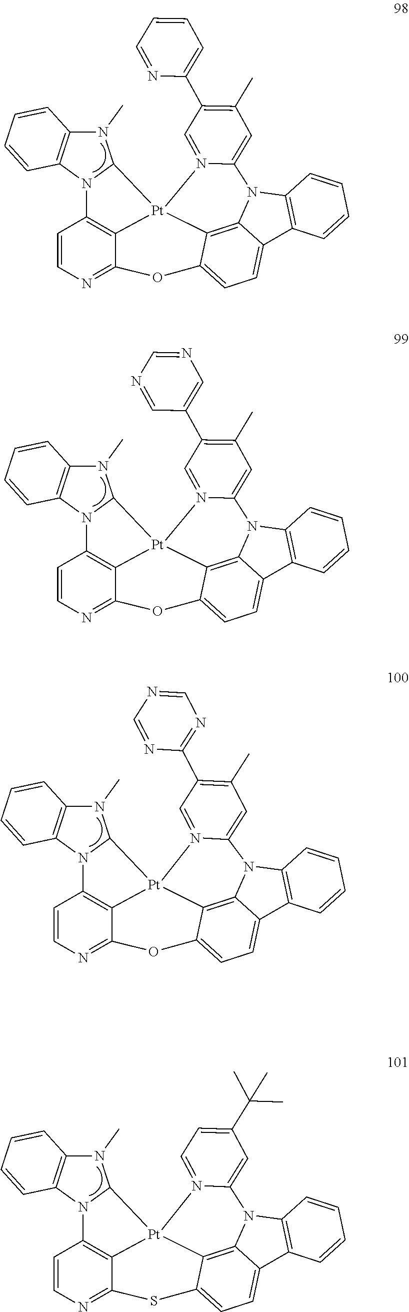

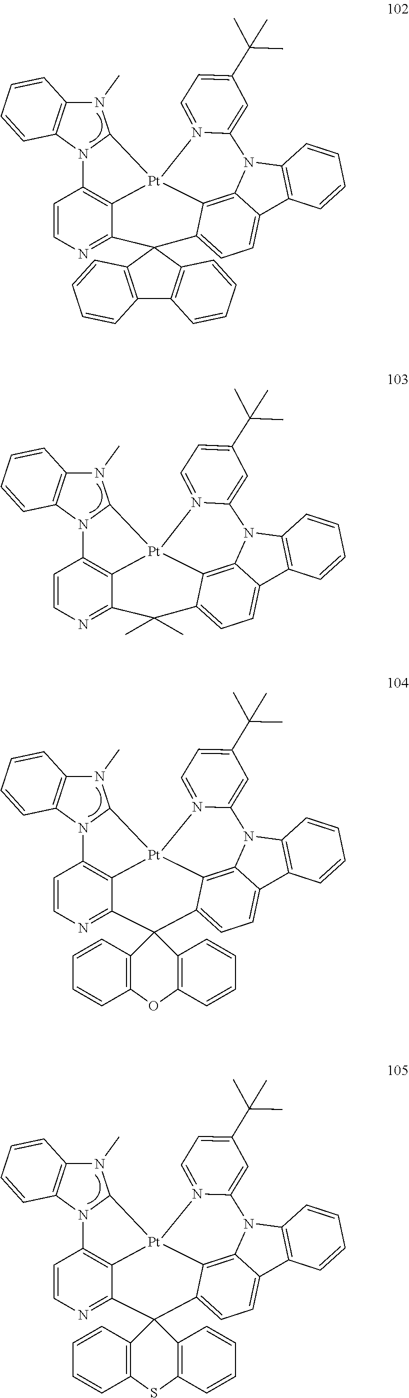

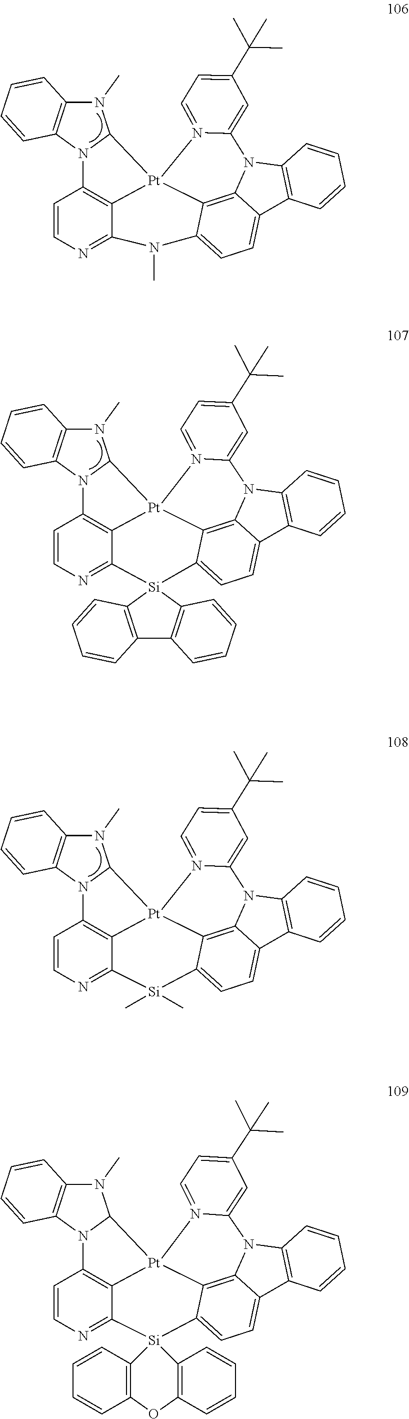

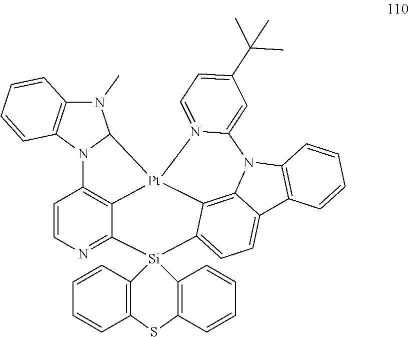

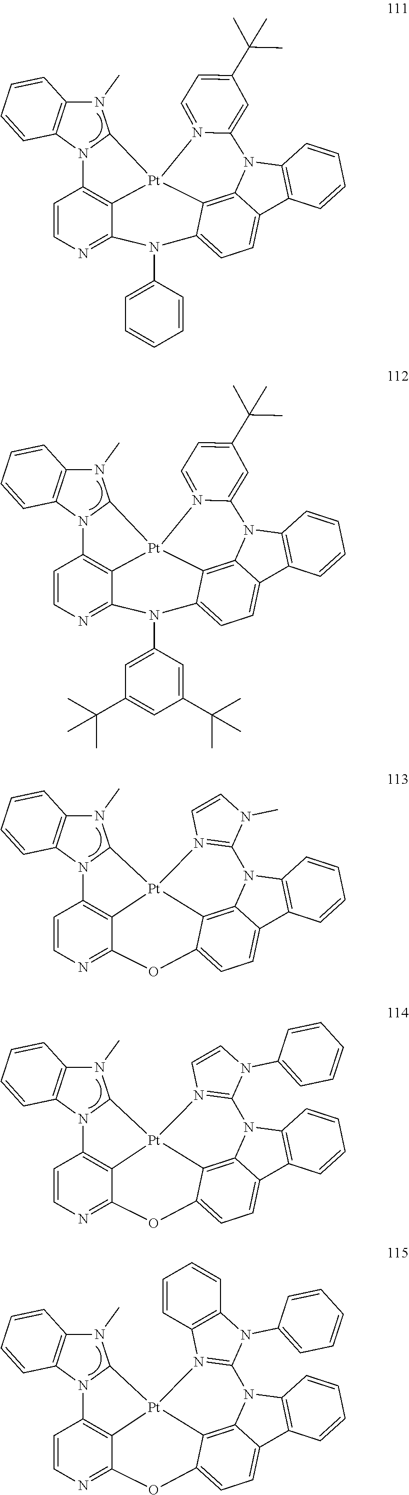

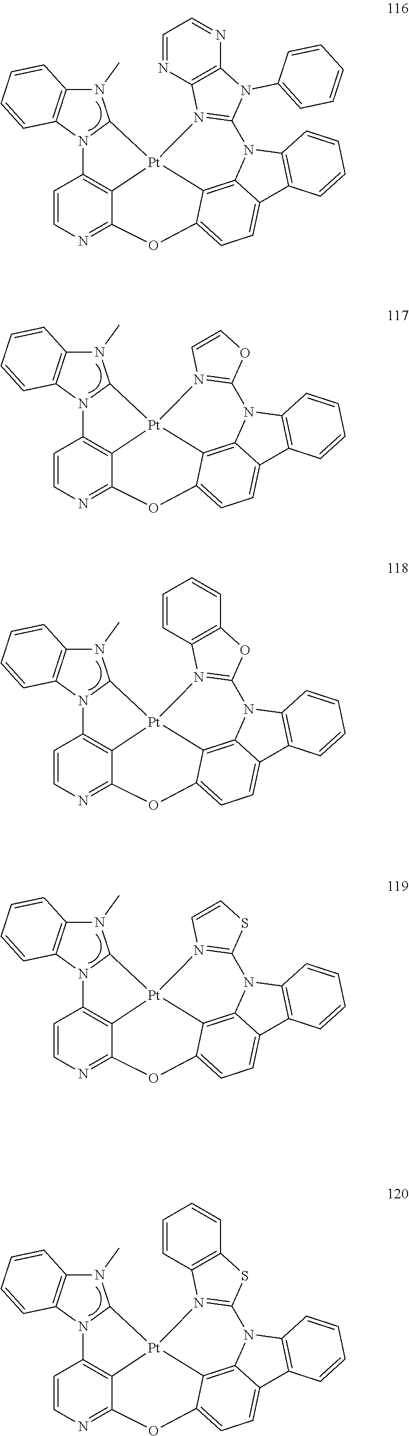

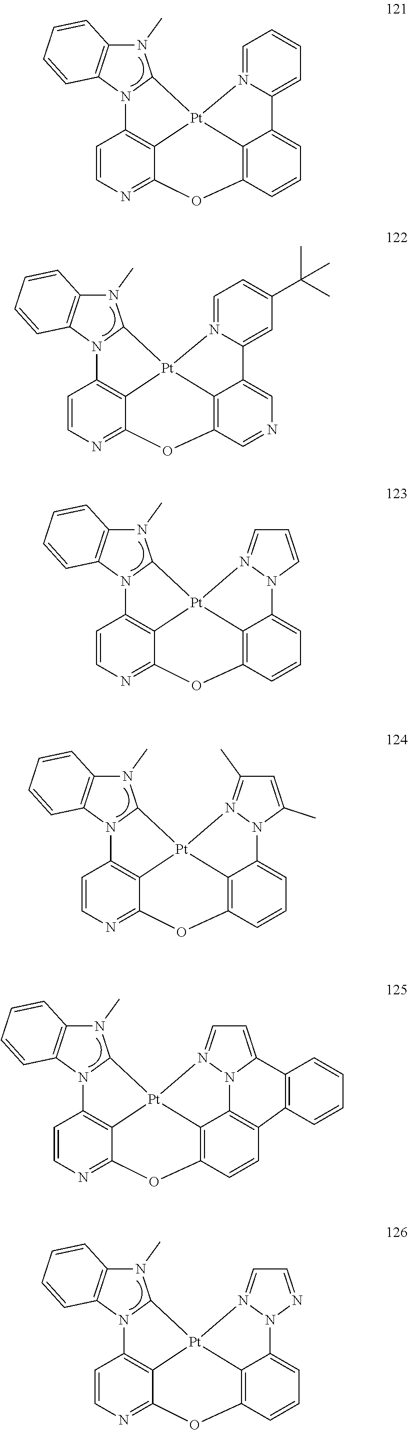

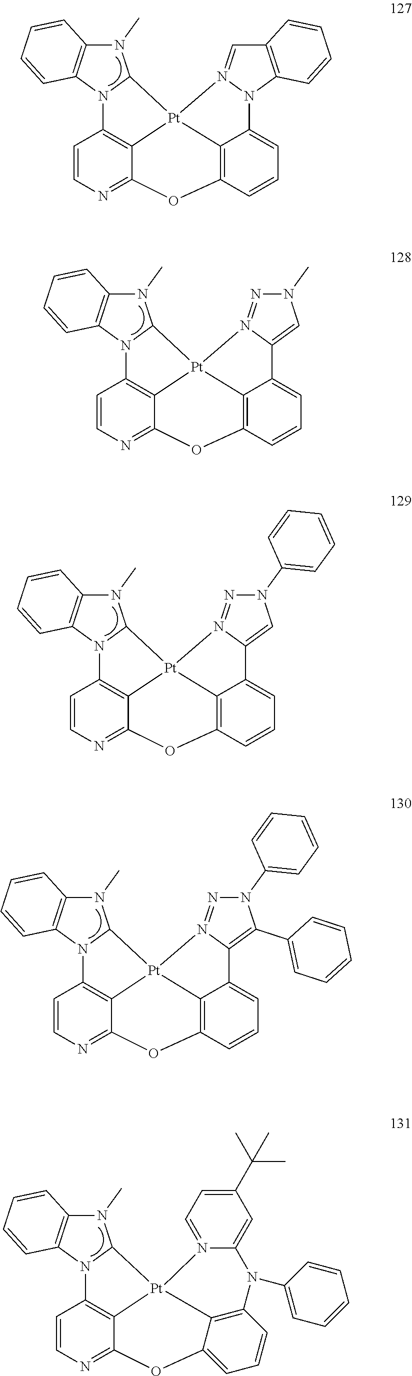

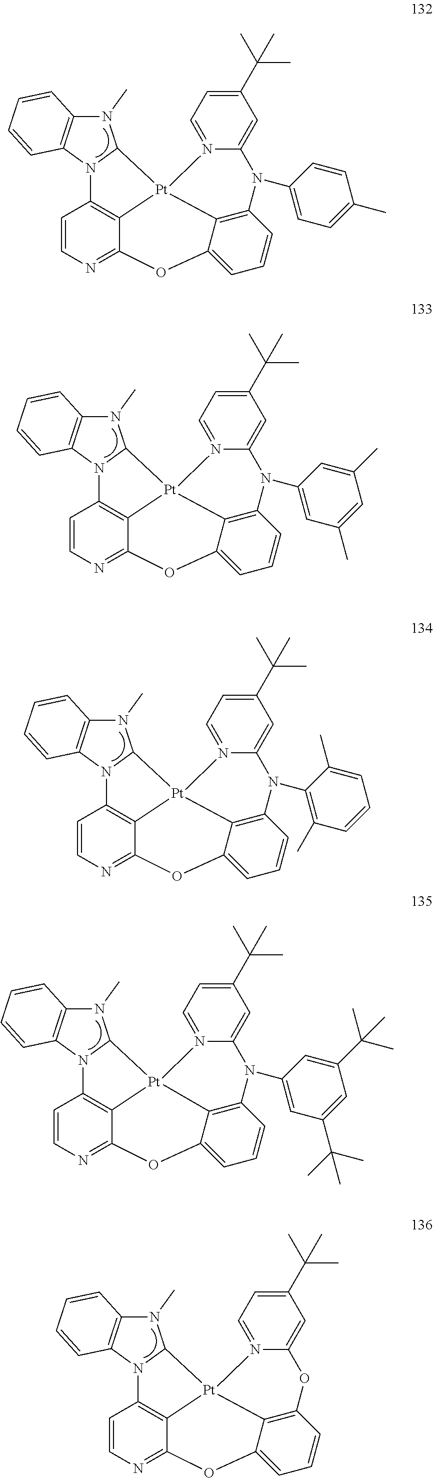

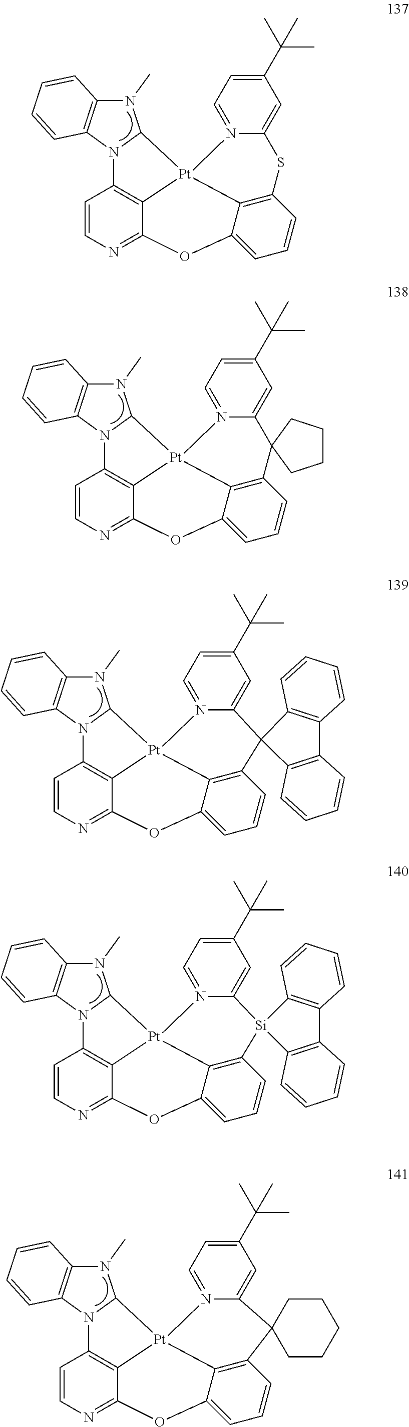

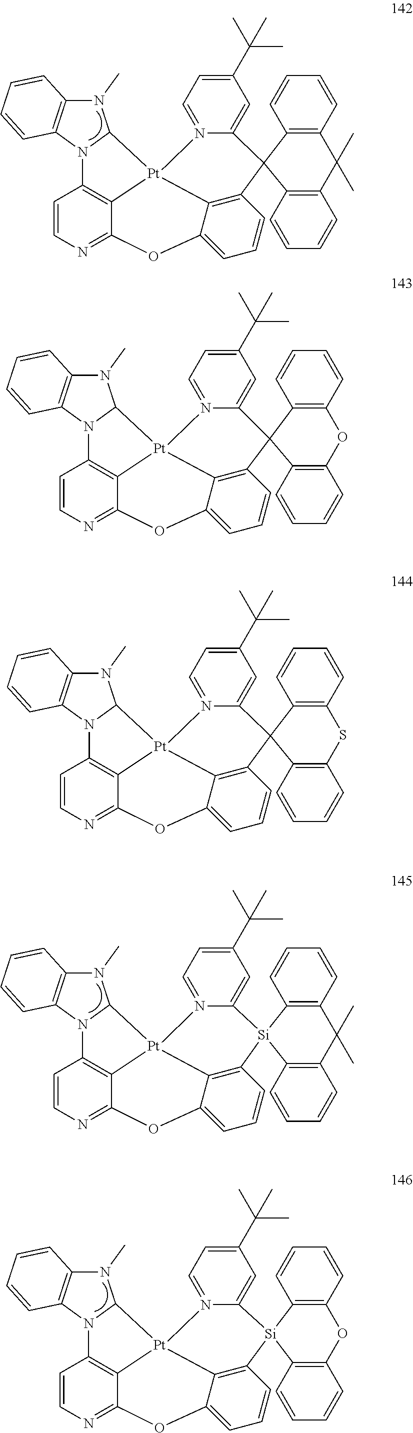

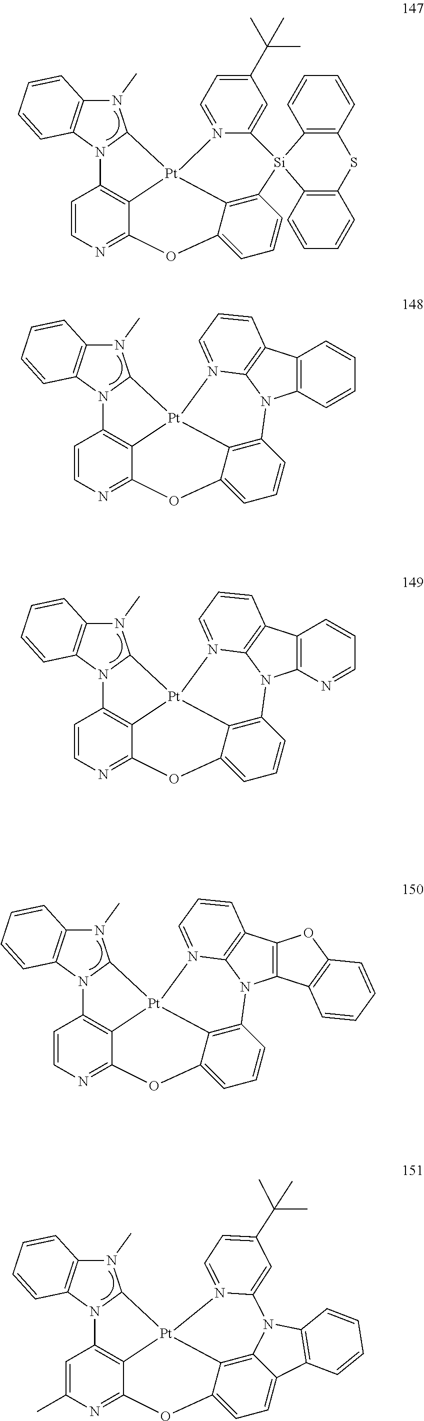

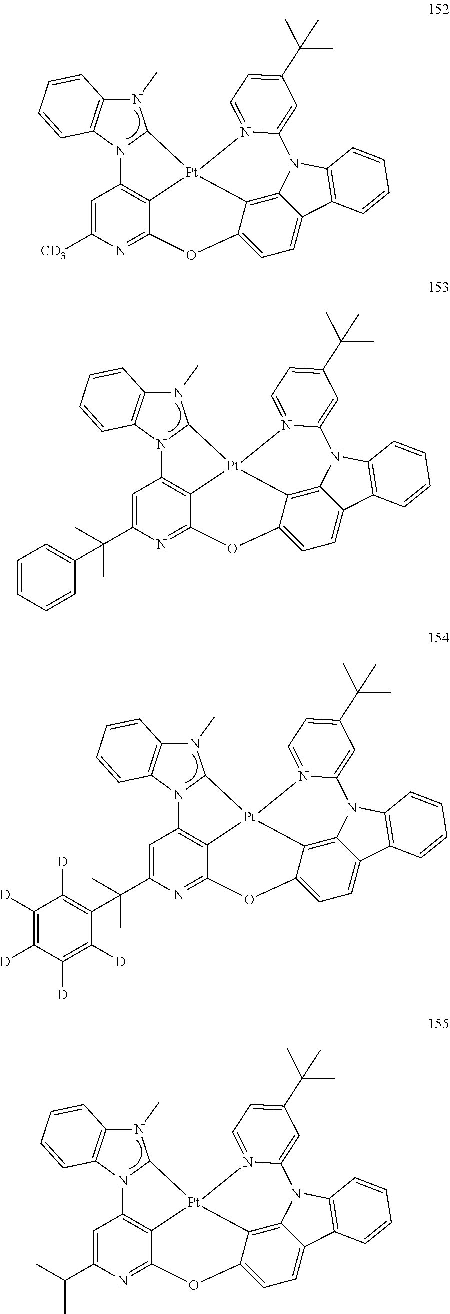

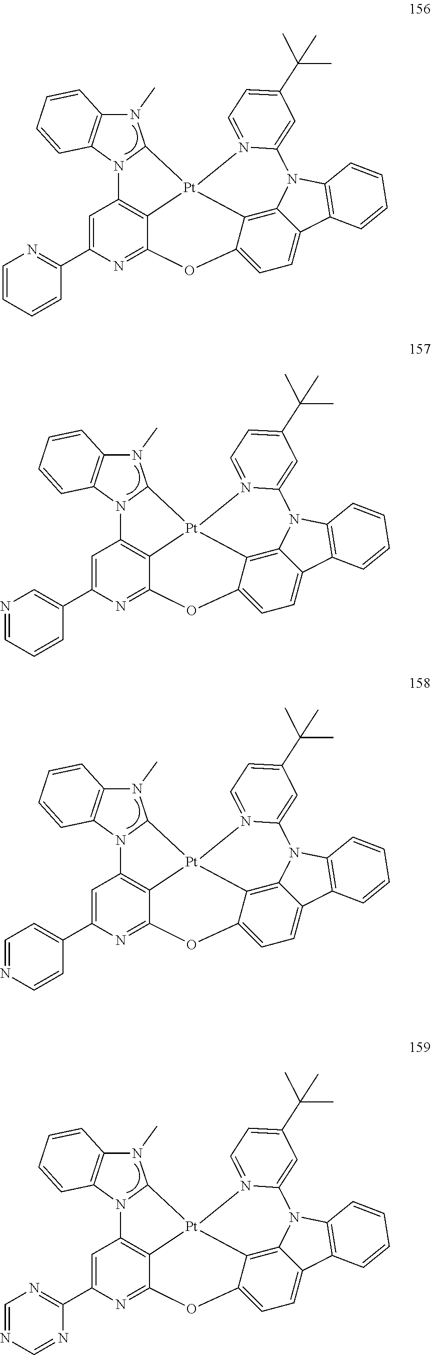

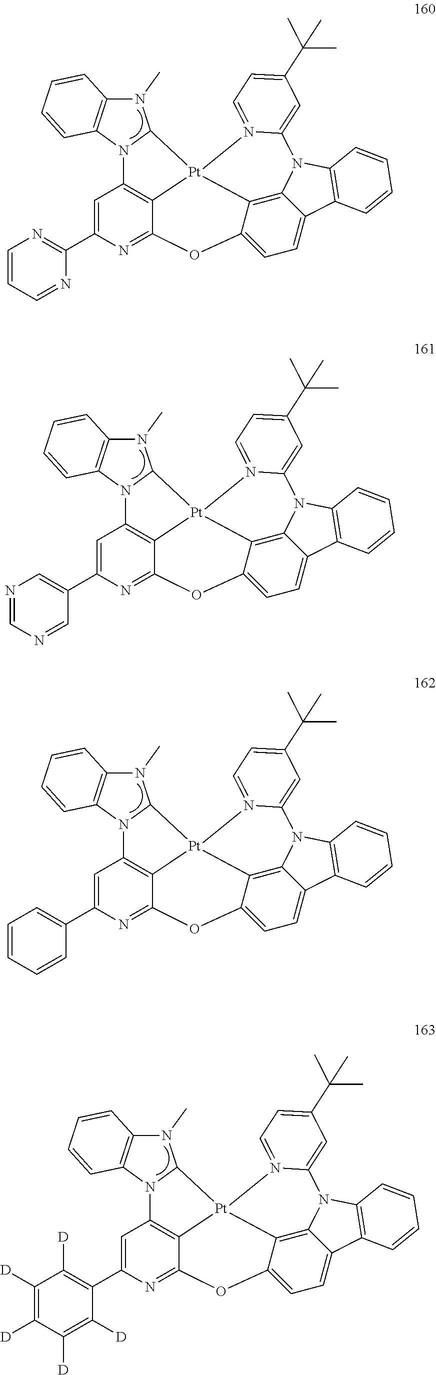

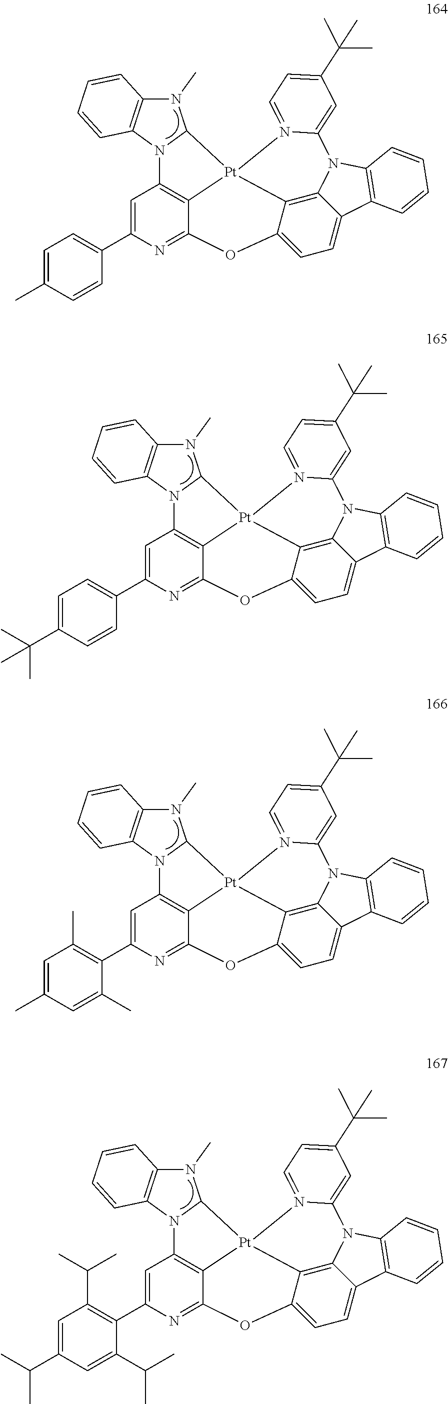

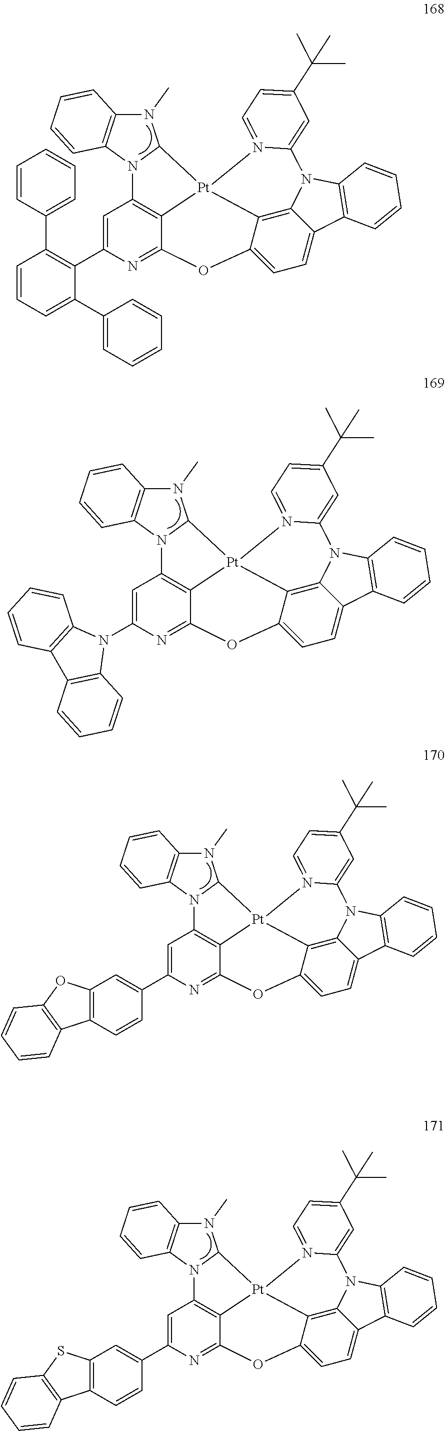

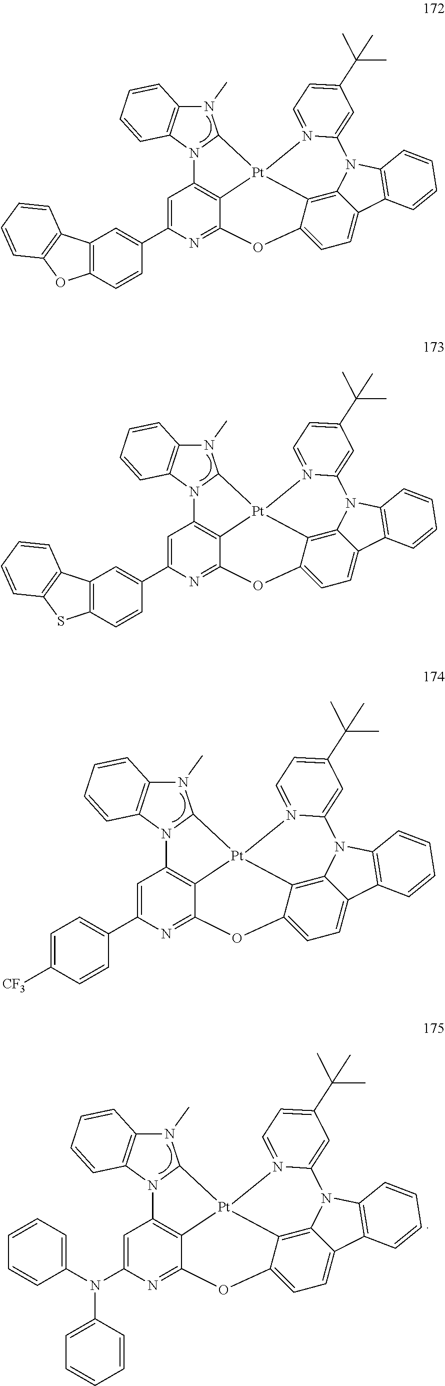

In the compounds listed in Compound Group 1, “D” corresponds to a deuterium atom.

The organometallic compound represented by Formula 1 includes a central metal atom, and a ligand bonded to the central metal atom. The organometallic compound represented by Formula 1 includes tetradentate ligands in which the first to fourth ligands are selectively connected with each other. The first ligand may be a six-membered heterocycle including a nitrogen atom as a ring-forming atom. For example, the first ligand may include a pyridine moiety or a pyrimidine moiety. The second ligand may be a N-heterocycle carbene group, and may be connected with the first ligand through a connecting group. The organometallic compound of an embodiment, represented by Formula 1 includes the first ligand and the second ligand, for example, the first ligand at a specific position, and may provide a deep blue emission color with high color purity. The first ligand is connected with the central metal atom at carbon at a meta position with respect to the nitrogen atom, and the organometallic compound represented by Formula 1 may have a deep HOMO energy level. Accordingly, the organometallic compound represented by Formula 1 may have a high triplet energy level, and may provide a deep blue emission color with high color purity.

In some embodiments, the organometallic compound according to an embodiment has a deep HOMO energy level, and accordingly, the hole trap phenomenon may be prevented or reduced, emission efficiency may increase, and device lifetime characteristics may be improved. When the HOMO energy level difference between a host and a dopant in an emission layer EML is large, trap phenomenon by which carriers move directly to (and, e.g., stay in) the HOMO of the dopant without passing through the HOMO of the host to form excitons, may increase. Such trap phenomenon reduces carrier transport capacity and increases the driving voltage of a light emitting device ED, and may become a main factor in degrading emission efficiency and device lifetime.

The organometallic compound of an embodiment may show a deep HOMO energy level and may not act as a trap site for holes injected to the emission layer EML. Accordingly, the trap phenomenon of holes by the dopant may be reduced in the emission layer EML, to improve carrier transport capacity. Accordingly, when the organometallic compound of an embodiment is utilized as the dopant material of the emission layer of a light emitting device ED, a light emitting device ED showing a low driving voltage, high efficiency, and long-lifetime characteristics may be achieved.

In an embodiment, the emission layer EML includes a host and a dopant, and may include the organometallic compound as the dopant. The organometallic compound of an embodiment, represented by Formula 1 may be provided as the dopant material of the emission layer.

The organometallic compound of an embodiment may be a dopant for emitting phosphorescence, which emits blue light. For example, in the light emitting device ED of an embodiment, an emission layer EML may include a host for emitting phosphorescence and a dopant for emitting phosphorescence. In some embodiments, in the light emitting device ED, an emission layer EML may include a host for emitting fluorescence and a dopant for emitting fluorescence, and may include the organometallic compound of an embodiment as the host for emitting fluorescence.

In the light emitting device ED of an embodiment, an emission layer EML may include a host for emitting delayed fluorescence and a dopant for emitting delayed fluorescence, and may include the organometallic compound of an embodiment as the dopant for emitting delayed fluorescence. In the light emitting device ED of an embodiment, an emission layer EML may include a host for emitting blue thermally activated delayed fluorescence (TADF) and a dopant for emitting blue thermally activated delayed fluorescence, and may include the organometallic compound of an embodiment as the host for emitting blue thermally activated delayed fluorescence. The emission layer EML may include at least one selected from among the organometallic compounds represented in Compound Group 1, as the dopant material of the emission layer EML.

In the light emitting device ED of an embodiment, a host may not emit light in the light emitting device ED but instead may play the role of transferring energy to a dopant. The emission layer EML may include one or more types (kinds) of hosts. For example, the emission layer EML may include two types (kinds) of different hosts. However, an embodiment of the present disclosure is not limited thereto, and the emission layer EML may include one type or kind of a host, or a mixture of two or more types (kinds) of different hosts.

In an embodiment, the emission layer EML may include two different hosts. The host may include a first host represented by Formula HT-1, and a second host which is different from the first host and represented by Formula ET-1 or Formula ET-2. In an embodiment, the first host may be a hole transport host, and the second host may be an electron transport host. In an embodiment, the emission layer EML may include a first host and a second host, and the first host and the second host may form exiplexes.

In the light emitting device ED of an embodiment, exiplexes may be formed by a hole transport host and an electron transport host in an emission layer. In this embodiment, the triplet energy of the exiplexes formed by the hole transport host and the electron transport host may correspond to the difference between the energy level of the lowest unoccupied molecular orbital (LUMO) of the electron transport host and the energy level of the highest occupied molecular orbital (HOMO) of the hole transport host.

For example, the absolute value of the triplet energy level (T1) of the exiplexes formed by the hole transport host and the electron transport host may be about 2.4 eV to about 3.0 eV. In some embodiments, the triplet energy of the exiplexes may be a value smaller than the energy gap of each host material. The exiplexes may have a triplet energy of about 3.0 eV or less, which is the energy gap of the hole transport host and the electron transport host.

The emission layer EML according to an embodiment may include a first host including a carbazole derivative moiety. The first host may be represented by Formula HT-1.

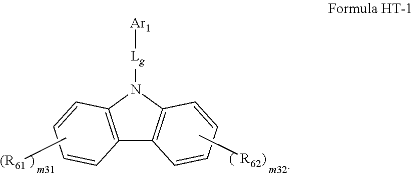

In Formula HT-1, L_{g} may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, Ar₁ may be a substituted or unsubstituted aryl group of 6 to 30 ring-forming carbon atoms, or a substituted or unsubstituted heteroaryl group of 2 to 30 ring-forming carbon atoms.

In Formula HT-1, R₆₁ and R₆₂ may each independently be a hydrogen atom, a deuterium atom, a halogen atom, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₆₁ and R₆₂ may each independently be a hydrogen atom, or a deuterium atom.

In Formula HT-1, m31 and m32 may each independently be an integer from 0 to 4. When m31 and m32 are 0, the first host may be unsubstituted with R₆₁ and R₆₂, respectively. Embodiments in which m31 and m32 are 4, and R₆₁ and R₆₂ are all hydrogen atoms in Formula HT-1, may be the same as embodiments in which m31 and m32 are 0 in Formula HT-1, respectively. When m31 and m32 are integers of 2 or more, each of multiple R₆₁ and R₆₂ may all be the same, or at least one selected from among each of multiple R₆₁ and R₆₂ may be different. For example, in Formula HT-1, m31 and m32 may be 0. In this embodiment, the carbazole group of Formula HT-1 corresponds to an unsubstituted one (unsubstituted carbazole group).

In Formula HT-1, L_{g} may be a direct linkage, a phenylene group, a divalent biphenyl group, a divalent carbazole group, and/or the like, but an embodiment of the present disclosure is not limited thereto. In some embodiments, Ar₁ may be a substituted or unsubstituted carbazole group, a substituted or unsubstituted dibenzofuran group, a substituted or unsubstituted dibenzothiophene group, a substituted or unsubstituted biphenyl group, a substituted or unsubstituted terphenyl group, and/or the like, but an embodiment of the present disclosure is not limited thereto.

The emission layer EML according to an embodiment may include a second host which is different from the first host. The second host may be represented by Formula ET-1 or Formula ET-2.

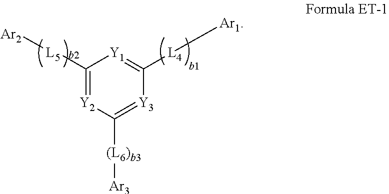

In Formula ET-1, Y₁ to Y₃ may each independently be N, or CRₐ. In an embodiment, at least one selected from among Y₁ to Y₃ may be N. For example, one or two selected from among Y₁ to Y₃ may be N, and the remainder may be CRₐ. In some embodiments, Y₁ to Y₃ may all be N.

In Formula ET-1, Rₐ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer from 0 to 10.

In Formula ET-1, L₄ to L₆ may each independently be a direct linkage, a substituted or unsubstituted arylene group of 6 to 30 ring-forming carbon atoms, or a substituted or unsubstituted heteroarylene group of 2 to 30 ring-forming carbon atoms.

In Formula ET-1, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

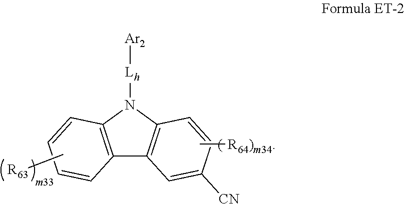

In Formula ET-2, Lₕ may be a direct linkage, a substituted or unsubstituted arylene group of 6 to 30 ring-forming carbon atoms, or a substituted or unsubstituted heteroarylene group of 2 to 30 ring-forming carbon atoms.

In Formula ET-2, Ar₂ may be a substituted or unsubstituted aryl group of 6 to 30 ring-forming carbon atoms, or a substituted or unsubstituted heteroaryl group of 2 to 30 ring-forming carbon atoms.

In Formula ET-2, R₆₃ and R₆₄ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, m33 may be an integer from 0 to 4, and m34 is an integer from 0 to 3.

When m33 is 0, the second host represented by Formula ET-2 may be unsubstituted with R₆₃. An embodiment in which m33 is 4, and R₆₃ are all hydrogen atoms in Formula ET-2, may be the same as an embodiment in which m33 is 0 in Formula ET-2. When m33 is an integer of 2 or more, multiple R₆₃ may be all the same, or at least one selected from among multiple R₆₃ may be different.

When m34 is 0, the second host represented by Formula ET-2 may be unsubstituted with R₆₄. An embodiment in which m34 is 3, and R₆₄ are all hydrogen atoms in Formula ET-2, may be the same as an embodiment in which m34 is 0 in Formula ET-2. When m34 is an integer of 2 or more, multiple R₆₄ may be all the same, or at least one selected from among multiple R₆₄ may be different.

When the emission layer EML of the light emitting device ED of an embodiment includes the first host represented by HT-1, and the second host represented by Formula ET-1 or Formula ET-2, in the emission layer EML at the same time (concurrently), excellent or suitable emission efficiency and long-lifetime characteristics may be shown.

In an embodiment, the first host represented by Formula HT-1 may be represented by at least one selected from among the compounds represented in Compound Group 2. The emission layer EML may include at least one selected from among the compounds represented in Compound Group 2 as a first host material.

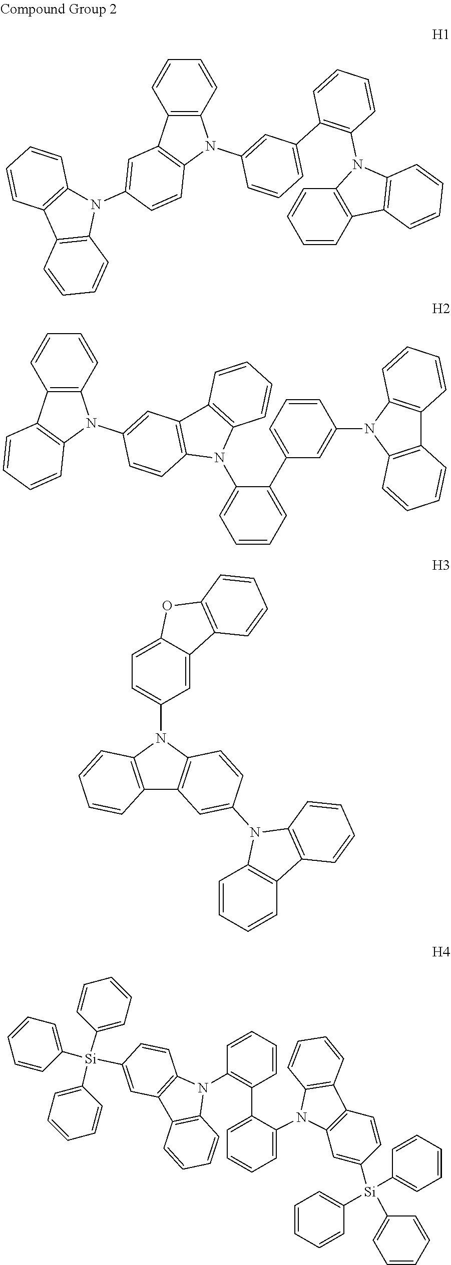

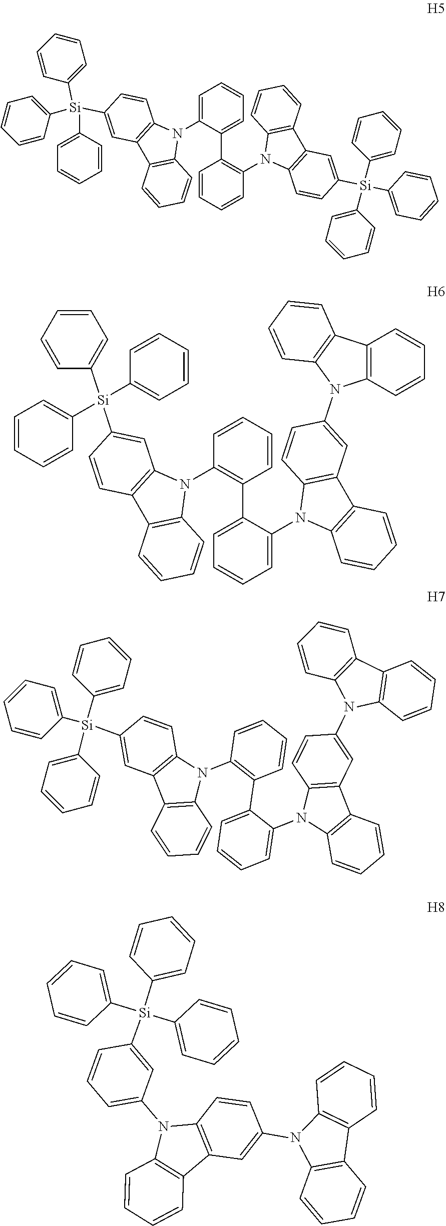

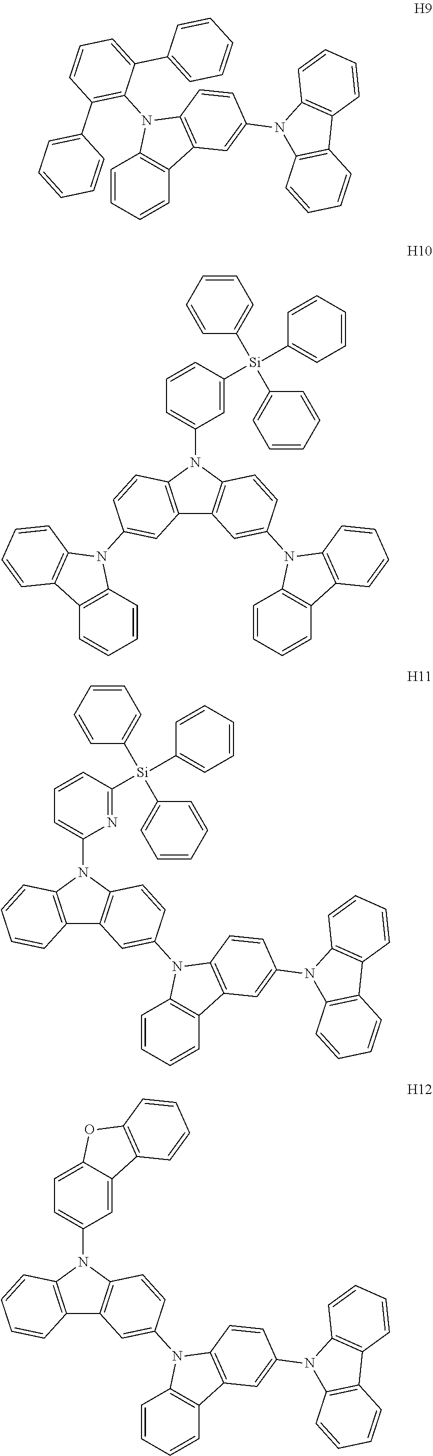

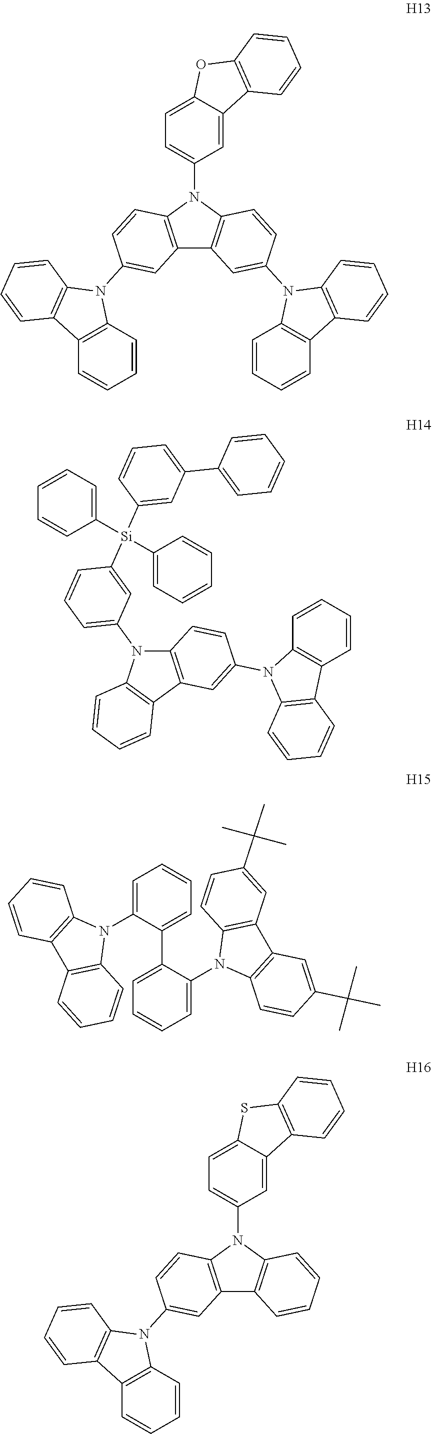 [SMILES: c1ccc2c(c1)oc1ccc(-n3c4ccc(-n5c6ccccc6c6ccccc65)cc4c4cc(-n5c6ccccc6c6ccccc65)ccc43)cc12 ; c1ccc(-c2cccc([Si](c3ccccc3)(c3ccccc3)c3cccc(-n4c5ccccc5c5cc(-n6c7ccccc7c7ccccc76)ccc54)c3)c2)cc1 ; CC(C)(C)c1ccc2c(c1)c1cc(C(C)(C)C)ccc1n2-c1ccccc1-c1ccccc1-n1c2ccccc2c2ccccc21 ; c1ccc2c(c1)sc1ccc(-n3c4ccccc4c4cc(-n5c6ccccc6c6ccccc65)ccc43)cc12]

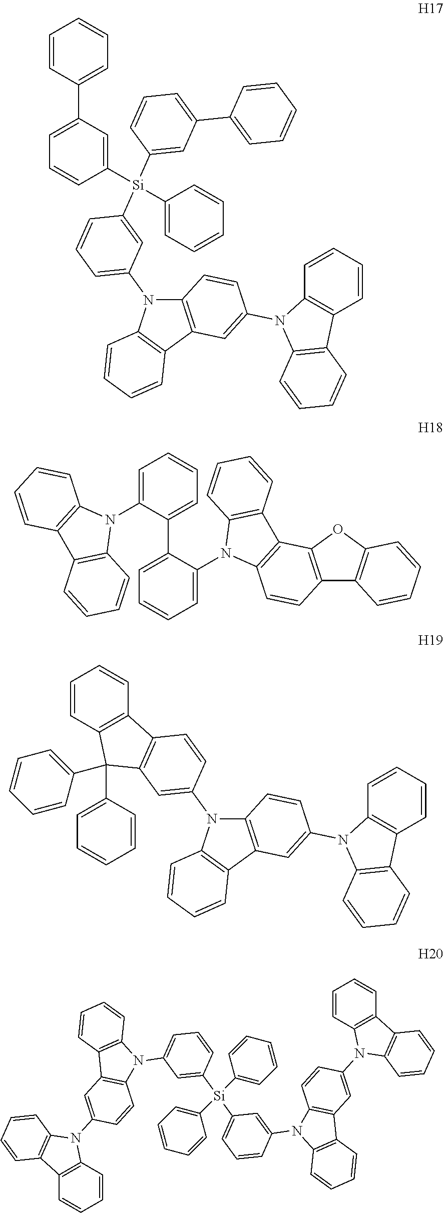 [SMILES: c1ccc(-c2cccc([Si](c3ccccc3)(c3cccc(-c4ccccc4)c3)c3cccc(-n4c5ccccc5c5cc(-n6c7ccccc7c7ccccc76)ccc54)c3)c2)cc1 ; c1ccc(-n2c3ccccc3c3ccccc32)c(-c2ccccc2-n2c3ccccc3c3c4oc5ccccc5c4ccc32)c1 ; c1ccc(C2(c3ccccc3)c3ccccc3-c3ccc(-n4c5ccccc5c5cc(-n6c7ccccc7c7ccccc76)ccc54)cc32)cc1 ; c1ccc([Si](c2ccccc2)(c2cccc(-n3c4ccccc4c4cc(-n5c6ccccc6c6ccccc65)ccc43)c2)c2cccc(-n3c4ccccc4c4cc(-n5c6ccccc6c6ccccc65)ccc43)c2)cc1]

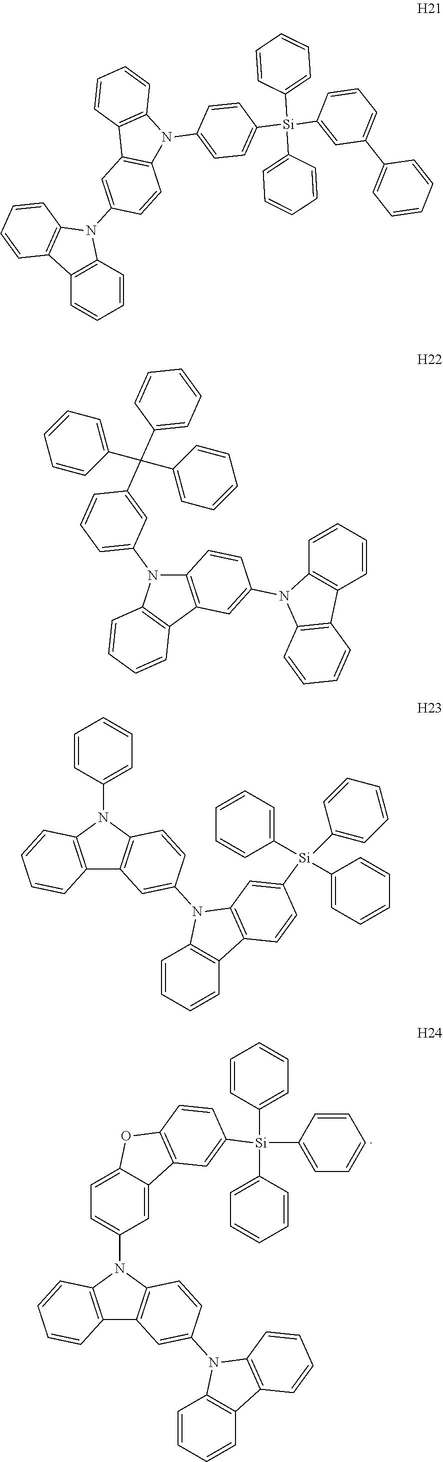 [SMILES: c1ccc(-c2cccc([Si](c3ccccc3)(c3ccccc3)c3ccc(-n4c5ccccc5c5cc(-n6c7ccccc7c7ccccc76)ccc54)cc3)c2)cc1 ; c1ccc(C(c2ccccc2)(c2ccccc2)c2cccc(-n3c4ccccc4c4cc(-n5c6ccccc6c6ccccc65)ccc43)c2)cc1 ; c1ccc(-n2c3ccccc3c3cc(-n4c5ccccc5c5ccc([Si](c6ccccc6)(c6ccccc6)c6ccccc6)cc54)ccc32)cc1 ; c1ccc([Si](c2ccccc2)(c2ccccc2)c2ccc3oc4ccc(-n5c6ccccc6c6cc(-n7c8ccccc8c8ccccc87)ccc65)cc4c3c2)cc1]

In an embodiment, the second host represented by Formula ET-1 or Formula ET-2 may be represented by any one selected from among the compounds represented in Compound Group 3. The emission layer EML may include at least one selected from among the compounds represented in Compound Group 3 as a second host material.

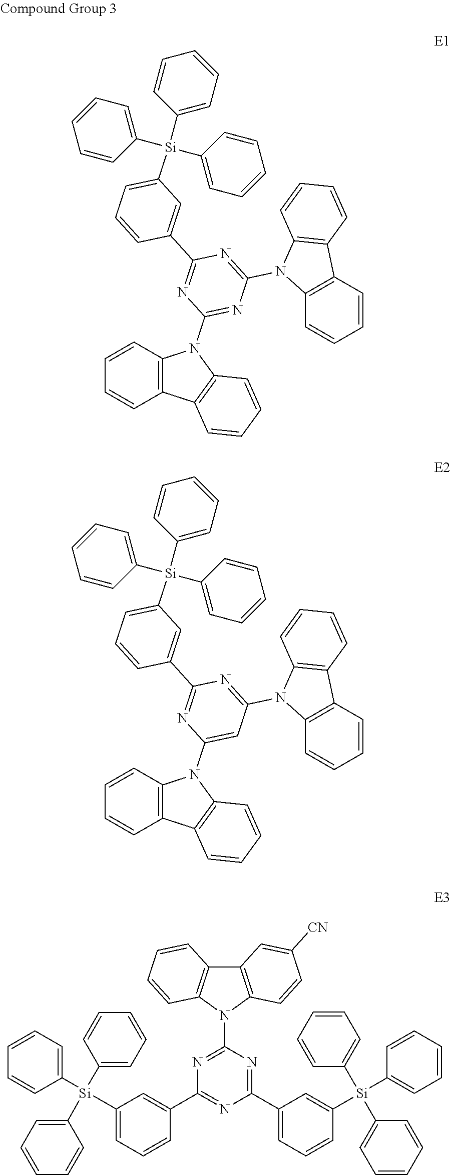

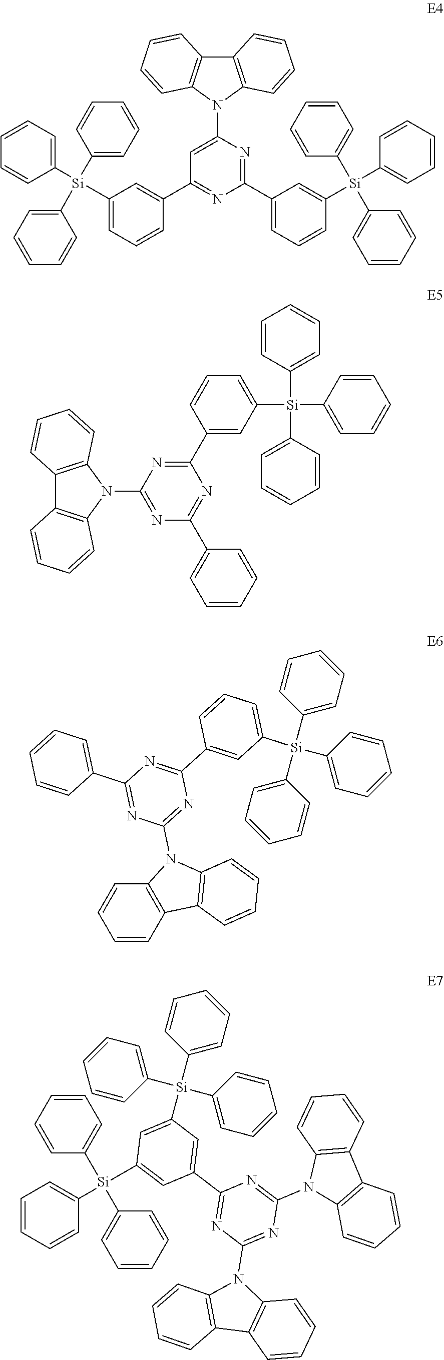 [SMILES: c1ccc([Si](c2ccccc2)(c2ccccc2)c2cccc(-c3cc(-n4c5ccccc5c5ccccc54)nc(-c4cccc([Si](c5ccccc5)(c5ccccc5)c5ccccc5)c4)n3)c2)cc1 ; c1ccc(-c2nc(-c3cccc([Si](c4ccccc4)(c4ccccc4)c4ccccc4)c3)nc(-n3c4ccccc4c4ccccc43)n2)cc1 ; c1ccc(-c2nc(-c3cccc([Si](c4ccccc4)(c4ccccc4)c4ccccc4)c3)nc(-n3c4ccccc4c4ccccc43)n2)cc1 ; c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1]

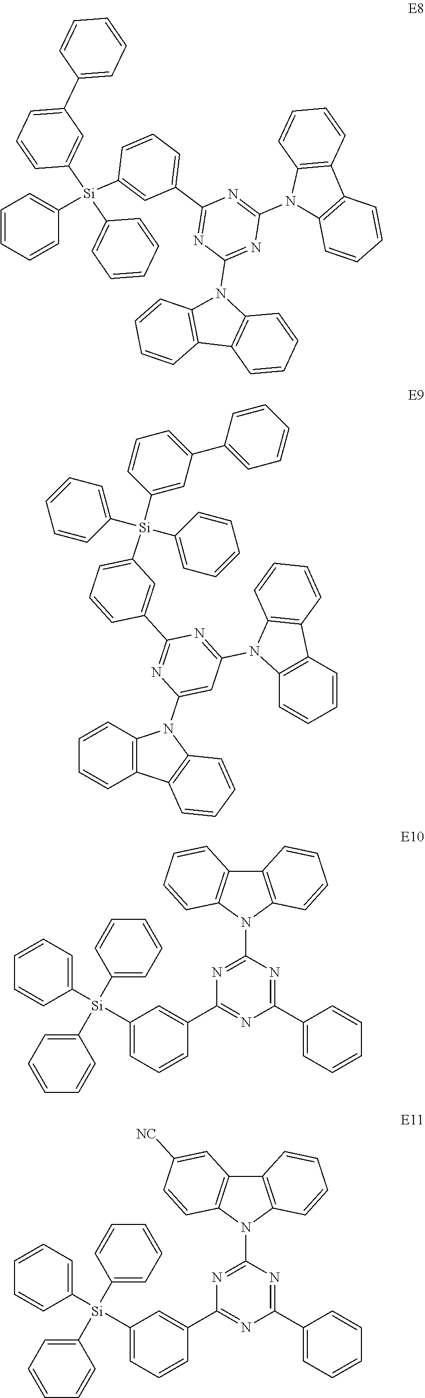

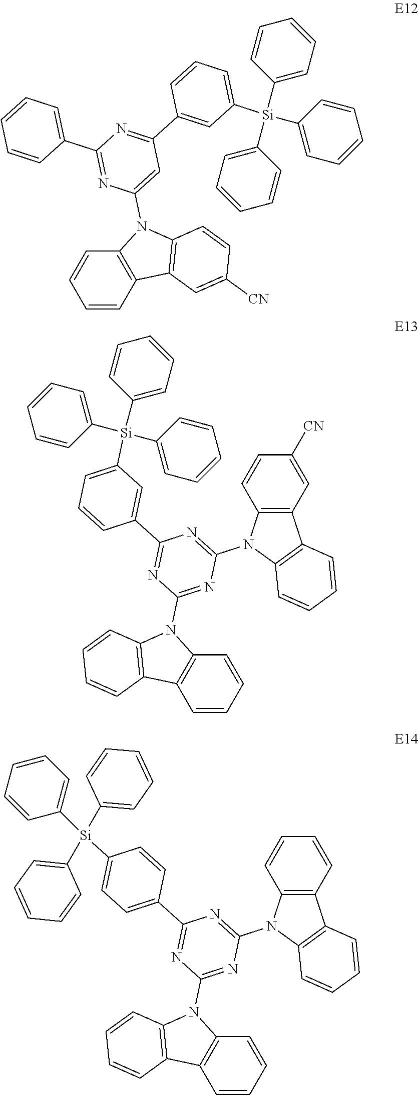

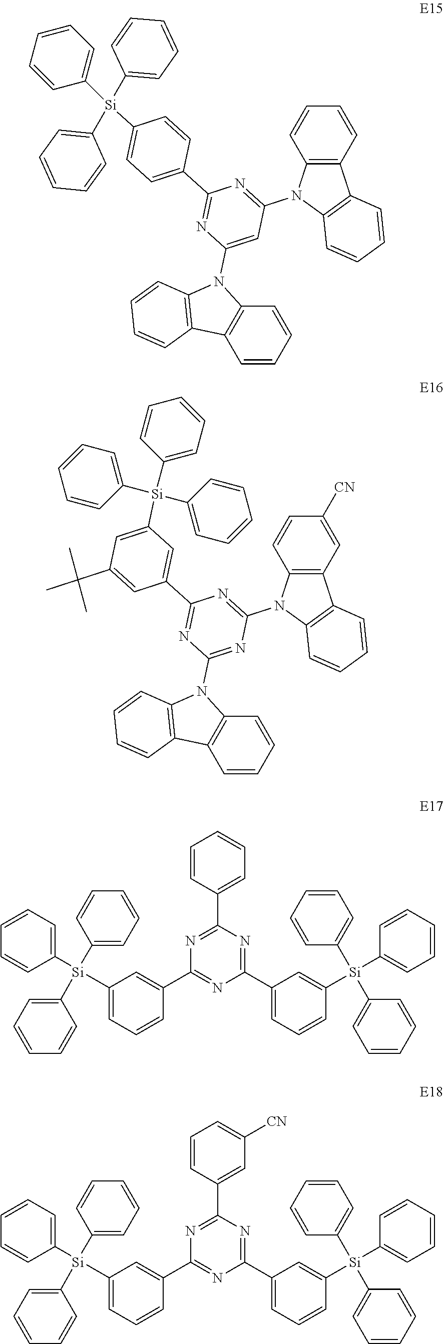 [SMILES: c1ccc([Si](c2ccccc2)(c2ccccc2)c2ccc(-c3nc(-n4c5ccccc5c5ccccc54)cc(-n4c5ccccc5c5ccccc54)n3)cc2)cc1 ; CC(C)(C)c1cc(-c2nc(-n3c4ccccc4c4ccccc43)nc(-n3c4ccccc4c4cc(C#N)ccc43)n2)cc([Si](c2ccccc2)(c2ccccc2)c2ccccc2)c1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; N#Cc1cccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c1]

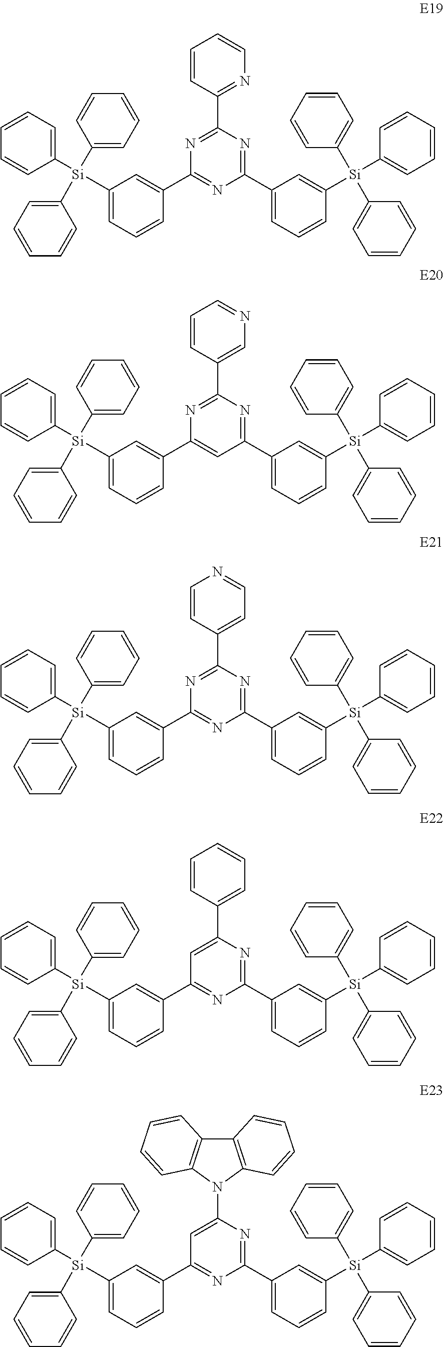

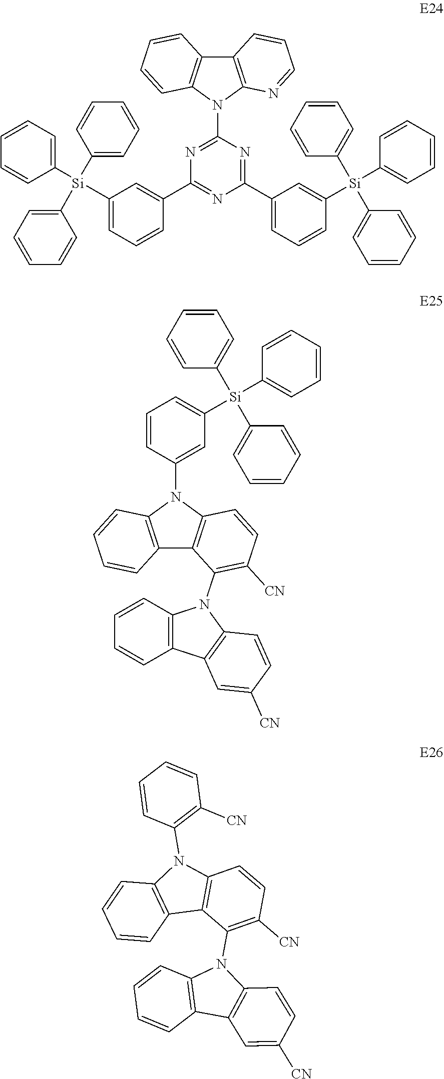 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cccnc54)n3)c2)cc1 ; N#Cc1ccc2c(c1)c1ccccc1n2-c1c(C#N)ccc2c1c1ccccc1n2-c1cccc([Si](c2ccccc2)(c2ccccc2)c2ccccc2)c1 ; N#Cc1ccc2c(c1)c1ccccc1n2-c1c(C#N)ccc2c1c1ccccc1n2-c1ccccc1C#N]

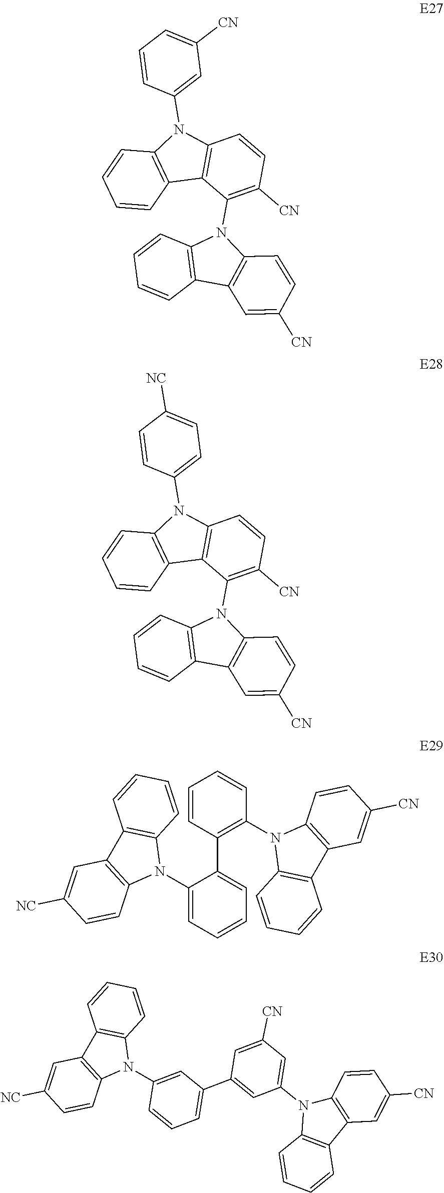 [SMILES: N#Cc1cccc(-n2c3ccccc3c3c(-n4c5ccccc5c5cc(C#N)ccc54)c(C#N)ccc32)c1 ; N#Cc1ccc(-n2c3ccccc3c3c(-n4c5ccccc5c5cc(C#N)ccc54)c(C#N)ccc32)cc1 ; N#Cc1ccc2c(c1)c1ccccc1n2-c1ccccc1-c1ccccc1-n1c2ccccc2c2cc(C#N)ccc21 ; N#Cc1cc(-c2cccc(-n3c4ccccc4c4cc(C#N)ccc43)c2)cc(-n2c3ccccc3c3cc(C#N)ccc32)c1]

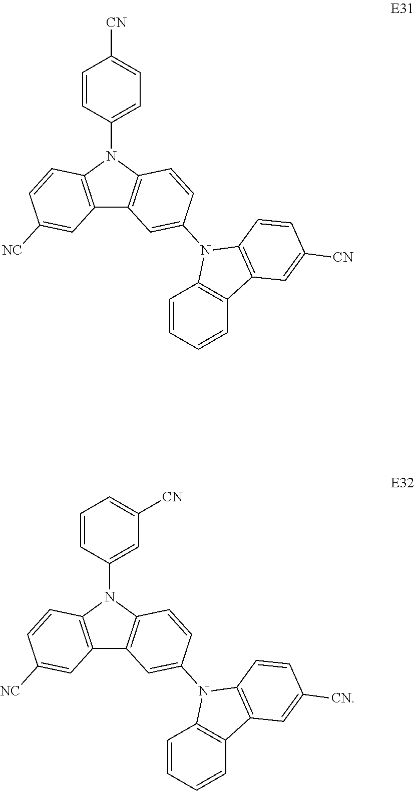 [SMILES: N#Cc1ccc(-n2c3ccc(C#N)cc3c3cc(-n4c5ccccc5c5cc(C#N)ccc54)ccc32)cc1 ; N#Cc1cccc(-n2c3ccc(C#N)cc3c3cc(-n4c5ccccc5c5cc(C#N)ccc54)ccc32)c1]

In the light emitting device ED of an embodiment, when the emission layer EML includes all of the first host, the second host and the dopant, the dopant content (e.g., amount) may be about 3 wt % to about 50 wt % based on the total weight of the first host, the second host and the dopant. However, an embodiment of the present disclosure is not limited thereto. When the dopant content (e.g., amount) satisfies the aforementioned ratio, energy transfer from the first host and the second host to the dopant may increase, and accordingly, emission efficiency and device lifetime may be improved (increased).

In the emission layer EML, the content (e.g., amount) of the first host and the second host may be the remaining content (e.g., amount) excluding the dopant weight. For example, in the emission layer EML, the content (e.g., amount) of the first host and the second host may be about 50 wt % to about 99 wt % based on the total weight of the first host, the second host and the dopant.

Utilizing the total weight of the first host and the second host, the weight ratio of the first host and the second host may be a ratio between about 2:8 and about 8:2.

When the content (e.g., amount) of the first host and the second host satisfies the aforementioned ratio, charge balance properties in the emission layer EML may be improved, and emission efficiency and device lifetime may be improved. When the contents of the first host and the second host deviate from the aforementioned ratio range, charge balance in the emission layer EML may be broken, and emission efficiency may be degraded, and the device may be easily deteriorated.

When the first host and the second host, and the dopant, included in the emission layer EML, satisfy the aforementioned content (e.g., amount) ratio range, excellent or suitable emission efficiency and long lifetime may be achieved.

In the light emitting device ED of an embodiment, the emission layer EML may include anthracene derivatives, pyrene derivatives, fluoranthene derivatives, chrysene derivatives, dihydrobenzanthracene derivatives, or triphenylene derivatives. For example, the emission layer EML may include anthracene derivatives or pyrene derivatives.

In the light emitting devices ED of embodiments, shown in FIG. 3 to FIG. 6, the emission layer EML may include a suitable host and a suitable dopant in addition to the aforementioned host and dopant. For example, the emission layer EML may include a compound represented by Formula E-1. The compound represented by Formula E-1 may be utilized as a fluorescence host material.

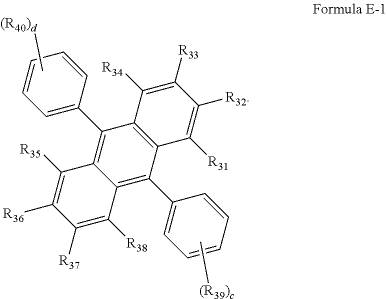

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer from 0 to 5.

Formula E-1 may be represented by any one selected from among Compound E1 to Compound E19.

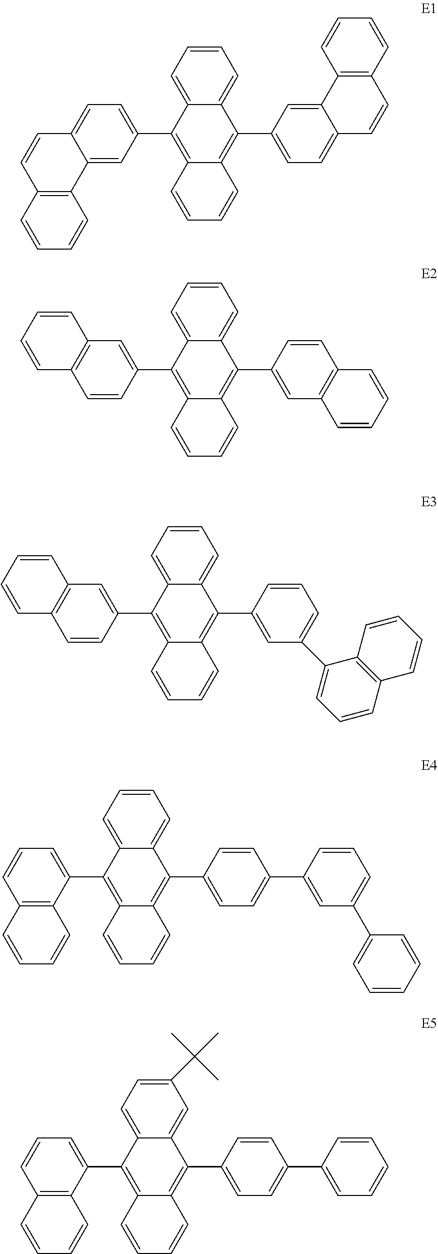

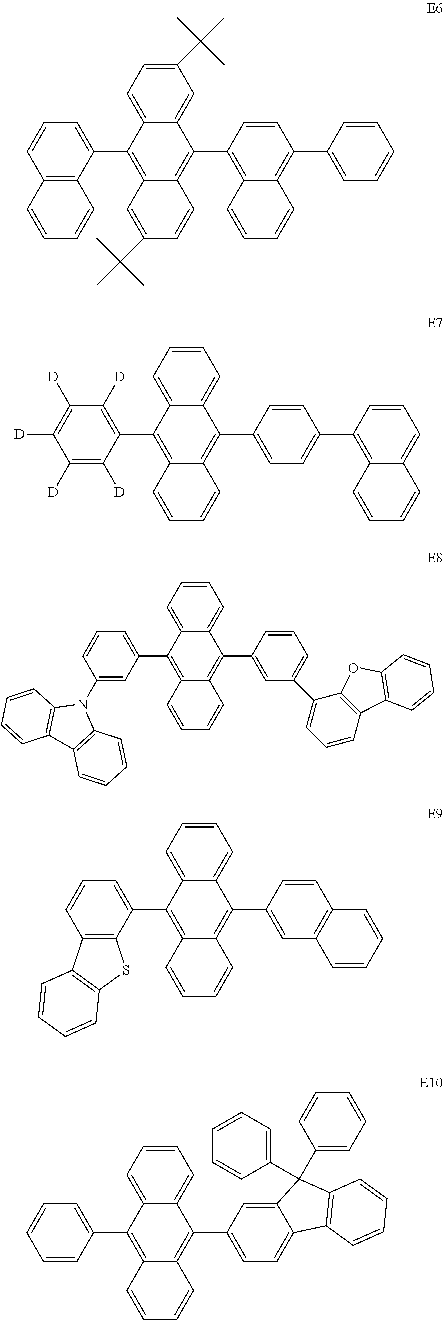

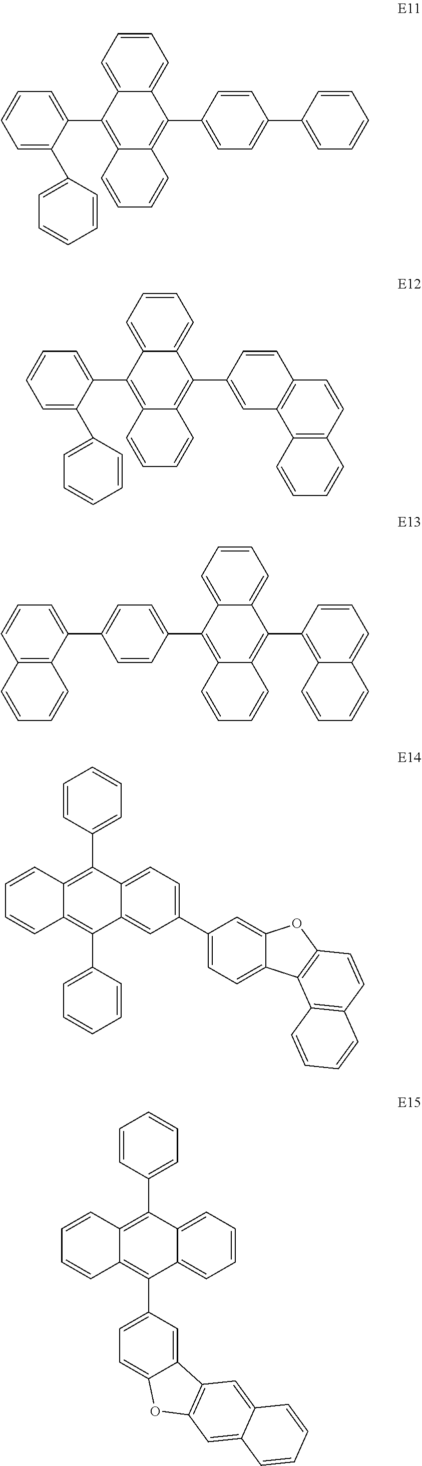

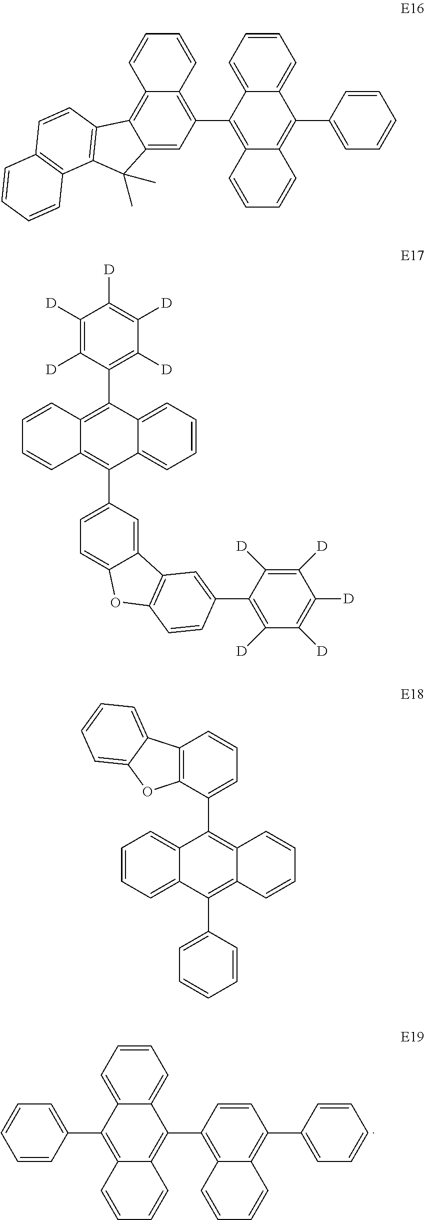

In an embodiment, the emission layer EML may include a compound represented by Formula E-2a or Formula E-2b. The compound represented by Formula E-2a or Formula E-2b may be utilized as a phosphorescence host material.

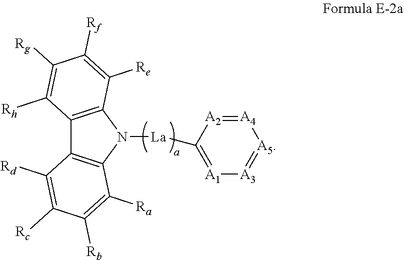

In Formula E-2a, “a” may be an integer from 0 to 10, Lₐ may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” is an integer of 2 or more, multiple Lₐ may each independently be a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₅ may each independently be N or CRi. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Rₐ to Rᵢ may be combined with an adjacent group to form a hydrocarbon ring or a heterocycle including N, O, S, etc. as a ring-forming atom.

In some embodiments, in Formula E-2a, two or three selected from A₁ to A₅ may be N, and the remainder may be CRᵢ.

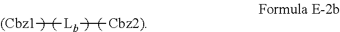

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” may be an integer from 0 to 10, and when “b” is an integer of 2 or more, multiple L_{b} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one selected from among the compounds in Compound Group E-2. However, the compounds shown in Compound Group E-2 are merely examples, and the compound represented by Formula E-2a or Formula E-2b is not limited to the compounds represented in Compound Group E-2.

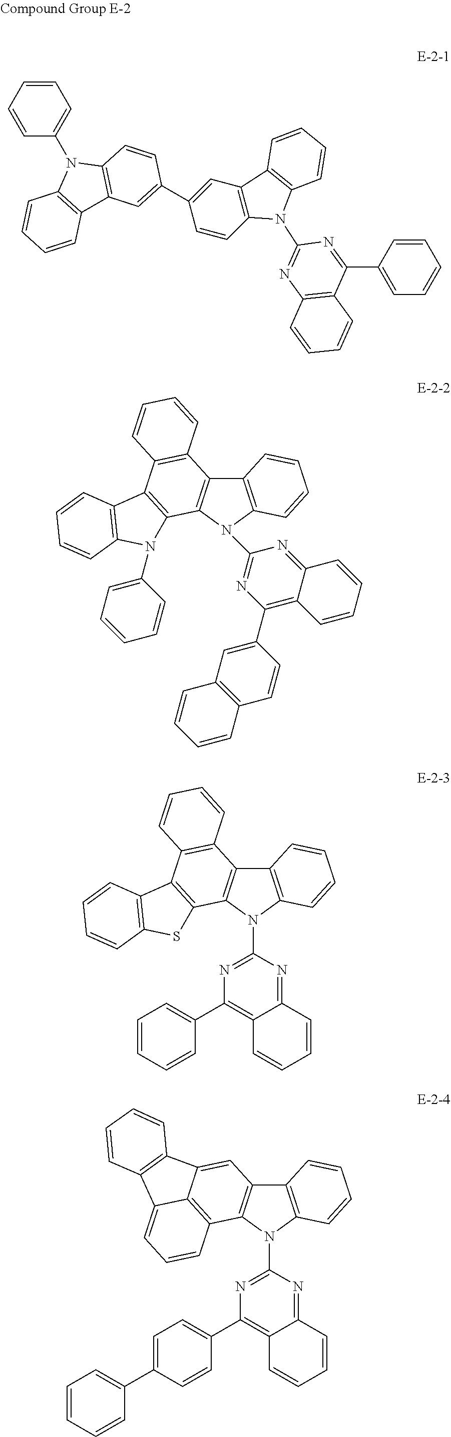

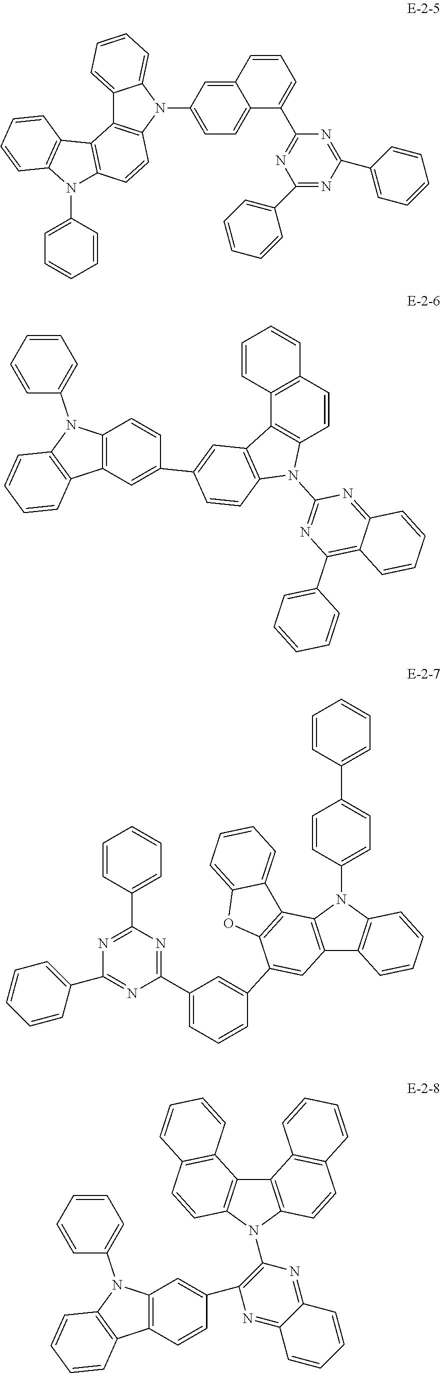 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

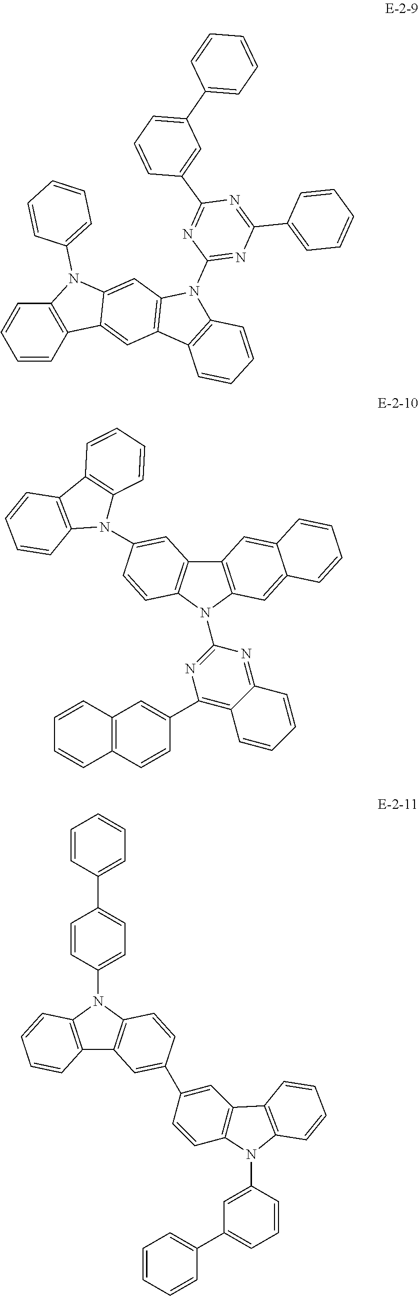 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

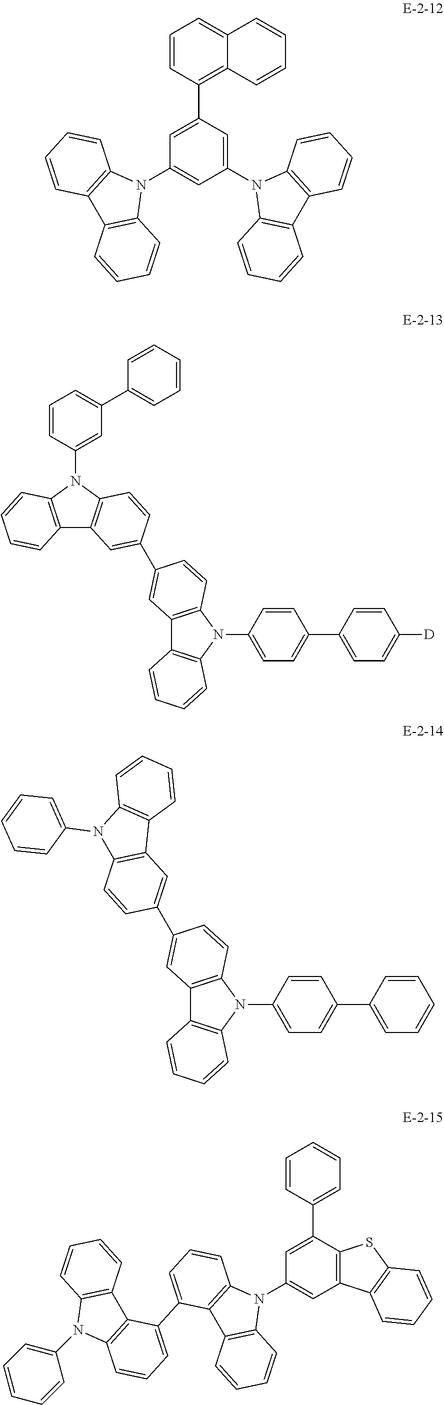 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

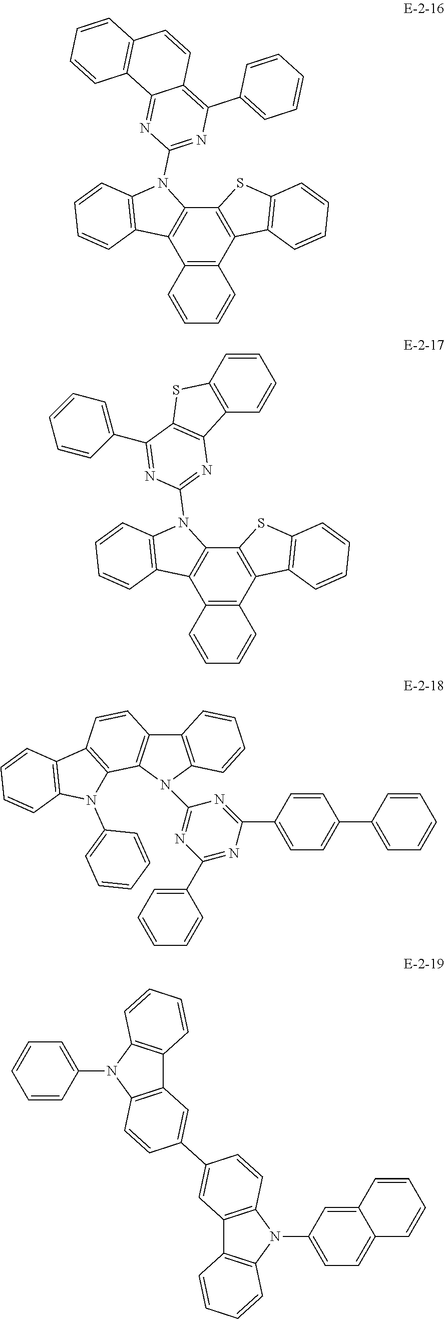

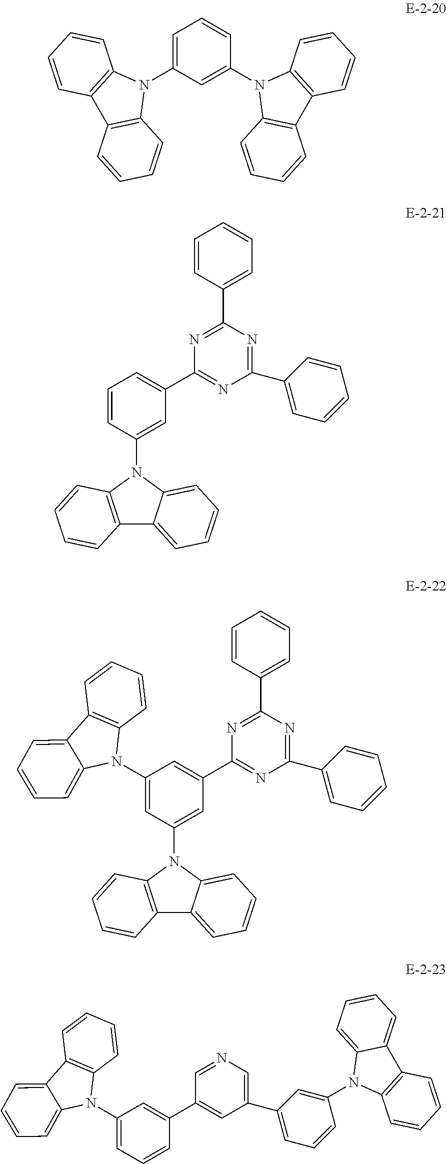 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

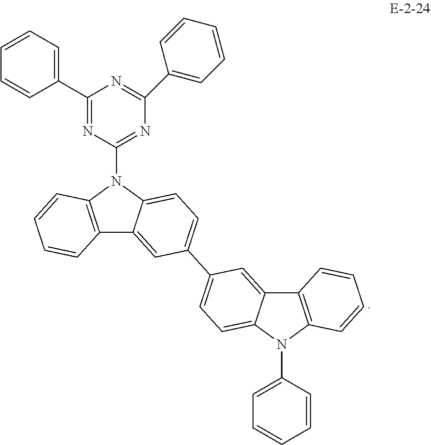 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material generally used/generally available in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, an embodiment of the present disclosure is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

The emission layer EML may further include a compound represented by Formula M-a. The compound represented by Formula M-a may be utilized as a phosphorescence dopant material.

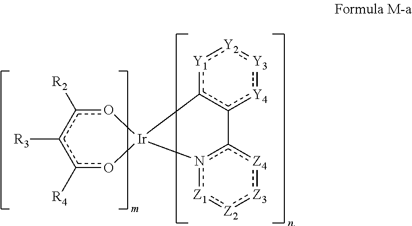

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “in” is 0 or 1, and “n” is 2 or 3. In Formula M-a, when “in” is 0, “n” is 3, and when “in” is 1, “n” is 2.

The compound represented by Formula M-a may be utilized as a phosphorescence dopant.

The compound represented by Formula M-a may be represented by any one selected from among Compounds M-a1 to M-a25. However, Compounds M-a1 to M-a25 are merely examples, and the compound represented by Formula M-a is not limited to the compounds represented by Compounds M-a1 to M-a25.

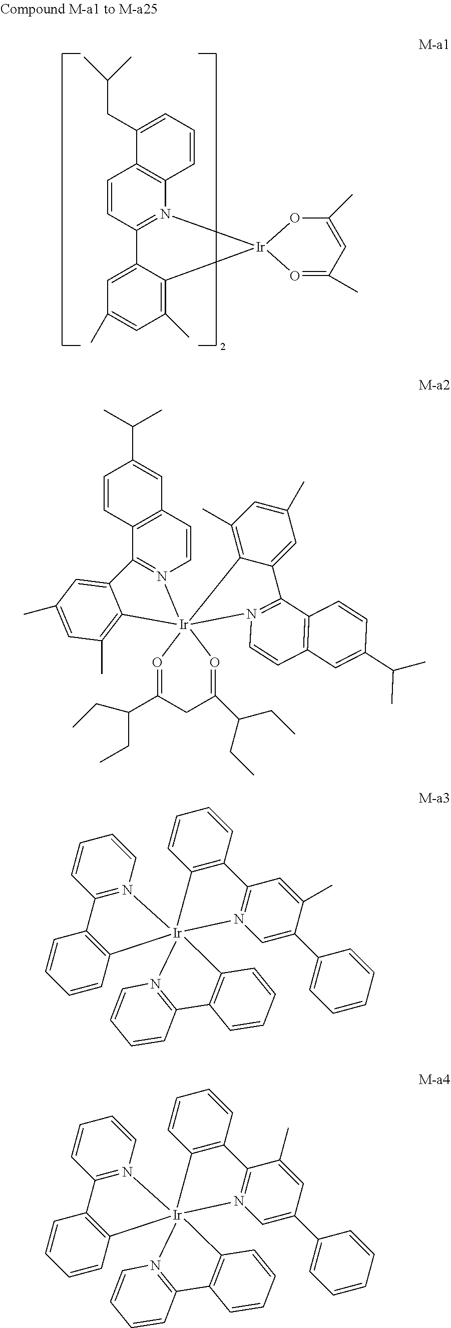

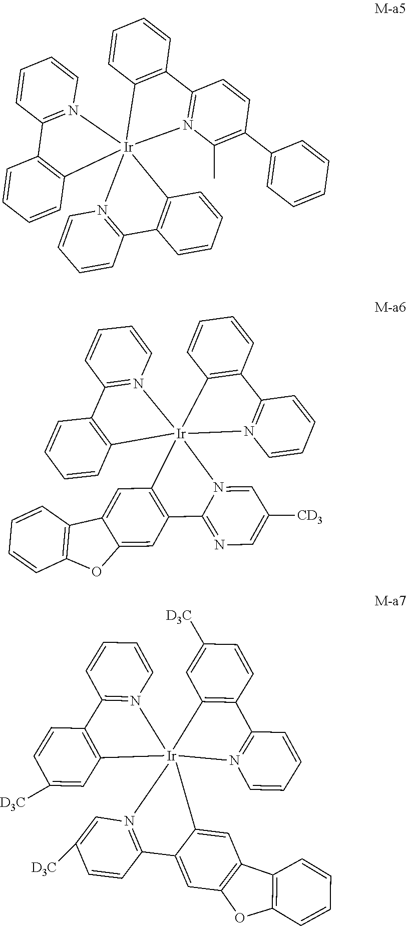

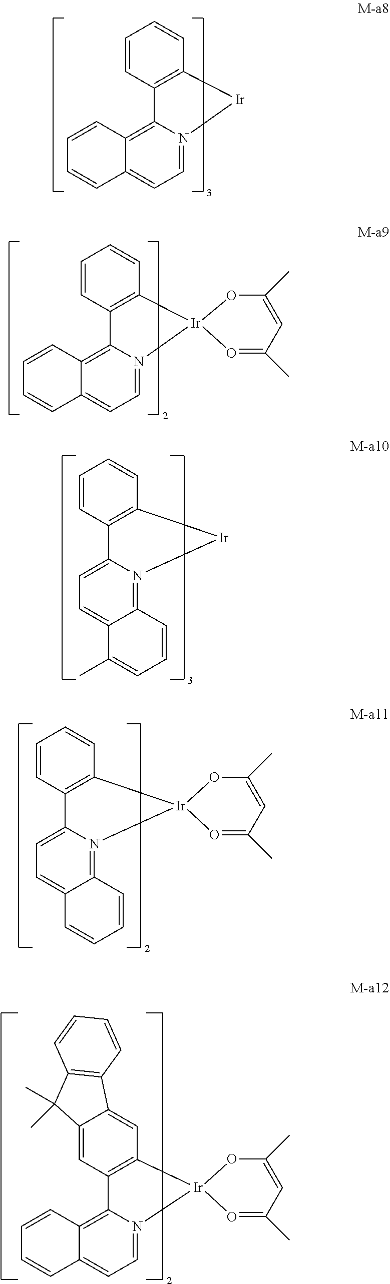

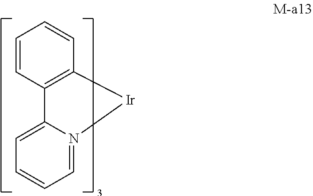

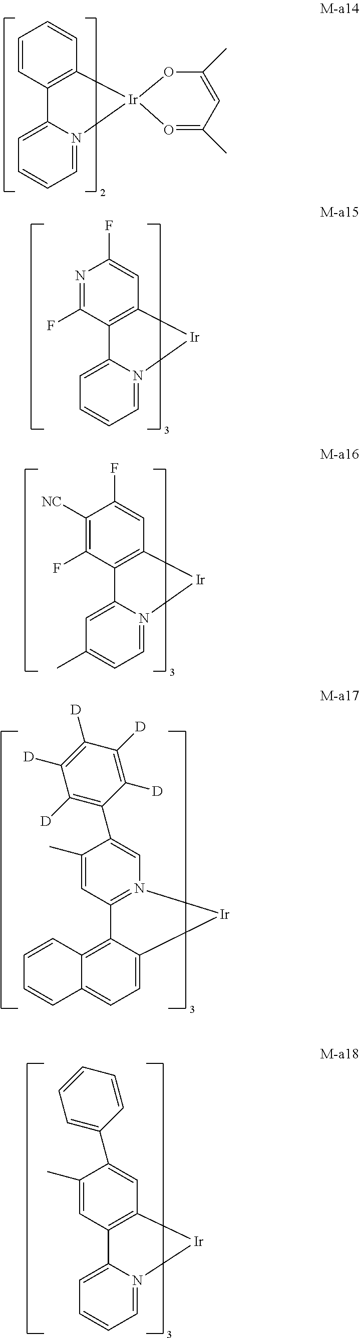

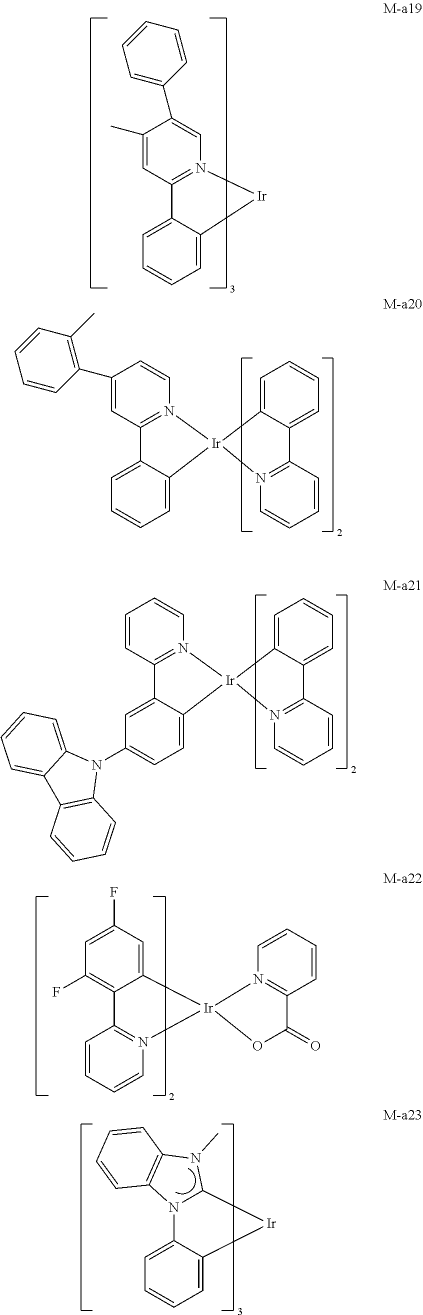

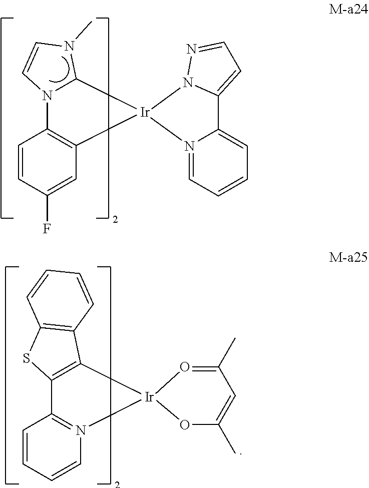

The emission layer EML may include any one selected from among Formula F-a to Formula F-c. The compounds represented by Formula F-a to Formula F-c may be utilized as fluorescence dopant materials.

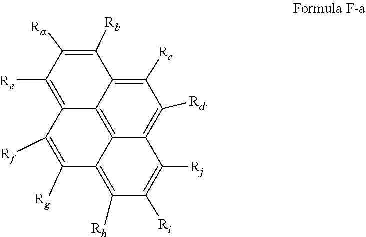

In Formula F-a, two selected from among Rₐ to Rⱼ may each independently be substituted with *—NAr₁Ar₂. The remainder not substituted with *—NAr₁Ar₂ among Rₐ to Rⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one selected from among Ar₁ and Ar₂ may be a heteroaryl group including O or S as a ring-forming atom.

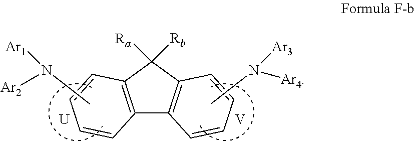

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may each independently be an aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms. At least one selected from among Ar₁ to Ar₄ may be a heteroaryl group including O or S as a ring-forming atom.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In some embodiments, when the number of both (e.g., simultaneously) U and V is 0, the fused ring of Formula F-b may be a ring compound with three rings. In some embodiments, when the number of both (e.g., simultaneously) U and V is 1, a fused ring having the fluorene core of Formula F-b may be a ring compound with five rings.

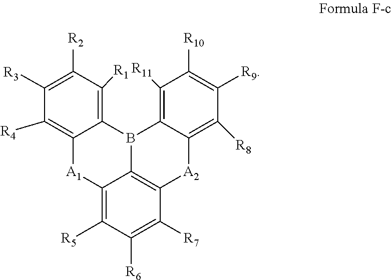

In Formula F-c, A₁ and A₂ may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ and A₂ are each independently NRₘ, A₁ may be combined with R₄ or R₅ to form a ring. In some embodiments, A₂ may be combined with R₇ or R₈ to form a ring.

In an embodiment, the emission layer EML may include as a generally used/generally available dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and/or the derivatives thereof (for example, 2,5,8,11-tetra-t-butylperylene (TBP)), pyrene and/or the derivatives thereof (for example, 1,1-dipyrene, 1,4-dipyrenylbenzene, and/or 1,4-bis(N,N-diphenylamino)pyrene), etc.

The emission layer EML may further include a generally used/generally available phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′)picolinate (Firpic), bis(2,4-difluorophenylpyridinato)-tetrakis(1-pyrazolyl)borate iridium(III) (Fir6), or platinum octaethyl porphyrin (PtOEP) may be utilized as the phosphorescence dopant. However, an embodiment of the present disclosure is not limited thereto.

The emission layer EML may include a quantum dot material. The core of the quantum dot may be selected from among a II-VI group compound, a III-VI group compound, a I-III-VI group compound, a III-V group compound, a III-II-V group compound, a IV-VI group compound, a IV group element, a IV group compound, and one or more combinations thereof.

The II-VI group compound may be selected from the group including (e.g., consisting of): a binary compound selected from the group including (e.g., consisting of) CdSe, CdTe, CdS, ZnS, ZnSe, ZnTe, ZnO, HgS, HgSe, HgTe, MgSe, MgS, and one or more compounds or mixtures thereof; a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more compounds or mixtures thereof; and/or a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and one or more compounds or mixtures thereof.

The III-VI group compound may include a binary compound such as In₂S₃, and In₂Se₃, a ternary compound such as InGaS₃, and InGaSe₃, or one or more combinations thereof.

The I-III-VI group compound may be selected from a ternary compound selected from the group including (e.g., consisting of) AgInS, AgInS₂, CuInS, CuInS₂, AgGaS₂, CuGaS₂, CuGaO₂, AgGaO₂, AgAlO₂ and one or more compounds or mixtures thereof, and/or a quaternary compound such as AgInGaS₂, and CuInGaS₂ (the quaternary compound may be used alone or in combination with any of the foregoing compounds or mixtures; and the quaternary compound may also be combined with other quaternary compounds).

The III-V group compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and one or more compounds or mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and one or more compounds or mixtures thereof, and/or a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and one or more compounds or mixtures thereof. In some embodiments, the III-V group compound may further include a II group metal. For example, InZnP, etc. may be selected as a III-II-V group compound.

The IV-VI group compound may be selected from the group including (e.g., consisting of) a binary compound selected from the group including (e.g., consisting of) SnS, SnSe, SnTe, PbS, PbSe, PbTe, and one or more compounds or mixtures thereof, a ternary compound selected from the group including (e.g., consisting of) SnSeS, SnSeTe, SnSTe, PbSeS, PbSeTe, PbSTe, SnPbS, SnPbSe, SnPbTe, and one or more compounds or mixtures thereof, and/or a quaternary compound selected from the group including (e.g., consisting of) SnPbSSe, SnPbSeTe, SnPbSTe, and one or more compounds or mixtures thereof. The IV group element may be selected from the group including (e.g., consisting of) Si, Ge, and one or more elements or mixtures thereof. The IV group compound may be a binary compound selected from the group including (e.g., consisting of) SiC, SiGe, and one or more compounds or mixtures thereof.

In this embodiment, the binary compound, the ternary compound or the quaternary compound may be present at a substantially uniform concentration in a particle form or may be present at a partially different concentration distribution state in substantially the same particle form. In some embodiments, a core/shell structure in which one quantum dot wraps (surrounds) another quantum dot may be possible. The interface of the core and the shell may have a concentration gradient in which the concentration of an element present in the shell is decreased toward the center.

In some embodiments, the quantum dot may have the above-described core-shell structure including a core including a nanocrystal and a shell wrapping (surrounding) the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or one or more combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, or a ternary compound such as MgAl₂O₄, CoFe₂O₄, NiFe₂O₄ and/or CoMn₂O₄, but an embodiment of the present disclosure is not limited thereto.

In some embodiments, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but an embodiment of the present disclosure is not limited thereto.

The quantum dot may have a full width of half maximum (FWHM) of emission wavelength spectrum of about 45 nm or less, about 40 nm or less, or about 30 nm or less. Within these ranges, color purity or color reproducibility may be improved (increased). In some embodiments, light emitted via such quantum dot is emitted in all directions, and light view angle properties may be improved.

In some embodiments, the shape of the quantum dot may be generally utilized shapes in the art, without limitation. For example, the shape of substantially spherical, pyramidal, multi-arm, or cubic nanoparticle, nanotube, nanowire, nanofiber, nanoplate particle, etc. may be utilized.

The quantum dot may control the color of light emitted according to the particle size, and accordingly, the quantum dot may have one or more suitable emission colors such as blue, red and green.

In the light emitting devices ED of embodiments, as shown in FIG. 3 to FIG. 6, the electron transport region ETR is provided on the emission layer EML. The electron transport region ETR may include at least one of a hole blocking layer HBL, an electron transport layer ETL or an electron injection layer EIL. However, an embodiment of the present disclosure is not limited thereto.

The electron transport region ETR may have a single layer formed utilizing a single material, a single layer formed utilizing multiple different materials, or a multilayer structure having multiple layers formed utilizing multiple different materials.

For example, the electron transport region ETR may have a single layer structure of an electron injection layer EIL or an electron transport layer ETL, or a single layer structure formed utilizing an electron injection material and an electron transport material. In some embodiments, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1.

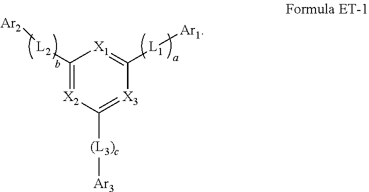

In Formula ET-1, at least one selected from among X₁ to X₃ is N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, “a” to “c” may each independently be an integer from 0 to 10. In Formula ET-1, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” to “c” are integers of 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, an embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and one or more compounds or mixtures thereof, without limitation.

The electron transport region ETR may include at least one selected from among Compounds ET1 to ET36.

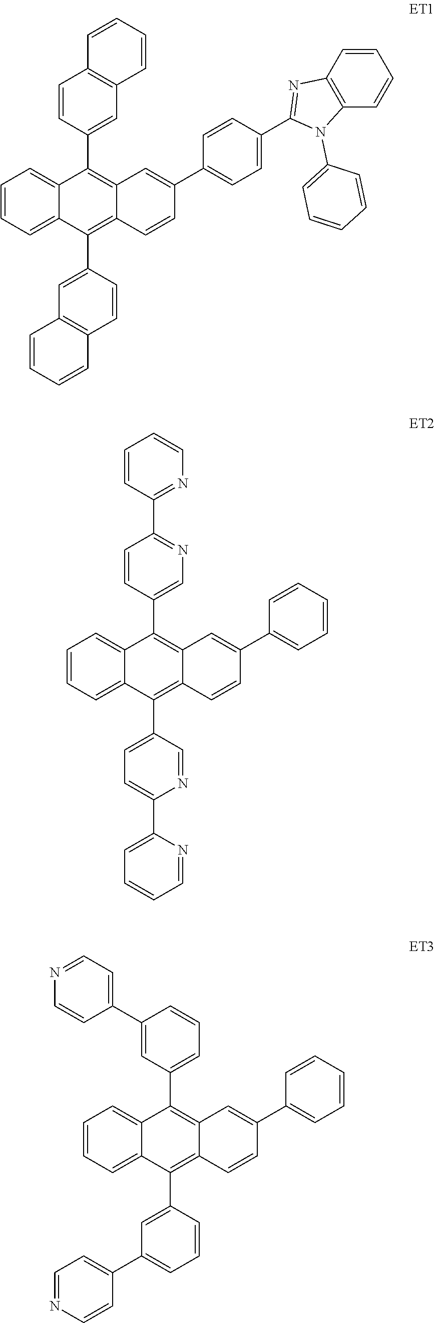 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

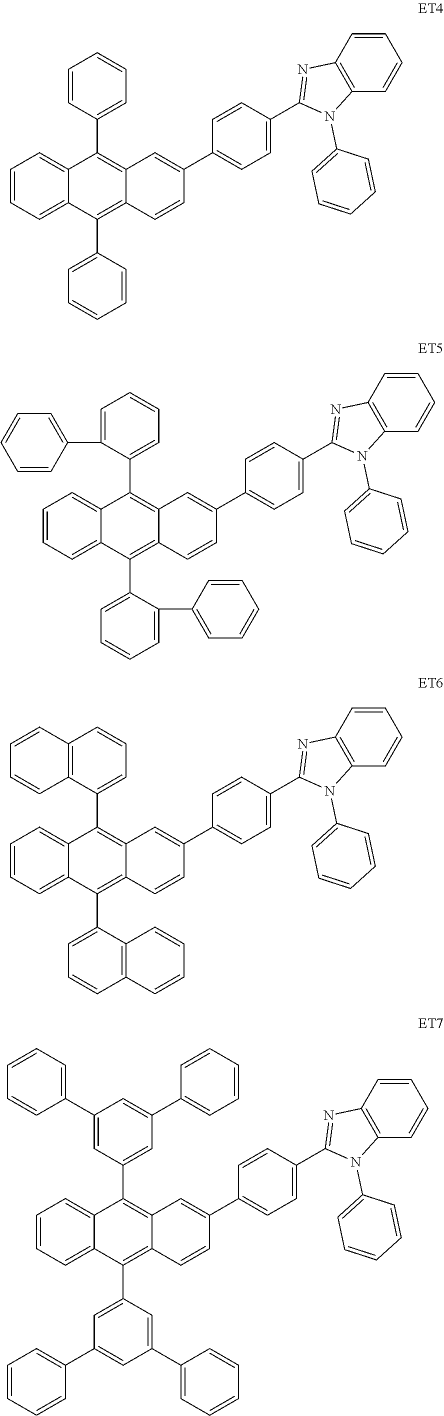 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

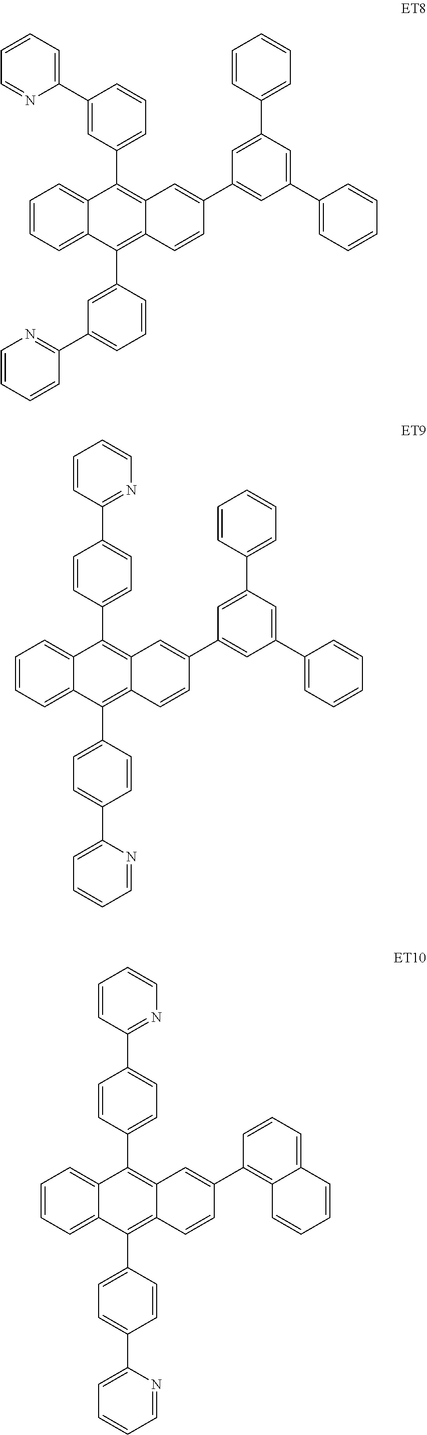 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

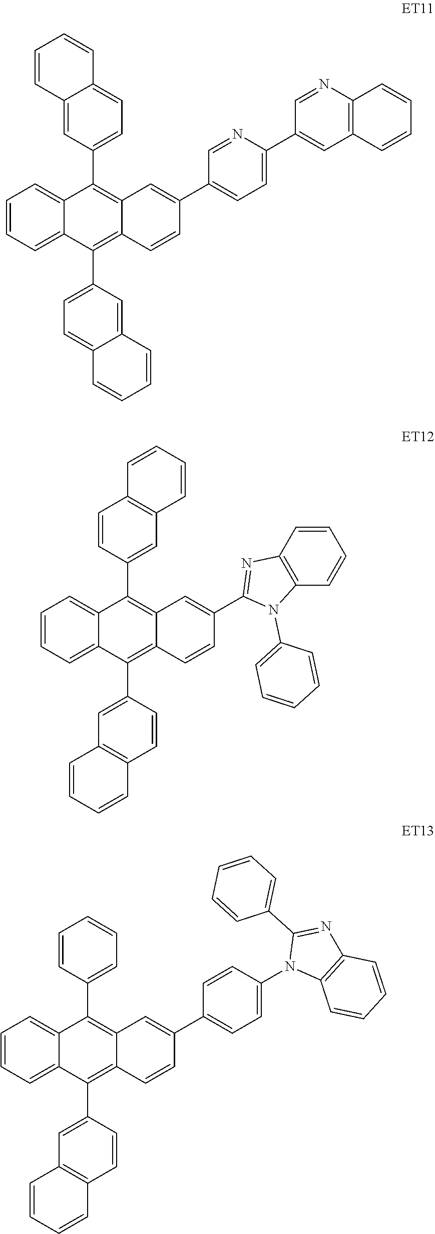 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

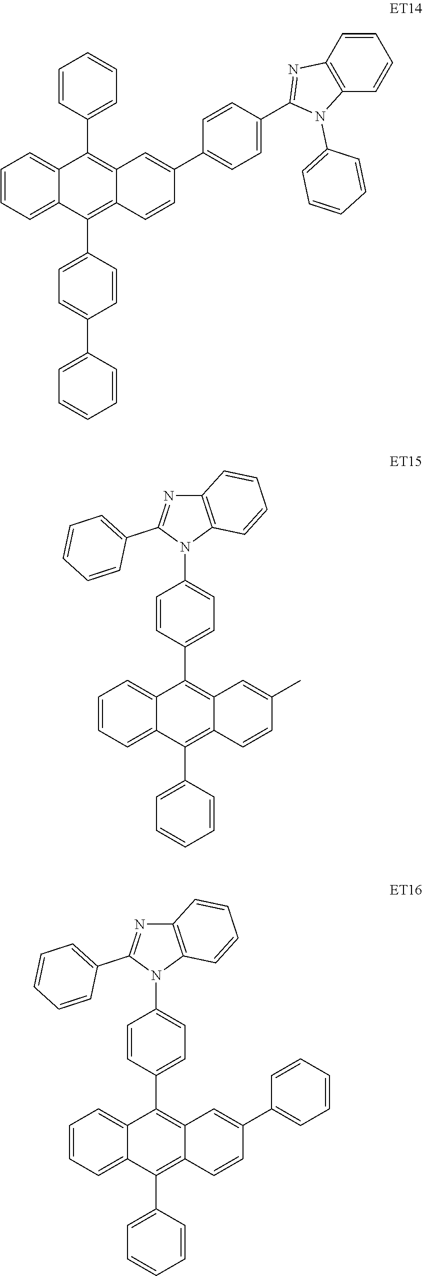 [SMILES: c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

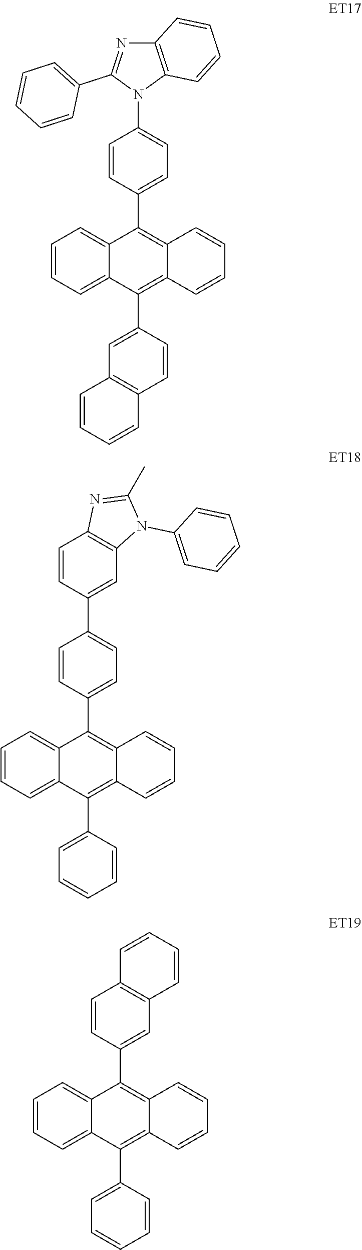

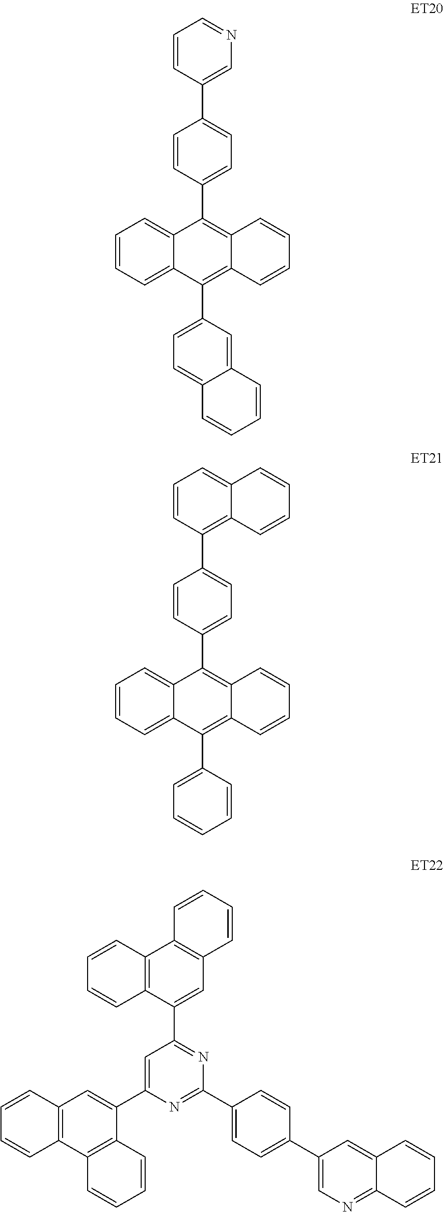

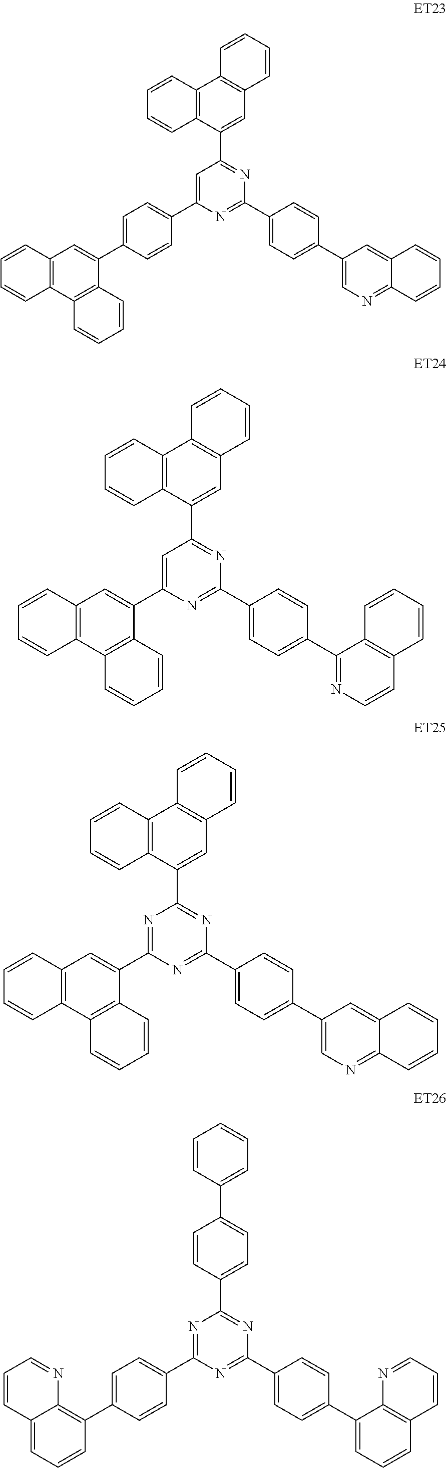 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

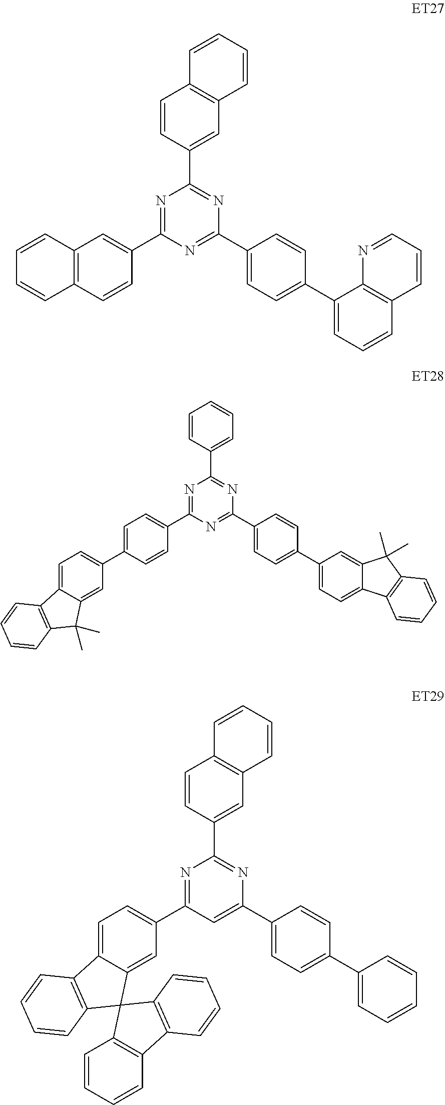 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

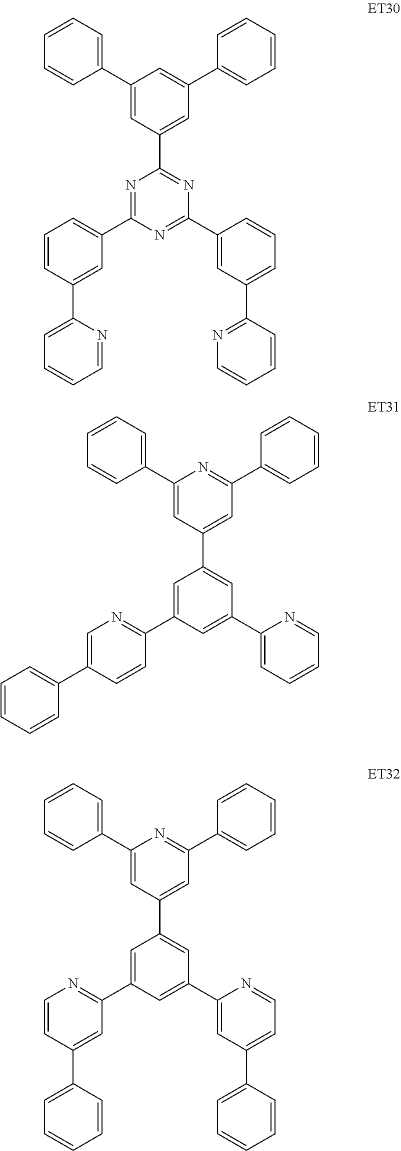 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

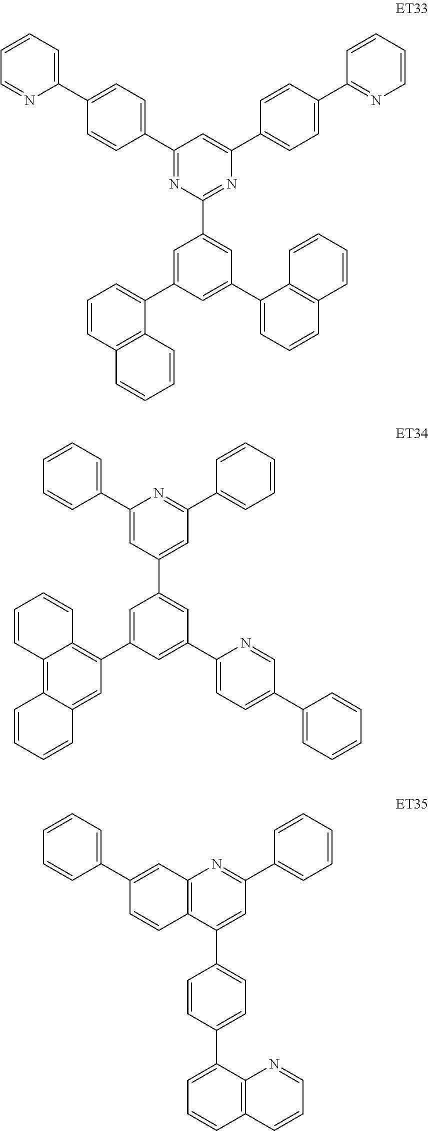 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccccc4)nc3c2)cc1]

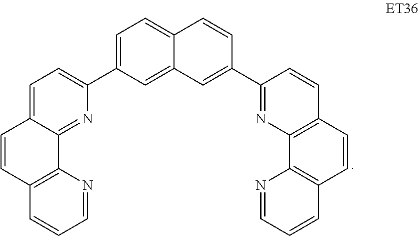 [SMILES: c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI and/or KI, a lanthanide metal such as Yb, or a co-depositing material of the metal halide and the lanthanide metal. For example, the electron transport region ETR may include KI:Yb, RbI:Yb, LiF:Yb, etc., as the co-depositing material. In some embodiments, the electron transport region ETR may utilize a metal oxide such as Li₂O and/or BaO, or 8-hydroxy-lithium quinolate (Liq). However, an embodiment of the present disclosure is not limited thereto. The electron transport region ETR also may be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, an embodiment of the present disclosure is not limited thereto.

The electron transport region ETR may include the compounds of the electron transport region in at least one selected from among an electron injection layer EIL, an electron transport layer ETL, and a hole blocking layer HBL.

When the electron transport region ETR includes the electron transport layer ETL, the thickness of the electron transport layer ETL may be from about 100 Å to about 1,000 Å, for example, from about 150 Å to about 500 Å. When the thickness of the electron transport layer ETL satisfies the above-described ranges, satisfactory (suitable) electron transport properties may be obtained without a substantial increase of a driving voltage. When the electron transport region ETR includes the electron injection layer EIL, the thickness of the electron injection layer EIL may be from about 1 Å to about 100 Å, or from about 3 Å to about 90 Å. When the thickness of the electron injection layer EIL satisfies the above described ranges, satisfactory (suitable) electron injection properties may be obtained without inducing a substantial increase of a driving voltage.

The second electrode EL2 may be provided on the electron transport region ETR. The second electrode EL2 may be a common electrode. The second electrode EL2 may be a cathode or an anode, but an embodiment of the present disclosure is not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, one or more compounds or mixtures thereof including (for example, AgMg, AgYb, or MgAg). In some embodiments, the second electrode EL2 may have a multilayered structure including a reflective layer or a transflective layer formed utilizing the above-described materials and a transparent conductive layer formed utilizing ITO, IZO, ZnO, ITZO, etc. For example, the second electrode EL2 may include the aforementioned metal materials, combinations of two or more metal materials selected from the aforementioned metal materials, or oxides of the aforementioned metal materials.

The second electrode EL2 may be connected with an auxiliary electrode. When the second electrode EL2 is connected with the auxiliary electrode, the resistance of the second electrode EL2 may decrease.

In some embodiments, on the second electrode EL2 in the light emitting device ED, a capping layer CPL may be further disposed. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNx, SiOy, etc.

For example, when the capping layer CPL includes an organic material, the organic material may include 2,2′-dimethyl-N,N′-di-[(1-naphthyl)-N,N′-diphenyl]-1,1′-biphenyl-4,4′-diamine (α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., or includes an epoxy resin, or acrylate such as methacrylate. In some embodiments, a capping layer CPL may include at least one selected from among Compounds P1 to P5, but an embodiment of the present disclosure is not limited thereto.

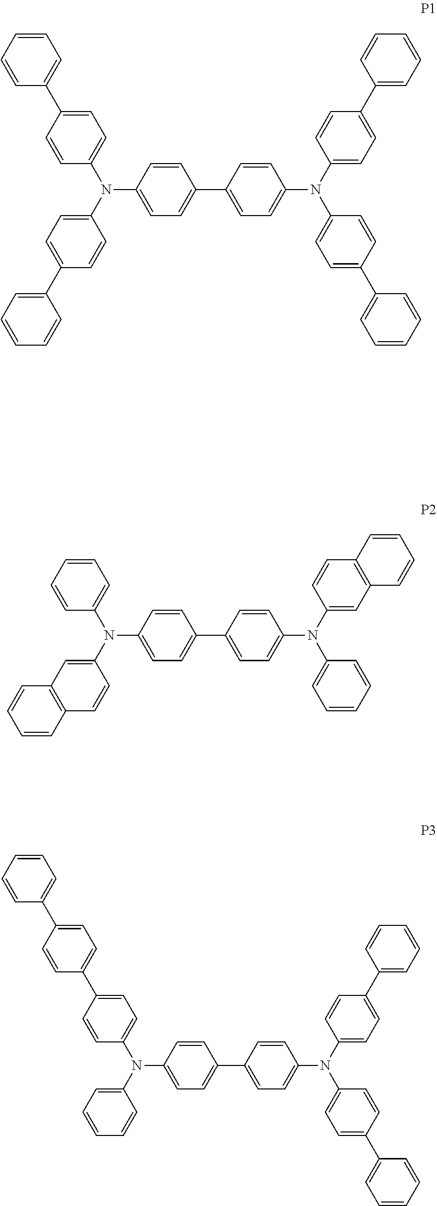 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

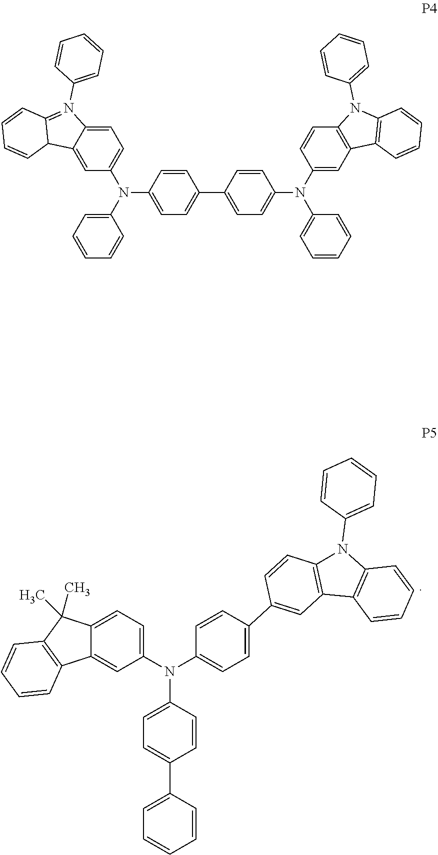

In some embodiments, the refractive index of the capping layer CPL may be about 1.6 or more. For example, the refractive index of the capping layer CPL with respect to light in a wavelength range of about 550 nm to about 660 nm may be about 1.6 or more.

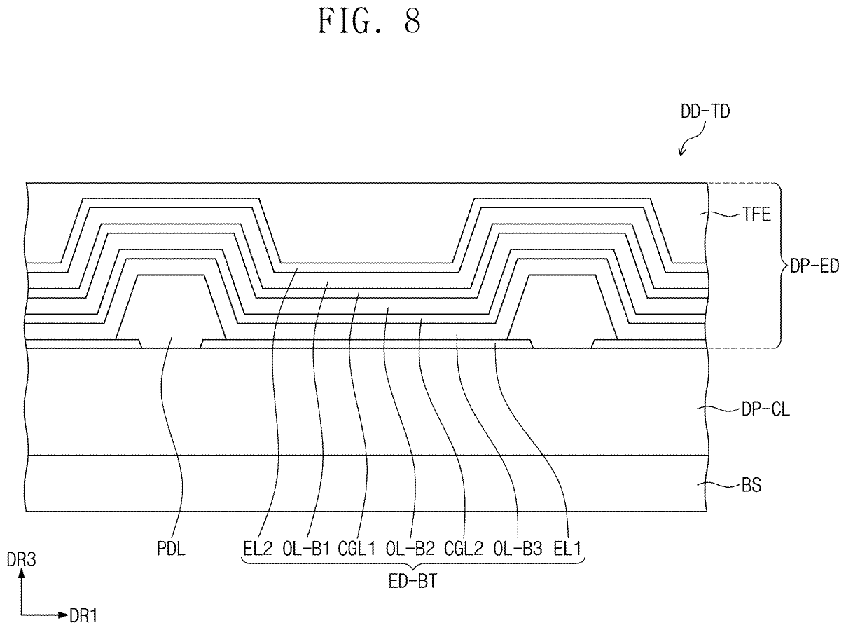

FIG. 7 and FIG. 8 are cross-sectional views on display apparatuses according to embodiments. In the explanation on the display apparatuses of embodiments, referring to FIG. 7 and FIG. 8, the overlapping parts with the explanation on FIG. 1 to FIG. 6 may not be explained again, and the different features will primarily be explained/described.

Referring to FIG. 7, a display apparatus DD according to an embodiment may include a display panel DP including a display device layer DP-ED, a light controlling layer CCL on the display panel DP, and a color filter layer CFL.

In an embodiment shown in FIG. 7, the display panel DP includes a base layer BS, a circuit layer DP-CL provided on the base layer BS and a display device layer DP-ED, and the display device layer DP-ED may include a light emitting device ED.

The light emitting device ED may include a first electrode EL1, a hole transport region HTR on the first electrode EL1, an emission layer EML on the hole transport region HTR, an electron transport region ETR on the emission layer EML, and a second electrode EL2 on the electron transport region ETR. In some embodiments, the same structures of the light emitting devices of FIG. 3 to FIG. 6 may be applied to the structure of the light emitting device ED shown in FIG. 7.

The emission layer EML of a light emitting device ED included in a display apparatus DD-a according to an embodiment, may include the organometallic compound of an embodiment.

Referring to FIG. 7, the emission layer EML may be disposed in an opening part OH defined in a pixel definition layer PDL. For example, the emission layer EML divided by the pixel definition layer PDL and correspondingly provided to each of luminous areas PXA-R, PXA-G and PXA-B may emit light in substantially the same wavelength region. In the display apparatus DD of an embodiment, the emission layer EML may emit blue light. In some embodiments, different from the drawings, the emission layer EML may be provided as a common layer for all luminous areas PXA-R, PXA-G and PXA-B.

The light controlling layer CCL may be on the display panel DP. The light controlling layer CCL may include a light converter. The light converter may be a quantum dot or a phosphor. The light converter may transform the wavelength of light provided and then emit. For example, the light controlling layer CCL may be a layer including a quantum dot or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be between the separated light controlling parts CCP1, CCP2 and CCP3, but an embodiment of the present disclosure is not limited thereto. In FIG. 7, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 converting first color light provided from the light emitting device ED into second color light, a second light controlling part CCP2 including a second quantum dot QD2 converting first color light into third color light, and a third light controlling part CCP3 transmitting first color light.

In an embodiment, the first light controlling part CCP1 may provide red light which is the second color light, and the second light controlling part CCP2 may provide green light which is the third color light. The third color controlling part CCP3 may transmit and provide blue light which is the first color light provided from the light emitting device ED. For example, the first quantum dot QD1 may be a red quantum dot, and the second quantum dot QD2 may be a green quantum dot. On the quantum dots QD1 and QD2, the same contents as those described above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a quantum dot but include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

Each of the first light controlling part CCP1, the second light controlling part CCP2, and the third light controlling part CCP3 may include base resins BR1, BR2 and BR3 dispersing the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3. The base resins BR1, BR2 and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may be acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may be on the light controlling parts CCP1, CCP2 and CCP3 to block or reduce the exposure of the light controlling parts CCP1, CCP2 and CCP3 to humidity/oxygen. In some embodiments, the barrier layer BFL1 may cover the light controlling parts CCP1, CCP2 and CCP3. In some embodiments, the barrier layer BFL2 may be provided between the light controlling parts CCP1, CCP2 and CCP3 and a color filter layer CFL.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride or a metal thin film securing light transmittance. In some embodiments, the barrier layers BFL1 and BFL2 may further include an organic layer. The barrier layers BFL1 and BFL2 may be composed of a single layer of multiple layers.

In the display apparatus DD of an embodiment, the color filter layer CFL may be on the light controlling layer CCL. For example, the color filter layer CFL may be directly on the light controlling layer CCL. In this embodiment, the barrier layer BFL2 may not be provided.

The color filter layer CFL may include a light blocking part BM and filters CF1, CF2 and CF3. The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye. However, an embodiment of the present disclosure is not limited thereto, and the third filter CF3 may not include (e.g., may exclude) the pigment or dye. The third filter CF3 may include a polymer photosensitive resin and not include a pigment or dye. The third filter CF3 may be transparent. The third filter CF3 may be formed utilizing a transparent photosensitive resin.

In some embodiments, the first filter CF1 and the second filter CF2 may be yellow filters. The first filter CF1 and the second filter CF2 may be provided in one body without distinction.

The light blocking part BM may be a black matrix. The light blocking part BM may be formed by including an organic light blocking material or an inorganic light blocking material including a black pigment or black dye. The light blocking part BM may prevent or reduce light leakage phenomenon and divide the boundaries among adjacent filters CF1, CF2 and CF3. In some embodiments, the light blocking part BM may be formed as a blue filter.

Each of the first to third filters CF1, CF2 and CF3 may be disposed corresponding to each of a red luminous area PXA-R, green luminous area PXA-G, and blue luminous area PXA-B.

On the color filter layer CFL, a base substrate BL may be disposed. The base substrate BL may be a member providing a base surface on which the color filter layer CFL, the light controlling layer CCL, etc. are disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, the base substrate BL may not be provided.

FIG. 8 is a cross-sectional view showing a portion of the display apparatus according to an embodiment. In FIG. 8, the cross-sectional view of a portion corresponding to the display panel DP in FIG. 7 is shown. In a display apparatus DD-TD of an embodiment, the light emitting device ED-BT may include multiple light emitting structures OL-B1, OL-B2 and OL-B3. The light emitting device ED-BT may include oppositely disposed first electrode EL1 and second electrode EL2, and the multiple light emitting structures OL-B1, OL-B2 and OL-B3 stacked in order in a thickness direction and provided between the first electrode EL1 and the second electrode EL2. Each of the light emitting structures OL-B1, OL-B2 and OL-B3 may include an emission layer EML (FIG. 7), and a hole transport region HTR and an electron transport region ETR, disposed with the emission layer EML (FIG. 7) therebetween.

For example, the light emitting device ED-BT included in the display apparatus DD-TD of an embodiment may be a light emitting device of a tandem structure including multiple emission layers.

In an embodiment shown in FIG. 8, light emitted from the light emitting structures OL-B1, OL-B2 and OL-B3 may be all blue light (e.g., light beams in the blue wavelength or in blue wavelength region). However, an embodiment of the present disclosure is not limited thereto, and the wavelength regions of light emitted from the light emitting structures OL-B1, OL-B2 and OL-B3 may be different from each other. For example, the light emitting device ED-BT including the multiple light emitting structures OL-B1, OL-B2 and OL-B3 emitting light in different wavelength regions may emit white light.

Between neighboring light emitting structures OL-B1, OL-B2 and OL-B3, charge generating layers CGL1 and CGL2 may be disposed. The charge generating layers CGL1 and CGL2 may include a p-type or kind charge generating layer and/or an n-type or kind charge generating layer.

In at least one selected from among the light emitting structures OL-B1, OL-B2 and OL-B3 included in the display apparatus DD-TD, the organometallic compound of an embodiment may be included. For example, at least one selected from among multiple emission layers included in the light emitting device ED-BT may include the organometallic compound of an embodiment.

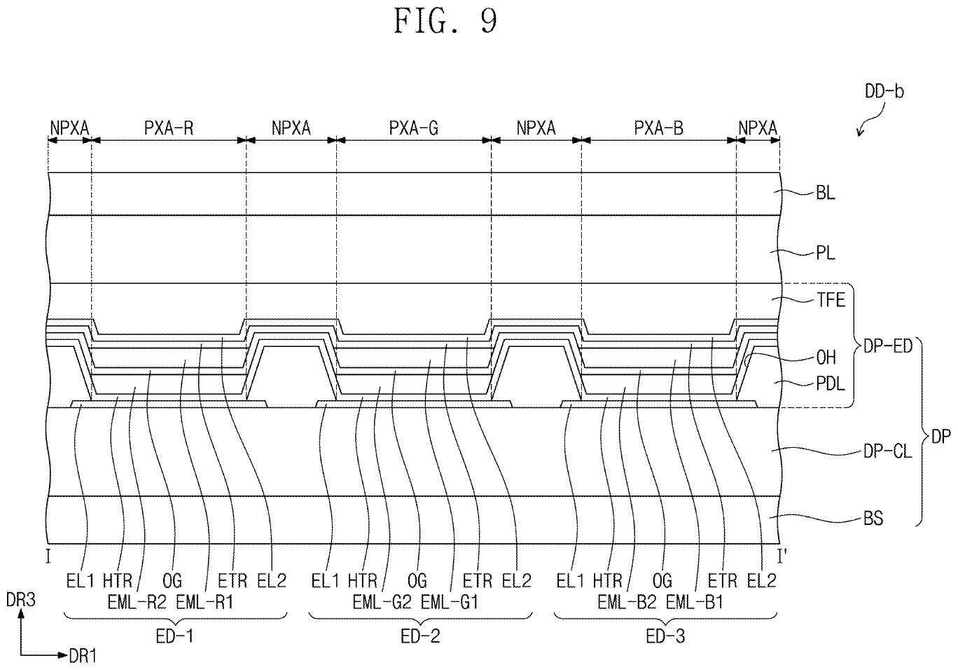

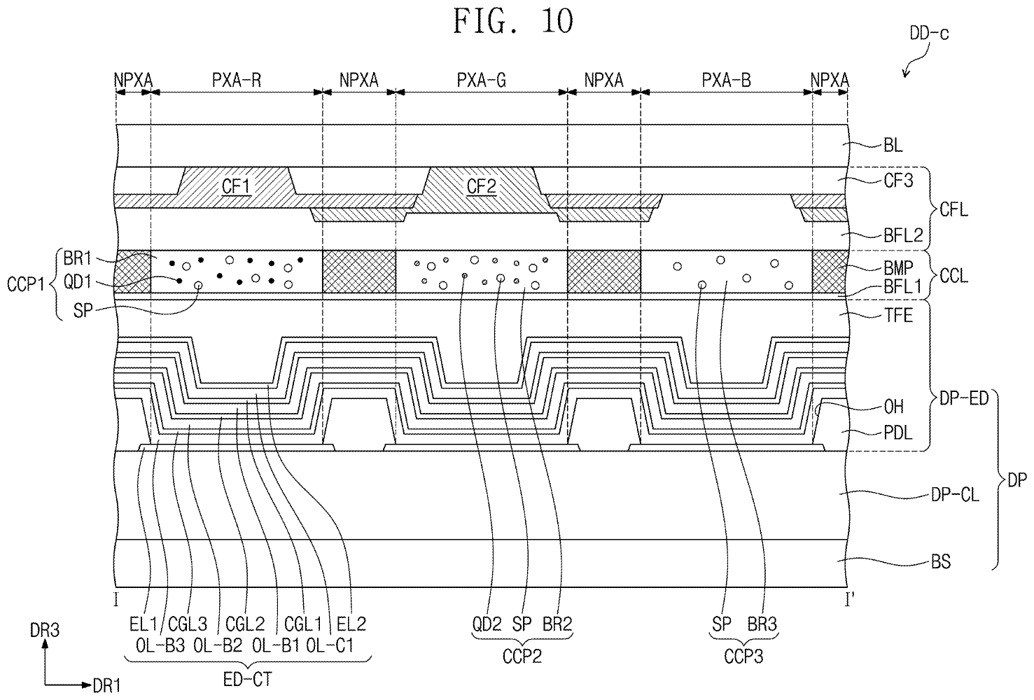

FIG. 9 is a cross-sectional view showing a display apparatus according to an embodiment. FIG. 10 is a cross-sectional view showing a display apparatus according to an embodiment.

Referring to FIG. 9, a display apparatus DD-b according to an embodiment may include light emitting devices ED-1, ED-2 and ED-3, formed by stacking two emission layers. Compared to the display apparatus DD of an embodiment, shown in FIG. 2, an embodiment shown in FIG. 9 is different in that first to third light emitting devices ED-1, ED-2 and ED-3 each include two emission layers stacked in a thickness direction. In the first to third light emitting devices ED-1, ED-2 and ED-3, two emission layers may emit light in substantially the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. For example, the emission auxiliary part OG may include an electron transport region, a charge generating layer, and a hole transport region that are sequentially stacked. The emission auxiliary part OG may be provided as a common layer in all of the first to third light emitting devices ED-1, ED-2 and ED-3. However, an embodiment of the present disclosure is not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be between the electron transport region ETR and the emission auxiliary part OG. The second red emission layer EML-R2, the second green emission layer EML-G2 and the second blue emission layer EML-B2 may be between the emission auxiliary part OG and the hole transport region HTR.

For example, the first light emitting device ED-1 may include a first electrode EL1, a hole transport region HTR, a second red emission layer EML-R2, an emission auxiliary part OG, a first red emission layer EML-R1, an electron transport region ETR, and a second electrode EL2 that are sequentially stacked. The second light emitting device ED-2 may include a first electrode EL1, a hole transport region HTR, a second green emission layer EML-G2, an emission auxiliary part OG, a first green emission layer EML-G1, an electron transport region ETR, and a second electrode EL2 that are sequentially stacked. The third light emitting device ED-3 may include a first electrode EL1, a hole transport region HTR, a second blue emission layer EML-B2, an emission auxiliary part OG, a first blue emission layer EML-B1, an electron transport region ETR, and a second electrode EL2 that are sequentially stacked.

In some embodiments, an optical auxiliary layer PL may be on a display element layer DP-ED. The optical auxiliary layer PL may include a polarization layer. The optical auxiliary layer PL may be on a display panel DP and may control reflected light at the display panel DP by external light. The optical auxiliary layer PL may not be provided from the display apparatus according to an embodiment.

At least one emission layer included in the display apparatus DD-b of an embodiment, shown in FIG. 9, may include the organometallic compound of an embodiment. For example, in an embodiment, at least one selected from among the first blue emission layer EML-B1 and the second blue emission layer EML-B2 may include the organometallic compound of an embodiment.

Different from FIG. 8 and FIG. 9, a display apparatus DD-c in FIG. 10 is shown to include four light emitting structures OL-B1, OL-B2, OL-B3 and OL-C1. A light emitting device ED-CT may include an oppositely disposed first electrode EL1 and second electrode EL2, and first to fourth light emitting structures OL-B1, OL-B2, OL-B3 and OL-C1 that are sequentially stacked in a thickness direction between the first electrode EL1 and the second electrode EL2. Between the first to fourth light emitting structures OL-B1, OL-B2, OL-B3 and OL-C1, charge generating layers CGL1, CGL2 and CGL3 may be disposed. Among the four light emitting structures, the first to third light emitting structures OL-B1, OL-B2 and OL-B3 may emit blue light, and the fourth light emitting structure OL-C1 may emit green light. However, an embodiment of the present disclosure is not limited thereto, and the first to fourth light emitting structures OL-B1, OL-B2, OL-B3 and OL-C1 may emit different wavelengths of light.

The charge generating layers CGL1, CGL2 and CGL3 disposed between the neighboring light emitting structures OL-B1, OL-B2, OL-B3 and OL-C1 may include a p-type or kind charge generating layer and/or an n-type or kind charge generating layer.

In at least one selected from among the light emitting structures OL-B1, OL-B2, OL-B3 and OL-C1, included in the display apparatus DD-c of an embodiment, the organometallic compound of an embodiment may be included. For example, in an embodiment, at least one selected from among the first to third light emitting structures OL-B1, OL-B2 and OL-B3 may include the organometallic compound of an embodiment.

Hereinafter, referring to embodiments and comparative embodiments, the organometallic compound according to an embodiment and the light emitting device according to an embodiment of the present disclosure will be explained in more detail. The embodiments below are merely examples to assist in the understanding of the present disclosure, and the scope of the present disclosure is not limited thereto.

### EXAMPLES

### 1. Synthesis of Organometallic Compound

First, the synthetic method of the organometallic compound according to an embodiment of the present disclosure will be explained in more detail referring to the synthetic methods of Compounds 1, 2, 3, 21, and 52. The synthetic methods of the organometallic compounds explained hereinafter are merely examples, and the synthetic methods of the organometallic compounds are not limited to the embodiments below.

### (1) Synthesis of Compound 1

Organometallic Compound 1 according to an embodiment may be synthesized by, for example, the reactions below.

### 1) Synthesis of Intermediate 1-A

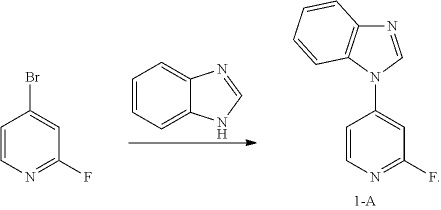 [SMILES: Fc1cc(Br)ccn1 ; c1ccc2[nH]cnc2c1 ; Fc1cc(-n2cnc3ccccc32)ccn1]

Benzimidazole (5.0 g, 42.3 mmol), 4-bromo-2-fluoropyridine (11.2 g, 63.5 mmol), potassium triphosphate (17.5 g, 84.6 mmol), copper iodide (800 mg, 4.2 mmol), and picolinic acid (500 mg, 4.2 mmol) were added to a reaction vessel and suspended in 420 mL of dimethyl sulfoxide. The reaction mixture was heated and stirred at about 160° C. for about 12 hours. After finishing the reaction, the resultant was cooled to room temperature and extracted with ethyl acetate. The organic layer thus extracted was washed with a saturated sodium chloride aqueous solution and dried over sodium sulfate. The residue after removing the solvent was separated utilizing column chromatography to obtain Intermediate 1-A (6.2 g, 29.0 mmol).

### 2) Synthesis of Intermediate 1-B

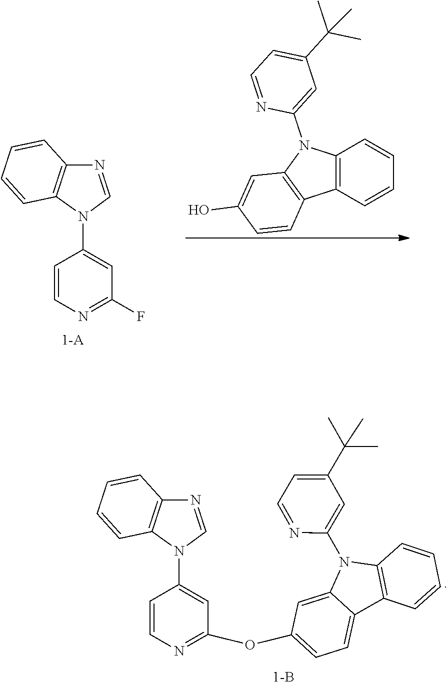 [SMILES: Fc1cc(-n2cnc3ccccc32)ccn1 ; CC(C)(C)c1ccnc(-n2c3ccccc3c3ccc(O)cc32)c1 ; CC(C)(C)c1ccnc(-n2c3ccccc3c3ccc(Oc4cc(-n5cnc6ccccc65)ccn4)cc32)c1]

Intermediate 1-A (6.2 g, 29.0 mmol), 9-(4-(tert-butyl)pyridin-2-yl)-9H-carbazol-2-ol (13.8 g, 43.5 mmol), and potassium triphosphate (12.0 g, 58.0 mmol) were added to a reaction vessel and suspended in 290 mL of dimethyl sulfoxide. The reaction mixture was heated and stirred at about 160° C. for about 12 hours. After finishing the reaction, the resultant was cooled to room temperature and extracted with ethyl acetate. The organic layer thus extracted was washed with a saturated sodium chloride aqueous solution and dried over sodium sulfate. The residue after removing the solvent was separated utilizing column chromatography to obtain Intermediate 1-B (7.2 g, 14.2 mmol).

### 3) Synthesis of Intermediate 1-C

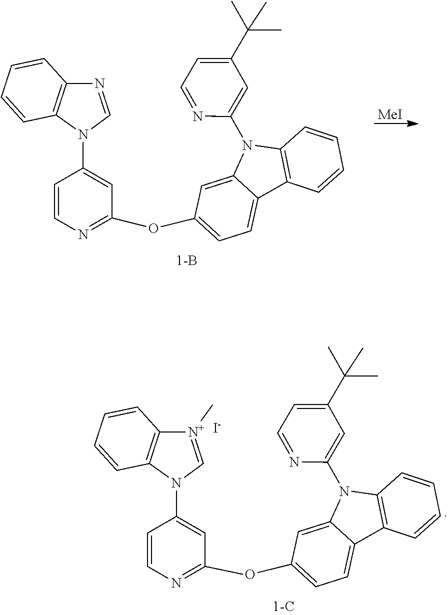 [SMILES: "MeI" ; CC(C)(C)c1ccnc(-n2c3ccccc3c3ccc(Oc4cc(-n5cnc6ccccc65)ccn4)cc32)c1 ; C[n+]1cn(-c2ccnc(Oc3ccc4c5ccccc5n(-c5cc(C(C)(C)C)ccn5)c4c3)c2)c2ccccc21 ; [I-]]

Intermediate 1-B (7.2 g, 14.2 mmol), and iodomethane (6.0 g, 42.6 mmol) were added to a reaction vessel and suspended in 140 mL of toluene. The reaction mixture was heated and stirred at about 110° C. for about 12 hours. After finishing the reaction, the resultant was cooled to room temperature, and a certain portion of the solvent was removed. Distilled water was added thereto, and the solid thus obtained was filtered. The solid thus filtered was separated utilizing a recrystallization method to obtain Intermediate 1-C (5.9 g, 9.1 mmol).

### 4) Synthesis of Compound 1

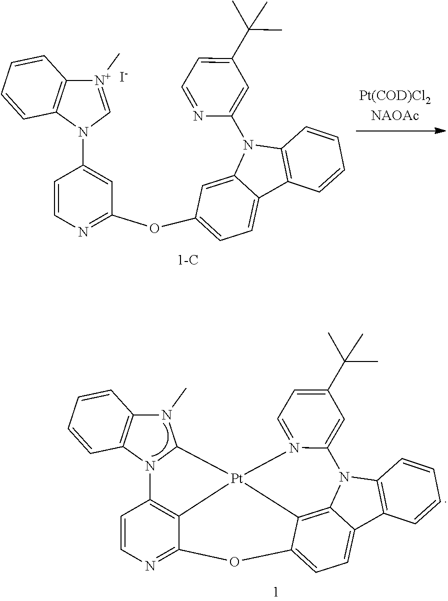

Intermediate 1-C (5.9 g, 9.1 mmol), dichloro(1,5-cyclooctadiene)platinum (3.8 g, 10.0 mmol), and sodium acetate (1.5 g, 18.2 mmol) were suspended in 360 mL of dioxane. The reaction mixture was heated and stirred at about 110° C. for about 72 hours. After finishing the reaction, the resultant was cooled to room temperature, 360 mL of distilled water was added thereto, and extraction with ethyl acetate was performed. The organic layer thus extracted was washed with a saturated sodium chloride aqueous solution and dried over sodium sulfate. The residue after removing the solvent was separated utilizing column chromatography to obtain Compound 1 (570 mg, 0.8 mmol).

### (2) Synthesis of Compound 2

Organometallic Compound 2 according to an embodiment may be synthesized by, for example, the reactions below.

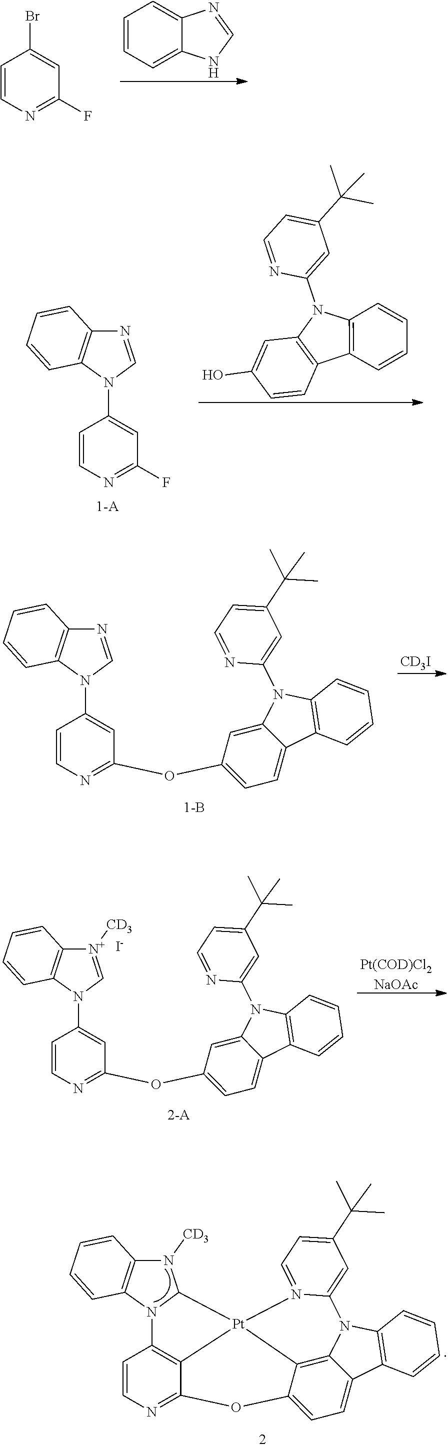

Compound 2 was obtained (650 mg, 0.9 mmol) utilizing substantially the same method as the synthesis of Compound 1 except for utilizing iodomethane-D₃ instead of iodomethane-H₃.

### (3) Synthesis of Compound 3

Organometallic Compound 3 according to an embodiment may be synthesized by, for example, the reactions below.

### 1) Synthesis of Intermediate 3-A

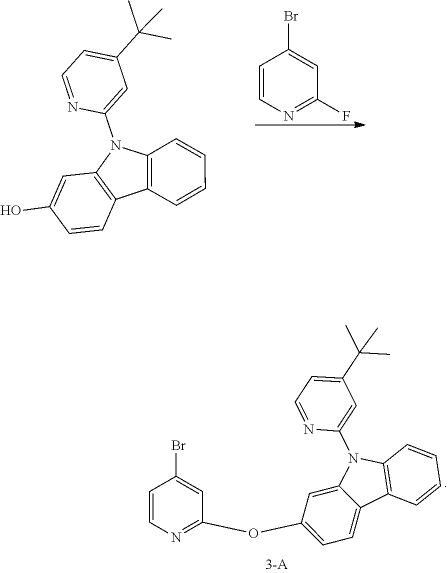 [SMILES: CC(C)(C)c1ccnc(-n2c3ccccc3c3ccc(O)cc32)c1 ; Fc1cc(Br)ccn1 ; CC(C)(C)c1ccnc(-n2c3ccccc3c3ccc(Oc4cc(Br)ccn4)cc32)c1]

9-(4-(Tert-butyl)pyridin-2-yl)-9H-carbazol-2-ol (11.1 g, 35.0 mmol), 4-bromo-2-fluoropyridine (12.3 g, 70.0 mmol), and potassium triphosphate (12.0 g, 70.0 mmol) were added to a reaction vessel and suspended in 360 mL of dimethyl sulfoxide. The reaction mixture was heated and stirred at about 160° C. for about 12 hours. After finishing the reaction, the resultant was cooled to room temperature and extracted with ethyl acetate. The organic layer thus extracted was washed with a saturated sodium chloride aqueous solution and dried over sodium sulfate. The residue after removing the solvent was separated utilizing column chromatography to obtain Intermediate 3-A (12.9 g, 27.3 mmol).

### 2) Synthesis of Intermediate 3-B

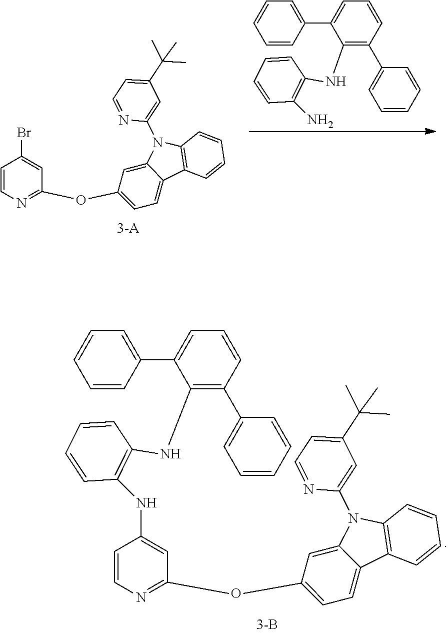 [SMILES: CC(C)(C)c1ccnc(-n2c3ccccc3c3ccc(Oc4cc(Br)ccn4)cc32)c1 ; Nc1ccccc1Nc1c(-c2ccccc2)cccc1-c1ccccc1 ; CC(C)(C)c1ccnc(-n2c3ccccc3c3ccc(Oc4cc(Nc5ccccc5Nc5c(-c6ccccc6)cccc5-c5ccccc5)ccn4)cc32)c1]

Intermediate 3-A (12.9 g, 27.3 mmol), N1-([1,1′:3′,1″-terphenyl]-2′-yl)benzene-1,2-diamine (10.1 g, 30.0 mmol), tris(dibenzylideneacetone)dipalladium (1.3 g, 1.4 mmol), Xpos (1.3 g, 2.7 mmol), and sodium tert-butoxide (6.2 g, 81.9 mmol) were added to a reaction vessel and suspended in 270 mL of dimethyl sulfoxide. The reaction mixture was heated and stirred at about 110° C. for about 3 hours. After finishing the reaction, the resultant was cooled to room temperature and extracted with ethyl acetate. The organic layer thus extracted was washed with a saturated sodium chloride aqueous solution and dried over sodium sulfate. The residue after removing the solvent was separated utilizing column chromatography to obtain Intermediate 3-B (9.8 g, 13.5 mmol).

### 3) Synthesis of Intermediate 3-C

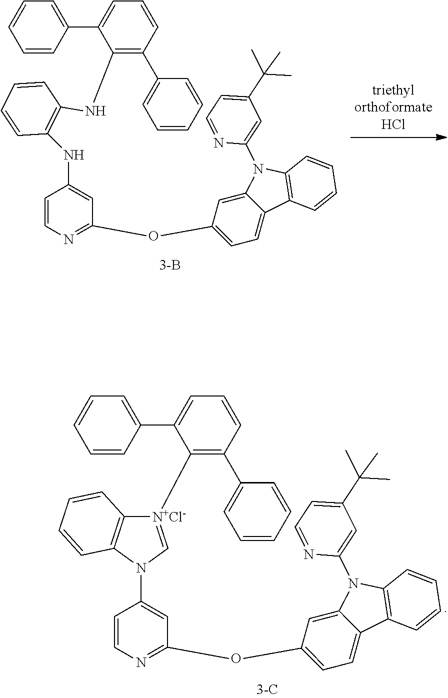

Intermediate 3-B (9.8 g, 13.5 mmol), triethyl orthoformate (90 mL, 675 mmol) and a HCl 35 wt % solution (6.4 mL, 74.3 mmol) were added to a reaction vessel and heated and stirred at about 80° C. for about 12 hours. After finishing the reaction, the resultant was cooled to room temperature, and the residue after removing the solvent was separated utilizing column chromatography to obtain Intermediate 3-C (7.7 g, 9.9 mmol).

### 4) Synthesis of Intermediate 3-D

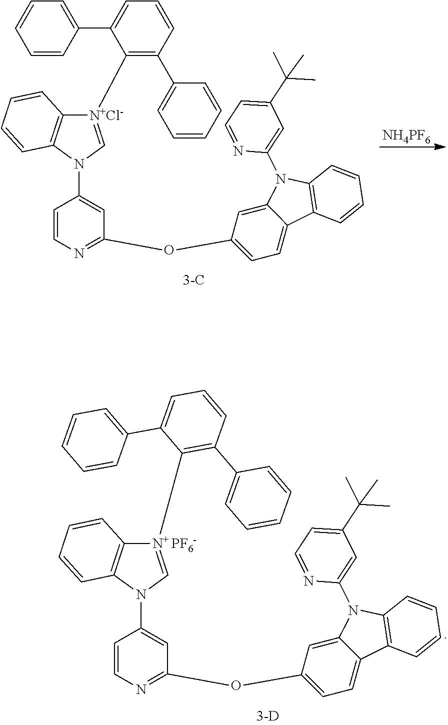

Intermediate 3-C (7.7 g, 9.9 mmol), and ammonium hexafluorophosphate (3.2 g, 19.8 mmol) were added to a reaction vessel and suspended in a solution of methanol/water in a ratio (e.g., amount) of 2:1. The reaction mixture was stirred at room temperature for about 12 hours. The solid thus obtained was filtered and separated utilizing column chromatography to obtain Intermediate 3-D (7.0 g, 7.9 mmol).

### 5) Synthesis of Compound 3

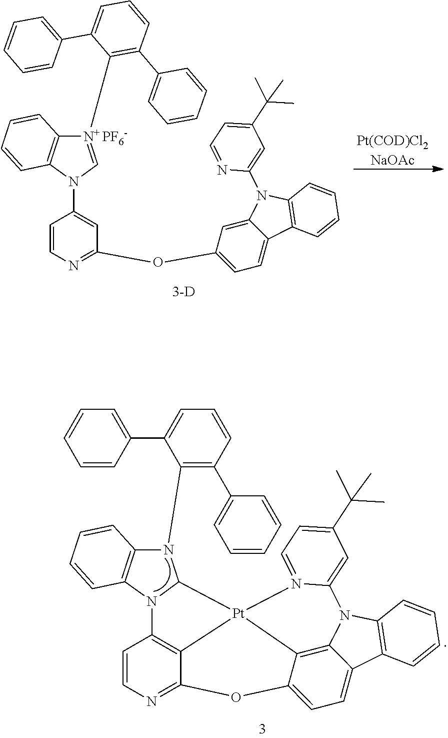

Intermediate 3-D (7.0 g, 7.9 mmol), dichloro(1,5-cyclooctadiene)platinum (3.3 g, 8.9 mmol), and sodium acetate (1.3 g, 16 mmol) were suspended in 160 mL of dioxane. The reaction mixture was heated and stirred at about 110° C. for about 72 hours. After finishing the reaction, the resultant was cooled to room temperature, and extracted with ethyl acetate. The organic layer thus extracted was washed with a saturated sodium chloride aqueous solution and dried over sodium sulfate. The residue after removing the solvent was separated utilizing column chromatography to obtain Compound 3 (740 mg, 0.8 mmol).

### (4) Synthesis of Compound 21

Organometallic Compound 21 according to an embodiment may be synthesized by, for example, the reactions below.

### 1) Synthesis of Intermediate 21-A

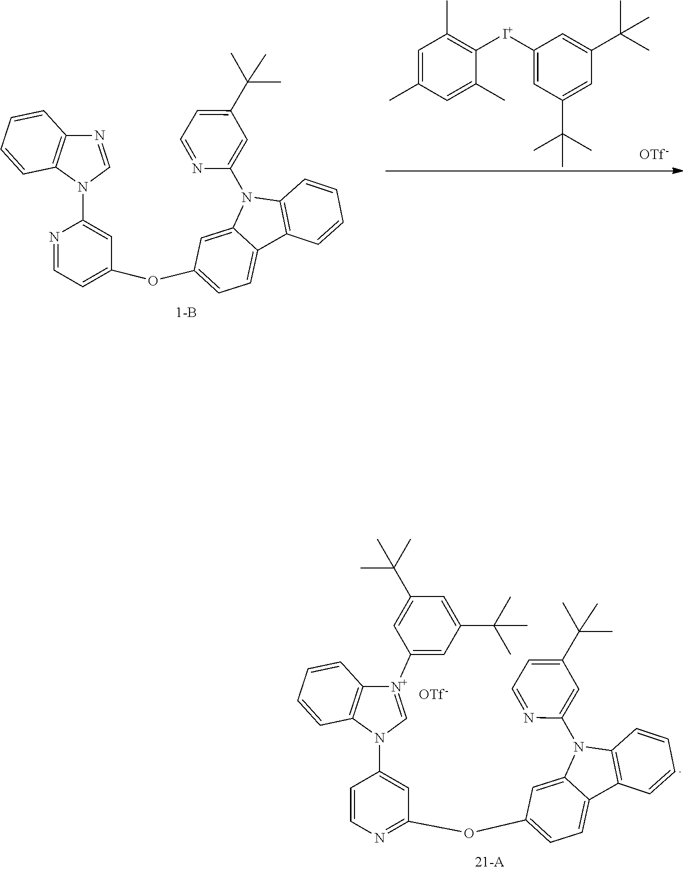 [SMILES: CC(C)(C)c1ccnc(-n2c3ccccc3c3ccc(Oc4ccnc(-n5cnc6ccccc65)c4)cc32)c1 ; Cc1cc(C)c([I+]c2cc(C(C)(C)C)cc(C(C)(C)C)c2)c(C)c1 ; CC(C)(C)c1cc(-[n+]2cn(-c3ccnc(Oc4ccc5c6ccccc6n(-c6cc(C(C)(C)C)ccn6)c5c4)c3)c3ccccc32)cc(C(C)(C)C)c1]

Intermediate 1-B (7.2 g, 14.2 mmol), (3,5-di-tert-butylphenyl)(mesityl)iodonium triflate (12.4 g, 21.3 mmol), and copper acetate (260 mg, 1.4 mmol) were suspended in 140 mL of dimethyl sulfoxide. The reaction mixture was heated and stirred at about 110° C. for about 24 hours. After finishing the reaction, the resultant was cooled to room temperature, 120 mL of distilled water was added thereto, and extraction with ethyl acetate was performed. The organic layer thus extracted was washed with a saturated sodium chloride aqueous solution and dried over sodium sulfate. The residue after removing the solvent was separated utilizing column chromatography to obtain Intermediate 21-A (9.2 g, 10.5 mmol).

### 2) Synthesis of Compound 21

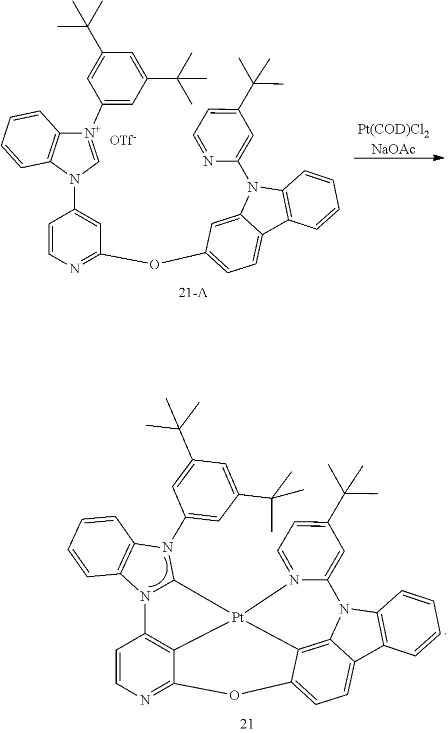

Intermediate 21-A (9.2 g, 10.5 mmol), dichloro(1,5-cyclooctadiene)platinum (4.4 g, 11.6 mmol), and sodium acetate (2.6 g, 31.5 mmol) were suspended in 420 mL of dioxane. The reaction mixture was heated and stirred at about 110° C. for about 72 hours. After finishing the reaction, the resultant was cooled to room temperature, 420 mL of distilled water was added thereto, and extraction with ethyl acetate was performed. The organic layer thus extracted was washed with a saturated sodium chloride aqueous solution and dried over sodium sulfate. The residue after removing the solvent was separated utilizing column chromatography to obtain Compound 21 (800 mg, 0.9 mmol).

### (5) Synthesis of Compound 52

Organometallic Compound 52 according to an embodiment may be synthesized by, for example, the reactions below.

### 1) Synthesis of Intermediate 52-A

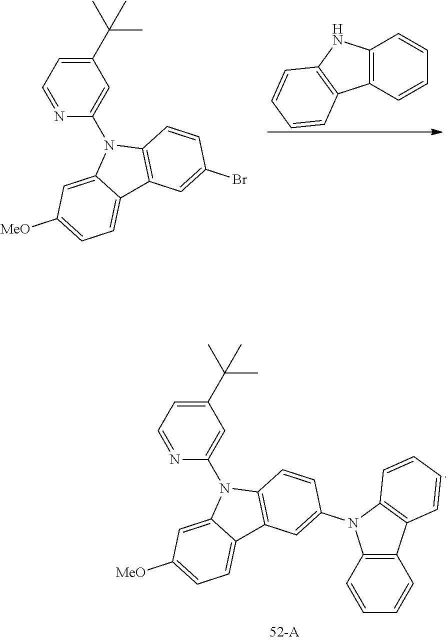 [SMILES: COc1ccc2c3cc(Br)ccc3n(-c3cc(C(C)(C)C)ccn3)c2c1 ; c1ccc2c(c1)[nH]c1ccccc12 ; COc1ccc2c3cc(-n4c5ccccc5c5ccccc54)ccc3n(-c3cc(C(C)(C)C)ccn3)c2c1]

6-Bromo-9-(4-(tert-butyl)pyridin-2-yl)-2-methoxy-9H-carbazole (30.0 g, 73.3 mmol), carbazole (18.4 g, 110.0 mmol), tris(dibenzylideneacetone)dipalladium (3.5 g, 3.7 mmol), Xpos (2.6 g, 5.5 mmol), and sodium tert-butoxide (16.6 g, 220 mmol) were added to a reaction vessel and suspended in 730 mL of toluene. The reaction mixture was heated and stirred at about 110° C. for about 12 hours. After finishing the reaction, the resultant was cooled to room temperature and extracted with ethyl acetate. The organic layer thus extracted was washed with a saturated sodium chloride aqueous solution and dried over sodium sulfate. The residue after removing the solvent was separated utilizing column chromatography to obtain Intermediate 52-A (25.8 g, 52.0 mmol).

### 2) Synthesis of Intermediate 52-B

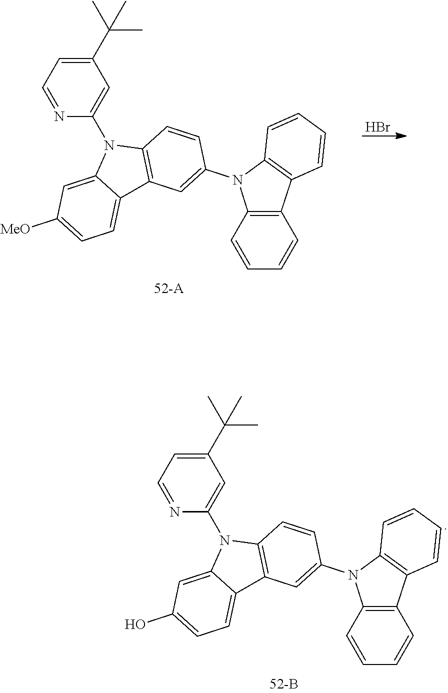 [SMILES: COc1ccc2c3cc(-n4c5ccccc5c5ccccc54)ccc3n(-c3cc(C(C)(C)C)ccn3)c2c1 ; Br ; CC(C)(C)c1ccnc(-n2c3ccc(-n4c5ccccc5c5ccccc54)cc3c3ccc(O)cc32)c1]

Intermediate 52-A (25.8 g, 52.0 mmol) was suspended in an excessive amount of a bromic acid solution. The reaction mixture was heated and stirred at about 110° C. for about 24 hours. After finishing the reaction, the resultant was cooled to room temperature, and an appropriate or suitable amount of sodium bicarbonate was added to neutralize. 300 mL of distilled water was added thereto, and extraction with ethyl acetate was performed. The organic layer thus extracted was washed with a saturated sodium chloride aqueous solution and dried over sodium sulfate. The residue after removing the solvent was separated utilizing column chromatography to obtain Intermediate 52-B (20.2 mg, 42.0 mmol).

### 3) Synthesis of Compound 52

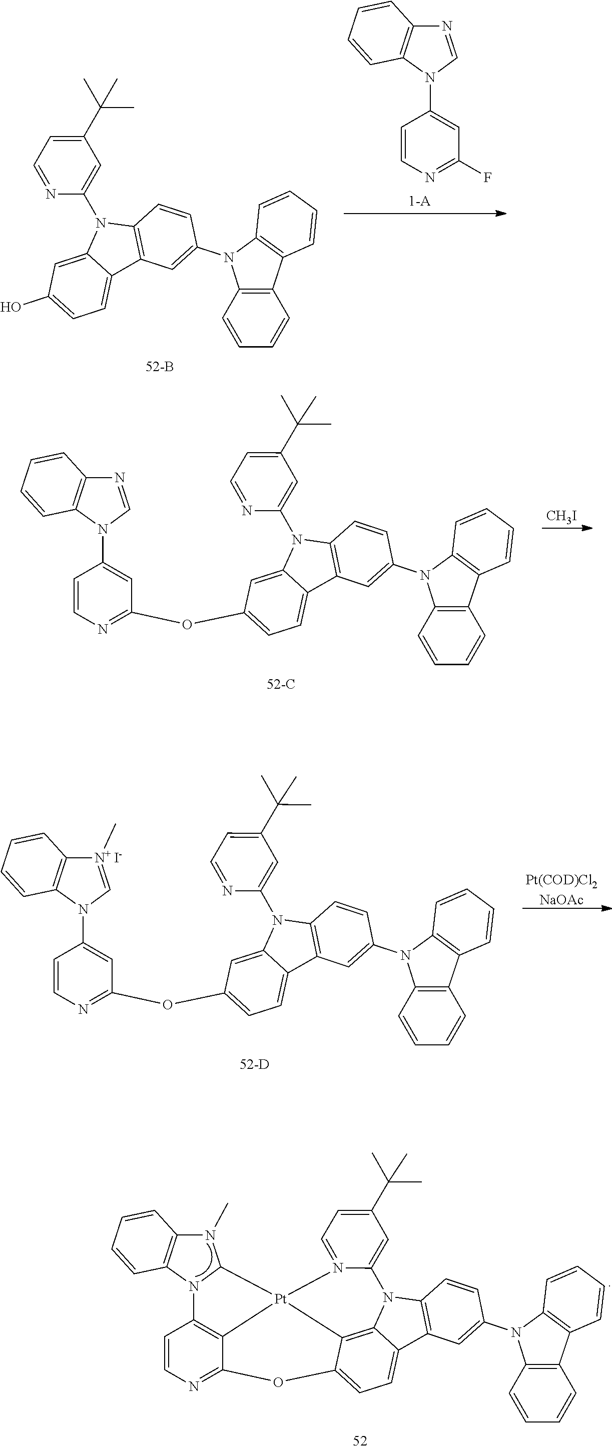

Then, Compound 52 was obtained (710 mg, 0.8 mmol) utilizing substantially the same method as the synthesis of Compound 1 except for utilizing Intermediate 52-B instead of 9-(4-(tert-butyl)pyridin-2-yl)-9H-carbazol-2-ol.

### 2. Manufacture and Evaluation of Light Emitting Device Including Organometallic Compound

A light emitting device of an embodiment, including an organometallic compound of an embodiment in an emission layer was manufactured by the following method. Light emitting devices of Examples 1 to 5 were manufactured utilizing the Example Compounds of Compounds 1, 2, 3, 21, and 52 as the dopant materials of emission layers. Comparative Example 1 corresponds to a light emitting device manufactured utilizing Comparative Compound C1 as the dopant material of an emission layer.

### Example Compounds

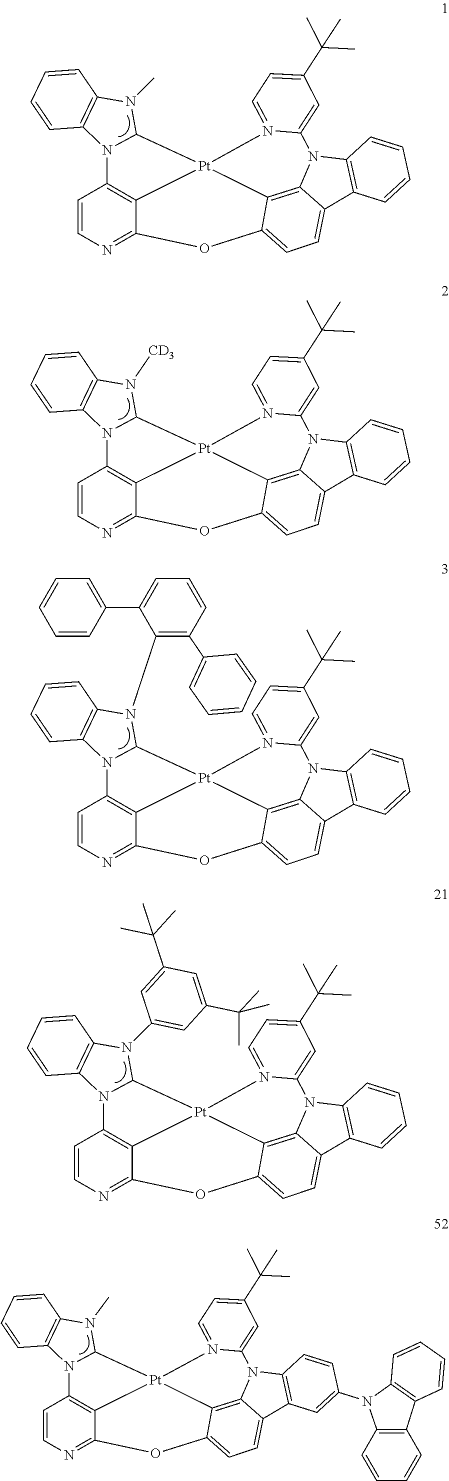

### Comparative Compounds

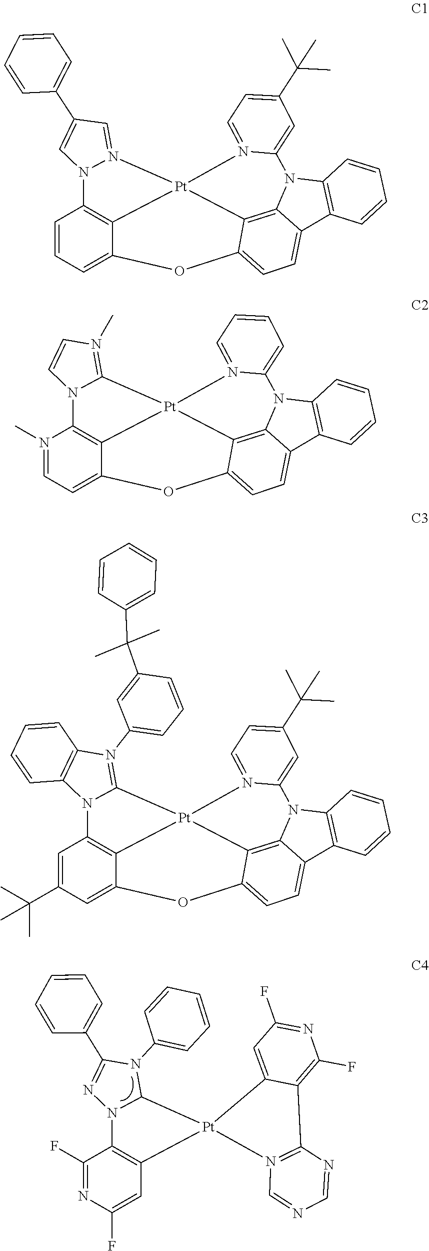

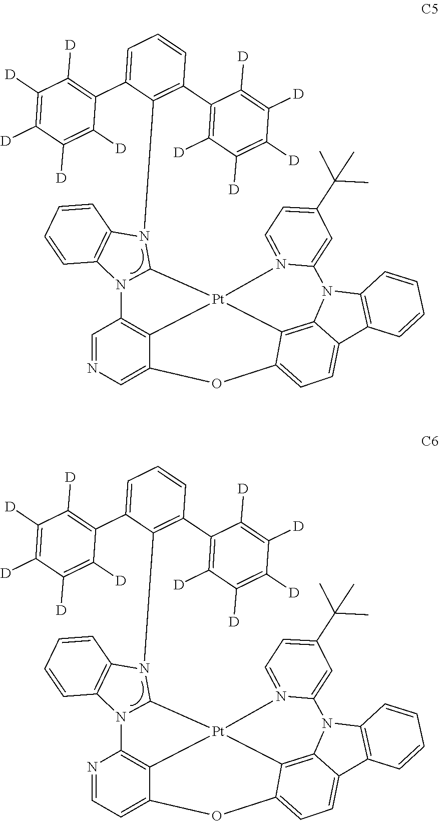

### Manufacture of Light Emitting Devices

### Example 1

An ITO glass substrate was cut into a size of about 50 mm×50 mm×0.7 mm, washed by ultrasonic waves utilizing isopropyl alcohol and distilled water for about 5 minutes each, and cleaned by exposing to ultraviolet rays for about 30 minutes and exposing to ozone, and then, the glass substrate was installed in a vacuum deposition apparatus. Then, a hole injection layer was formed utilizing 4,4′4″-tris[2-naphthyl(phenyl)amino]triphenylamine (2-TNATA) to a thickness of about 600 Å, and a hole transport layer was formed utilizing NPB to a thickness of about 300 Å. Then, an emission layer was formed utilizing a host obtained by mixing Compound H1 and Compound E2 in a weight ratio of about 5:5 and doped with Compound 1 of an embodiment in a 10% ratio, to a thickness of about 300 Å. Then, a hole blocking layer was formed utilizing ETH2 to a thickness of about 50 Å, and an electron transport layer was formed utilizing Alq₃ to a thickness of about 300 Å. Then, an electron injection layer was formed utilizing LiF to a thickness of about 10 Å, and a second electrode was formed utilizing Al to a thickness of about 3000 Å. All layers were formed by a vacuum deposition method.

### Example 2

A light emitting device was manufactured by substantially the same method as Example 1 except for utilizing Compound 2 instead of Compound 1 during forming a blue emission layer.

### Example 3

A light emitting device was manufactured by substantially the same method as Example 1 except for utilizing Compound 3 instead of Compound 1 during forming a blue emission layer.

### Example 4

A light emitting device was manufactured by substantially the same method as Example 1 except for utilizing Compound 21 instead of Compound 1 during forming a blue emission layer.

### Example 5

A light emitting device was manufactured by substantially the same method as Example 1 except for utilizing Compound 52 instead of Compound 1 during forming a blue emission layer.

### Comparative Example 1

A light emitting device was manufactured by substantially the same method as Example 1 except for utilizing Comparative Compound C1 instead of Compound 1 during forming a blue emission layer.

### Comparative Example 2

A light emitting device was manufactured by substantially the same method as Example 1 except for utilizing Comparative Compound C2 instead of Compound 1 during forming a blue emission layer.

### Comparative Example 3

A light emitting device was manufactured by substantially the same method as Example 1 except for utilizing Comparative Compound C3 instead of Compound 1 during forming a blue emission layer.

### Comparative Example 4

A light emitting device was manufactured by substantially the same method as Example 1 except for utilizing Comparative Compound C4 instead of Compound 1 during forming a blue emission layer.

### Comparative Example 5

A light emitting device was manufactured by substantially the same method as Example 1 except for utilizing Comparative Compound C5 instead of Compound 1 during forming a blue emission layer.

### Comparative Example 6

A light emitting device was manufactured by substantially the same method as Example 1 except for utilizing Comparative Compound C6 instead of Compound 1 during forming a blue emission layer.

The compounds utilized for the manufacture of the light emitting devices of the Examples and Comparative Examples are shown. The materials are suitable materials, and commercial products were purified by sublimation and then, utilized for the manufacture of the devices.

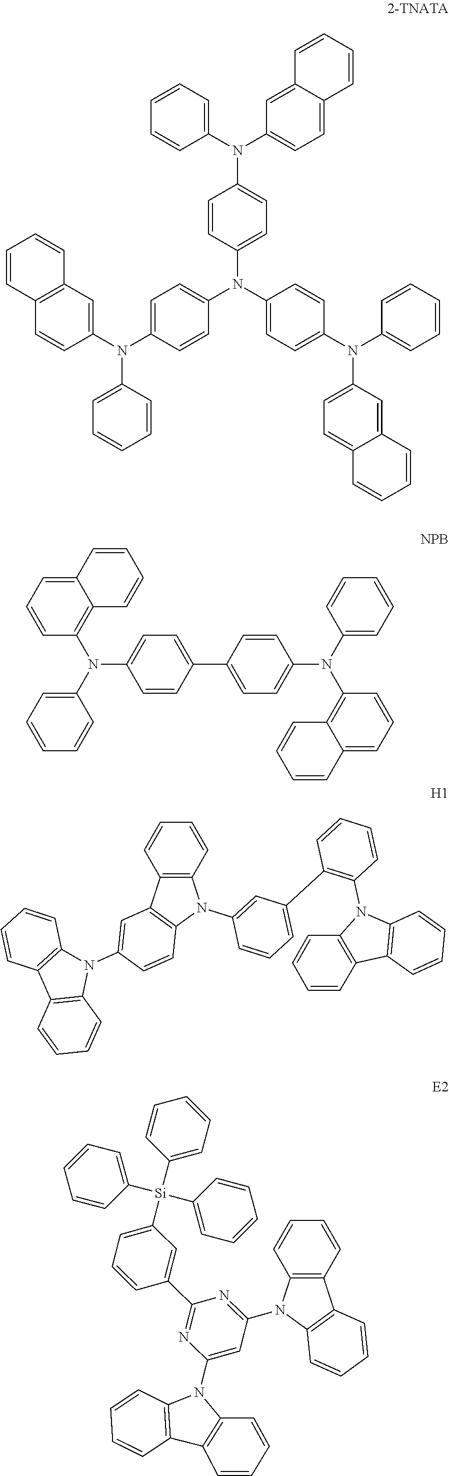

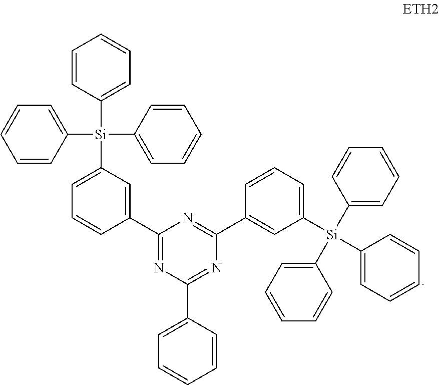 [SMILES: c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

The ¹H NMR and MS/FAB of Compounds 1, 2, 3, 21, and 52 synthesized in the above synthetic examples are shown in Table 1.

Compounds other than the compounds shown in Table 1 should be apparent to one of ordinary skill in the art upon reviewing the above-described synthetic methods and raw materials.

TABLE 1

| Compound | | MS/FAB | |
|---|---|---|---|
| No. | ¹H NMR (CDCl₃, 400 MHz) | found | calc. |
| 1 | 8.77 (m, 1H), 8.31 (m, 1H), 8.25 (m, 1H), 7.55- | 716.1859 | 716.1863 |
| | 7.49 (m, 3H), 7.41-7.38 (m, 4H), 7.18 (m, 1H), | | |
| | 7.05 (m, 1H), 6.65 (m, 1H), 6.55 (m, 1H), 5.75 | | |
| | (m, 1H), 3.45 (s, 3H), 1.33 (s, 9H) | | |
| 2 | 8.75 (m, 1H), 8.26 (m, 1H), 8.21 (m, 1H), 7.54- | 719.2055 | 719.2052 |
| | 7.50 (m, 3H), 7.39-7.37 (m, 4H), 7.20 (m, 1H), | | |
| | 7.08 (m, 1H), 6.68 (m, 1H), 6.57 (m, 1H), 5.77 | | |
| | (m, 1H), 1.35 (s, 9H) | | |
| 3 | 8.75 (m, 1H), 8.22-8.18 (m, 4H), 7.55-7.53 (m, | 930.2651 | 930.2646 |
| | 2H), 7.48 (m, 1H), 7.45-7.39 (m, 9H), 7.19-7.16 | | |
| | (m, 3H), 7.02-6.95 (m, 6H), 6.45 (m, 1H), 5.58 | | |
| | (m, 1H), 1.37 (s, 9H) | | |
| 21 | 8.67 (m, 1H), 8.25-8.21 (m, 2H), 7.55 (m, 1H), | 890.3274 | 890.3272 |
| | 7.51-7.49 (m, 2H), 7.41 (m, 2H), 7.21-7.19 (m, | | |
| | 3H), 7.15-7.13 (m, 3H), 6.98-6.95 (m, 2H), 6.54 | | |
| | (m, 1H), 5.68 (m, 1H), 1.45 (s, 9H), 1.43 (s, 9H), | | |
| | 1.33 (s, 9H) | | |
| 52 | 8.88 (m, 1H), 8.56 (m, 1H), 8.25-8.23 (m, 2H), | 881.2446 | 881.2442 |
| | 7.99 (m, 1H), 7.70-7.68 (m, 2H), 7.55-7.52 (m, | | |
| | 3H), 7.42-7.39 (m, 5H), 7.33 (m, 1H), 7.19-7.17 | | |
| | (m, 2H), 7.01 (m, 1H), 6.75 (m, 1H), 6.53 (m, | | |
| | 1H), 5.61 (m, 1H), 3.41 (s, 3H), 1.28 (s, 9H) | | |

### Evaluation of Properties of Light Emitting Device

The device efficiency and device lifetime of the light emitting devices manufactured utilizing Example Compounds 1, 2, 3, 21, and 52, and Comparative Compounds C1, C2, C3, C4, C5, and C6 were evaluated. In Table 2, the evaluation results of the light emitting devices for Example 1 to Example 5, and Comparative Example 1 to Comparative Example 6 are shown. In the evaluation results on the properties for the Examples and Comparative Examples, shown in Table 2, the driving voltage and current density were measured utilizing V7000 OLED IVL Test System, (Polaronix). The emission efficiency and device lifetime are measured results at a current density of about 100 mA/cm². In Table 2, lifetime (T₅₀) is consumed time measured for the luminance reached 50% in contrast to an initial luminance.

TABLE 2

| | | | | | Emission | | | |
|---|---|---|---|---|---|---|---|---|
| | | | | | efficiency | | Maximum | |
| | | First | | Driving | (cd/A) | | emission | Device |
| | | host:second | Luminance | voltage | (relative | | wavelength | lifetime |
| | Dopant | host (ratio) | (cd/m²) | (V) | value) | CIE_y | (nm) | (T₉₅, h) |
| Example | 1 | H1:E2 (5:5) | 1000 | 4.1 | 110 | 0.201 | 459 | 115 |
| 1 | | | | | | | | |
| Example | 2 | H1:E2 (5:5) | 1000 | 4.1 | 112 | 0.202 | 459 | 124 |
| 2 | | | | | | | | |
| Example | 3 | H1:E2 (5:5) | 1000 | 4.0 | 120 | 0.193 | 462 | 133 |
| 3 | | | | | | | | |
| Example | 21 | H1:E2 (5:5) | 1000 | 4.0 | 119 | 0.196 | 463 | 126 |
| 4 | | | | | | | | |
| Example | 52 | H1:E2 (5:5) | 1000 | 3.5 | 135 | 0.187 | 461 | 118 |
| 5 | | | | | | | | |
| Comparative | C1 | H1:E2 (5:5) | 1000 | 4.7 | 100 | 0.235 | 458 | 100 |
| Example | | | | | | | | |
| 1 | | | | | | | | |
| Comparative | C2 | H1:E2 (5:5) | 1000 | 4.8 | 89 | 0.240 | 460 | 89 |
| Example | | | | | | | | |
| 2 | | | | | | | | |
| Comparative | C3 | H1:E2 (5:5) | 1000 | 4.9 | 102 | 0.222 | 466 | 108 |
| Example | | | | | | | | |
| 3 | | | | | | | | |
| Comparative | C4 | H1:E2 (5:5) | 1000 | 5.1 | 69 | 0.237 | 457 | 14 |
| Example | | | | | | | | |
| 4 | | | | | | | | |
| Comparative | C5 | H1:E2 (5:5) | 1000 | 4.3 | 105 | 0.205 | 463 | 101 |
| Example | | | | | | | | |
| 5 | | | | | | | | |
| Comparative | C6 | H1:E2 (5:5) | 1000 | 4.5 | 99 | 0.219 | 465 | 87 |
| Example | | | | | | | | |
| 6 | | | | | | | | |

Referring to the results of Table 1, it could be confirmed that the Examples of the light emitting devices utilizing the organometallic compounds of embodiments of the present disclosure as the dopant materials of emission layers showed improved emission efficiency and device lifetime when compared to the Comparative Examples. The organometallic compound according to an embodiment of the present disclosure includes a central metal atom, and a ligand bonded to the central metal atom. The ligand includes first to fourth ligands, and the first to fourth ligands may selectively be connected with each other to form one tetradentate ligand. In the organometallic compound of an embodiment, the first ligand among the ligands bonded to the central metal atom may include a pyridine moiety. The first ligand may be bonded to the central metal atom at carbon at a meta position with respect to a nitrogen atom. In some embodiments, the first ligand may be bonded to the second ligand at a para position with respect to the nitrogen atom, and bonded to the third ligand at carbon at an ortho position with respect to the nitrogen atom and the carbon atom connected with the central metal atom. The first ligand having such a connection structure may contribute to the control of the HOMO energy level of a whole molecule. For example, the organometallic compound of an embodiment, represented by Formula 1 includes the first ligand at a specific position and may have a deep HOMO energy level, and accordingly, when the organometallic compound represented by Formula 1 is utilized as a dopant material in an emission layer EML, the HOMO energy level difference between a host and a dopant in an emission layer may be reduced, blue light with high color purity may be shown, and a low driving voltage, excellent or suitable emission efficiency and improved lifetime characteristics may be shown.

Comparative Compound C1 to Comparative Compound C3, included in Comparative Example 1 to Comparative Example 3 include a central metal atom, and four ligands bonded to the central metal atom, but do not include the first ligand suggested in the present disclosure. Accordingly, it could be confirmed that the driving voltage was high, and both (e.g., simultaneously) emission efficiency and device lifetime were degraded when compared to the Examples. In the embodiment of Comparative Compound C1, the HOMO energy level became shallow when compared to the Example Compounds including the first ligand, and the HOMO energy level difference with a host could be increased. Accordingly, trap phenomenon due to a dopant increased in an emission layer may be increased, the driving voltage may be increased, and the emission efficiency and device lifetime may be reduced.

Comparative Compound C4 included in Comparative Example 4 includes a central metal atom, and four ligands bonded to the central metal atom, and includes a pyridine moiety as the first ligand, but has a structure in which the first ligand and a ligand corresponding to the third ligand are not connected via a separate connecting group. Accordingly, it could be confirmed that the driving voltage was high, and the emission efficiency and device lifetime were reduced when compared to the Examples.

Comparative Compound C5 and Comparative Compound C6, included in Comparative Example 5 and Comparative Example 6 include a central metal atom, and four ligands bonded to the central metal atom, and include a pyridine moiety as the first ligand, but has a connection structure which is different from the connection structure of the first ligand suggested in the present disclosure, and accordingly, it could be confirmed that the driving voltage was high, and the emission efficiency and device lifetime were reduced when compared to the Examples. For example, it could be found that the effects of the Examples were better than Comparative Example 5 utilizing Comparative Compound C5 in which the first ligand is bonded to the central metal atom at a para position with respect to a nitrogen atom. In some embodiments, it could be found that the effects of the Examples were better than Comparative Example 6 utilizing Comparative Compound C6 in which the first ligand is bonded to the central metal atom at a meta position based on a nitrogen atom but has a connection structure not with the second ligand but with the third ligand at a para position based on a nitrogen atom.

The light emitting device of an embodiment may show improved device properties of a high efficiency and a long lifetime.

The organometallic compound of an embodiment is included in a hole transport region of a light emitting device and may contribute to the increase of the efficiency and lifetime of the light emitting device.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The light emitting device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A light emitting device, comprising:
a first electrode;
a second electrode oppositely disposed to the first electrode; and
an emission layer between the first electrode and the second electrode,
wherein the emission layer comprises an organometallic compound represented by Formula 1: 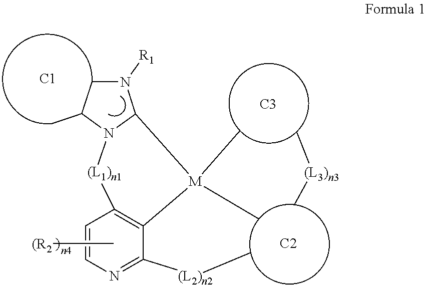
wherein in Formula 1,
M is Pt, Pd, Cu, Ag, Au, Rh, Ir, Ru or Os,
rings C1 to C3 are each independently a substituted or unsubstituted hydrocarbon ring of 5 to 60 ring-forming carbon atoms, or a substituted or unsubstituted heterocycle of 2 to 60 ring-forming carbon atoms,
L₁ to L₃ are each independently a direct linkage, *—O—*′, *—S—*′, *—C(R₁₁)(R₁₂)—*′, *—*C(R₁₃)═*′, *═C(R₁₄)—*′, *—C(R₁₅)═C(R₁₆)—*′, *—C(═O)—*′, *—C(═S)—*′, *—C≡C—*′, *—B(R₁₇)—*′, *—N(R₁₈)—*′, *—P(R₁₉)—*′, *—Si(R₂₀)(R₂₁)*′, *—P(R₂₂)(R₂₃)—*′ or *—Ge(R₂₄)(R₂₅)*′,
R₁ is a hydrogen atom, a deuterium atom, a halogen atom, a substituted or unsubstituted thio group, a substituted or unsubstituted oxy group, a substituted or unsubstituted boron group, a substituted or unsubstituted amine group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₂, and R₁₁ to R₂₅ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
n1 to n3 are each independently an integer from 1 to 3, and
n4 is an integer from 0 to 2.

2. The light emitting device of claim 1, wherein the emission layer is configured to emit phosphorescence.

3. The light emitting device of claim 1, wherein the emission layer comprises a host and a dopant, and
the dopant comprises the organometallic compound represented by Formula 1.

4. The light emitting device of claim 1, wherein the organometallic compound represented by Formula 1 is represented by Formula 2: 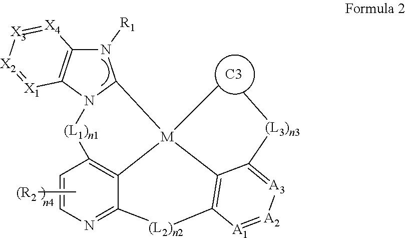
wherein in Formula 2,
X₁ to X₄, and A₁ to A₃ are each independently N or CR₃,
R₃ is a hydrogen atom, a deuterium atom, a halogen atom, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
M, C3, L₁ to L₃, R₁, R₂, and n1 to n4 are the same as defined in Formula 1.

5. The light emitting device of claim 4, wherein the organometallic compound represented by Formula 2 is represented by Formula 3: 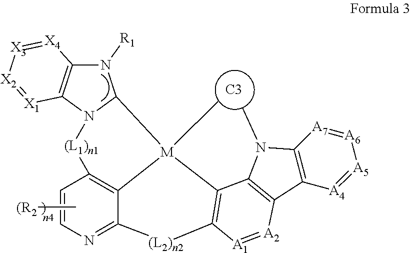
wherein in Formula 3,
A₄ to A₇ are each independently N or CR₄,
R₄ is a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
M, C3, L₁, L₂, X₁ to X₄, R₁, R₂, n1, n2, n4, A₁, and A₂ are the same as defined in Formula 1 and Formula 2.

6. The light emitting device of claim 4, wherein the organometallic compound represented by Formula 2 is represented by Formula 4: 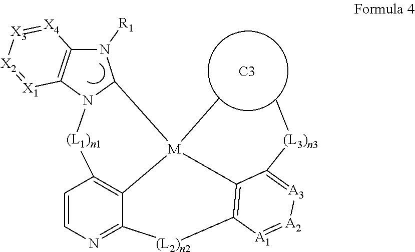
wherein in Formula 4,
M, C3, L₁ to L₃, R₁, X₁ to X₄, n1 to n3, and A₁ to A₃ are the same as defined in Formula 1 and Formula 2.

7. The light emitting device of claim 4, wherein the organometallic compound represented by Formula 2 is represented by any one selected from among Formula 5-1 to Formula 5-3: 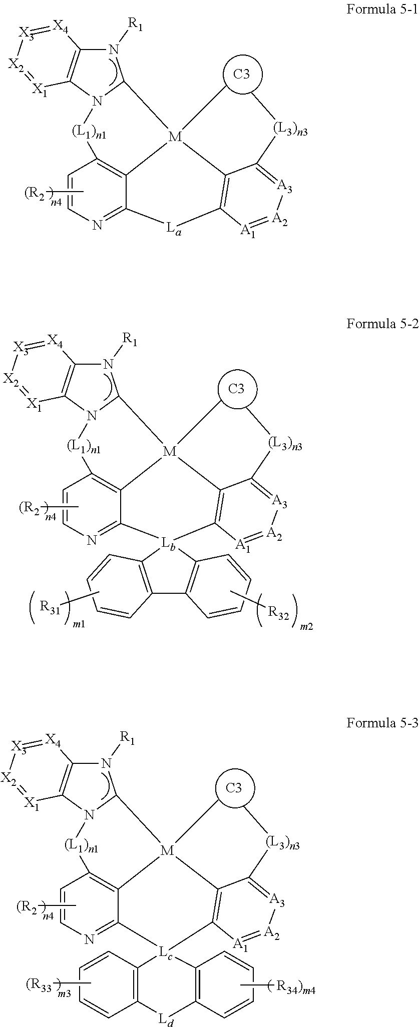
wherein in Formula 5-1 to Formula 5-3,
Lₐ is *—O—*′, *—S—*′, *—C(R₃₅)(R₃₆)*′, *—N(R₃₇)—*′, or *—Si(R₃₈)(R₃₉)—*′,
L_{b}, and L_{c} are each independently C or Si,
L_{d} is *—O—*′, or *—S—*′,
R₃₁ to R₃₉ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m1 to m4 are each independently an integer from 0 to 4, and
M, C3, L₁, L₃, X₁ to X₄, R₁, R₂, n1, n3, n4, and A₁ to A₃ are the same as defined in Formula 1 and Formula 2.

8. The light emitting device of claim 4, wherein the organometallic compound represented by Formula 2 is represented by Formula 6-1 or Formula 6-2: 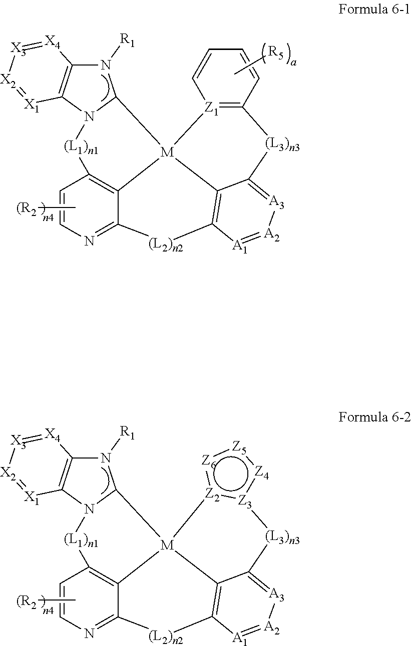
wherein in Formula 6-1 and Formula 6-2,
Z₁ to Z₃ are each independently N or C,
Z₄ to Z₆ are each independently N, NR₆, CR₇, O, or S,
R₅ is a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₆ and R₇ are each independently a hydrogen atom, a deuterium atom, a halogen atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
“a” is an integer from 0 to 4, and
M, L₁ to L₃, X₁ to X₄, R₁, R₂, n1 to n4, and A₁ to A₃ are the same as defined in Formula 1 and Formula 2.

9. The light emitting device of claim 8, wherein the organometallic compound represented by Formula 6-1 is represented by any one selected from among Formula 7-1 to Formula 7-6: 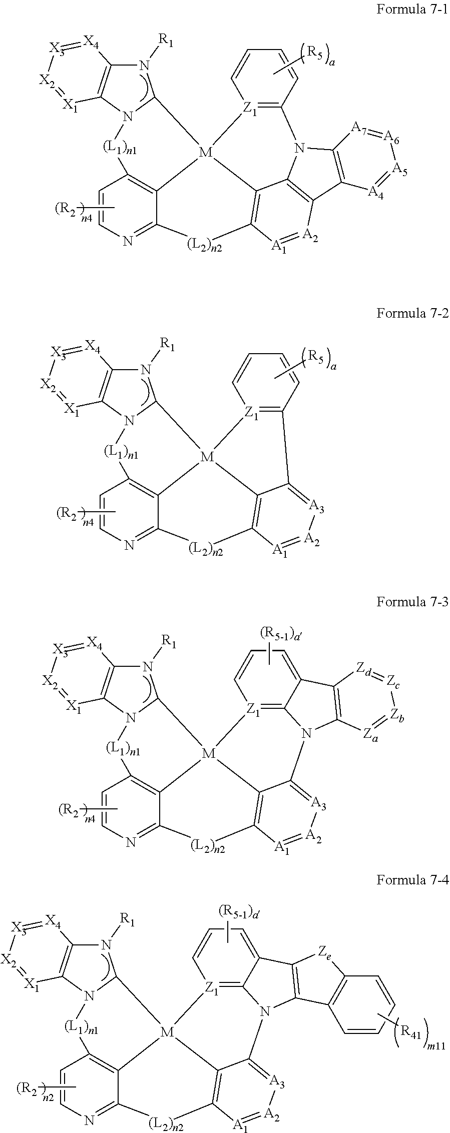 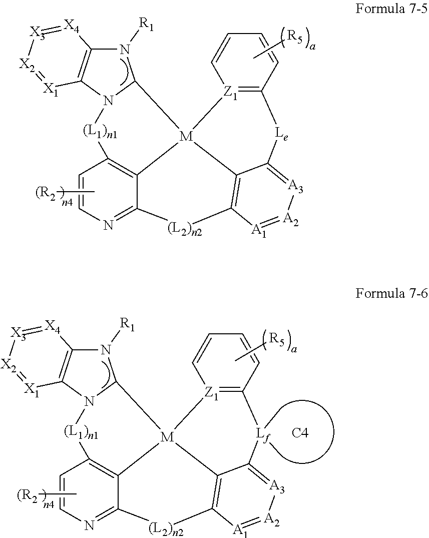
wherein in Formula 7-1 to Formula 7-6,
A₄ to A₇, and Zₐ to Z_{d} are each independently N or CR₄₂,
Zₑ is NR₄₃ or O,
Lₑ is *—O—*′, *—S—*′, or *—N(R₄₄)—*′,
L_{f} is C or Si,
R₅-1, and R₄₁ to R₄₄ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
ring C4 is a substituted or unsubstituted hydrocarbon ring of 5 to 60 ring-forming carbon atoms, or a substituted or unsubstituted heterocycle of 2 to 60 ring-forming carbon atoms,
a′ is an integer from 0 to 3,
m11 is an integer from 0 to 4, and
M, L₁, L₂, X₁ to X₄, Z₁, R₁, R₂, n1, n2, n4, “a”, R₅, and A₁ to A₃ are the same as defined in Formula 1, Formula 2 and Formula 6-1.

10. The light emitting device of claim 8, wherein the organometallic compound represented by Formula 6-2 is represented by any one selected from among Formula 8-1 to Formula 8-6: 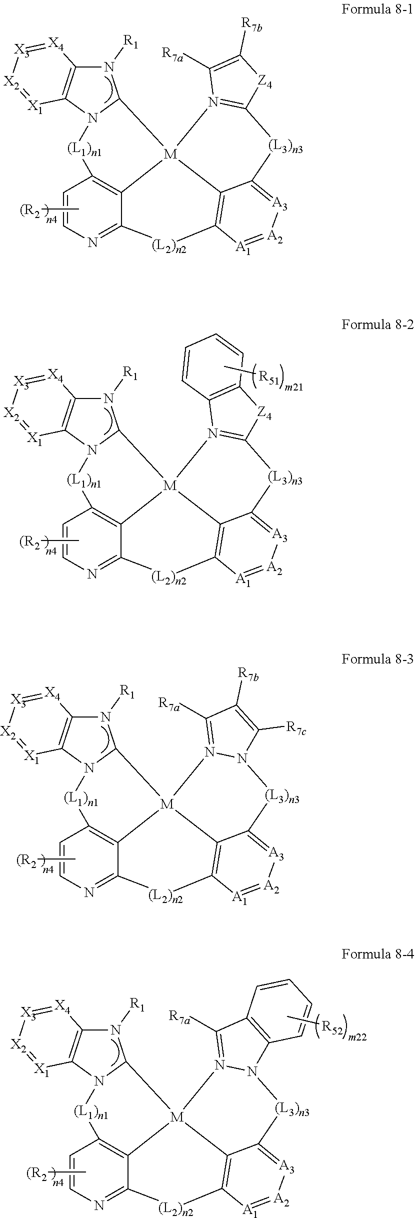 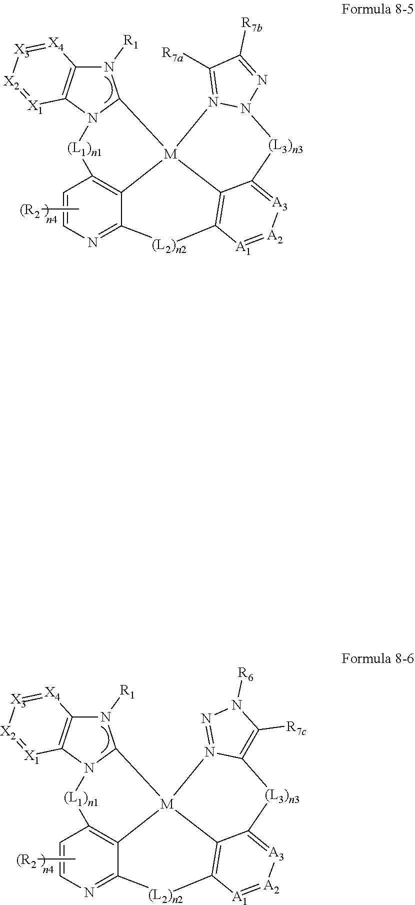
wherein in Formula 8-1 to Formula 8-6,
R₇ₐ to R_{7c}, R₅₁, and R₅₂ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m21 and m22 are each independently an integer from 0 to 4, and
M, L₁ to L₃, X₁ to X₄, R₁, R₂, n1 to n4, Z₄, A₁ to A₃, and R₆ are the same as defined in Formula 1, Formula 2 and Formula 6-2.

11. The light emitting device of claim 1, wherein the organometallic compound represented by Formula 1 comprises at least one selected from among compounds represented in Compound Group 1:

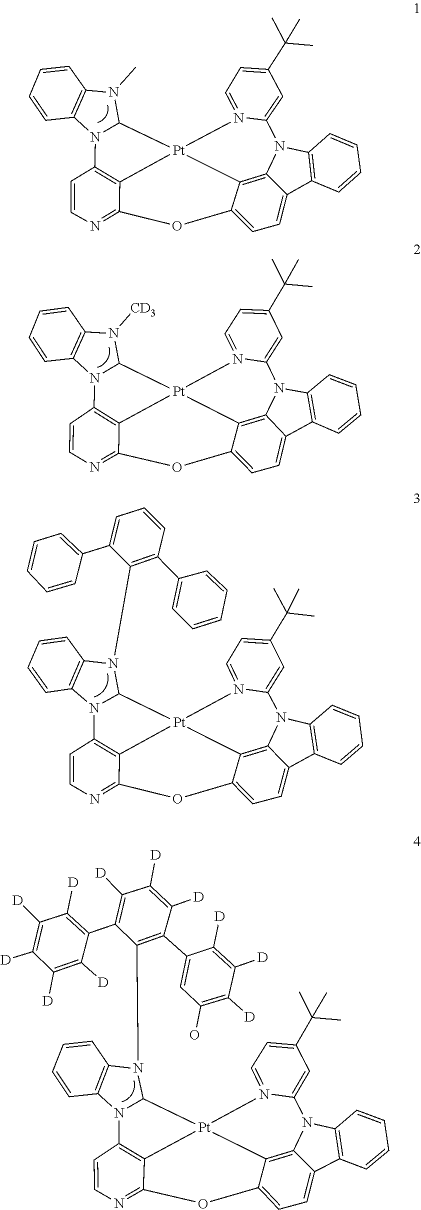

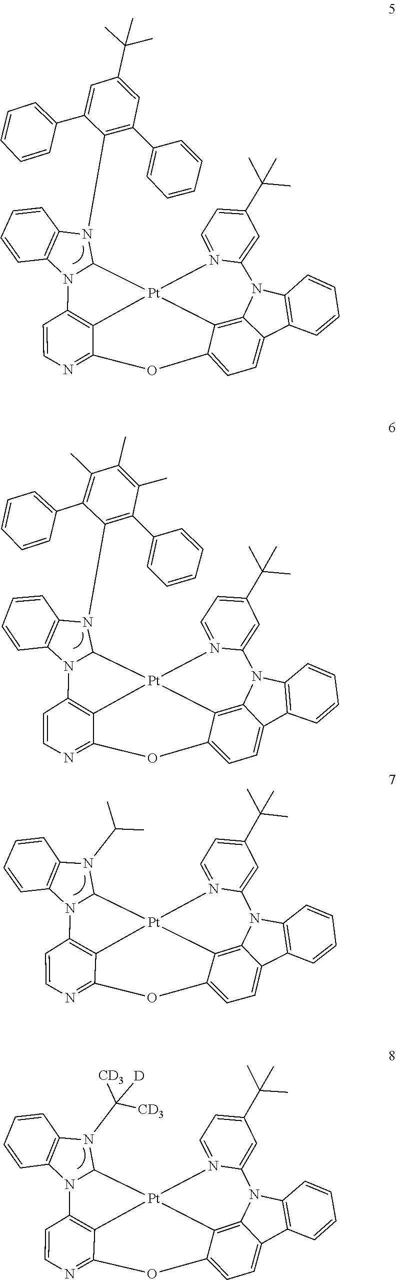

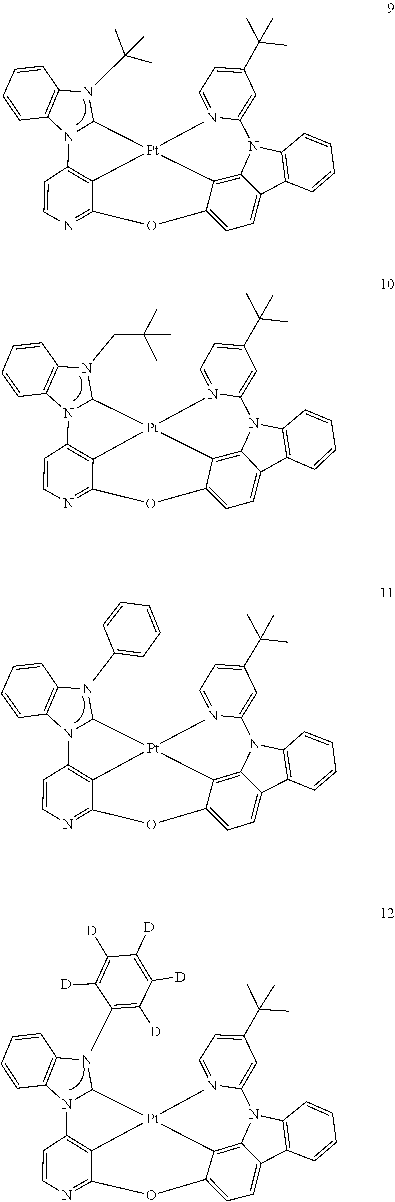

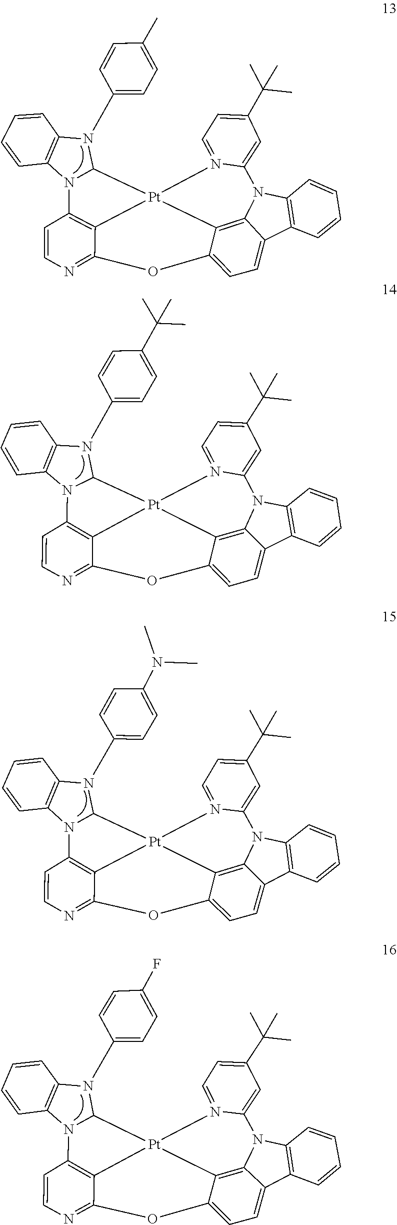

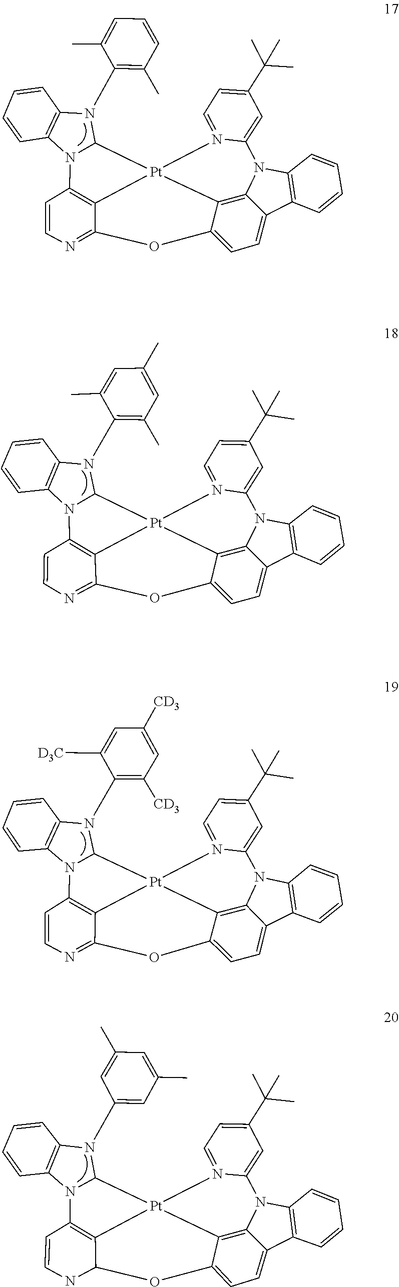

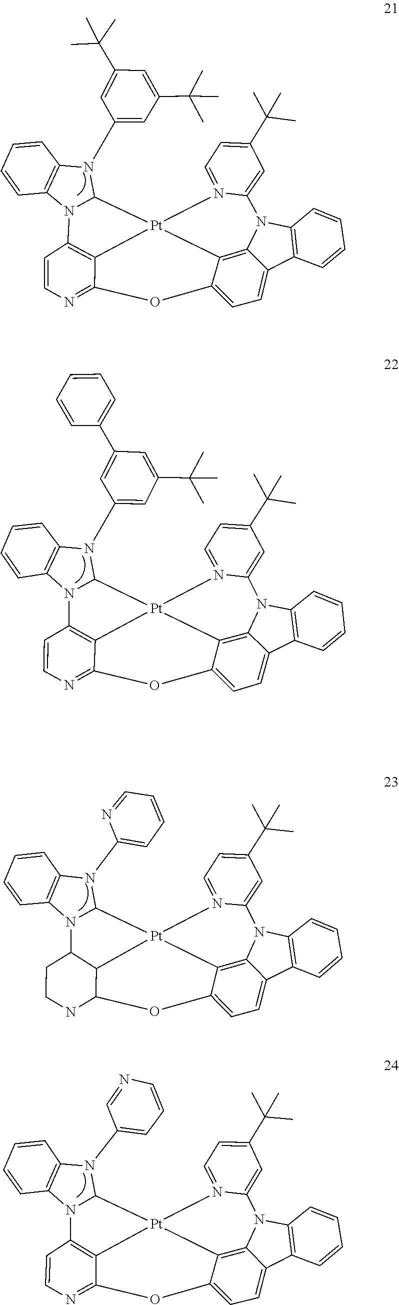

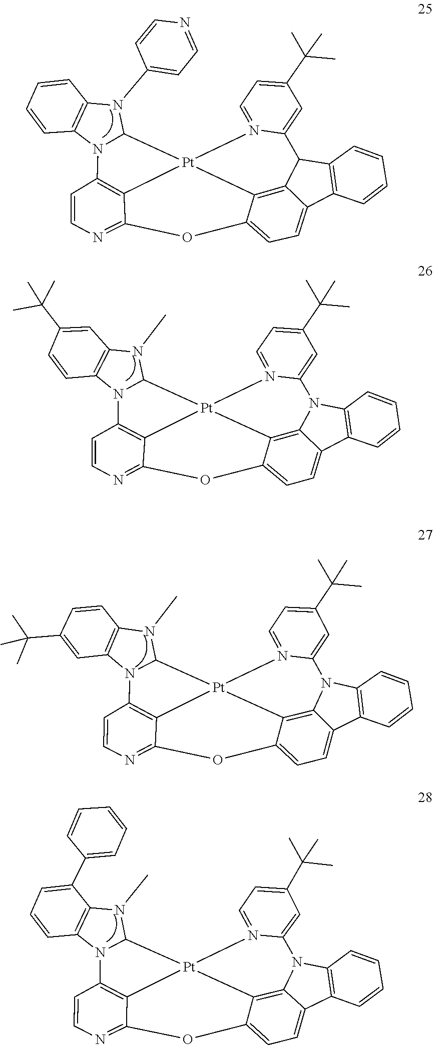

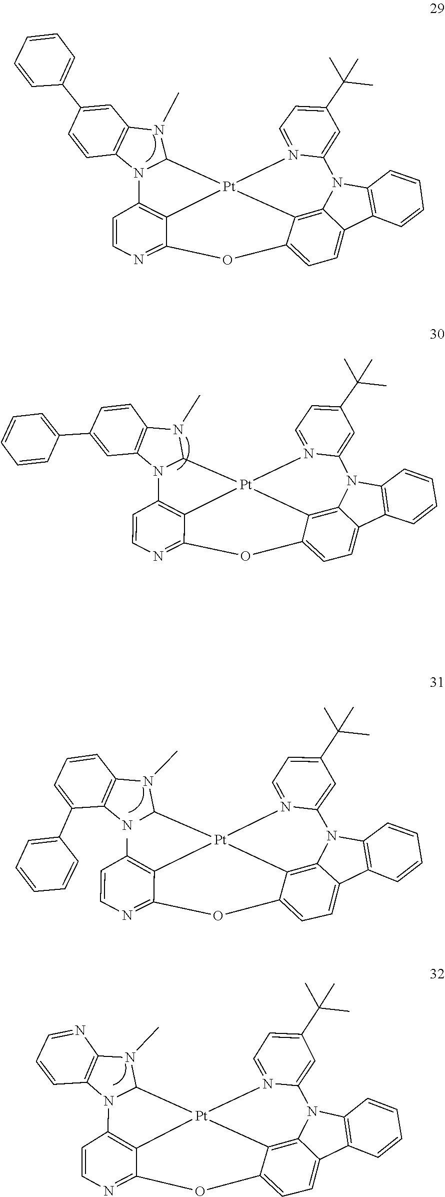

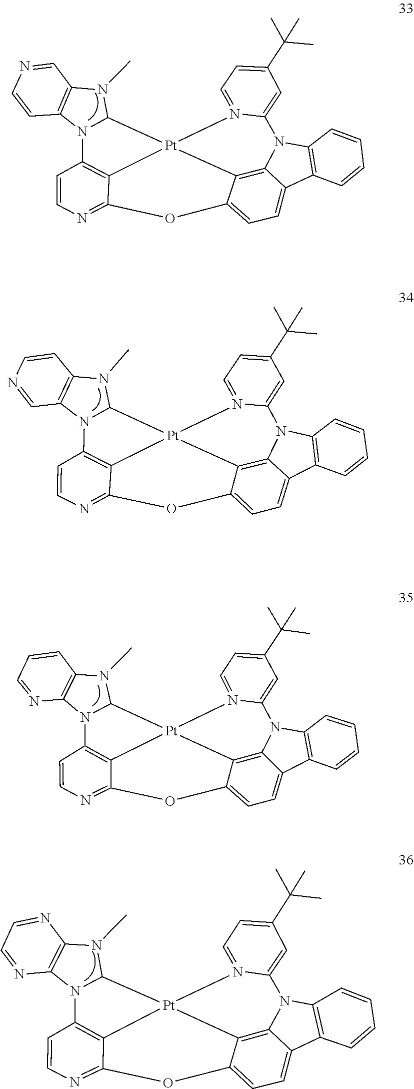

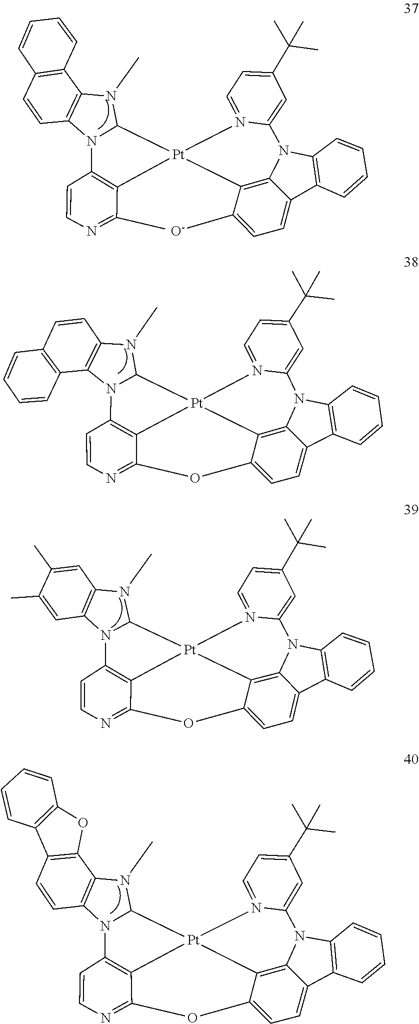

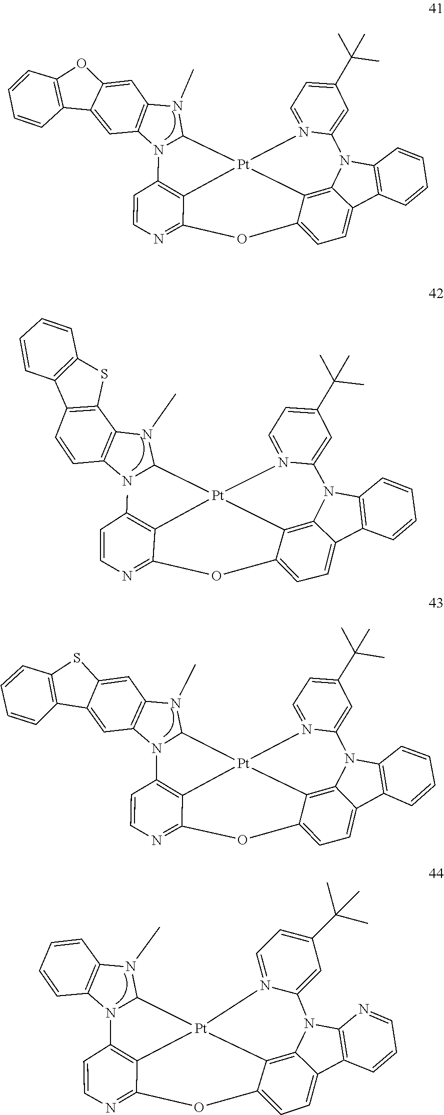

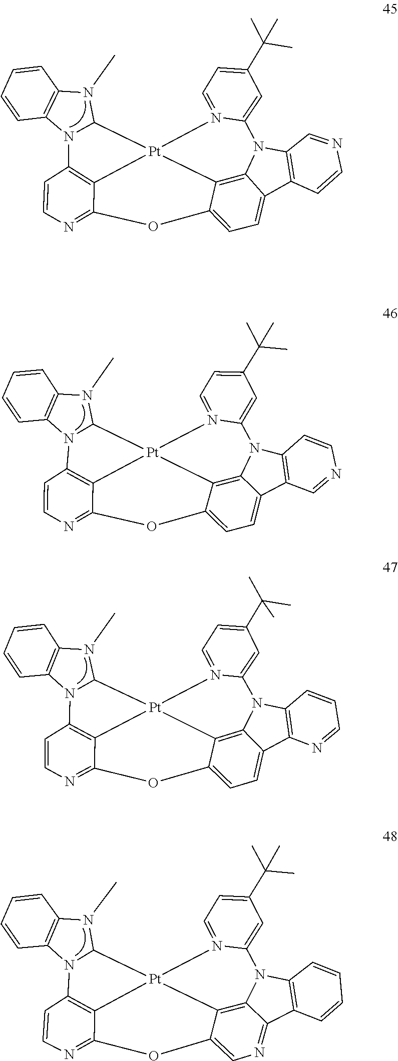

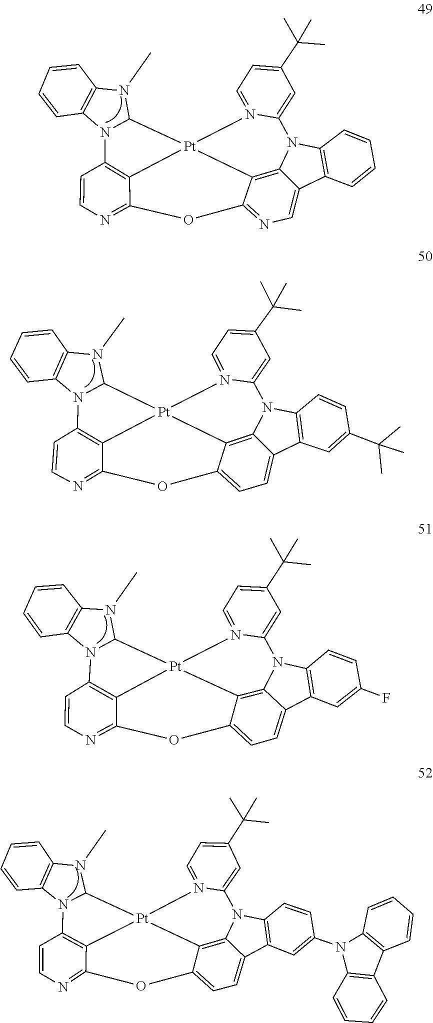

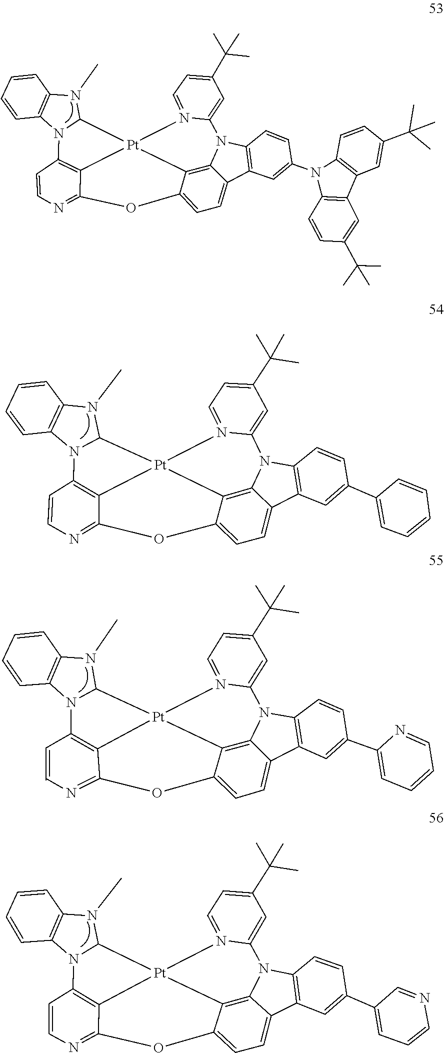

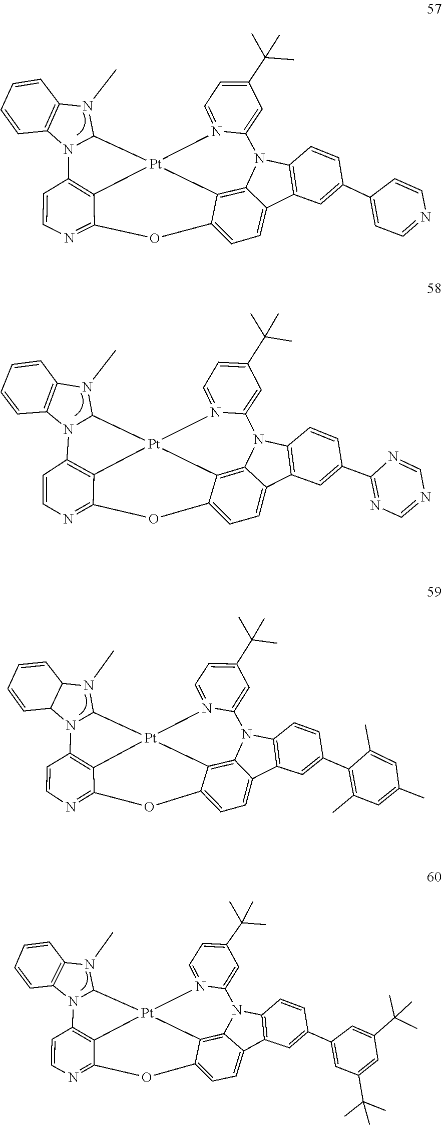

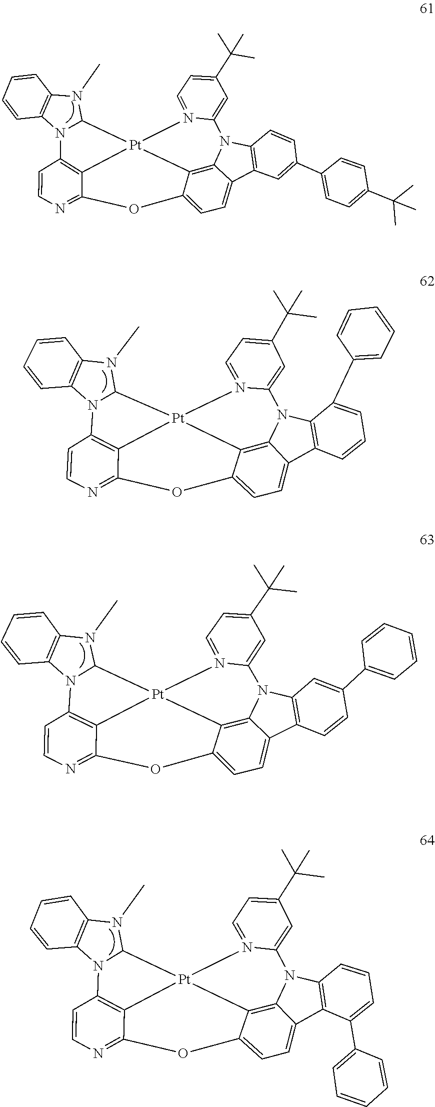

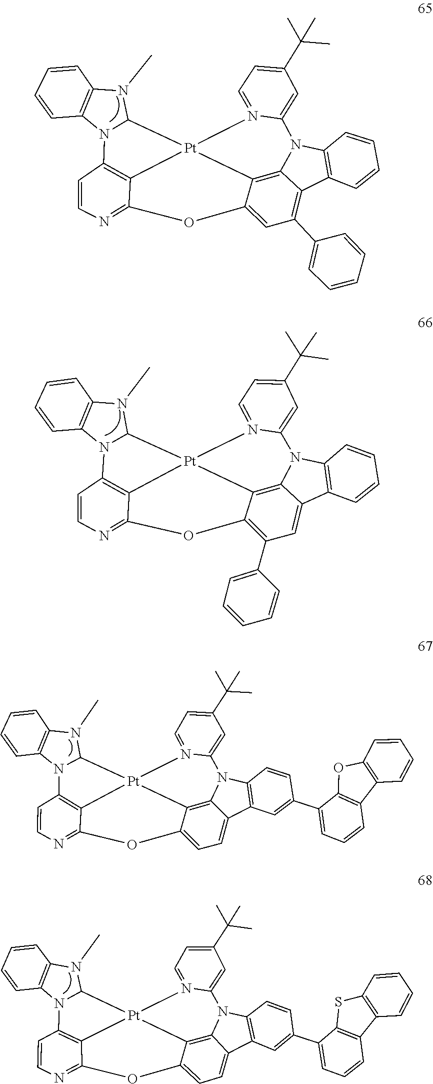

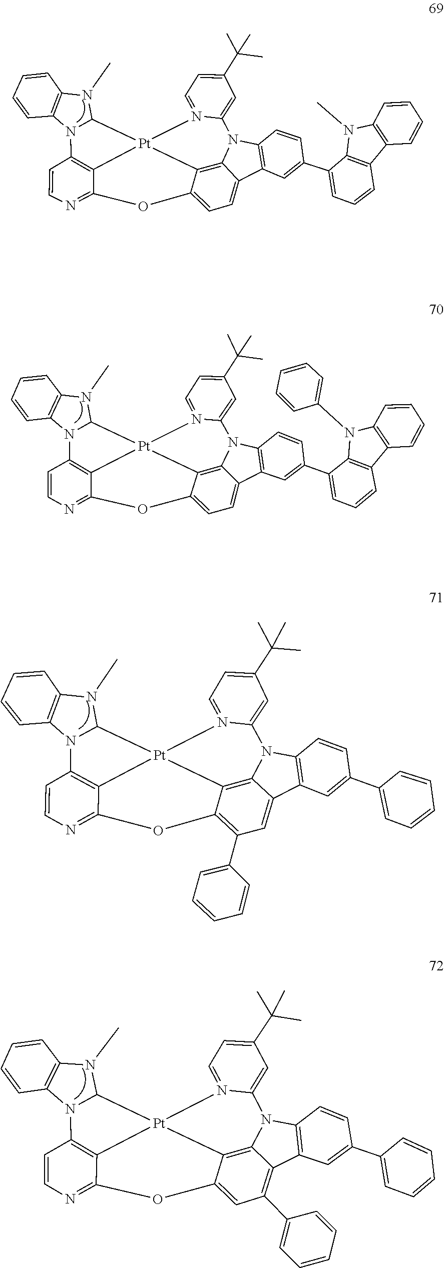

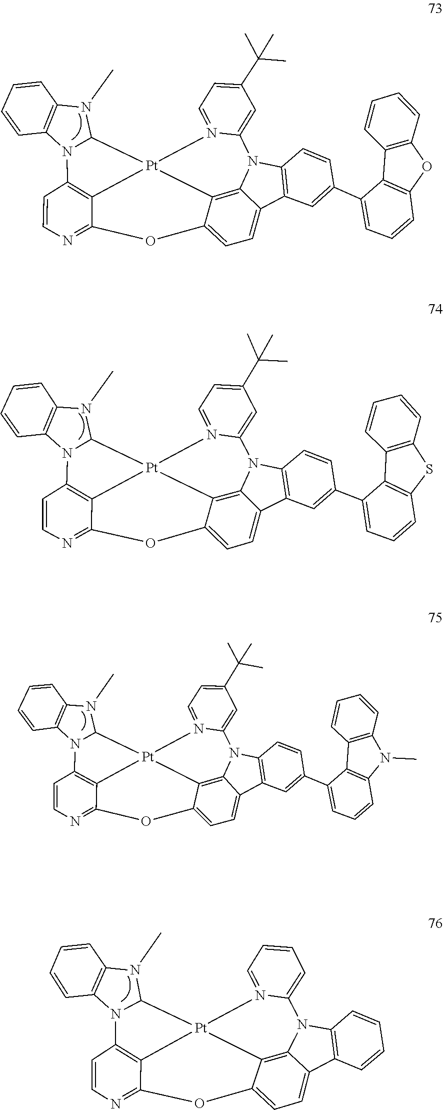

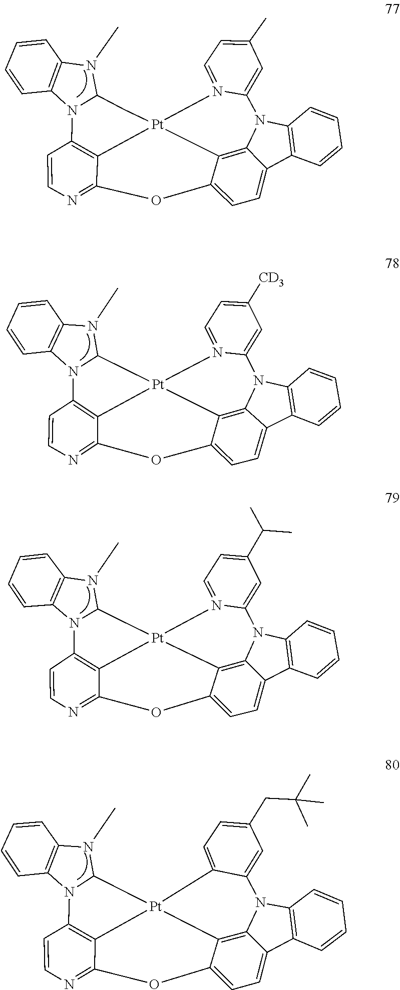

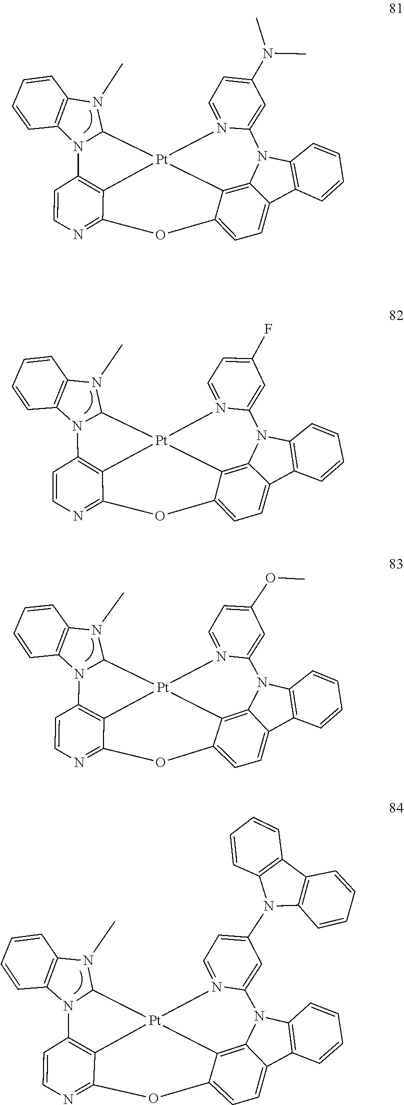

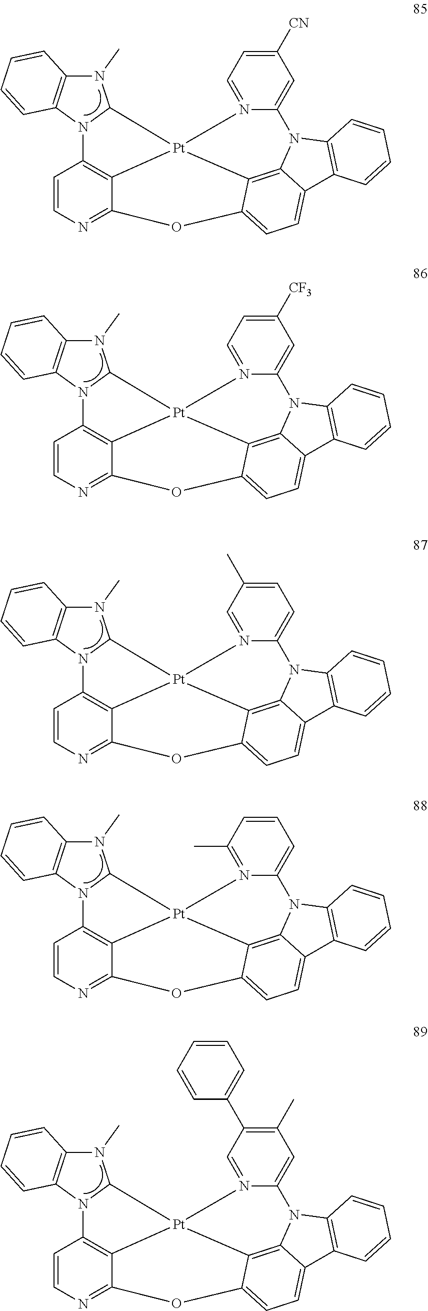

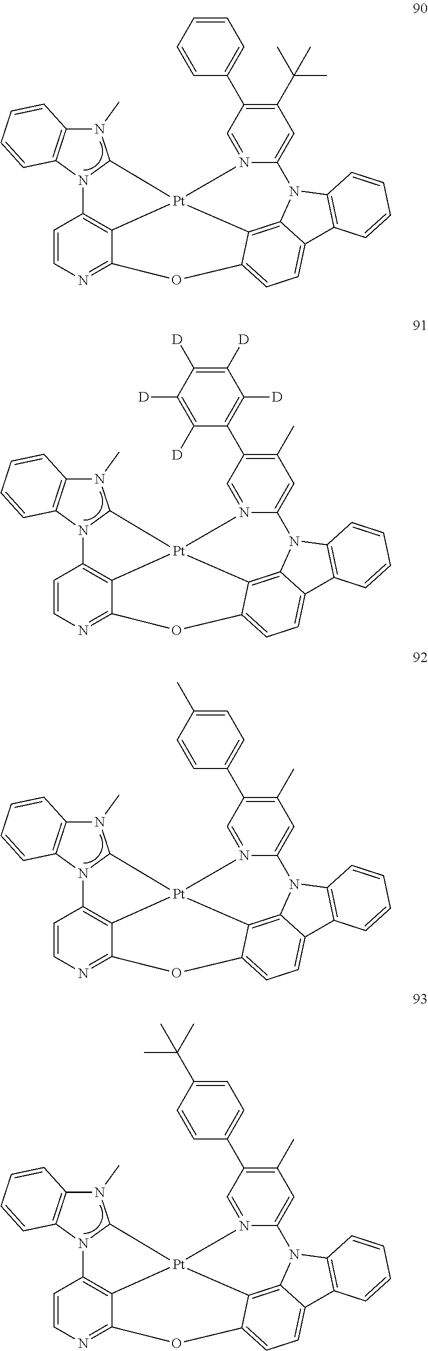

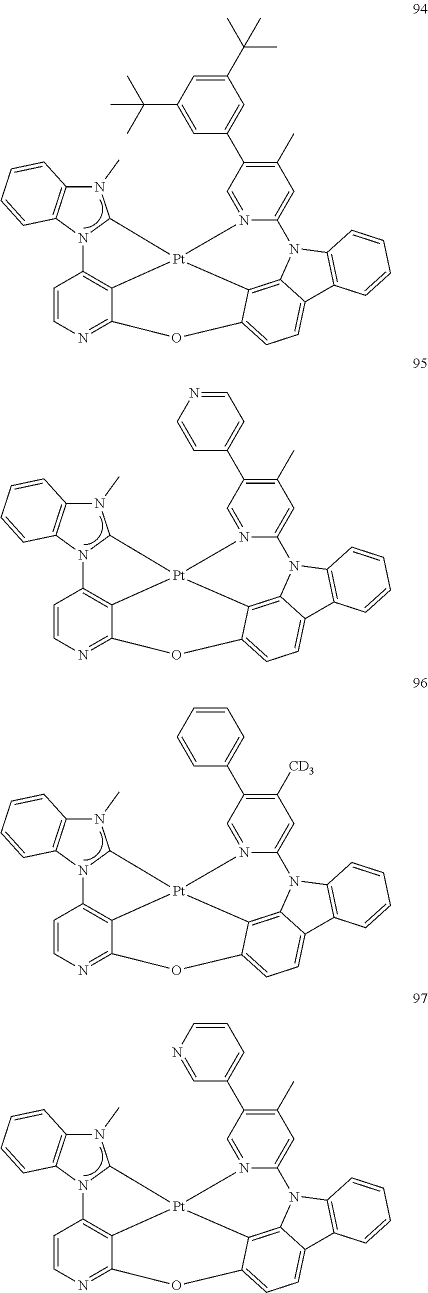

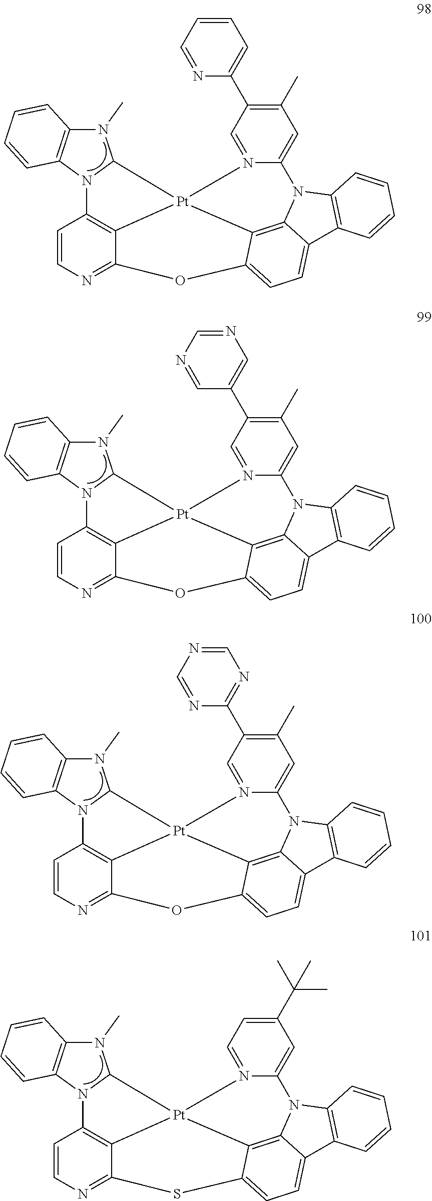

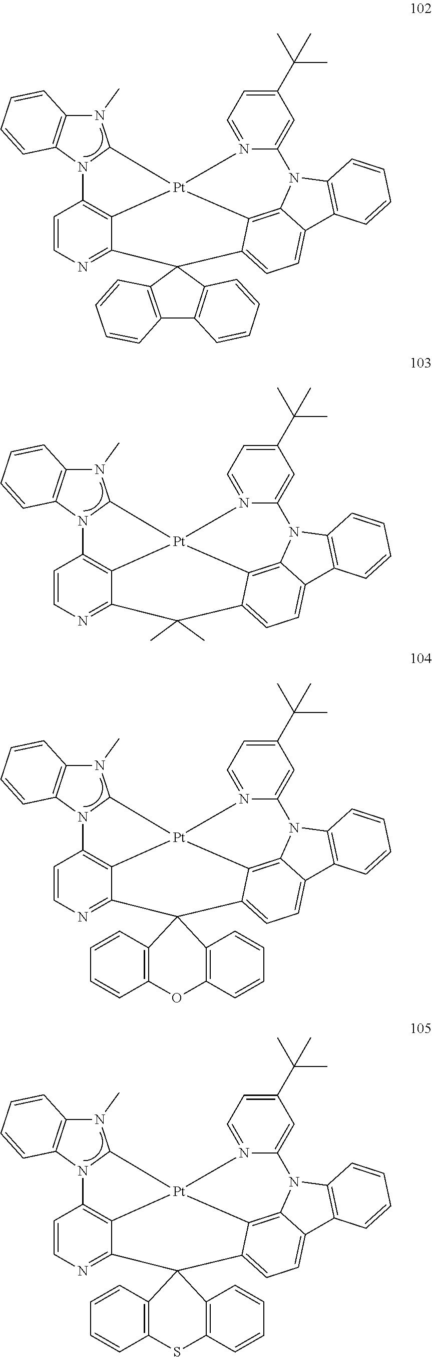

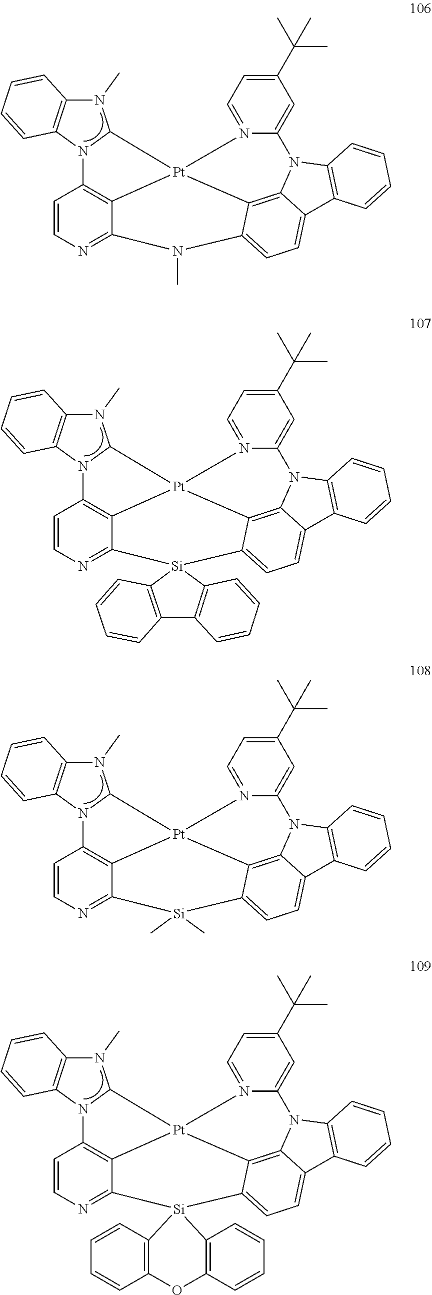

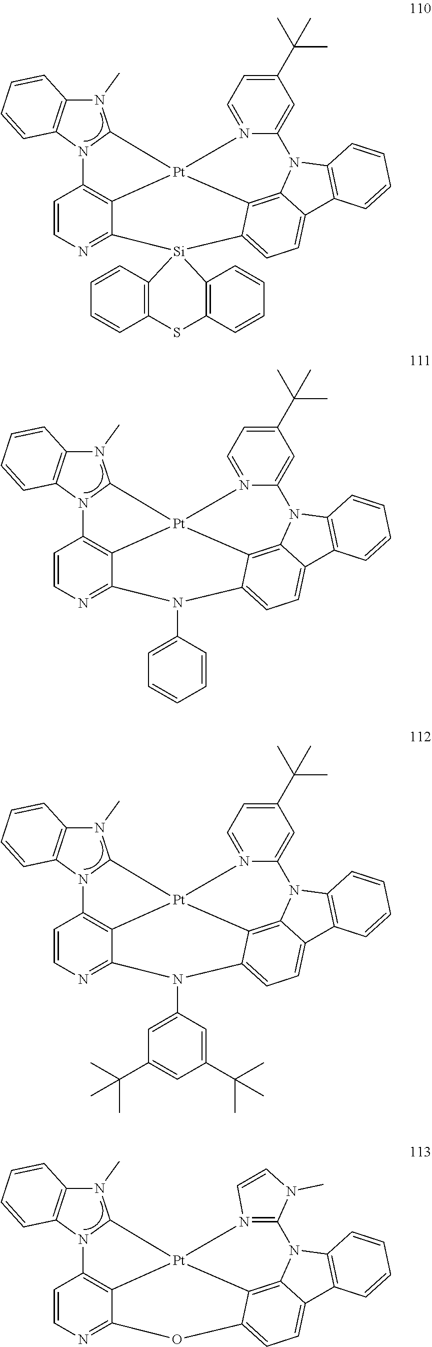

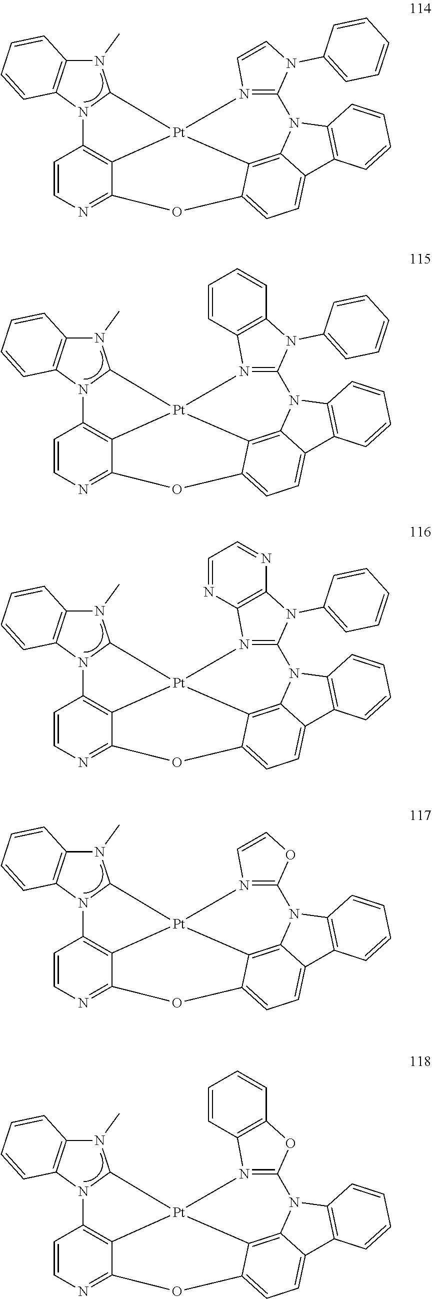

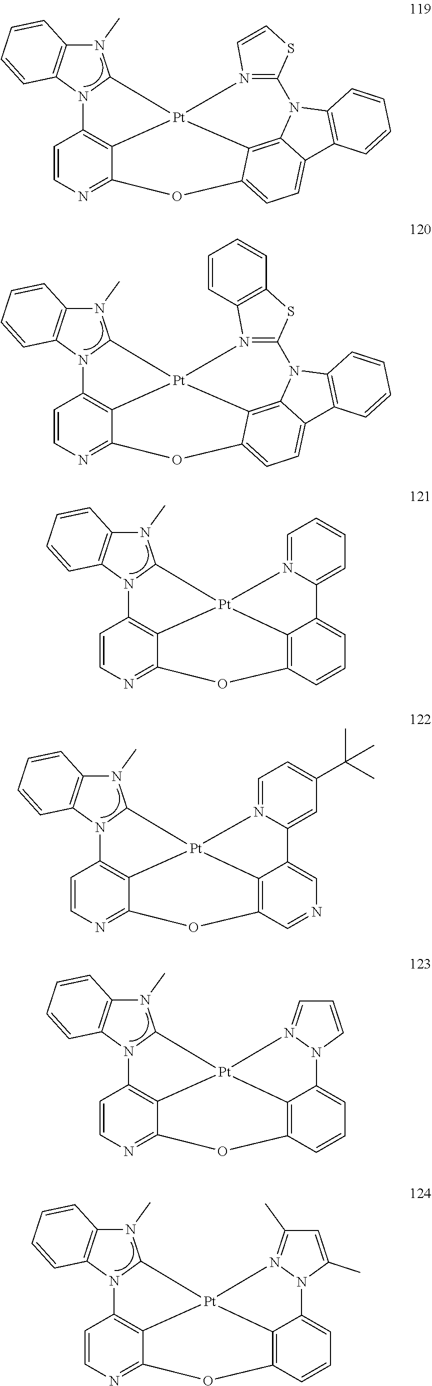

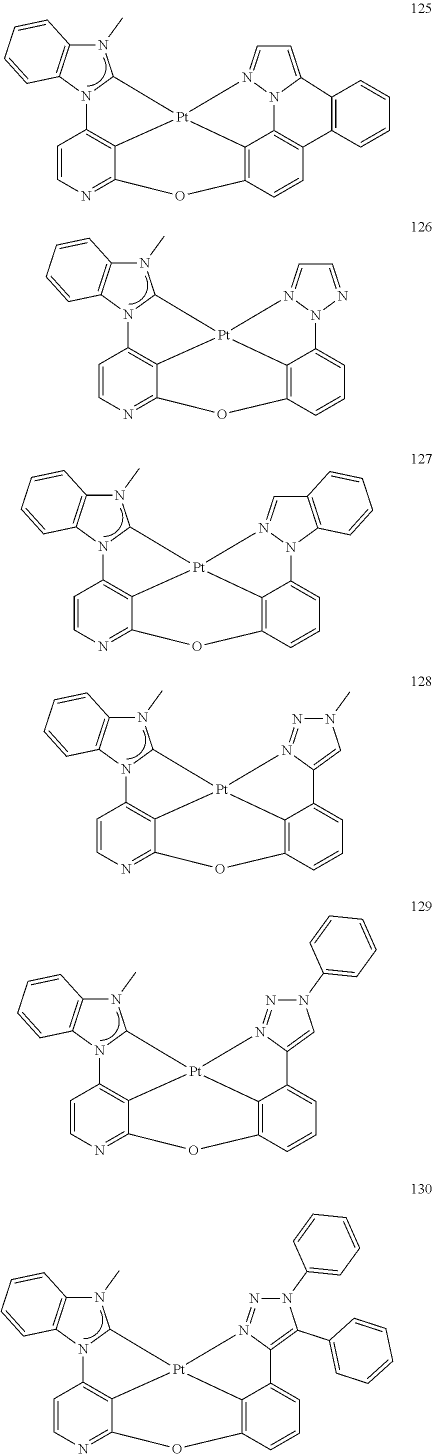

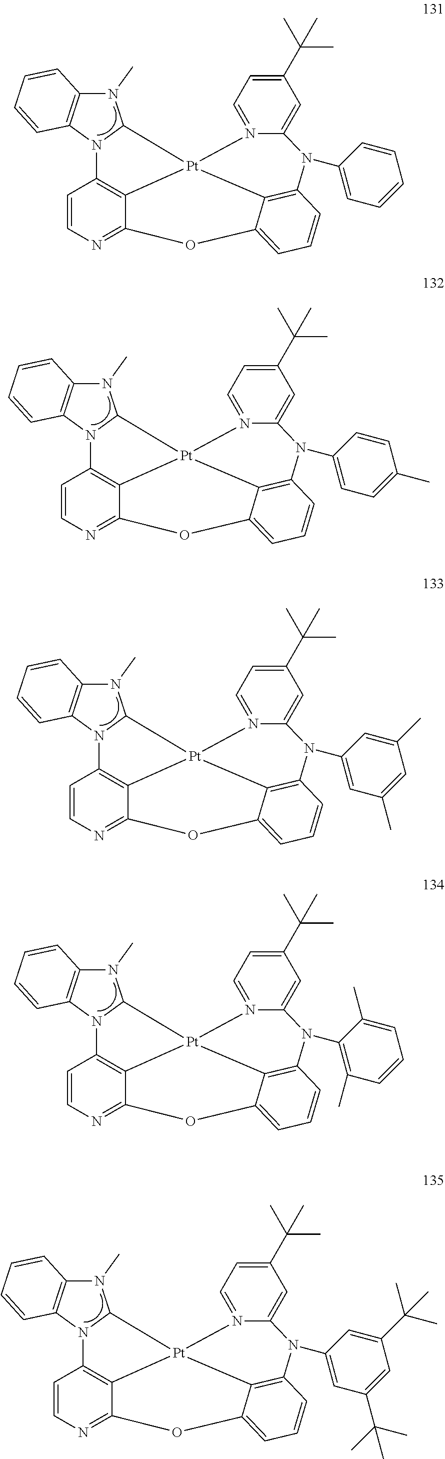

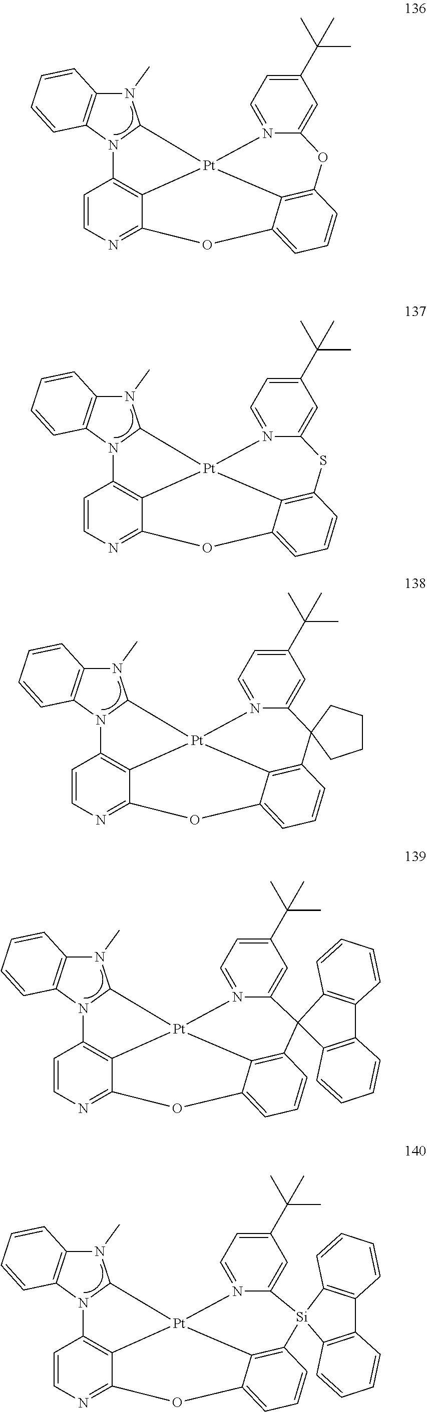

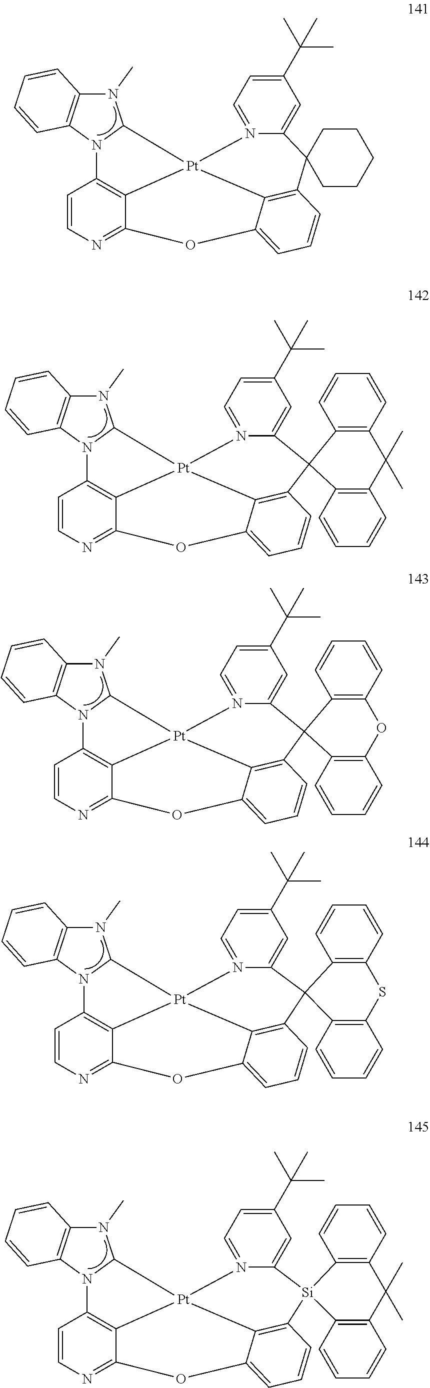

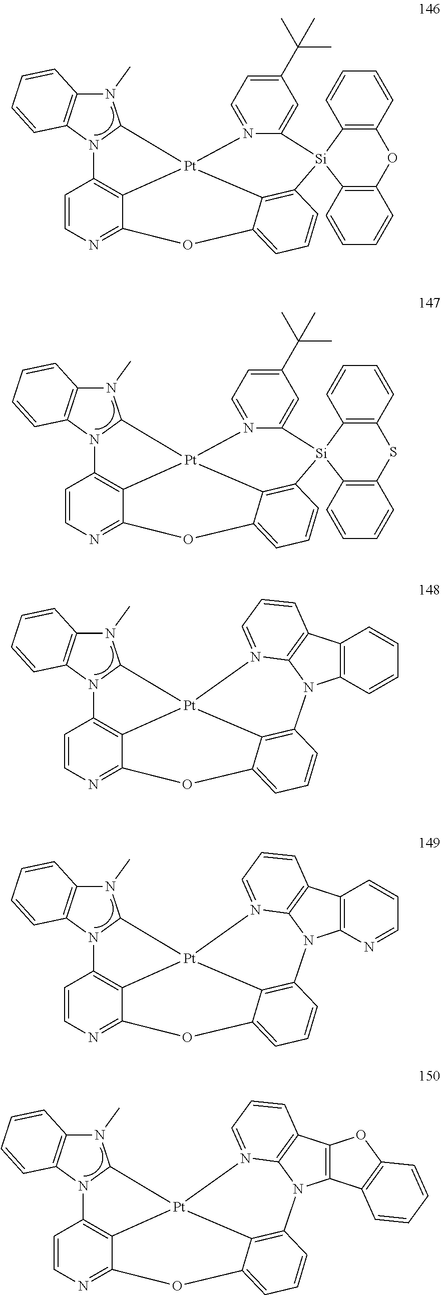

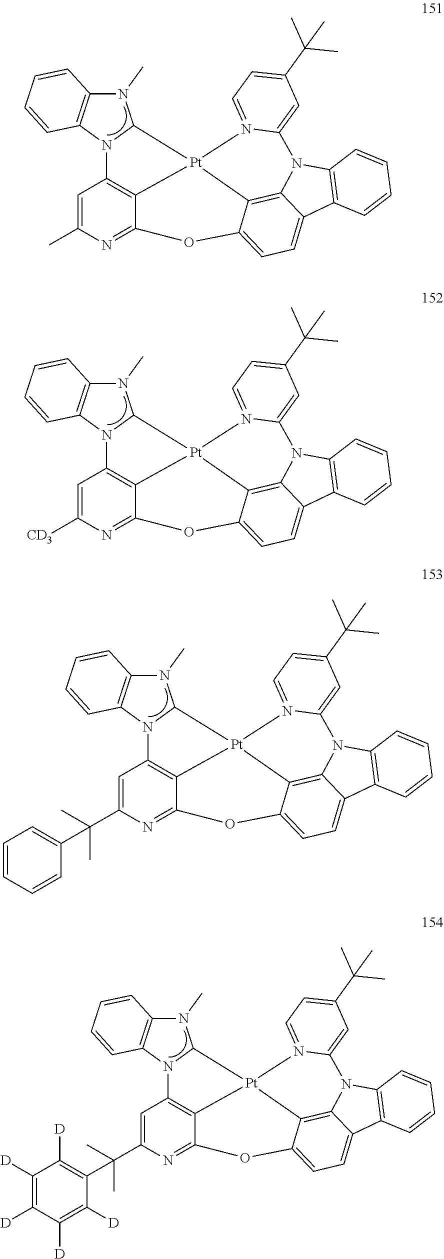

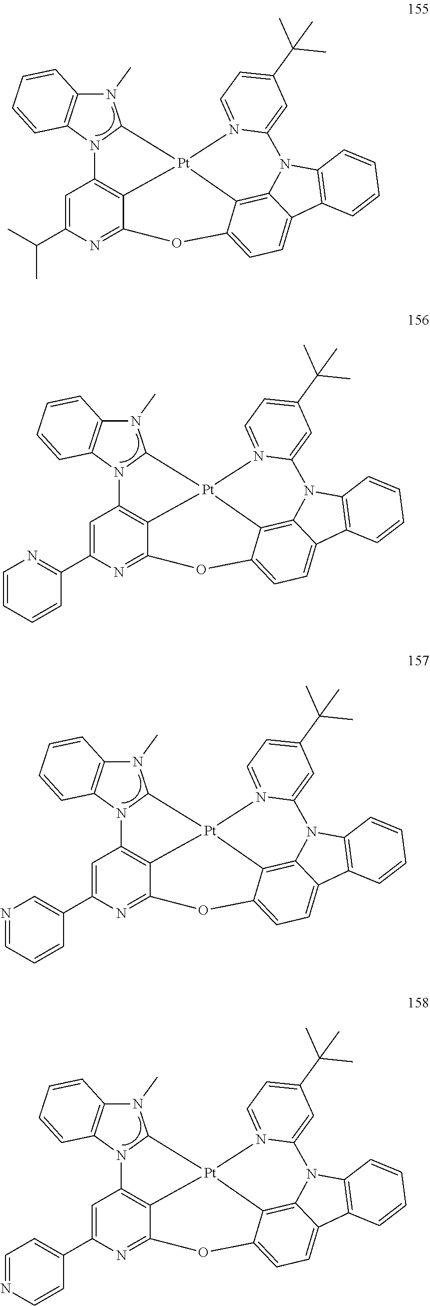

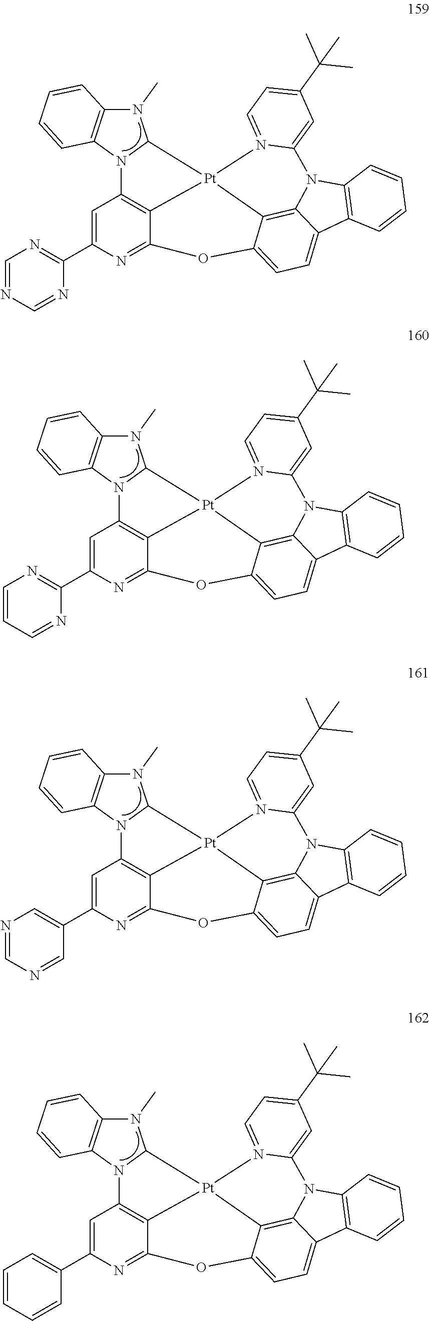

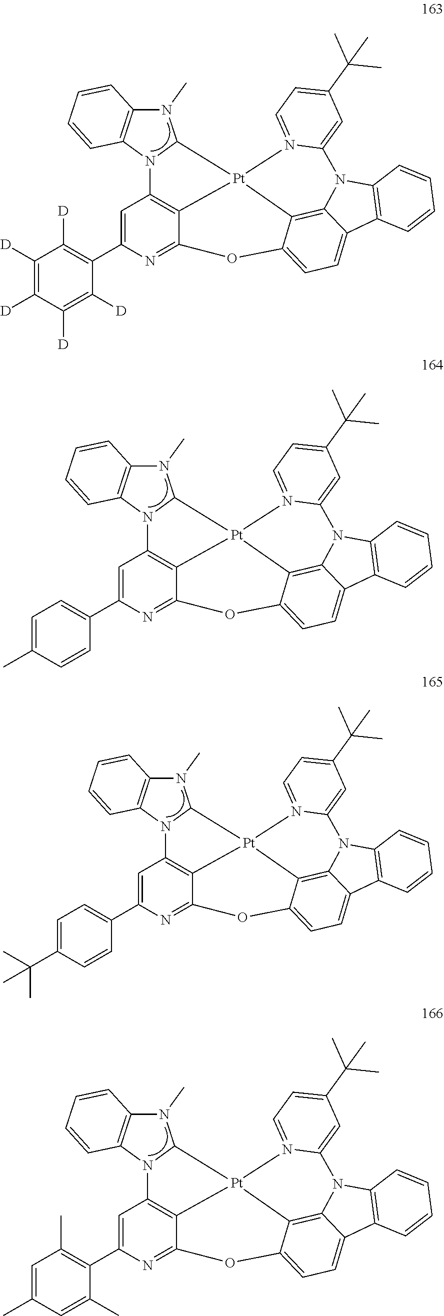

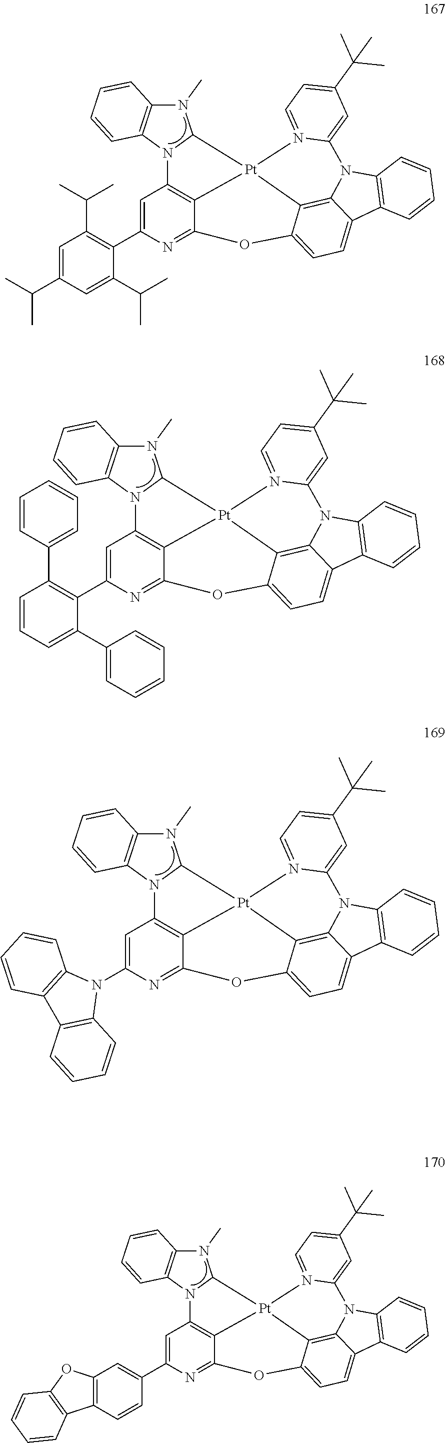

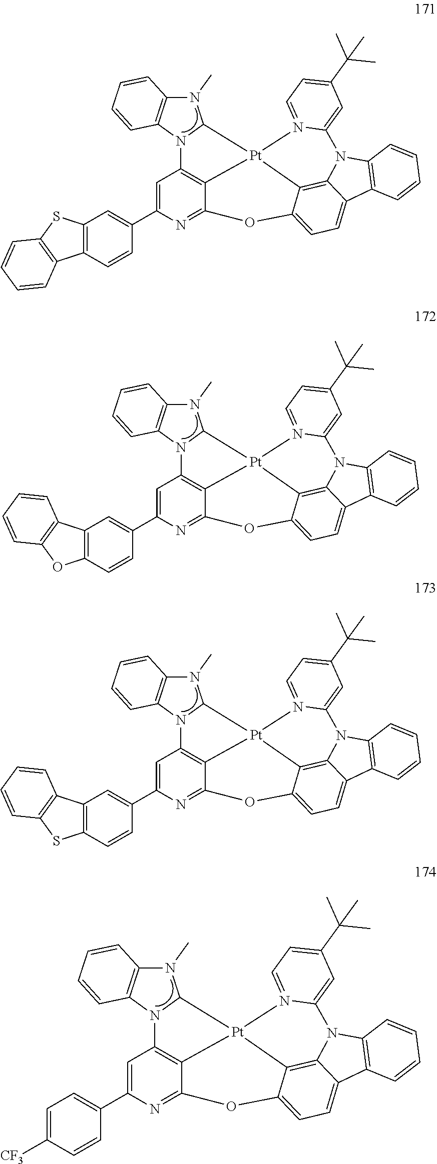

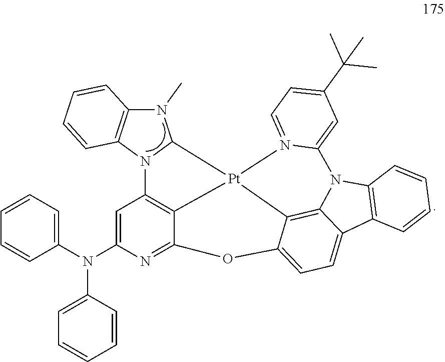

12. The light emitting device of claim 3, wherein
the host comprises a first host and a second host,
the first host is represented by Formula HT-1, and
the second host is represented by Formula ET-1 or Formula ET-2: 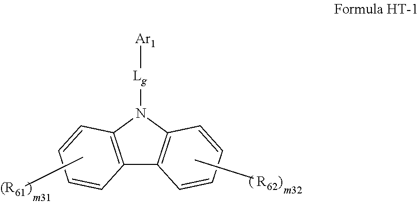
wherein in Formula HT-1,
L_{g} is a direct linkage, a substituted or unsubstituted arylene group of 6 to 30 ring-forming carbon atoms, or a substituted or unsubstituted heteroarylene group of 2 to 30 ring-forming carbon atoms,
Ar₁ is a substituted or unsubstituted aryl group of 6 to 30 ring-forming carbon atoms, or a substituted or unsubstituted heteroaryl group of 2 to 30 ring-forming carbon atoms,
R₆₁ and R₆₂ are each independently a hydrogen atom, a deuterium atom, a halogen atom, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
m31 and m32 are each independently an integer from 0 to 4, 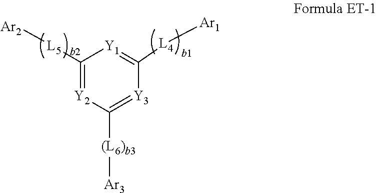
wherein in Formula ET-1,
Y₁ to Y₃ are each independently N or CRₐ,
Rₐ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
b1 to b3 are each independently an integer from 0 to 10,
L₄ to L₆ are each independently a direct linkage, a substituted or unsubstituted arylene group of 6 to 30 ring-forming carbon atoms, or a substituted or unsubstituted heteroarylene group of 2 to 30 ring-forming carbon atoms, and
Ar₁ to Ar₃ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, 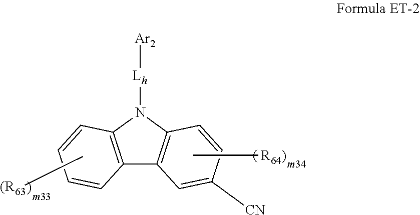
wherein in Formula ET-2,
Lₕ is a direct linkage, a substituted or unsubstituted arylene group of 6 to 30 ring-forming carbon atoms, or a substituted or unsubstituted heteroarylene group of 2 to 30 ring-forming carbon atoms,
Ar₂ is a substituted or unsubstituted aryl group of 6 to 30 ring-forming carbon atoms, or a substituted or unsubstituted heteroaryl group of 2 to 30 ring-forming carbon atoms,
R₆₃ and R₆₄ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m33 is an integer from 0 to 4, and
m34 is an integer from 0 to 3.

13. The light emitting device of claim 12, wherein the host comprises at least one selected from among compounds in Compound Group 2 and Compound Group 3:

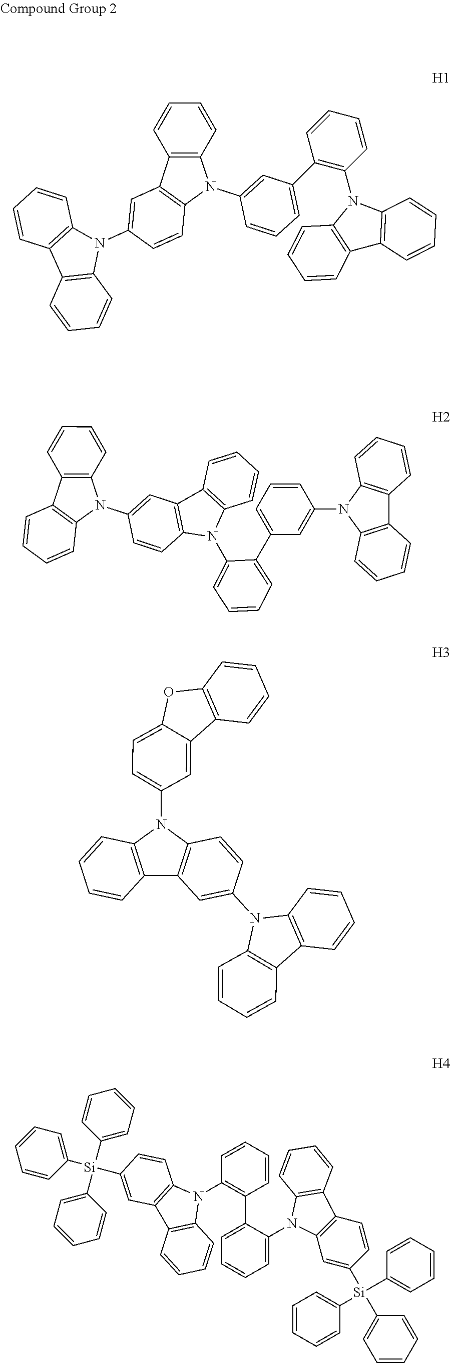 [SMILES: c1cc(-c2ccccc2-n2c3ccccc3c3ccccc32)cc(-n2c3ccccc3c3cc(-n4c5ccccc5c5ccccc54)ccc32)c1 ; c1cc(-c2ccccc2-n2c3ccccc3c3cc(-n4c5ccccc5c5ccccc54)ccc32)cc(-n2c3ccccc3c3ccccc32)c1 ; c1ccc2c(c1)oc1ccc(-n3c4ccccc4c4cc(-n5c6ccccc6c6ccccc65)ccc43)cc12 ; c1ccc([Si](c2ccccc2)(c2ccccc2)c2ccc3c(c2)c2ccccc2n3-c2ccccc2-c2ccccc2-n2c3ccccc3c3ccc([Si](c4ccccc4)(c4ccccc4)c4ccccc4)cc32)cc1]

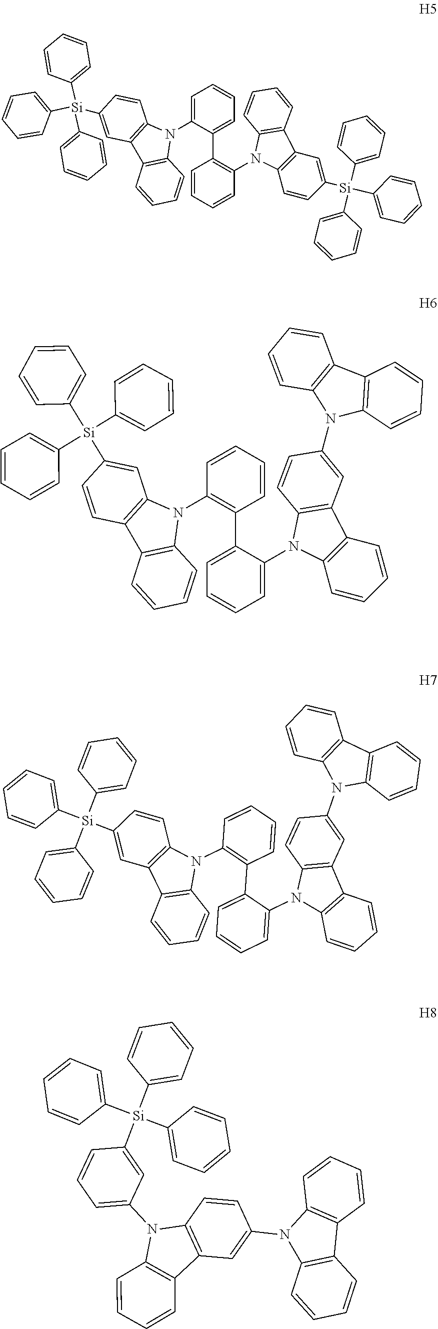

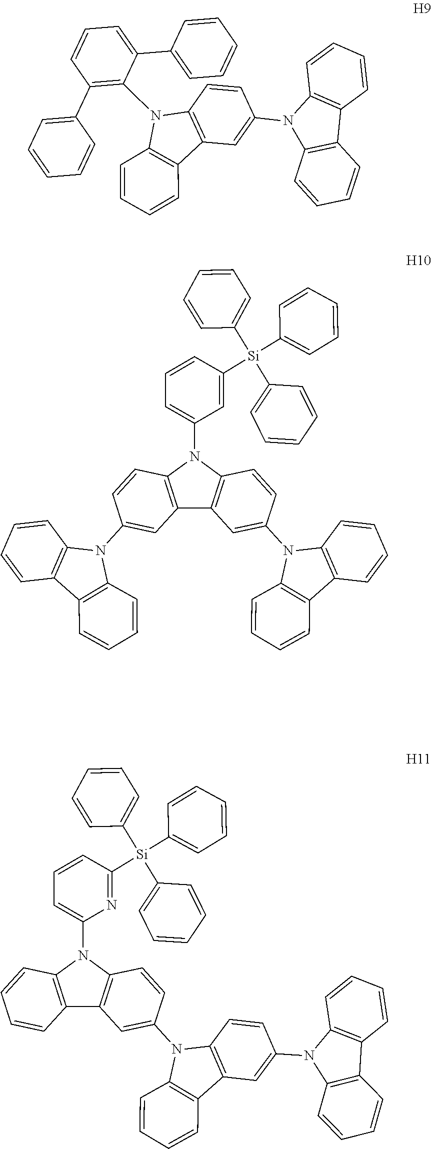

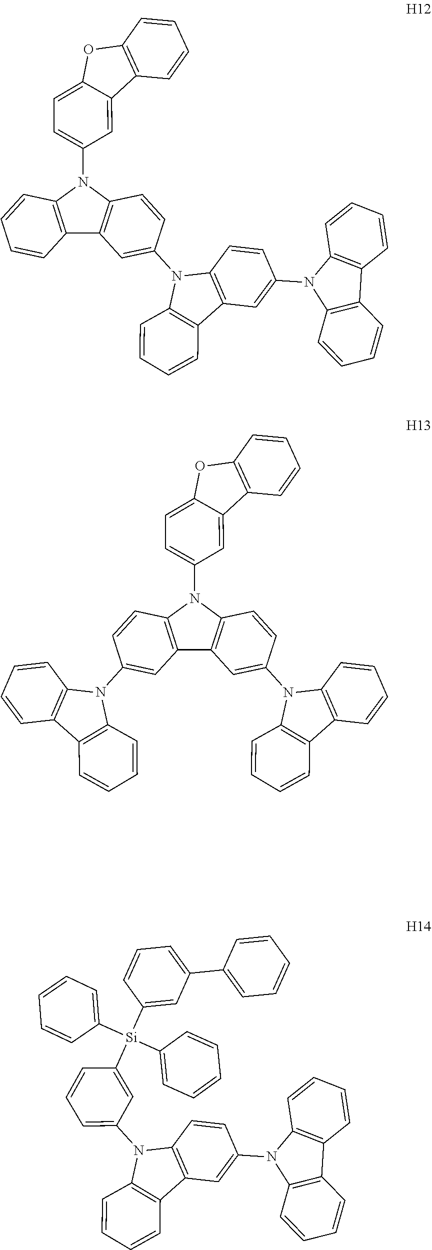

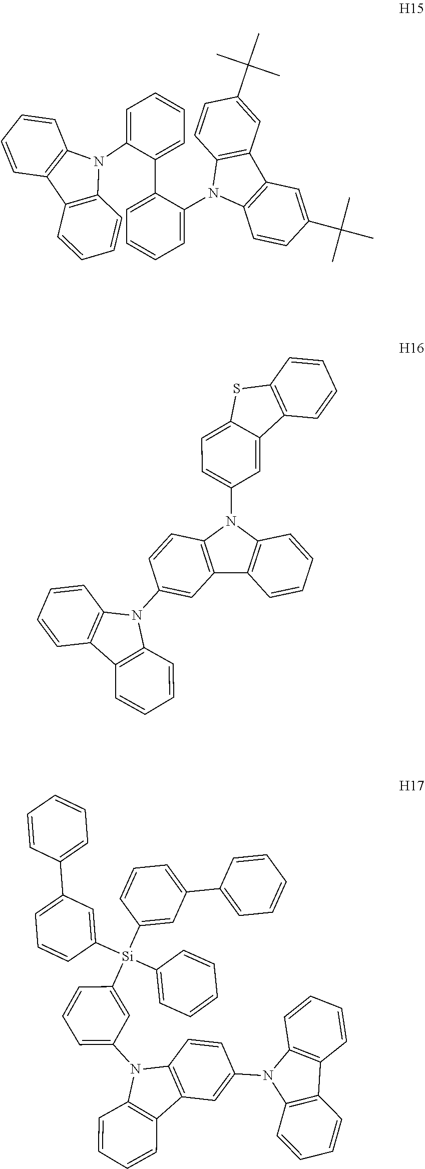

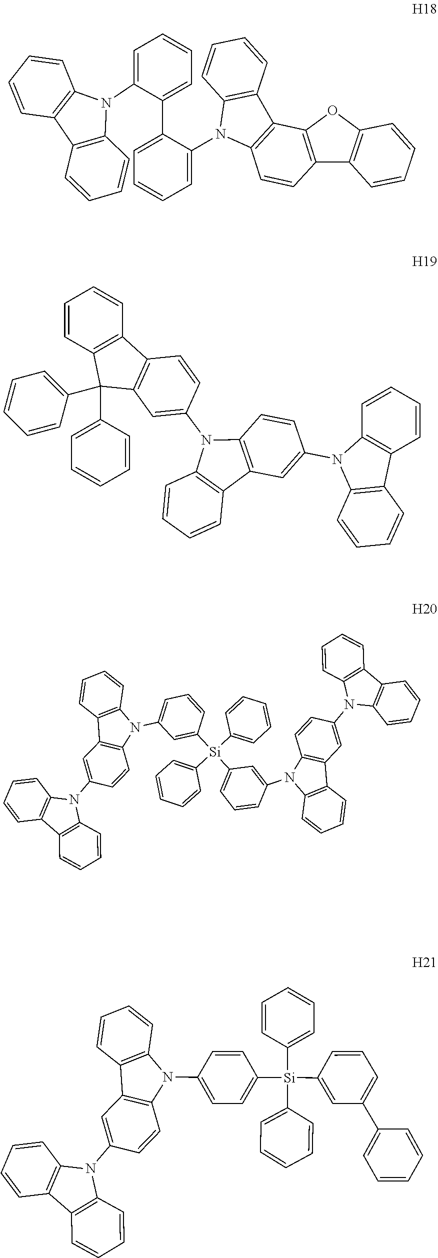

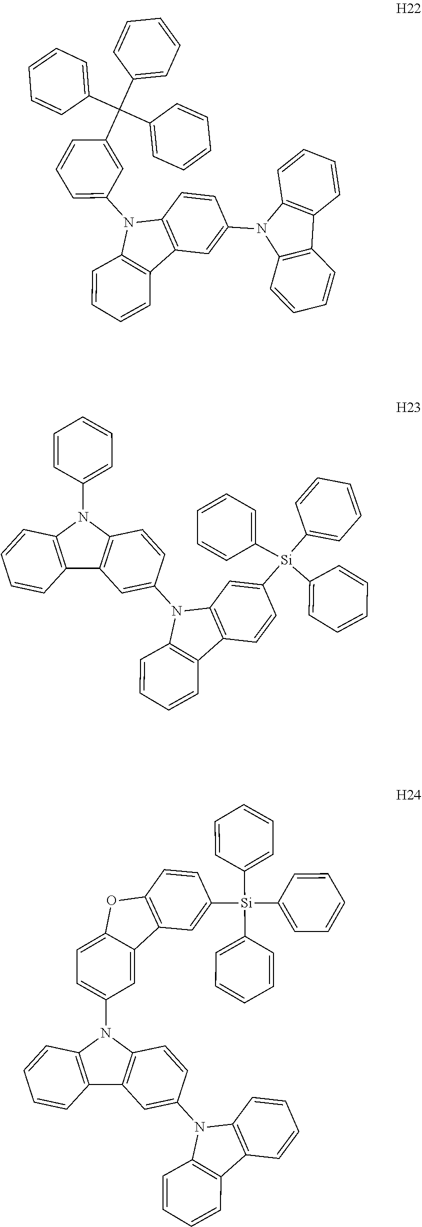

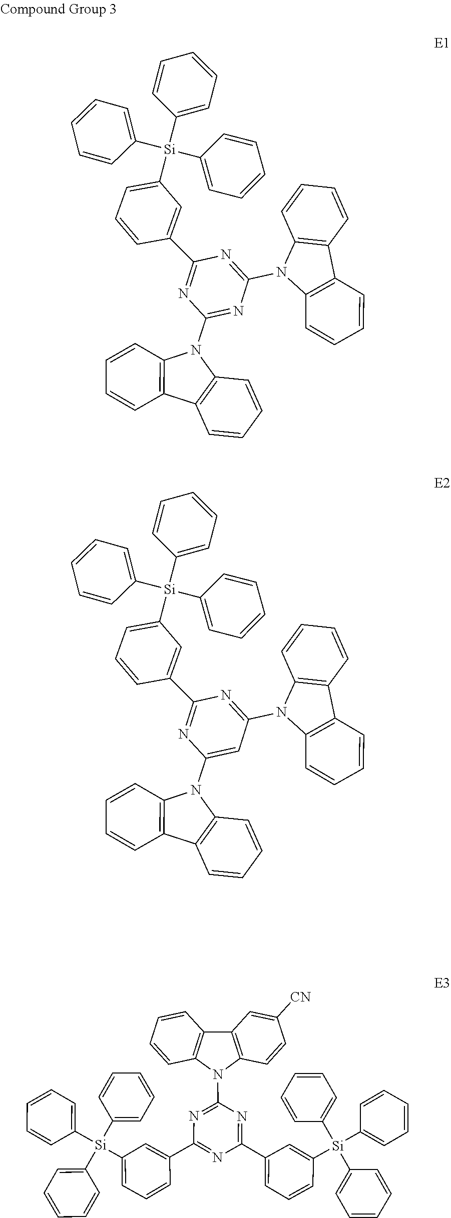 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)cc(-n4c5ccccc5c5ccccc54)n3)c2)cc1 ; N#Cc1ccc2c(c1)c1ccccc1n2-c1nc(-c2cccc([Si](c3ccccc3)(c3ccccc3)c3ccccc3)c2)nc(-c2cccc([Si](c3ccccc3)(c3ccccc3)c3ccccc3)c2)n1]

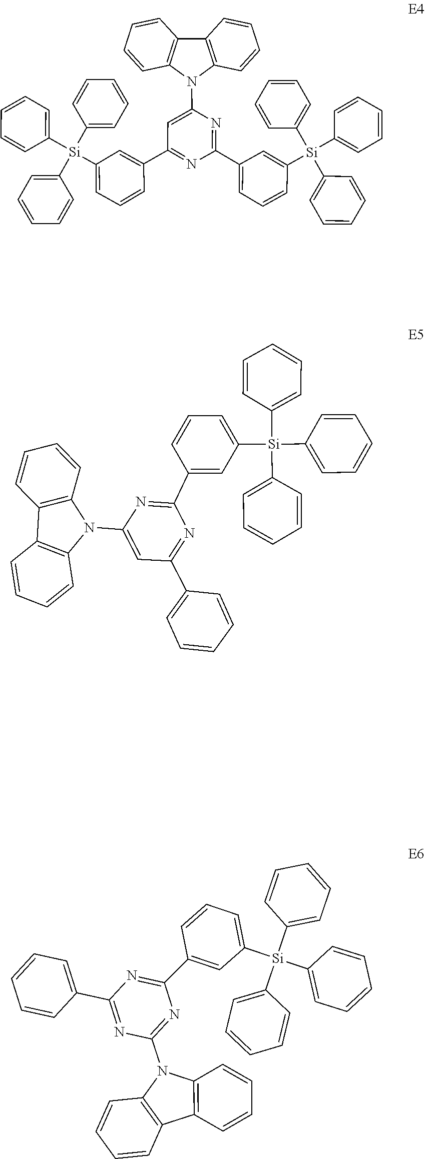 [SMILES: c1ccc([Si](c2ccccc2)(c2ccccc2)c2cccc(-c3cc(-n4c5ccccc5c5ccccc54)nc(-c4cccc([Si](c5ccccc5)(c5ccccc5)c5ccccc5)c4)n3)c2)cc1 ; c1ccc(-c2cc(-n3c4ccccc4c4ccccc43)nc(-c3cccc([Si](c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-n3c4ccccc4c4ccccc43)n2)cc1]

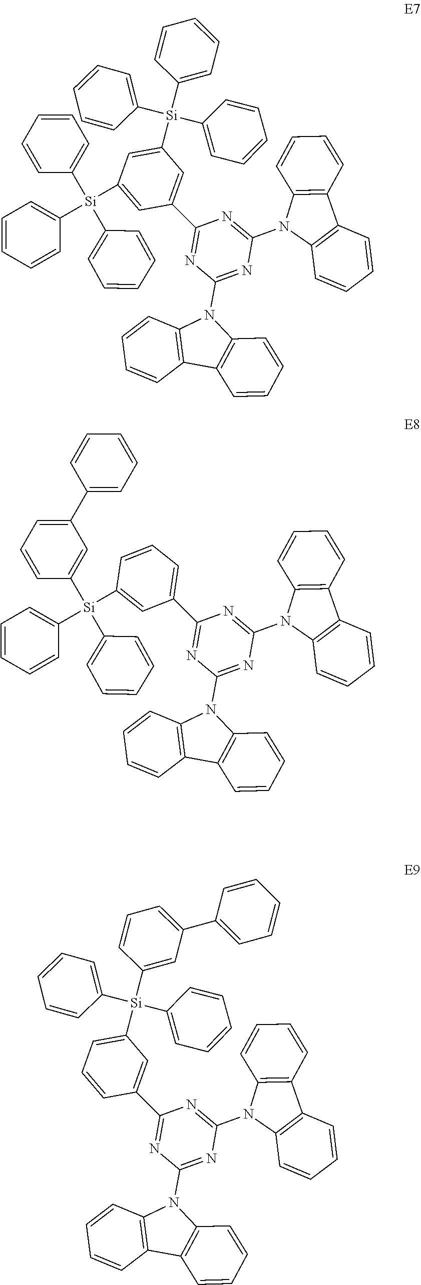 [SMILES: c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1 ; c1ccc(-c2cccc([Si](c3ccccc3)(c3ccccc3)c3cccc(-c4nc(-n5c6ccccc6c6ccccc65)nc(-n5c6ccccc6c6ccccc65)n4)c3)c2)cc1 ; c1ccc(-c2cccc([Si](c3ccccc3)(c3ccccc3)c3cccc(-c4nc(-n5c6ccccc6c6ccccc65)nc(-n5c6ccccc6c6ccccc65)n4)c3)c2)cc1]

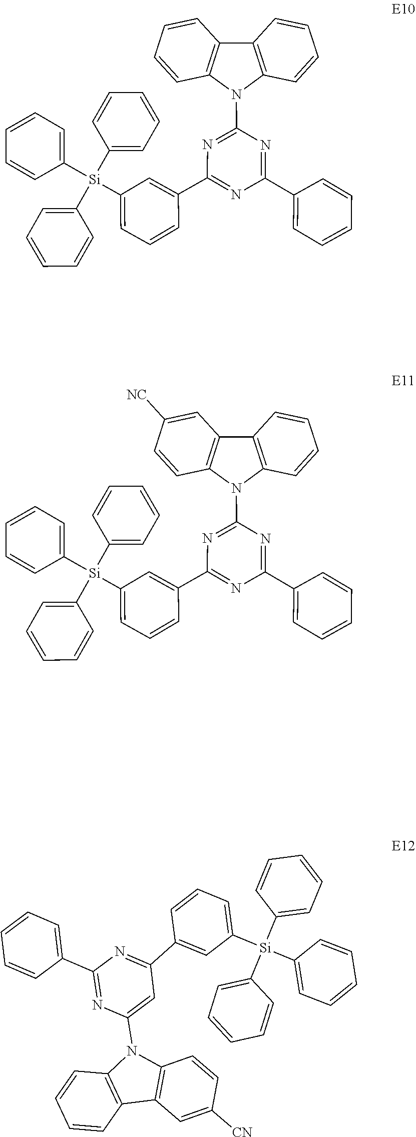 [SMILES: c1ccc(-c2nc(-c3cccc([Si](c4ccccc4)(c4ccccc4)c4ccccc4)c3)nc(-n3c4ccccc4c4ccccc43)n2)cc1 ; N#Cc1ccc2c(c1)c1ccccc1n2-c1nc(-c2ccccc2)nc(-c2cccc([Si](c3ccccc3)(c3ccccc3)c3ccccc3)c2)n1 ; N#Cc1ccc2c(c1)c1ccccc1n2-c1cc(-c2cccc([Si](c3ccccc3)(c3ccccc3)c3ccccc3)c2)nc(-c2ccccc2)n1]

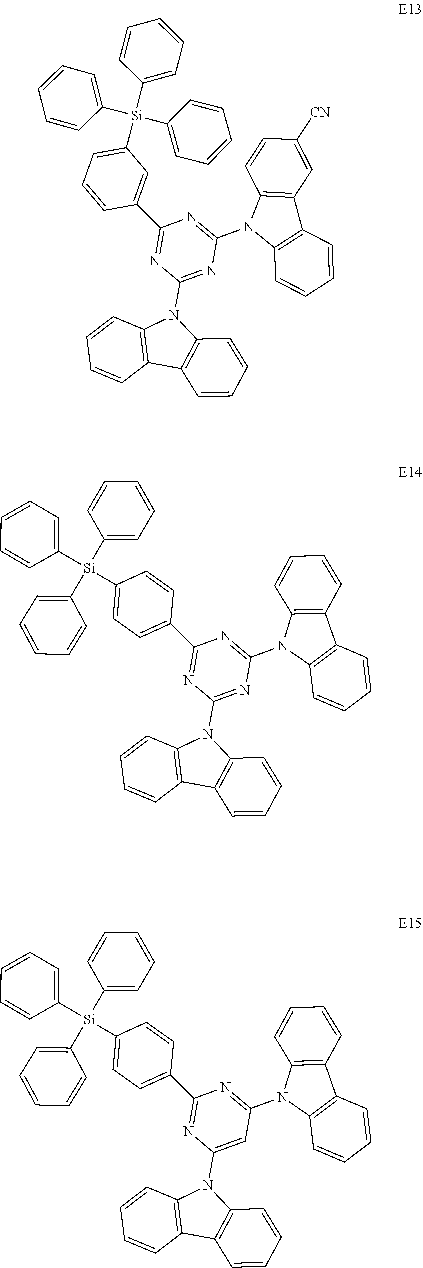 [SMILES: N#Cc1ccc2c(c1)c1ccccc1n2-c1nc(-c2cccc([Si](c3ccccc3)(c3ccccc3)c3ccccc3)c2)nc(-n2c3ccccc3c3ccccc32)n1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)cc(-n4c5ccccc5c5ccccc54)n3)cc2)cc1]

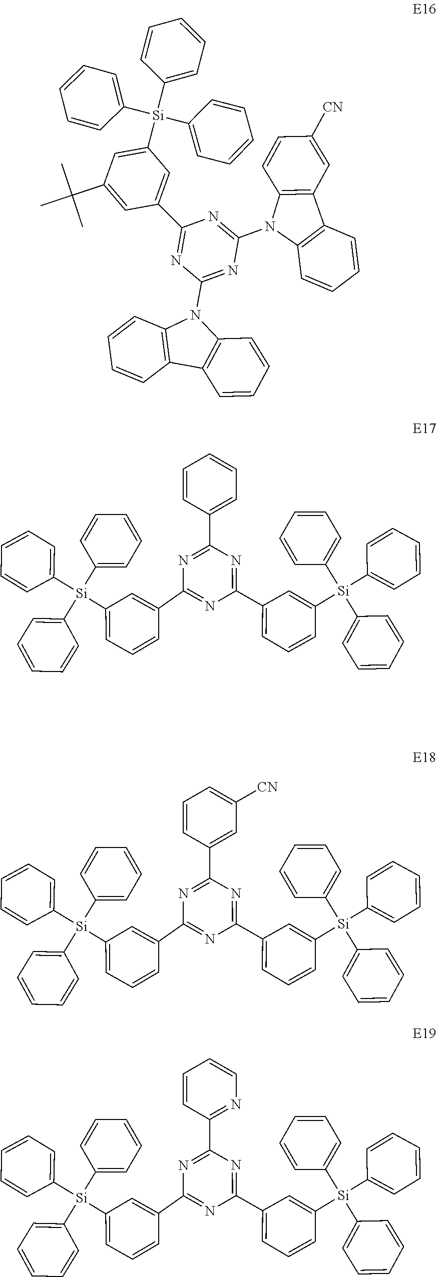 [SMILES: CC(C)(C)c1cc(-c2nc(-n3c4ccccc4c4ccccc43)nc(-n3c4ccccc4c4cc(C#N)ccc43)n2)cc([Si](c2ccccc2)(c2ccccc2)c2ccccc2)c1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; N#Cc1cccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c1 ; c1ccc([Si](c2ccccc2)(c2ccccc2)c2cccc(-c3nc(-c4cccc([Si](c5ccccc5)(c5ccccc5)c5ccccc5)c4)nc(-c4ccccn4)n3)c2)cc1]

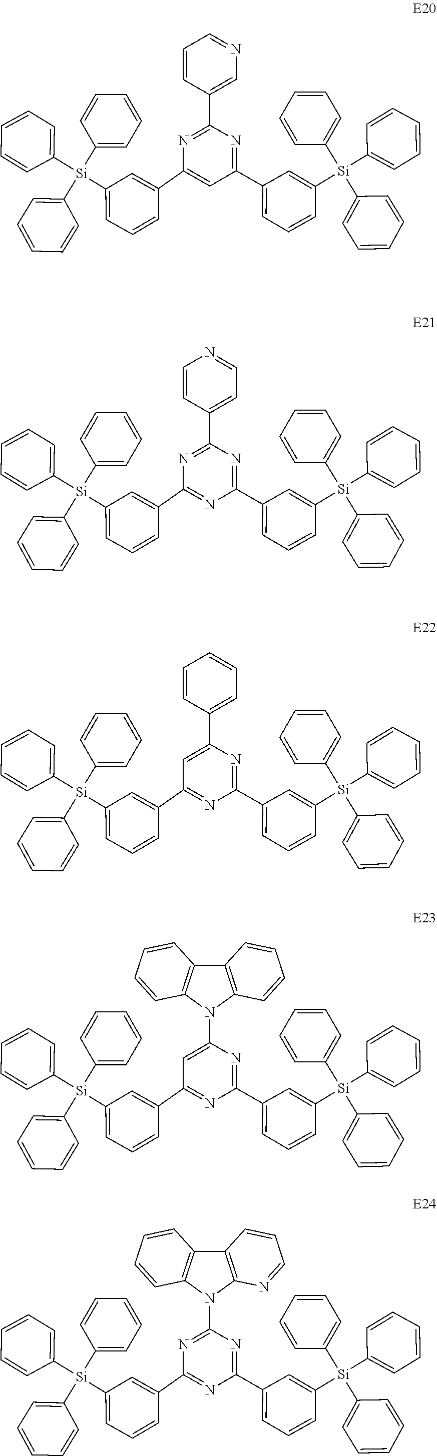

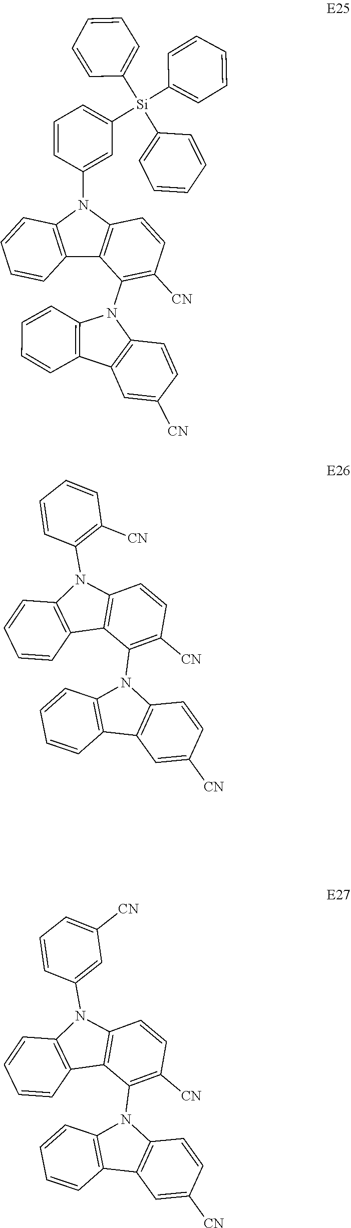 [SMILES: N#Cc1ccc2c(c1)c1ccccc1n2-c1c(C#N)ccc2c1c1ccccc1n2-c1cccc([Si](c2ccccc2)(c2ccccc2)c2ccccc2)c1 ; N#Cc1ccc2c(c1)c1ccccc1n2-c1c(C#N)ccc2c1c1ccccc1n2-c1ccccc1C#N ; N#Cc1cccc(-n2c3ccccc3c3c(-n4c5ccccc5c5cc(C#N)ccc54)c(C#N)ccc32)c1]

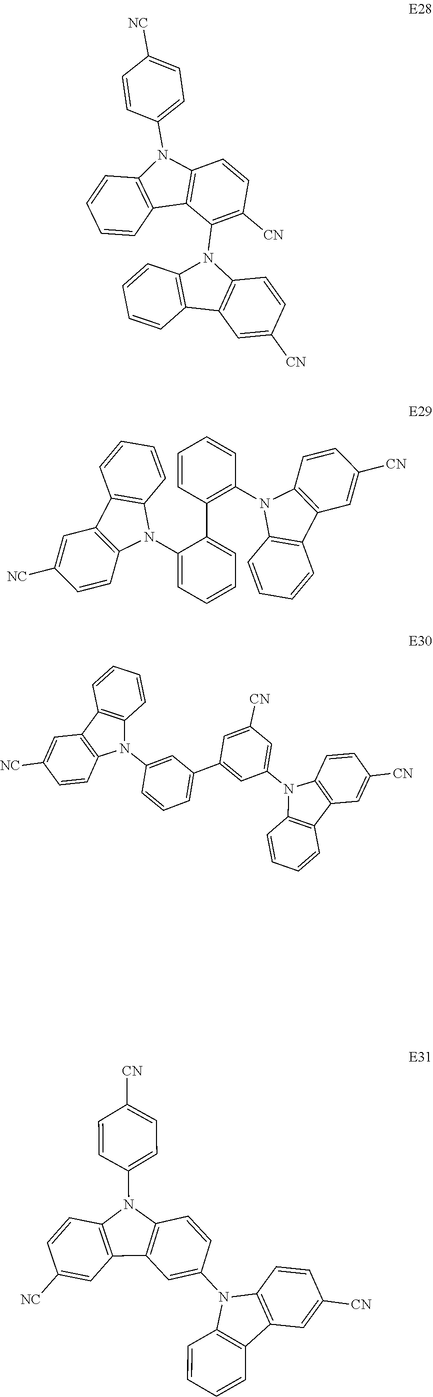 [SMILES: N#Cc1ccc(-n2c3ccccc3c3c(-n4c5ccccc5c5cc(C#N)ccc54)c(C#N)ccc32)cc1 ; N#Cc1ccc2c(c1)c1ccccc1n2-c1ccccc1-c1ccccc1-n1c2ccccc2c2cc(C#N)ccc21 ; N#Cc1cc(-c2cccc(-n3c4ccccc4c4cc(C#N)ccc43)c2)cc(-n2c3ccccc3c3cc(C#N)ccc32)c1 ; N#Cc1ccc(-n2c3ccc(C#N)cc3c3cc(-n4c5ccccc5c5cc(C#N)ccc54)ccc32)cc1]

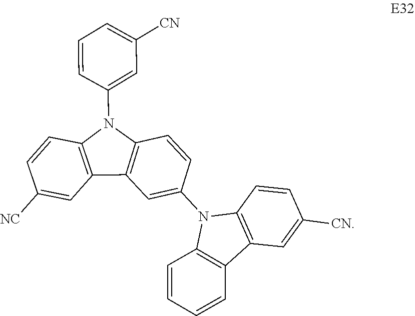 [SMILES: N#Cc1cccc(-n2c3ccc(C#N)cc3c3cc(-n4c5ccccc5c5cc(C#N)ccc54)ccc32)c1]

14. An organometallic compound represented by Formula 1: 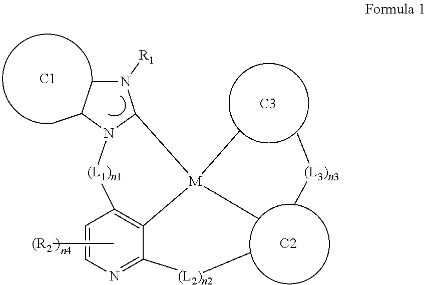
wherein in Formula 1,
M is Pt, Pd, Cu, Ag, Au, Rh, Ir, Ru or Os,
rings C1 to C3 are each independently a substituted or unsubstituted hydrocarbon ring of 5 to 60 ring-forming carbon atoms, or a substituted or unsubstituted heterocycle of 2 to 60 ring-forming carbon atoms,
L₁ to L₃ are each independently a direct linkage, *—O—*′, *—S—*′, *—C(R₁₁)(R₁₂)—*′, *—C(R₁₃)═*′, *═C(R₁₄)—*′, *—C(R₁₅)═C(R₁₆)—*′, *—C(═O)—*′, *—C(═S)—*′, *—C≡C—*′, *—B(R₁₇)—*′, *—N(R₁₈)—*′, *—P(R₁₉)—*′, *—Si(R₂₀)(R₂₁)—*′, *—P(R₂₂)(R₂₃)—*′ or *—Ge(R₂₄)(R₂₅)*′,
R₁ is a hydrogen atom, a deuterium atom, a halogen atom, a substituted or unsubstituted thio group, a substituted or unsubstituted oxy group, a substituted or unsubstituted boron group, a substituted or unsubstituted amine group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₂, and R₁₁ to R₂₅ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
n1 to n3 are each independently an integer from 1 to 3, and
n4 is an integer from 0 to 2.

15. The organometallic compound of claim 14, wherein the organometallic compound represented by Formula 1 is represented by Formula 2: 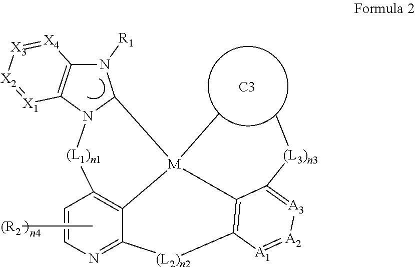
wherein in Formula 2,
X₁ to X₄, and A₁ to A₃ are each independently N or CR₃,
R₃ is a hydrogen atom, a deuterium atom, a halogen atom, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
M, C3, L₁ to L₃, R₁, R₂, and n1 to n4 are the same as defined in Formula 1.

16. The organometallic compound of claim 15, wherein the organometallic compound represented by Formula 2 is represented by Formula 3: 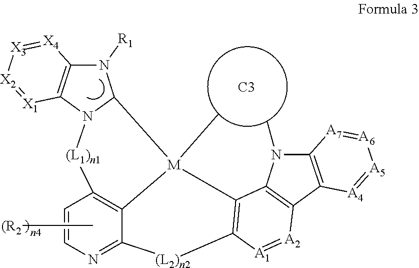
wherein Formula 3,
A₄ to A₇ are each independently N or CR₄,
R₄ is a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
M, C3, L₁, L₂, X₁ to X₄, R₁, R₂, n1, n2, n4, A₁, and A₂ are the same as defined in Formula 1 and Formula 2.

17. The organometallic compound of claim 15, wherein the organometallic compound represented by Formula 2 is represented by Formula 4: 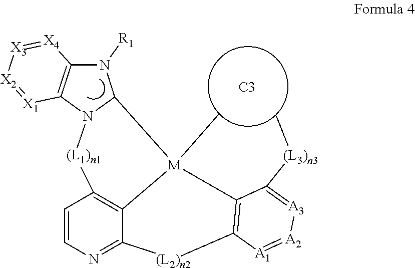
wherein in Formula 4,
M, C3, L₁ to L₃, R₁, X₁ to X₄, n1 to n3, and A₁ to A₃ are the same as defined in Formula 1 and Formula 2.

18. The organometallic compound of claim 15, wherein the organometallic compound represented by Formula 2 is represented by any one selected from among Formula 5-1 to Formula 5-3: 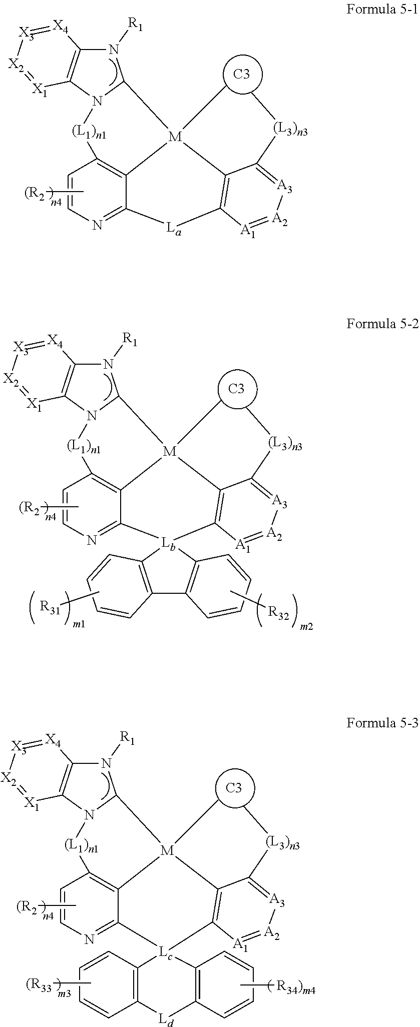
wherein in Formula 5-1 to Formula 5-3,
Lₐ is *—O—*′, *—S—*′, *—C(R₃₅)(R₃₆)*′, *—N(R₃₇)—*′, or *—Si(R₃₈)(R₃₉)—*′,
L_{b}, and L_{c} are each independently C or Si,
L_{d} is *—O—*′, or *—S—*′,
R₃₁ to R₃₉ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m1 to m4 are each independently an integer from 0 to 4, and
M, C3, L₁, L₃, X₁ to X₄, R₁, R₂, n1, n3, n4, and A₁ to A₃ are the same as defined in Formula 1 and Formula 2.

19. The organometallic compound of claim 15, wherein the organometallic compound represented by Formula 2 is represented by Formula 6-1 or Formula 6-2: 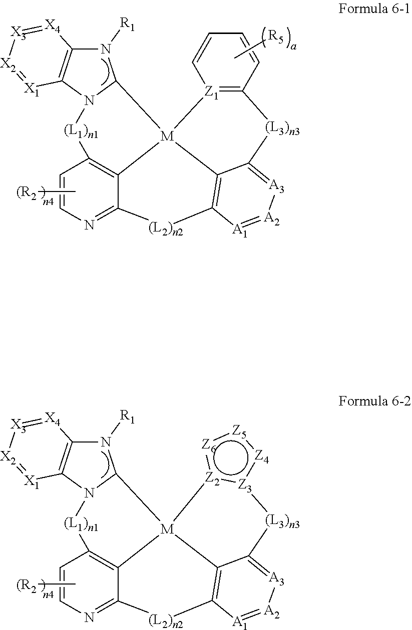
Wherein in Formula 6-1 and Formula 6-2,
Z₁ to Z₃ are each independently N or C,
Z₄ to Z₆ are each independently N, NR₆, CR₇, O, or S,
R₅ is a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₆ and R₇ are each independently a hydrogen atom, a deuterium atom, a halogen atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
“a” is an integer from 0 to 4, and
M, L₁ to L₃, X₁ to X₄, R₁, R₂, n1 to n4, and A₁ to A₃ are the same as defined in Formula 1 and Formula 2.

20. The organometallic compound of claim 14, wherein the organometallic compound represented by Formula 1 comprises at least one selected from among compounds represented in Compound Group 1: 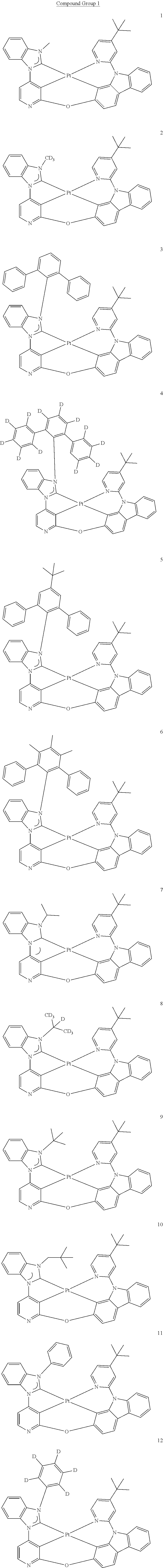 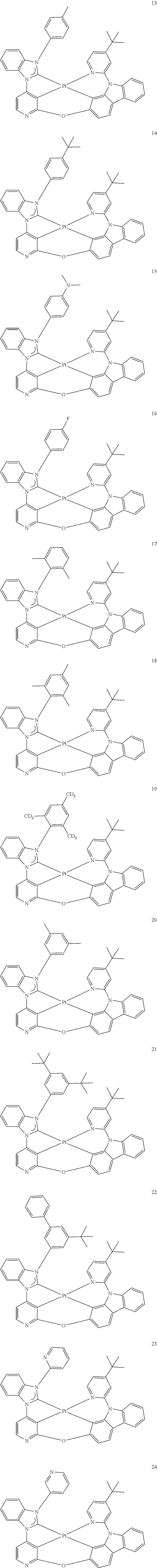 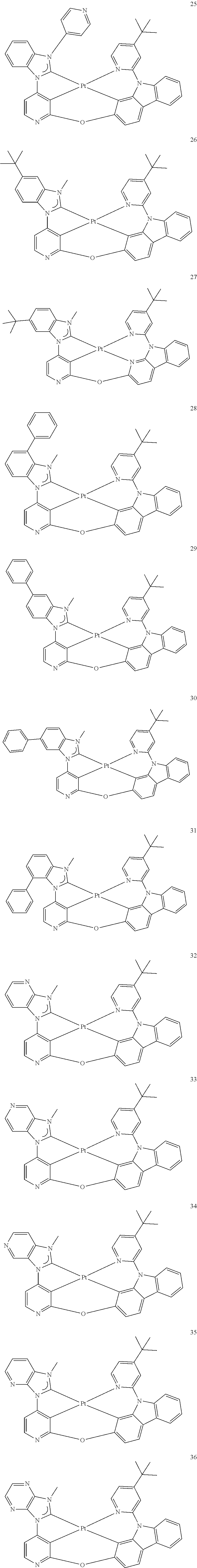 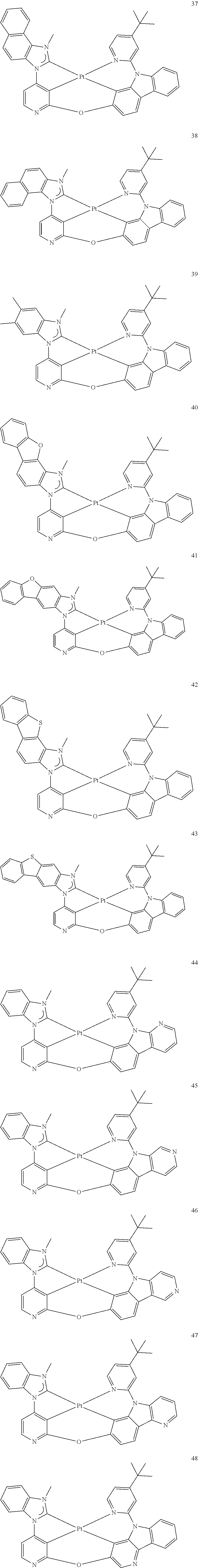 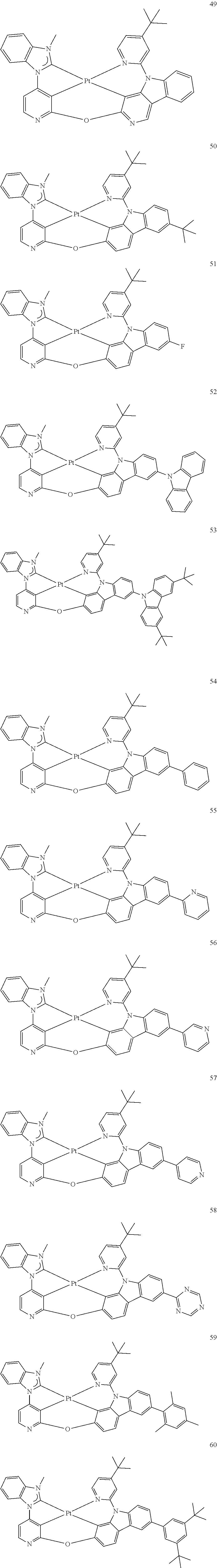 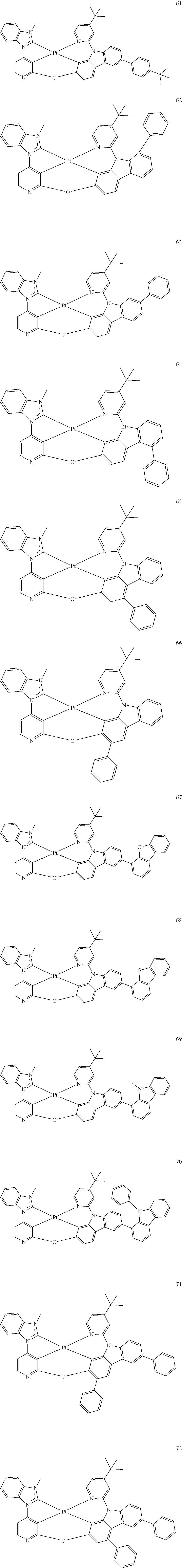 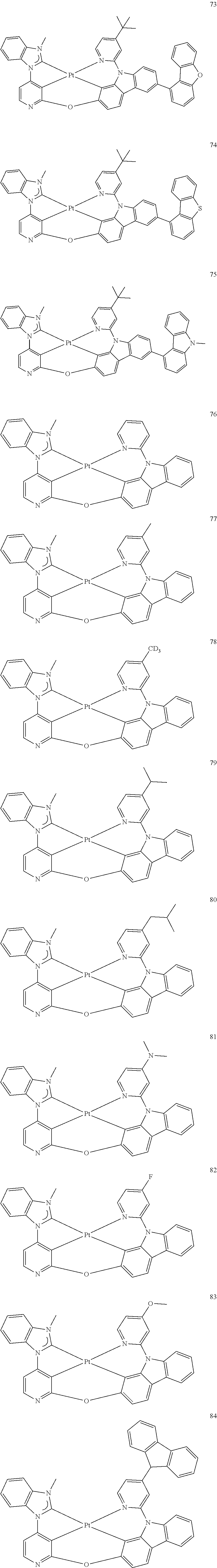 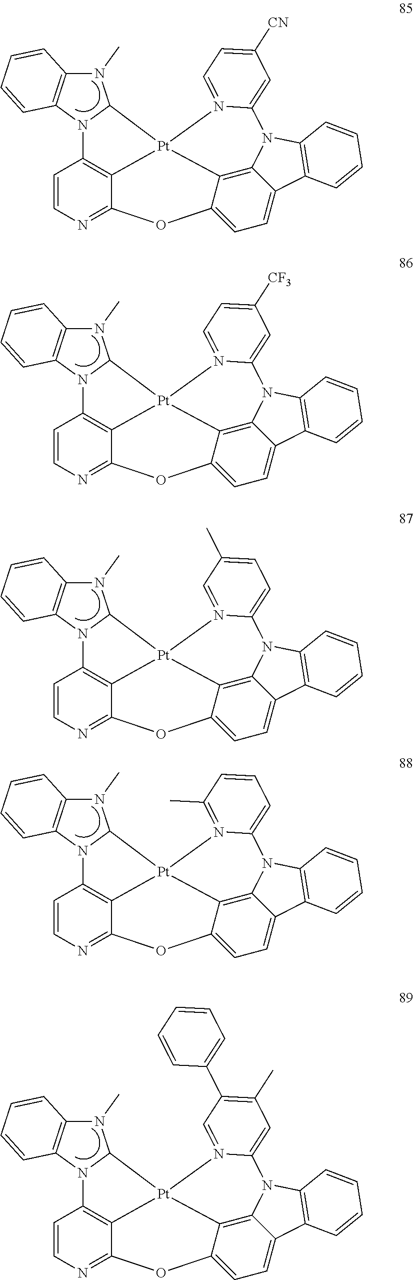 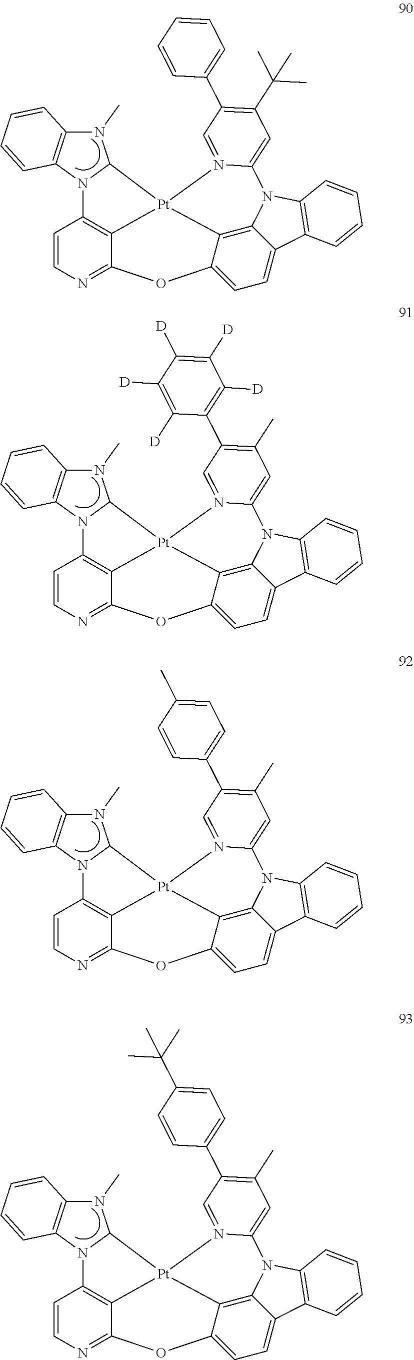 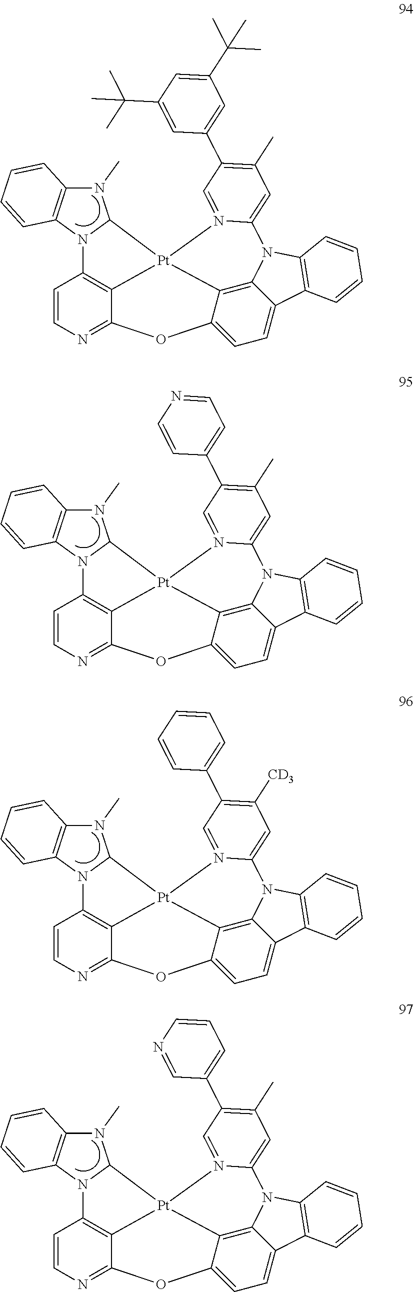 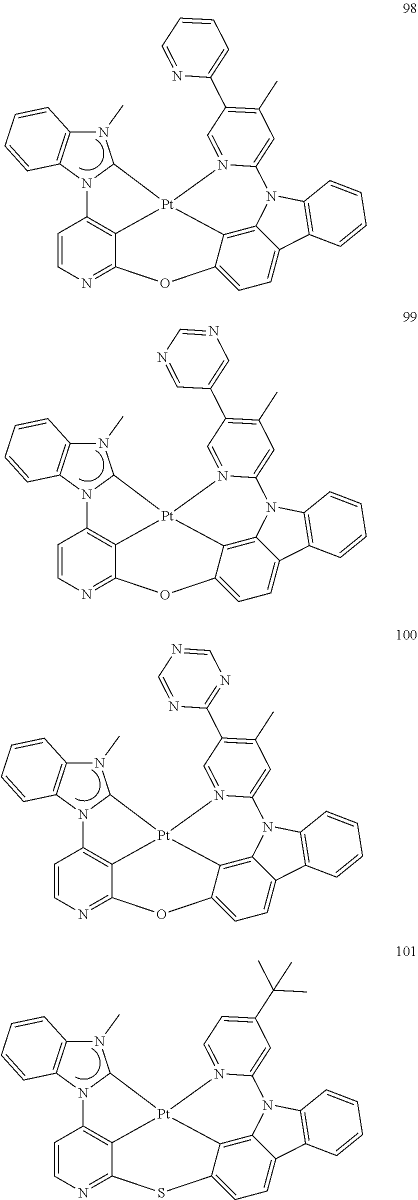 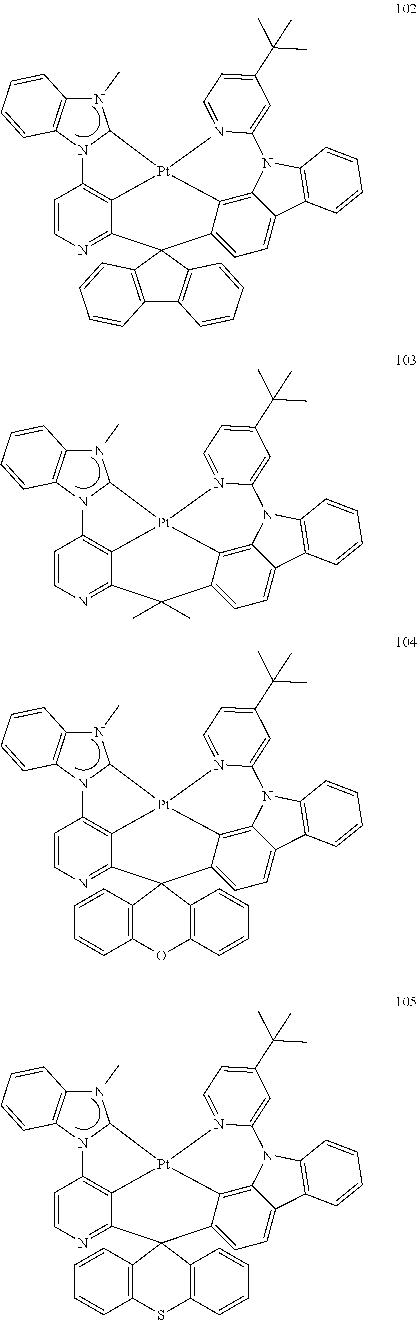 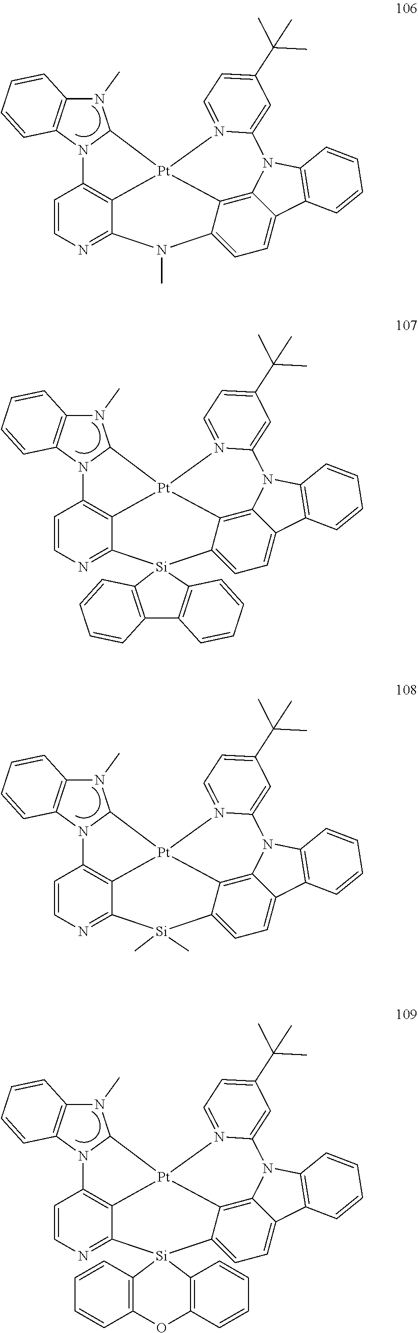 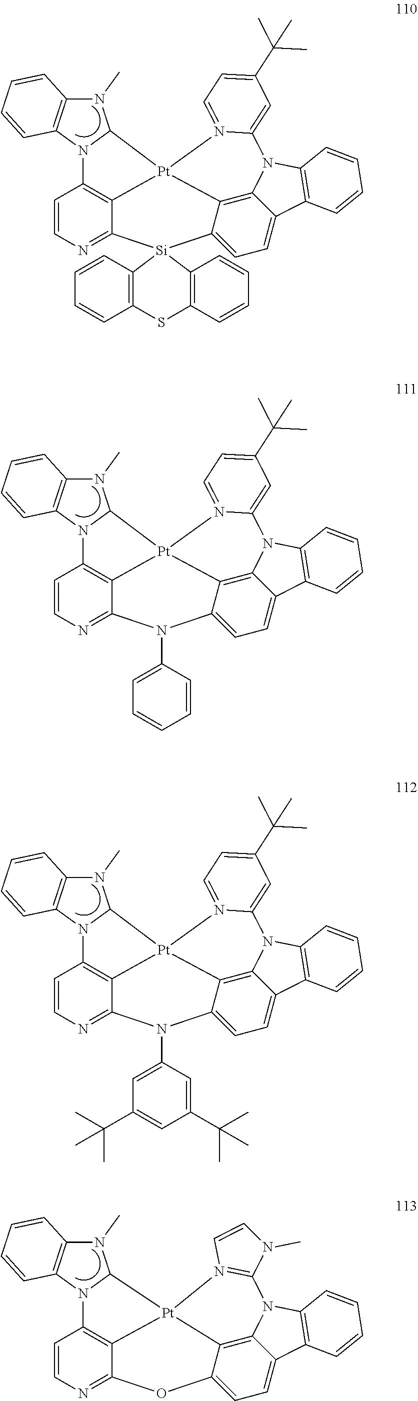 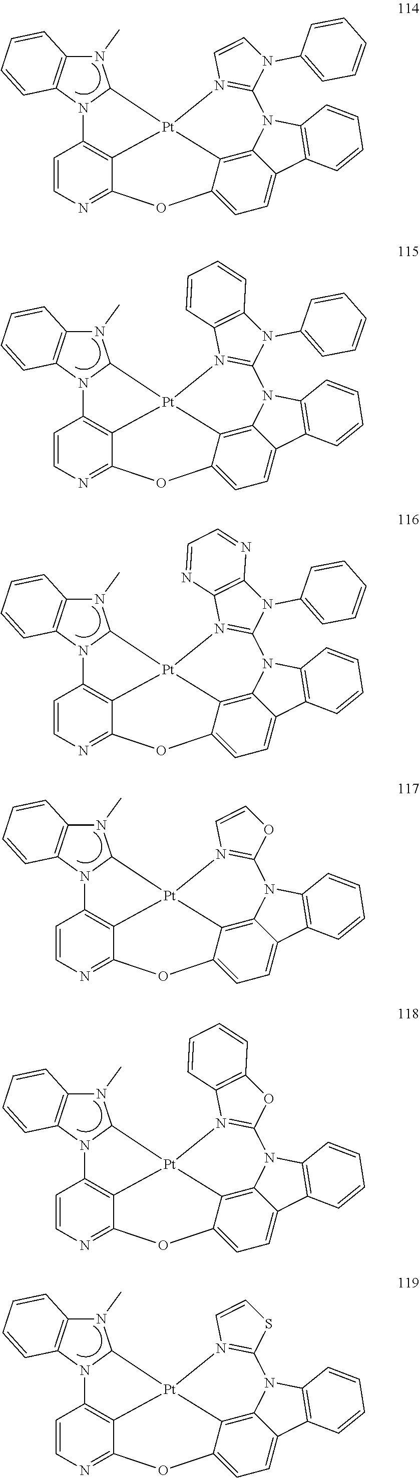 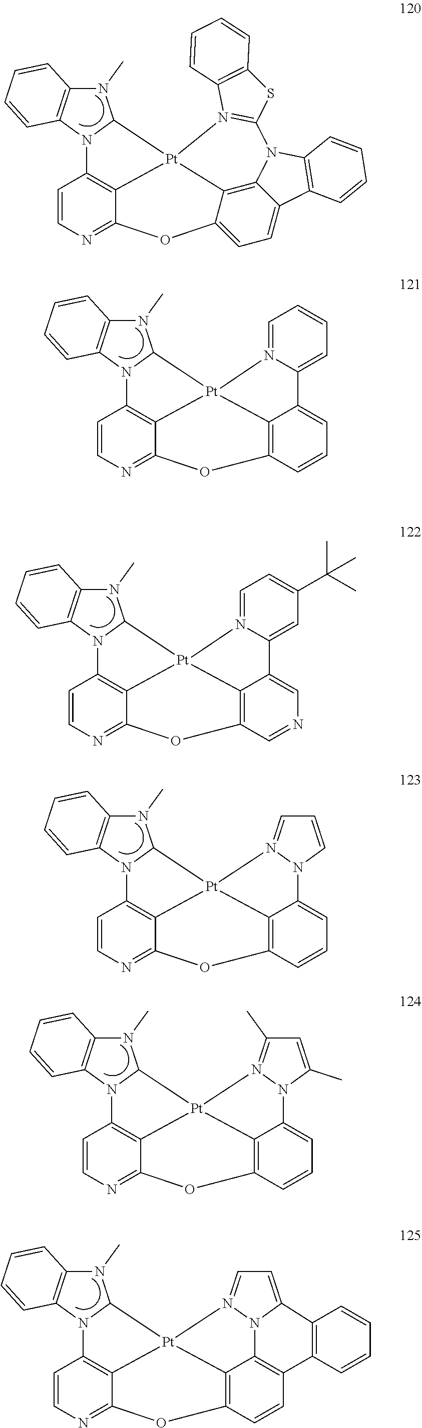 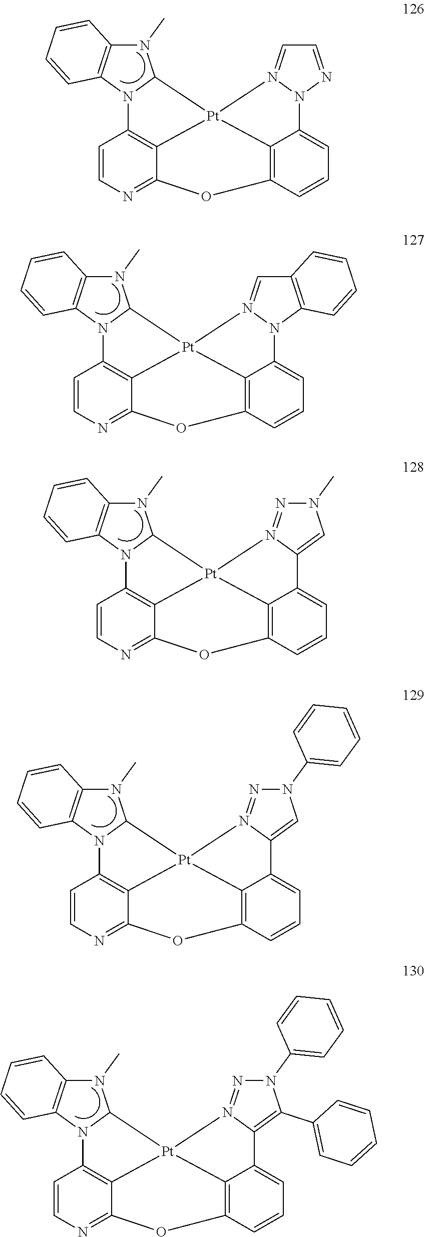 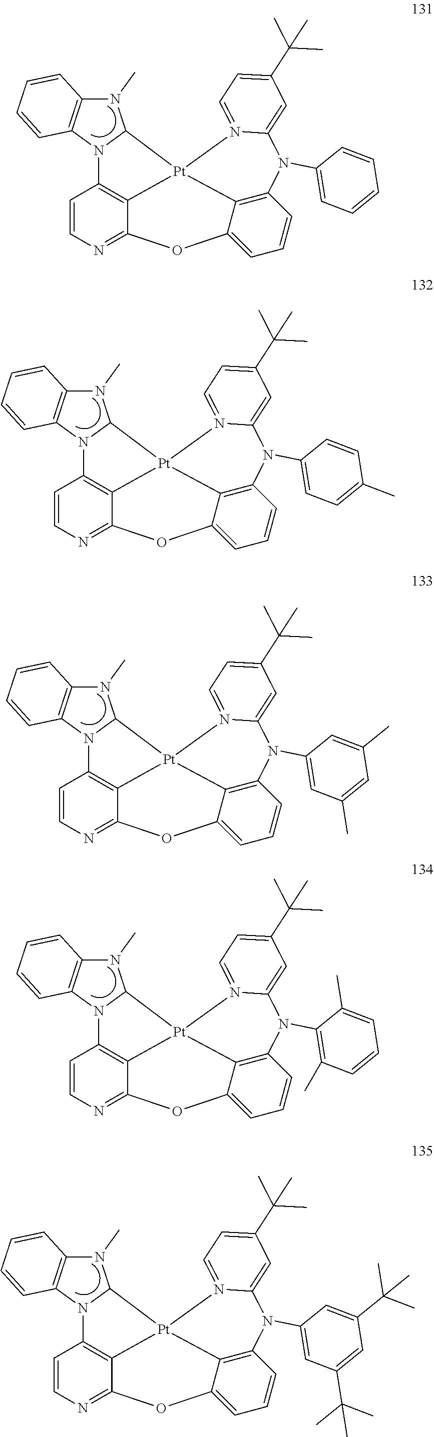 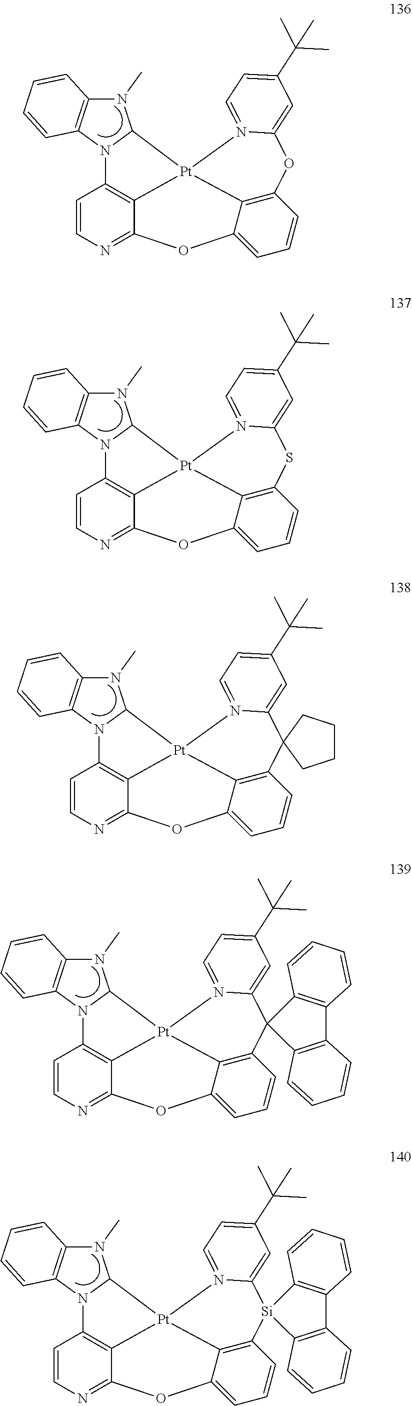 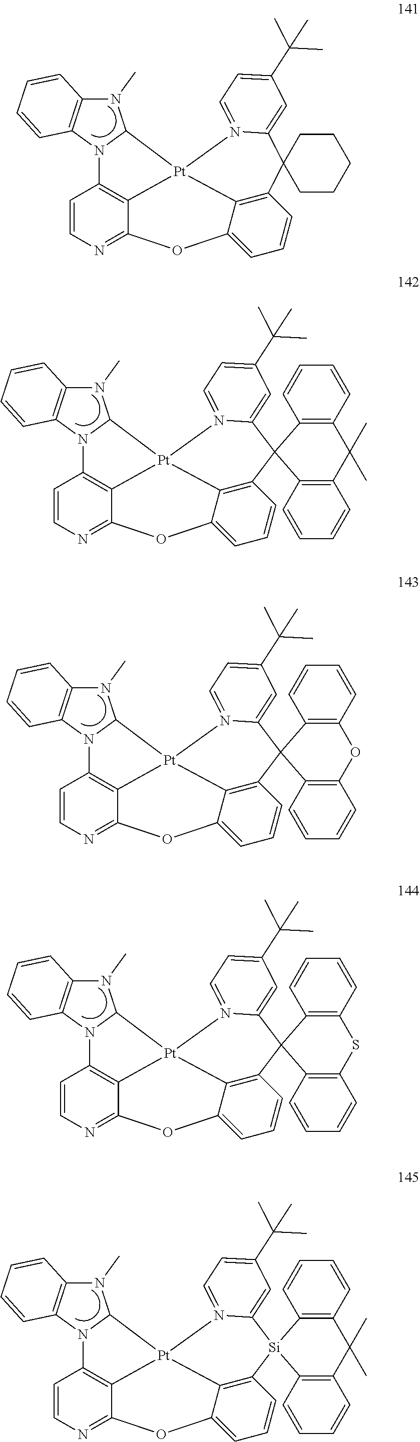 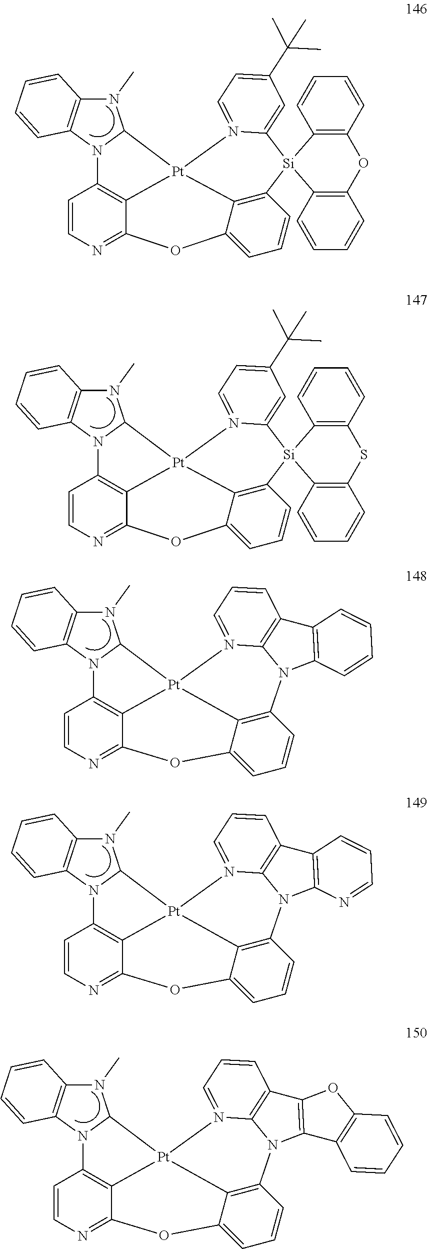 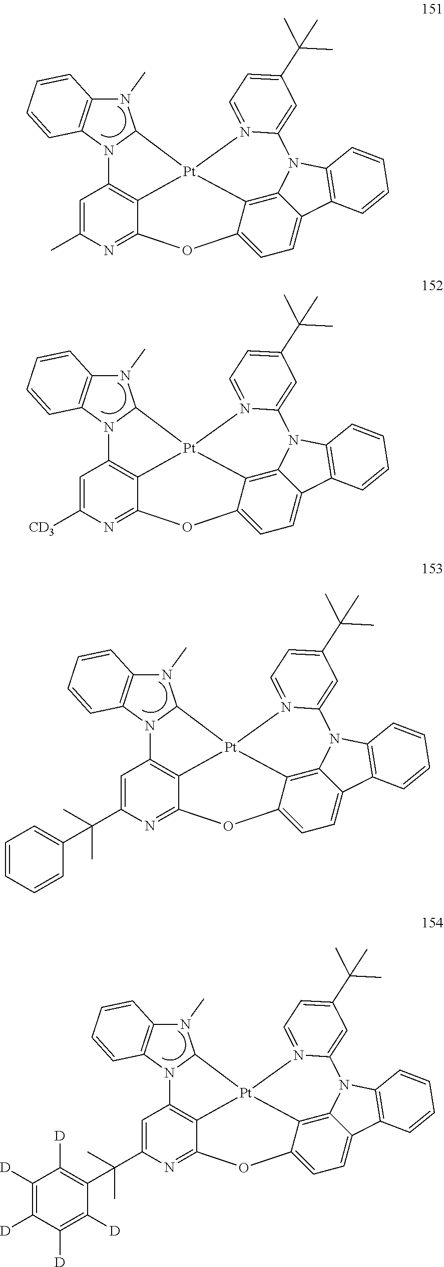 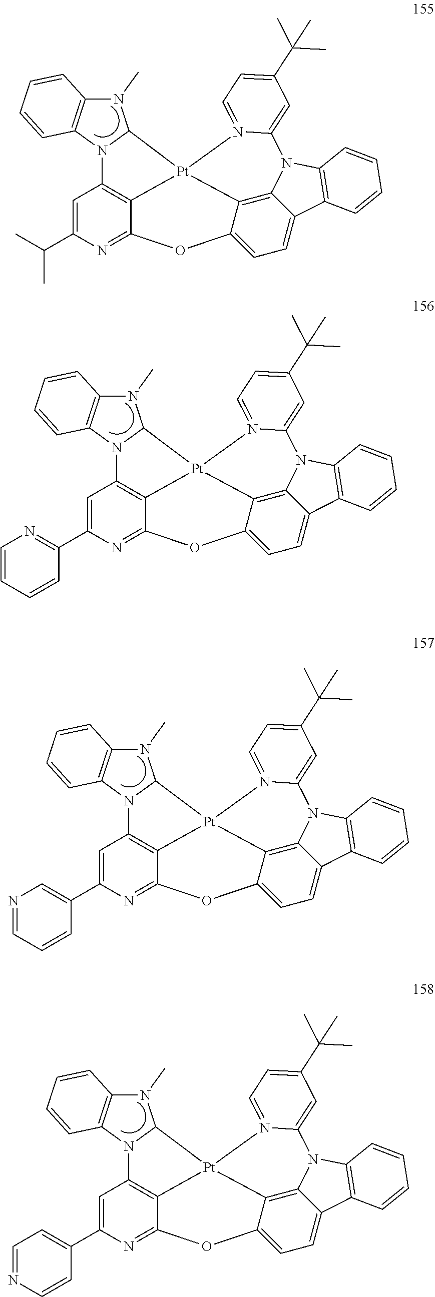 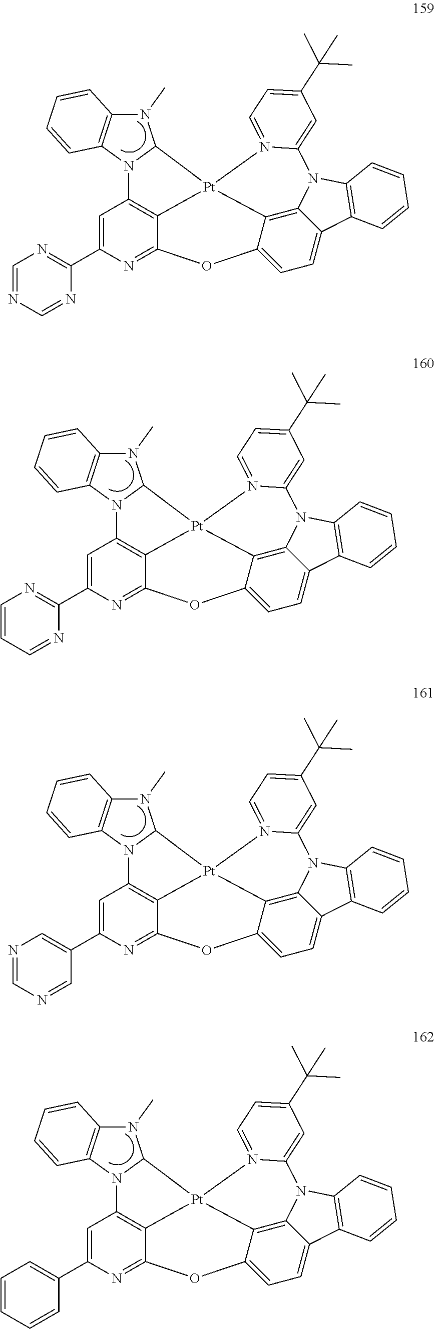 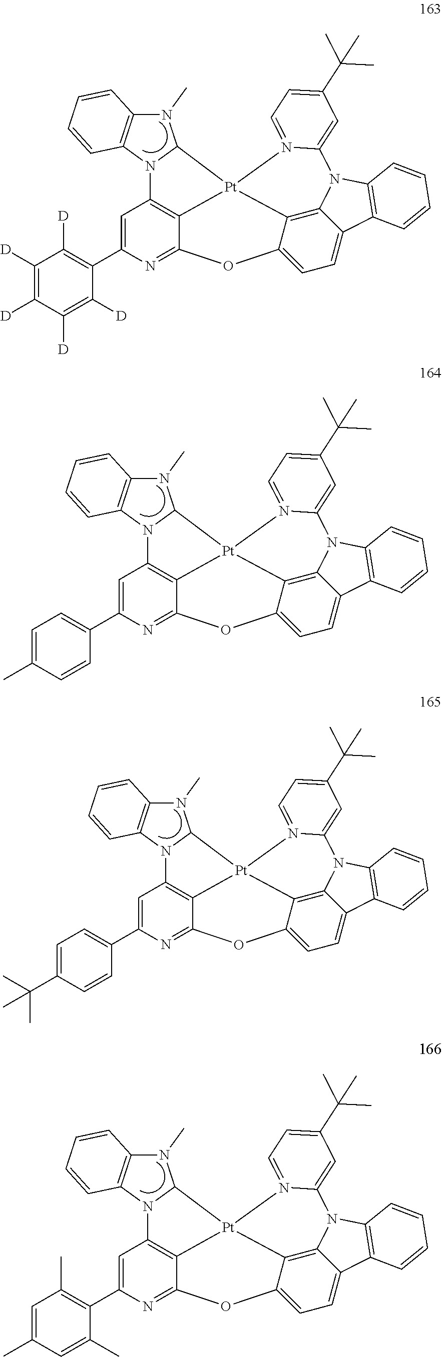 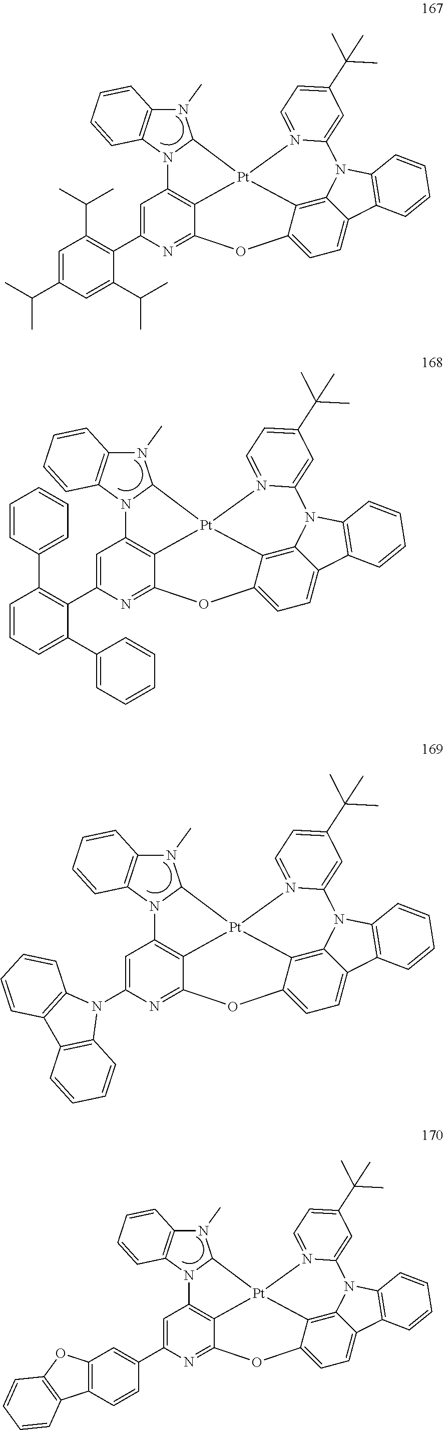 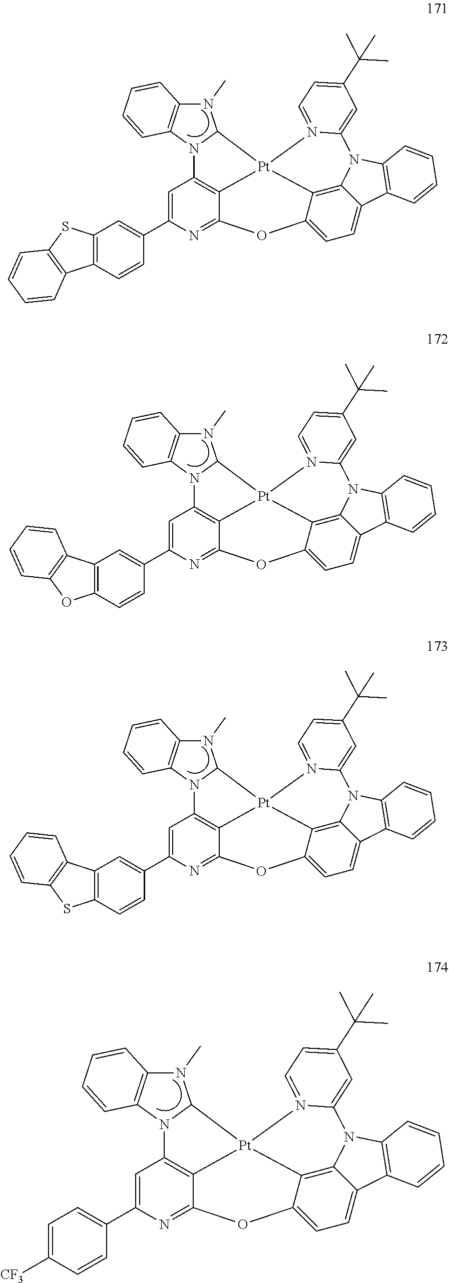 [chemical structure]
